(19) United States
(12) Patent Application Publication
(10) Pub. No.: US 2022/0006013 A1
(43) Pub. Date: Jan. 6, 2022

(54) ORGANOELECTROLUMINESCENT DEVICE USING POLYCYCLIC AROMATIC COMPOUNDS

(71) Applicant: SFC CO., LTD., Cheongju-si (KR)

(72) Inventors: Sung-hoon JOO, Cheongju-si (KR); Bong-ki SHIN, Cheongju-si (KR); Byung-sun YANG, Cheongju-si (KR); Ji-hwan KIM, Cheongju-si (KR); Hyeon-jun JO, Cheongju-si (KR); Sung-eun CHOI, Cheongju-si (KR)

(73) Assignee: SFC CO., LTD., Cheongju-si (KR)

(21) Appl. No.: 17/198,430

(22) Filed: Mar. 11, 2021

(30) Foreign Application Priority Data
Mar. 2, 2020 (KR) 10-2020-0026186

(51) Int. Cl. H01L 51/00; C07F 5/02; C09K 11/06

(52) U.S. Cl. CPC H01L 51/008; C07F 5/027; H01L 51/5012; H01L 51/009; C09K 11/06

(57) ABSTRACT

Disclosed is a polycyclic aromatic compound that can be employed in an organic layer of an organic electroluminescent device. Also disclosed is an organic electroluminescent device including the polycyclic aromatic compound. The use of the polycyclic aromatic compound significantly improves the luminous efficiency of the device and ensures high efficiency and long lifetime of the device.

### BACKGROUND OF THE INVENTION

### 1. Field of the Invention

The present invention relates to a highly efficient and long-lasting organic electroluminescent device with significantly improved luminous efficiency using a polycyclic aromatic compound.

### 2. Description of the Related Art

Organic electroluminescent devices are self-luminous devices in which electrons injected from an electron injecting electrode (cathode) recombine with holes injected from a hole injecting electrode (anode) in a light emitting layer to form excitons, which emit light while releasing energy. Such organic electroluminescent devices have the advantages of low driving voltage, high luminance, large viewing angle, and short response time and can be applied to full-color light emitting flat panel displays. Due to these advantages, organic electroluminescent devices have received attention as next-generation light sources.

The above characteristics of organic electroluminescent devices are achieved by structural optimization of organic layers of the devices and are supported by stable and efficient materials for the organic layers, such as hole injecting materials, hole transport materials, light emitting materials, electron transport materials, electron injecting materials, and electron blocking materials. However, more research still needs to be done to develop structurally optimized structures of organic layers for organic electroluminescent devices and stable and efficient materials for organic layers of organic electroluminescent devices.

Thus, there is a continued need to develop structures of organic electroluminescent devices optimized to improve their luminescent properties and new materials capable of supporting the optimized structures of organic electroluminescent devices.

### SUMMARY OF THE INVENTION

Therefore, the present invention intends to provide a highly efficient and long-lasting organic electroluminescent device including a light emitting layer in which novel compounds are employed to allow the device to be driven at a low voltage and have a high external quantum efficiency and significantly improved life characteristics.

One aspect of the present invention provides an organic electroluminescent device including a first electrode, a second electrode opposite to the first electrode, and a light emitting layer interposed between the first and second electrodes.

The light emitting layer includes (i) a compound represented by Formula A-1:

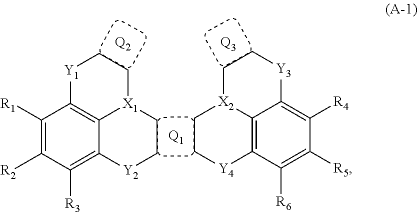

and/or

a compound represented by Formula A-2:

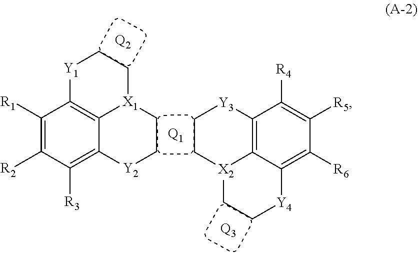

and

(ii) a compound represented by Formula B:

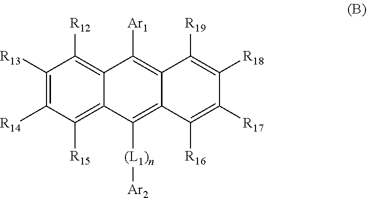

A description will be given concerning the structures of the compounds of Formulae A-1, A-2, and B, the definitions of the substituents in the compounds. A description will also be given concerning exemplary compounds that can be represented by Formulae A-1, A-2, and B.

The organic electroluminescent device of the present invention incudes a light emitting layer that employs the polycyclic aromatic compound represented by Formula A-1 and/or A-2 as a dopant compound in combination with the compound represented by Formula B as a host compound to allow the device to be driven at a low voltage and have a high external quantum efficiency and significantly improved life characteristics. The use of the dopant and host compounds also ensures high efficiency and long lifetime of the organic electroluminescent device.

### DETAILED DESCRIPTION OF THE INVENTION

The present invention will now be described in more detail.

One aspect of the present invention provides an organic electroluminescent device including a first electrode, a second electrode opposite to the first electrode, and a light emitting layer interposed between the first and second electrodes wherein the light emitting layer includes (i) a polycyclic aromatic compound represented by Formula A-1:

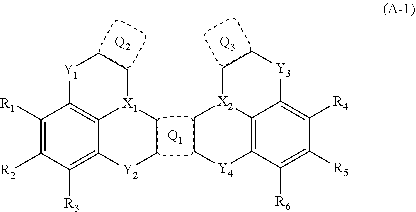

wherein Q₁ to Q₃ are identical to or different from each other and are each independently a substituted or unsubstituted C₆-C₅₀ aromatic hydrocarbon ring or a substituted or unsubstituted C₂-C₅₀ heteroaromatic ring, X₁ and X₂ are identical to or different from each other and are each independently selected from B, P, and P═O, Y₁ to Y₄ are identical to or different from each other and are each independently selected from NR₇, CR₈R₉, O, S, Se, and SiR₁₀R₁₁, R₁ to R₁₁ are identical to or different from each other and are each independently selected from hydrogen, deuterium, substituted or unsubstituted C₁-C₃₀ alkyl, substituted or unsubstituted C₆-C₅₀ aryl, substituted or unsubstituted C₃-C₃₀ cycloalkyl, substituted or unsubstituted C₂-C₅₀ heteroaryl, substituted or unsubstituted C₁-C₃₀ alkoxy, substituted or unsubstituted C₆-C₃₀ aryloxy, substituted or unsubstituted C₁-C₃₀ alkylthioxy, substituted or unsubstituted C₅-C₃₀ arylthioxy, substituted or unsubstituted C₁-C₃₀ alkylamine, substituted or unsubstituted C₅-C₃₀ arylamine, substituted or unsubstituted C₁-C₃₀ alkylsilyl, substituted or unsubstituted C₅-C₃₀ arylsilyl, nitro, cyano, and halogen, with the proviso that R₁ and R₂ are optionally linked to each other to form an alicyclic or aromatic monocyclic or polycyclic ring, R₂ and R₃ are optionally linked to each other to form an alicyclic or aromatic monocyclic or polycyclic ring, R₄ and R₅ are optionally linked to each other to form an alicyclic or aromatic monocyclic or polycyclic ring, and R₅ and R₆ are optionally linked to each other to form an alicyclic or aromatic monocyclic or polycyclic ring, and/or

a compound represented by Formula A-2:

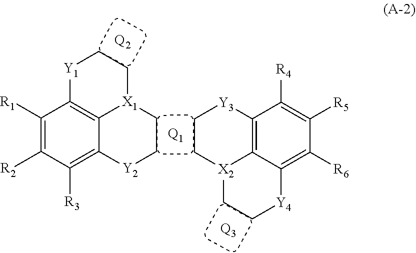

wherein Q₁ to Q₃, X₁, X₂, Y₁ to Y₄, and R₁ to R₁₁ are as defined in Formula A-1, as a dopant compound, and

(ii) a compound represented by Formula B:

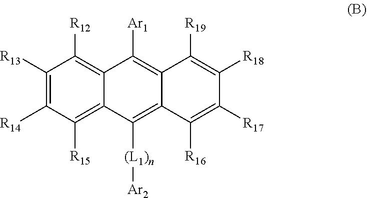

wherein R₁₂ to R₁₉ are identical to or different from each other and are each independently selected from hydrogen, deuterium, substituted or unsubstituted C₁-C₃₀ alkyl, substituted or unsubstituted C₆-C₅₀ aryl, substituted or unsubstituted C₂-C₅₀ heteroaryl, substituted or unsubstituted C₁-C₃₀ alkylsilyl, substituted or unsubstituted C₅-C₃₀ arylsilyl, cyano, and halogen, Ar₁ and Ar₂ are identical to or different from each other and are each independently selected from substituted or unsubstituted C₆-C₅₀ aryl and substituted or unsubstituted C₂-C₅₀ heteroaryl, L₁ is a single bond or is selected from substituted or unsubstituted C₆-C₂₀ arylene and substituted or unsubstituted C₂-C₂₀ heteroarylene, n is an integer from 1 to 3, provided that when n is 2 or more, the linkers L₁ are identical to or different from each other, as a host compound.

The structural features of the dopant and host compounds ensure high efficiency and long lifetime of the organic electroluminescent device.

According to one embodiment of the present invention, each of R₇ to R₁₁ may be optionally bonded to Q₁, Q₂, Q₃, R₁, R₂, R₃, R₄, R₅ or R₆ to form an alicyclic or aromatic monocyclic or polycyclic ring.

According to one embodiment of the present invention, R₈ and R₉ may be optionally linked to each other to form an alicyclic or aromatic monocyclic or polycyclic ring and R₁₀ and R₁₁ may be optionally linked to each other to form an alicyclic or aromatic monocyclic or polycyclic ring.

According to one embodiment of the present invention, Q₁ in each of Formulae A-1 and A-2 is represented by one of the following structures 1 to 8:

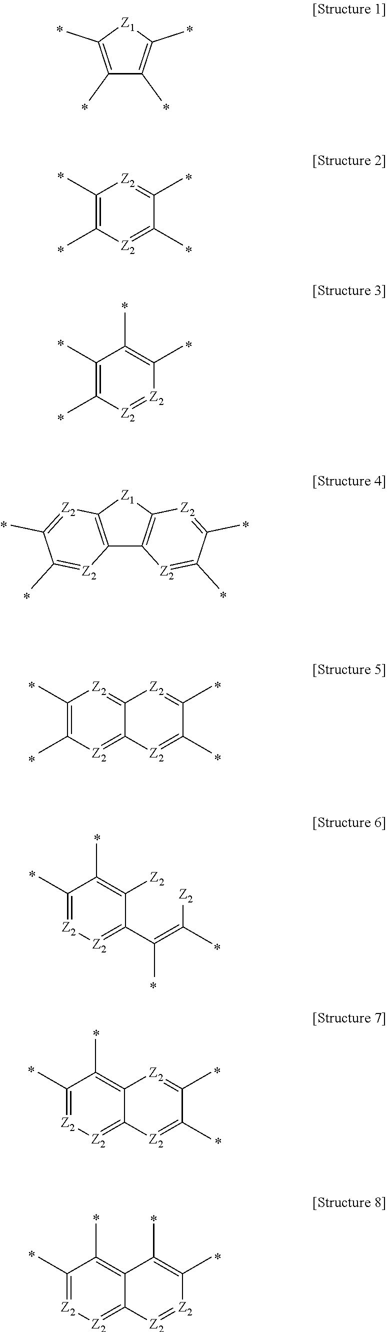

wherein each Z₁ is O, S, CRR′ or SiRR′, the moieties Z₂ are identical to or different from each other and are each independently CR″ or N, R, R′, and R″ are identical to or different from each other and are each independently selected from hydrogen, deuterium, substituted or unsubstituted C₁-C₃₀ alkyl, substituted or unsubstituted C₆-C₅₀ aryl, substituted or unsubstituted C₃-C₃₀ cycloalkyl, substituted or unsubstituted C₂-C₅₀ heteroaryl, substituted or unsubstituted C₁-C₃₀ alkoxy, substituted or unsubstituted C₆-C₃₀ aryloxy, substituted or unsubstituted C₁-C₃₀ alkylthioxy, substituted or unsubstituted C₅-C₃₀ arylthioxy, substituted or unsubstituted C₁-C₃₀ alkylamine, substituted or unsubstituted C₅-C₃₀ arylamine, substituted or unsubstituted C₁-C₃₀ alkylsilyl, substituted or unsubstituted C₅-C₃₀ arylsilyl, nitro, cyano, and halogen, and the asterisks (*) indicate sites at which Q₁ is bonded to X₁, X₂, Y₂, and Y₄ in Formula A-1 or X₁, X₂, Y₂, and Y₃ in Formula A-2.

According to one embodiment of the present invention, Q₂ and Q₃ in each of Formulae A-1 and A-2 are each independently represented by one of the following structures 9 to 13:

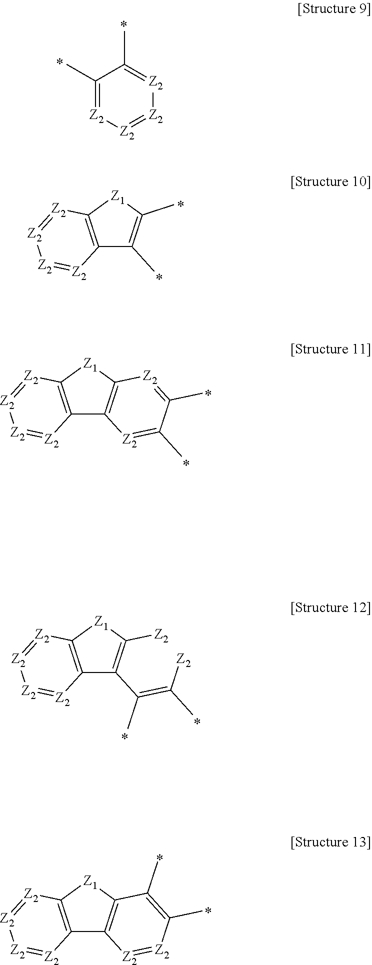

wherein each Z₁ is O, S, CRR′ or SiRR′, the moieties Z₂ are identical to or different from each other and are each independently CR″ or N, R, R′, and R″ are identical to or different from each other and are each independently selected from hydrogen, deuterium, substituted or unsubstituted C₁-C₃₀ alkyl, substituted or unsubstituted C₆-C₅₀ aryl, substituted or unsubstituted C₃-C₃₀ cycloalkyl, substituted or unsubstituted C₂-C₅₀ heteroaryl, substituted or unsubstituted C₁-C₃₀ alkoxy, substituted or unsubstituted C₆-C₃₀ aryloxy, substituted or unsubstituted C₁-C₃₀ alkylthioxy, substituted or unsubstituted C₅-C₃₀ arylthioxy, substituted or unsubstituted C₁-C₃₀ alkylamine, substituted or unsubstituted C₅-C₃₀ arylamine, substituted or unsubstituted C₁-C₃₀ alkylsilyl, substituted or unsubstituted C₅-C₃₀ arylsilyl, nitro, cyano, and halogen, and the asterisks (*) indicate sites at which Q₂ is bonded to X₁ and Y₁ and Q₃ is bonded to X₂ and Y₃ in Formula A-1 or Q₂ is bonded to X₁ and Y₁ and Q₃ is bonded to X₂ and Y₄ in Formula A-2.

According to one embodiment of the present invention, the host compound may be represented by Formula B-1:

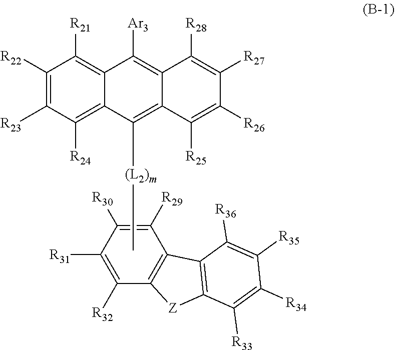

wherein R₂₁ to R₃₆ are identical to or different from each other and are each independently selected from hydrogen, deuterium, substituted or unsubstituted C₁-C₃₀ alkyl, substituted or unsubstituted C₃-C₃₀ cycloalkyl, substituted or unsubstituted C₆-C₅₀ aryl, substituted or unsubstituted C₂-C₅₀ heteroaryl, substituted or unsubstituted C₁-C₃₀ alkylsilyl, substituted or unsubstituted C₅-C₃₀ arylsilyl, cyano, and halogen, Ar₃ is substituted or unsubstituted C₆-C₅₀ aryl or substituted or unsubstituted C₂-C₅₀ heteroaryl, Z is an oxygen (O) or sulfur (S) atom, L₂ is a single bond or is substituted or unsubstituted C₆-C₂₀ arylene or substituted or unsubstituted C₂-C₂₀ heteroarylene, m is an integer from 1 to 3, provided that when m is 2 or more, the linkers L₂ are identical to or different from each other.

As used herein, the term “substituted” in the definition of Q₁ to Q₃, R, R′, R″, L₁, L₂, Ar₁ to Ar₃, R₁ to R₃₆, etc. indicates substitution with one or more substituents selected from the group consisting of deuterium, cyano, halogen, hydroxyl, nitro, C₁-C₂₄ alkyl, C₃-C₂₄ cycloalkyl, C₁-C₂₄ haloalkyl, C₁-C₂₄ alkenyl, C₁-C₂₄ alkynyl, C₁-C₂₄ heteroalkyl, C₁-C₂₄ heterocycloalkyl, C₆-C₂₄ aryl, C₆-C₂₄ arylalkyl, C₂-C₂₄ heteroaryl, C₂-C₂₄ heteroarylalkyl, C₁-C₂₄ alkoxy, C₁-C₂₄ alkylamino, C₁-C₂₄ arylamino, C₁-C₂₄ heteroarylamino, C₁-C₂₄ alkylsilyl, C₁-C₂₄ arylsilyl, and C₁-C₂₄ aryloxy, or a combination thereof. The term “unsubstituted” in the same definition indicates having no substituent.

In the “substituted or unsubstituted C₁-C₁₀ alkyl”, “substituted or unsubstituted C₆-C₃₀ aryl”, etc., the number of carbon atoms in the alkyl or aryl group indicates the number of carbon atoms constituting the unsubstituted alkyl or aryl moiety without considering the number of carbon atoms in the substituent(s). For example, a phenyl group substituted with a butyl group at the para-position corresponds to a C₆ aryl group substituted with a C₄ butyl group.

As used herein, the expression “form a ring with an adjacent substituent” means that the corresponding substituent combines with an adjacent substituent to form a substituted or unsubstituted alicyclic or aromatic ring and the term “adjacent substituent” may mean a substituent on an atom directly attached to an atom substituted with the corresponding substituent, a substituent disposed sterically closest to the corresponding substituent or another substituent on an atom substituted with the corresponding substituent. For example, two substituents substituted at the ortho position of a benzene ring or two substituents on the same carbon in an aliphatic ring may be considered “adjacent” to each other.

In the present invention, the alkyl groups may be straight or branched. The number of carbon atoms in the alkyl groups is not particularly limited but is preferably from 1 to 20. Specific examples of the alkyl groups include, but are not limited to, methyl, ethyl, propyl, n-propyl, isopropyl, butyl, n-butyl, isobutyl, tert-butyl, sec-butyl, 1-methylbutyl, 1-ethylbutyl, pentyl, n-pentyl, isopentyl, neopentyl, tert-pentyl, hexyl, n-hexyl, 1-methylpentyl, 2-methylpentyl, 4-methyl-2-pentyl, 3,3-dimethylbutyl, 2-ethylbutyl, heptyl, n-heptyl, 1-methylhexyl, cyclopentylmethyl, cyclohexylmethyl, octyl, n-octyl, tert-octyl, 1-methylheptyl, 2-ethylhexyl, 2-propylpentyl, n-nonyl, 2,2-dimethylheptyl, 1-ethylpropyl, 1,1-dimethylpropyl, isohexyl, 2-methylpentyl, 4-methylhexyl, and 5-methylhexyl groups.

The alkenyl group is intended to include straight and branched ones and may be optionally substituted with one or more other substituents. The alkenyl group may be specifically a vinyl, 1-propenyl, isopropenyl, 1-butenyl, 2-butenyl, 3-butenyl, 1-pentenyl, 2-pentenyl, 3-pentenyl, 3-methyl-1-butenyl, 1,3-butadienyl, allyl, 1-phenylvinyl-1-yl, 2-phenylvinyl-1-yl, 2,2-diphenylvinyl-1-yl, 2-phenyl-2-(naphthyl-1-yl)vinyl-1-yl, 2,2-bis(diphenyl-1-yl)vinyl-1-yl, stilbenyl or styrenyl group but is not limited thereto.

The alkynyl group is intended to include straight and branched ones and may be optionally substituted with one or more other substituents. The alkynyl group may be, for example, ethynyl or 2-propynyl but is not limited thereto.

The cycloalkyl group is intended to include monocyclic and polycyclic ones and may be optionally substituted with one or more other substituents. As used herein, the term “polycyclic” means that the cycloalkyl group may be directly attached or fused to one or more other cyclic groups. The other cyclic groups may be cycloalkyl groups and other examples thereof include heterocycloalkyl, aryl, and heteroaryl groups. The cycloalkyl group may be specifically a cyclopropyl, cyclobutyl, cyclopentyl, 3-methylcyclopentyl, 2,3-dimethylcyclopentyl, cyclohexyl, 3-methylcyclohexyl, 4-methylcyclohexyl, 2,3-dimethylcyclohexyl, 3,4,5-trimethylcyclohexyl, 4-tert-butylcyclohexyl, cycloheptyl or cyclooctyl group but is not limited thereto.

The heterocycloalkyl group is intended to include monocyclic and polycyclic ones interrupted by a heteroatom such as O, S, Se, N or Si and may be optionally substituted with one or more other substituents. As used herein, the term “polycyclic” means that the heterocycloalkyl group may be directly attached or fused to one or more other cyclic groups. The other cyclic groups may be heterocycloalkyl groups and other examples thereof include cycloalkyl, aryl, and heteroaryl groups.

The aryl groups may be monocyclic or polycyclic ones. Examples of the monocyclic aryl groups include, but are not limited to, phenyl, biphenyl, terphenyl, and terphenyl groups. Examples of the polycyclic aryl groups include naphthyl, anthracenyl, phenanthrenyl, pyrenyl, perylenyl, tetracenyl, chrysenyl, fluorenyl, acenaphathcenyl, triphenylene, and fluoranthrene groups but the scope of the present invention is not limited thereto.

The heteroaryl groups refer to heterocyclic groups interrupted by one or more heteroatoms. Examples of the heteroaryl groups include, but are not limited to, thiophene, furan, pyrrole, imidazole, triazole, oxazole, oxadiazole, triazole, pyridyl, bipyridyl, pyrimidyl, triazine, triazole, acridyl, pyridazine, pyrazinyl, quinolinyl, quinazoline, quinoxalinyl, phthalazinyl, pyridopyrimidinyl, pyridopyrazinyl, pyrazinopyrazinyl, isoquinoline, indole, carbazole, benzoxazole, benzimidazole, benzothiazole, benzocarbazole, benzothiophene, dibenzothiophene, benzofuranyl, dibenzofuranyl, phenanthroline, thiazolyl, isoxazolyl, oxadiazolyl, thiadiazolyl, benzothiazolyl, and phenothiazinyl groups.

The alkoxy group may be specifically a methoxy, ethoxy, propoxy, isobutyloxy, sec-butyloxy, pentyloxy, iso-amyloxy or hexyloxy group, but is not limited thereto.

The silyl group is intended to include alkyl-substituted silyl groups and aryl-substituted silyl groups. Specific examples of such silyl groups include trimethylsilyl, triethylsilyl, triphenylsilyl, trimethoxysilyl, dimethoxyphenylsilyl, diphenylmethylsilyl, diphenylvinylsilyl, methylcyclobutylsilyl, and dimethylfurylsilyl.

The amine groups may be, for example, —NH₂, alkylamine groups, and arylamine groups. The arylamine groups are aryl-substituted amine groups and the alkylamine groups are alkyl-substituted amine groups. Examples of the arylamine groups include substituted or unsubstituted monoarylamine groups, substituted or unsubstituted diarylamine groups, and substituted or unsubstituted triarylamine groups. The aryl groups in the arylamine groups may be monocyclic or polycyclic ones. The arylamine groups may include two or more aryl groups. In this case, the aryl groups may be monocyclic aryl groups or polycyclic aryl groups. Alternatively, the aryl groups may consist of a monocyclic aryl group and a polycyclic aryl group. The aryl groups in the arylamine groups may be selected from those exemplified above.

The aryl groups in the aryloxy group and the arylthioxy group are the same as those described above. Specific examples of the aryloxy groups include, but are not limited to, phenoxy, p-tolyloxy, m-tolyloxy, 3,5-dimethylphenoxy, 2,4,6-trimethylphenoxy, p-tert-butylphenoxy, 3-biphenyloxy, 4-biphenyloxy, 1-naphthyloxy, 2-naphthyloxy, 4-methyl-1-naphthyloxy, 5-methyl-2-naphthyloxy, 1-anthryloxy, 2-anthryloxy, 9-anthryloxy, 1-phenanthryloxy, 3-phenanthryloxy, and 9-phenanthryloxy groups. The arylthioxy group may be, for example, a phenylthioxy, 2-methylphenylthioxy or 4-tert-butylphenylthioxy group but is not limited thereto.

The halogen group may be, for example, fluorine, chlorine, bromine or iodine.

More specifically, the polycyclic aromatic compound represented by Formula A-1 or A-2 can be selected from the following compounds 1 to 165:

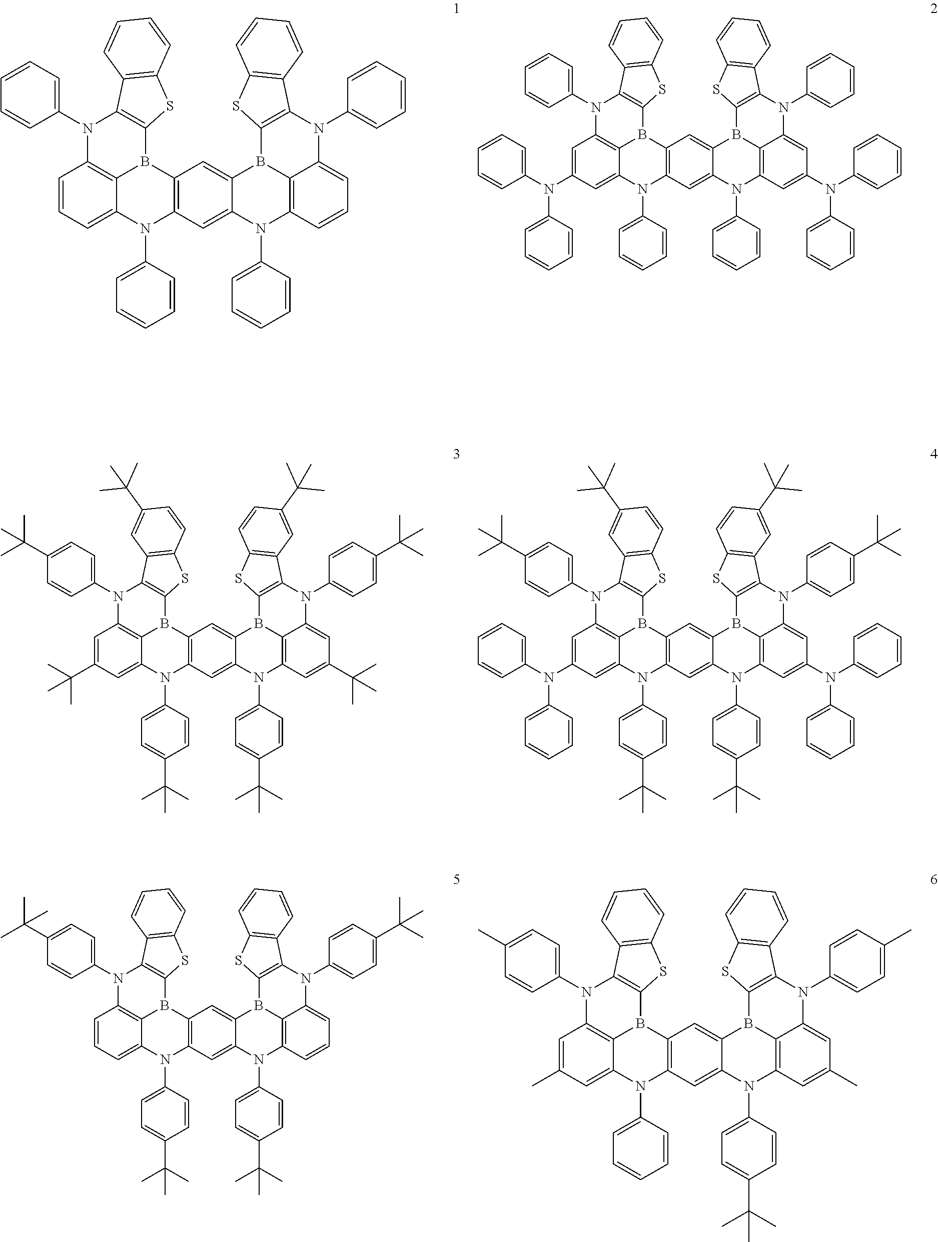

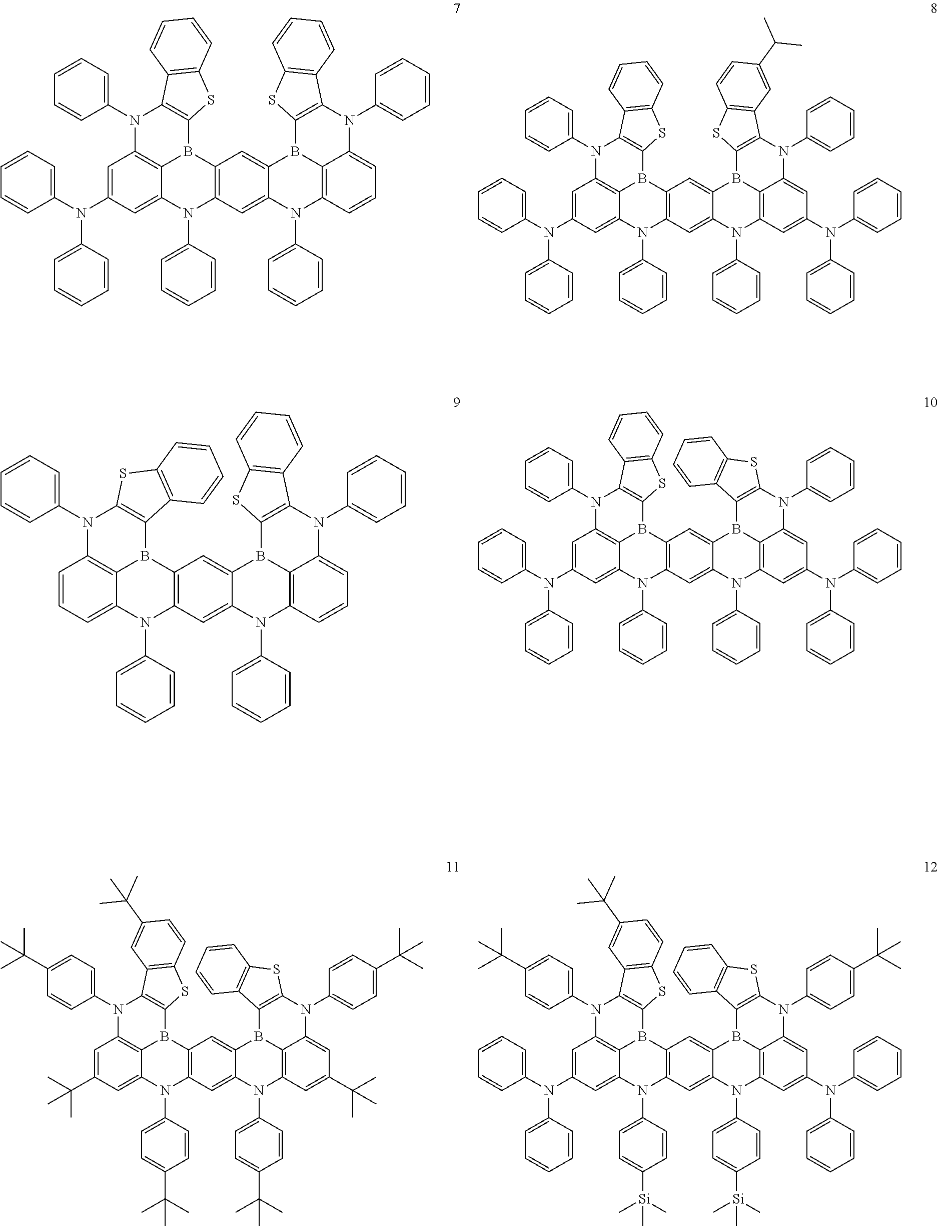

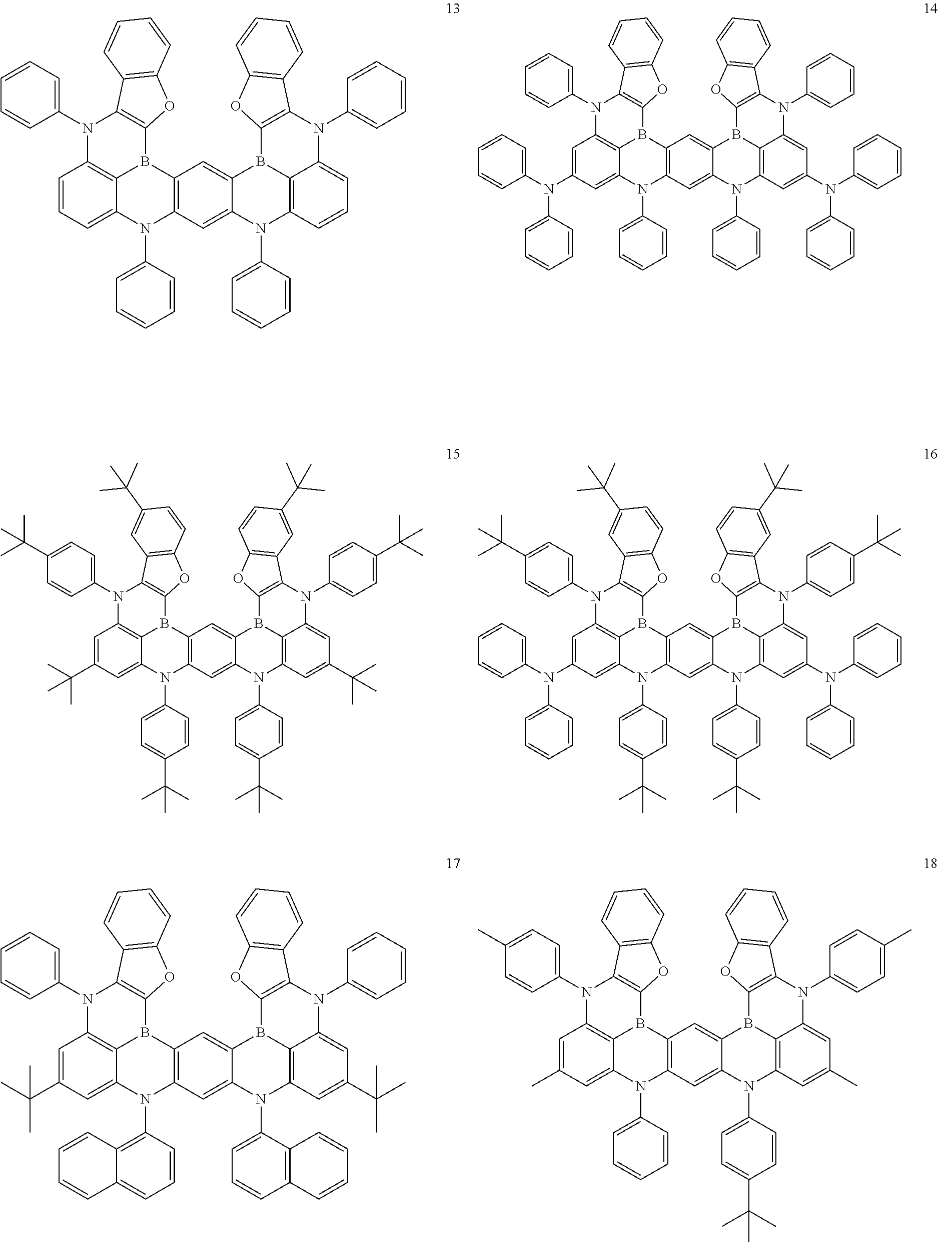

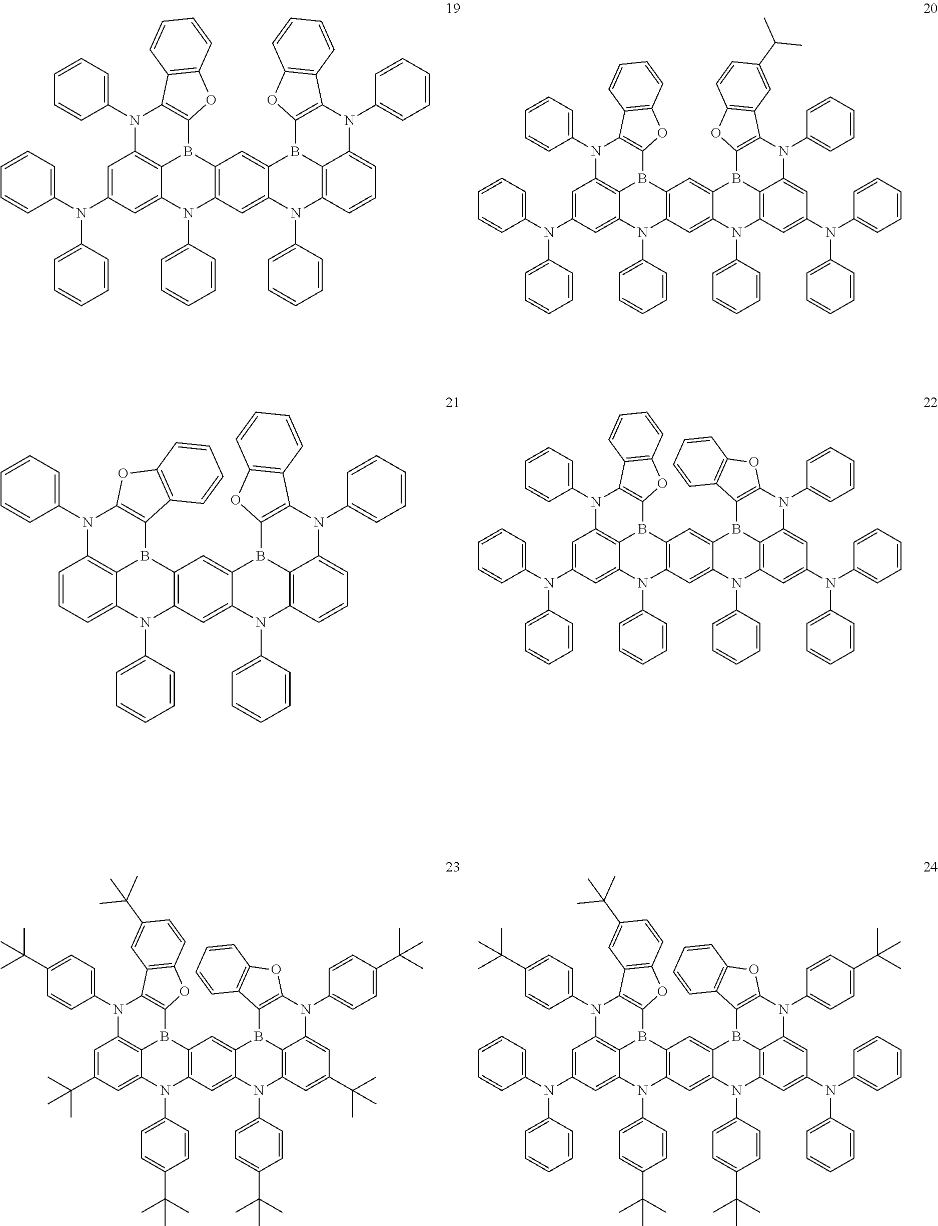

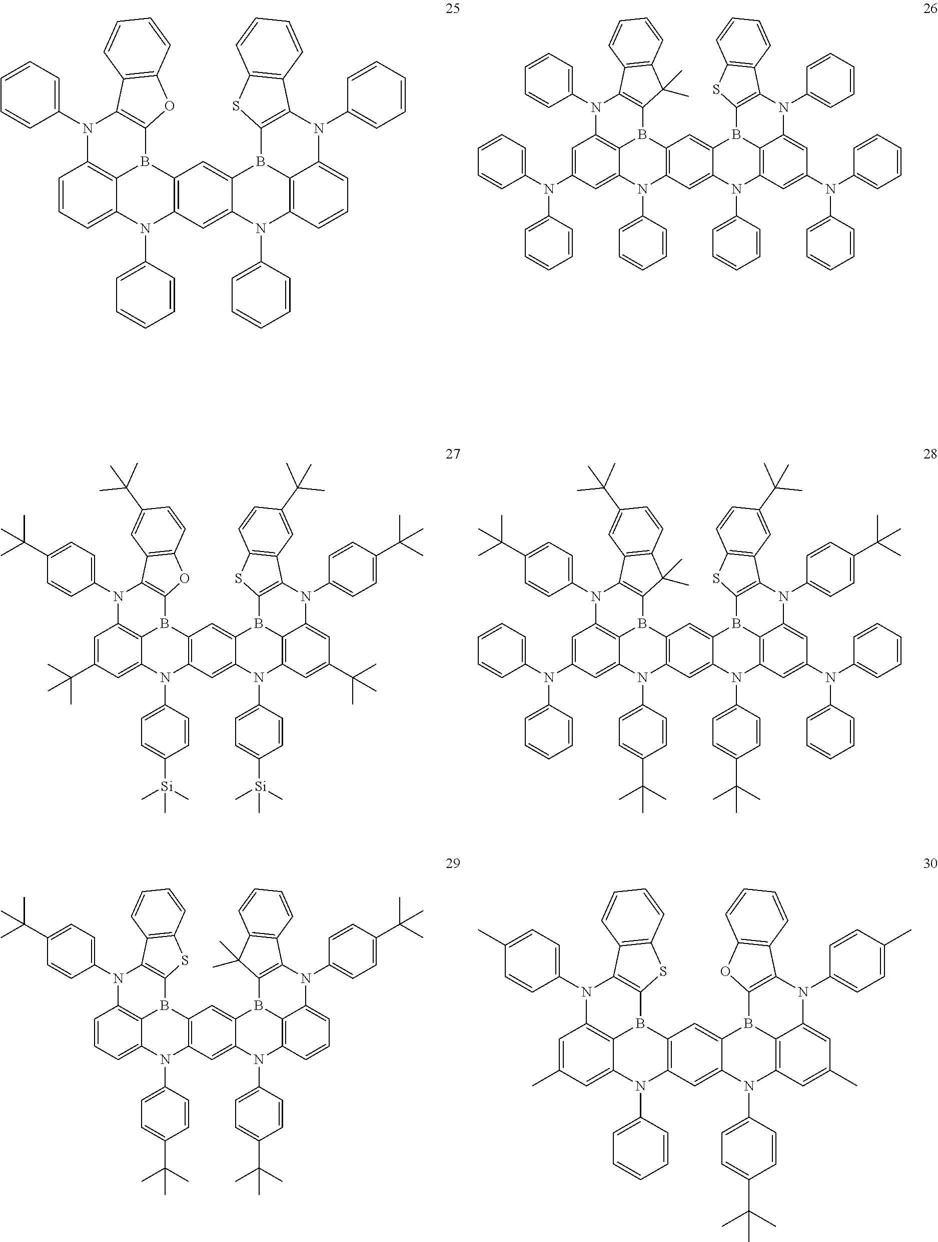

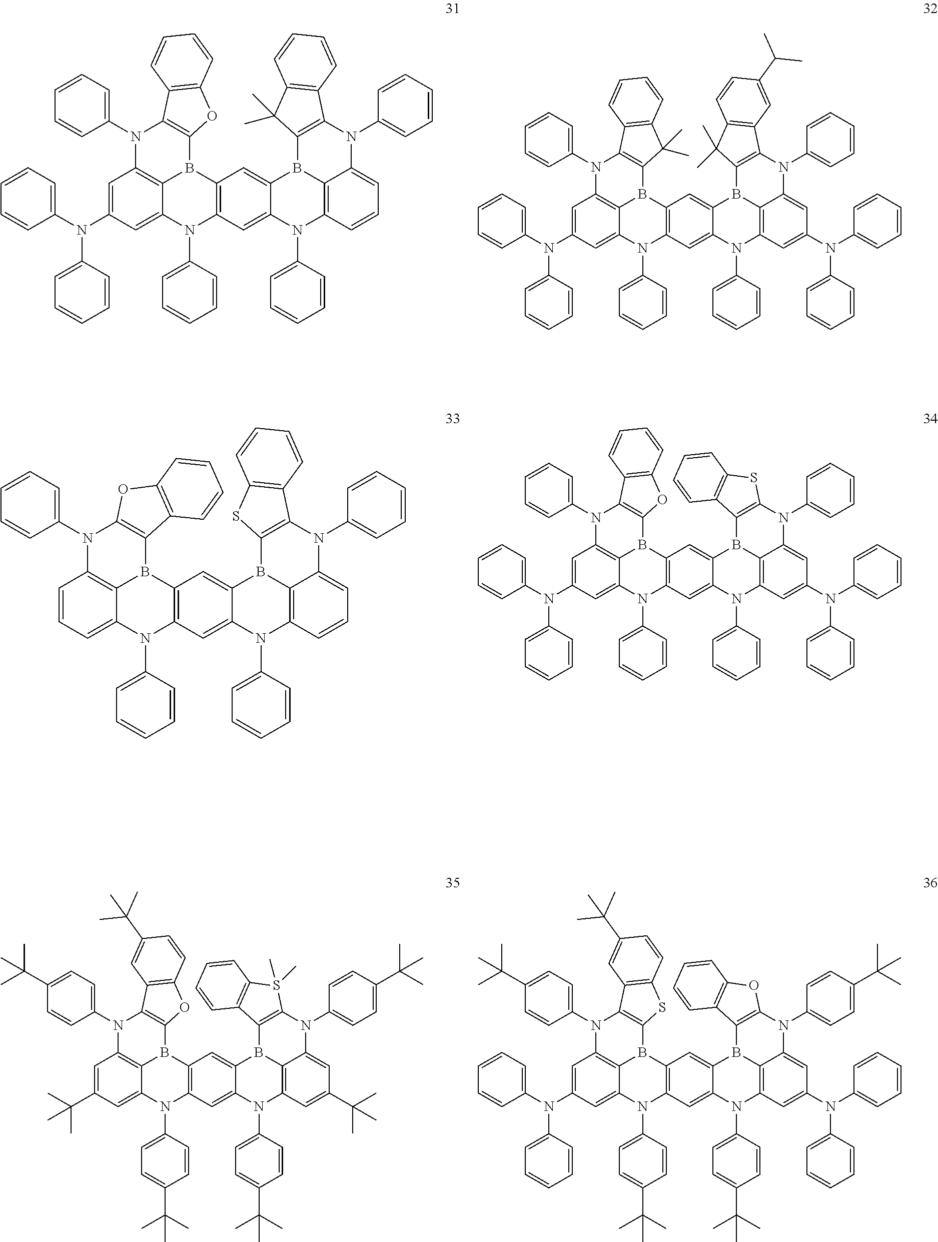

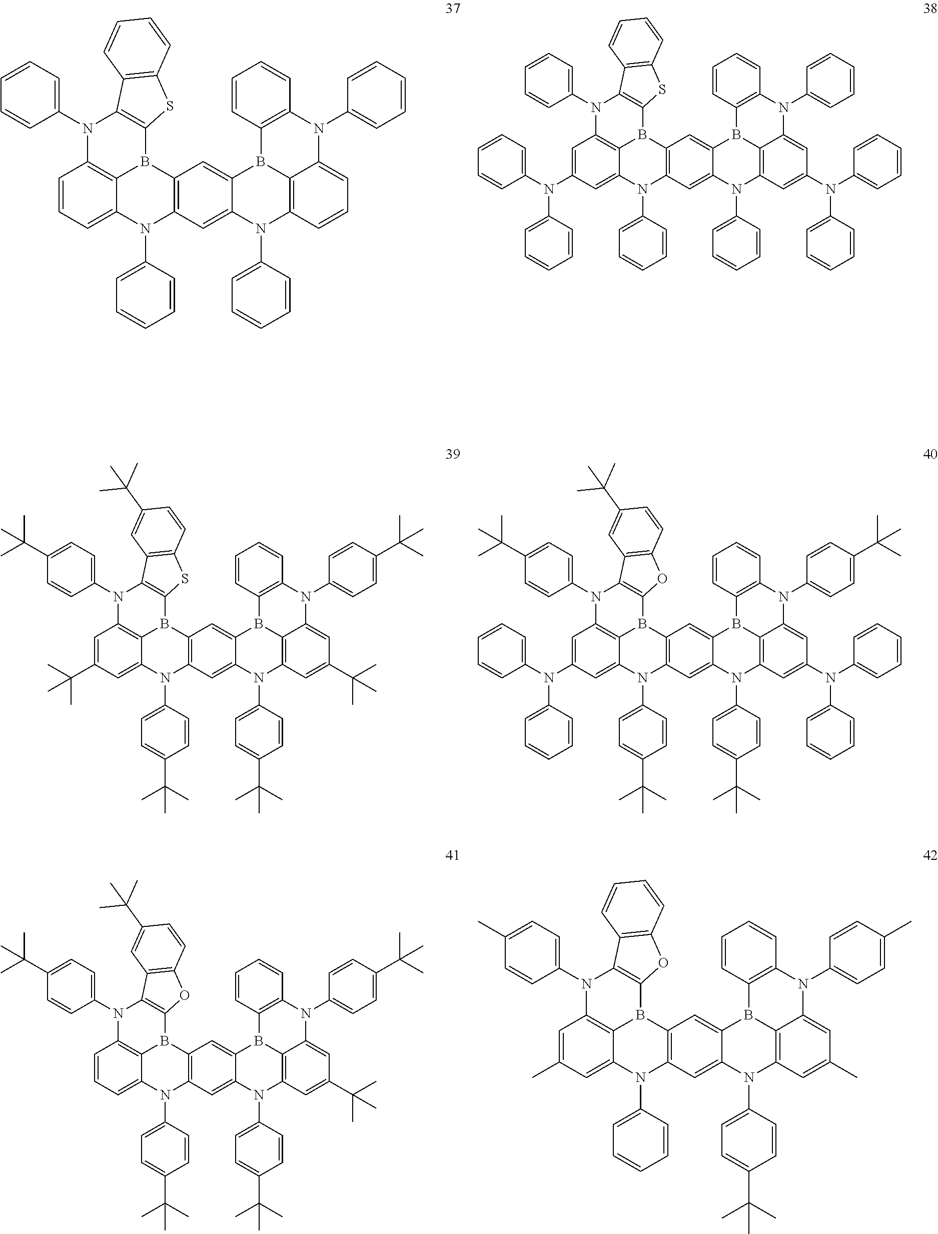

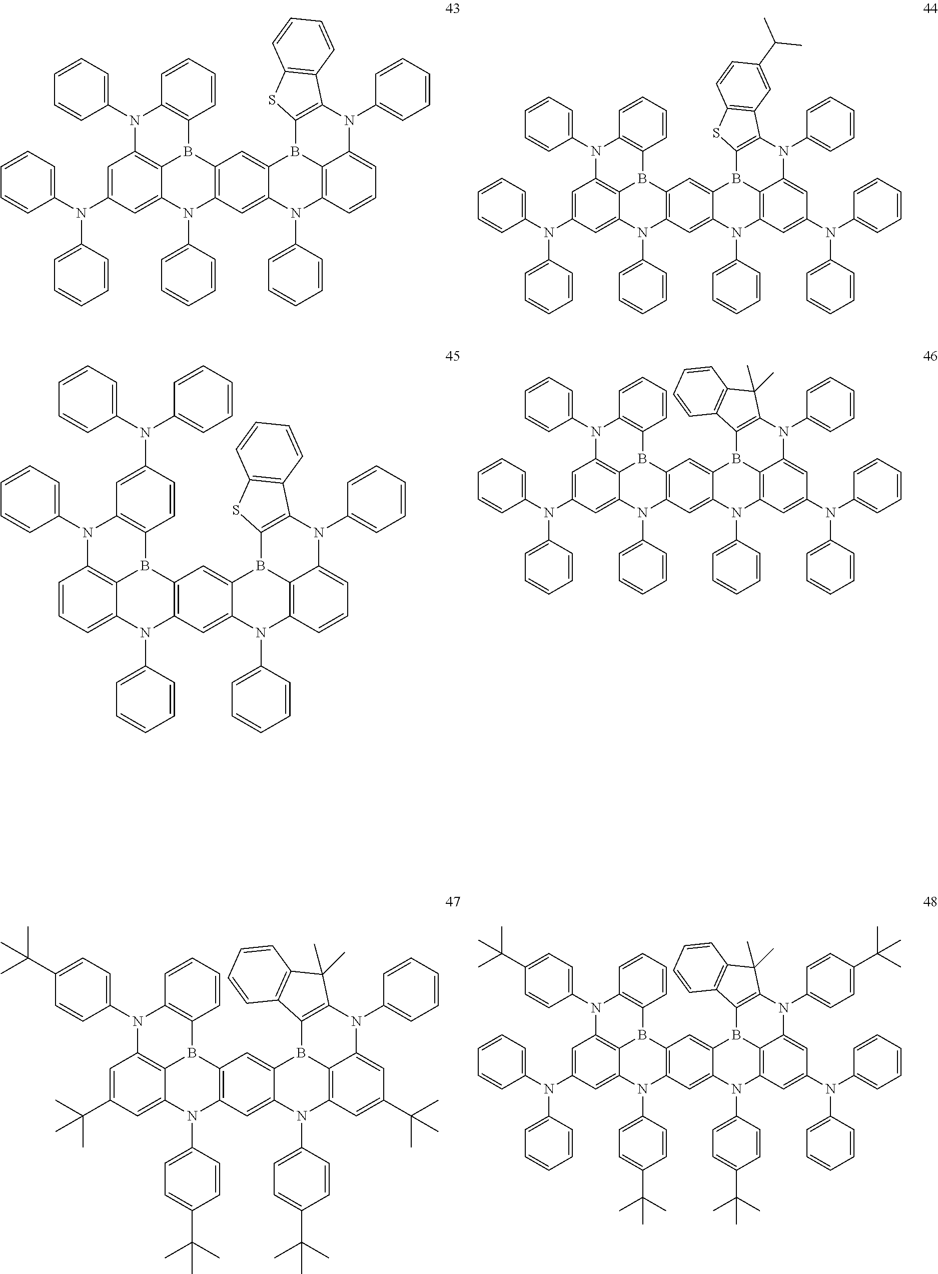

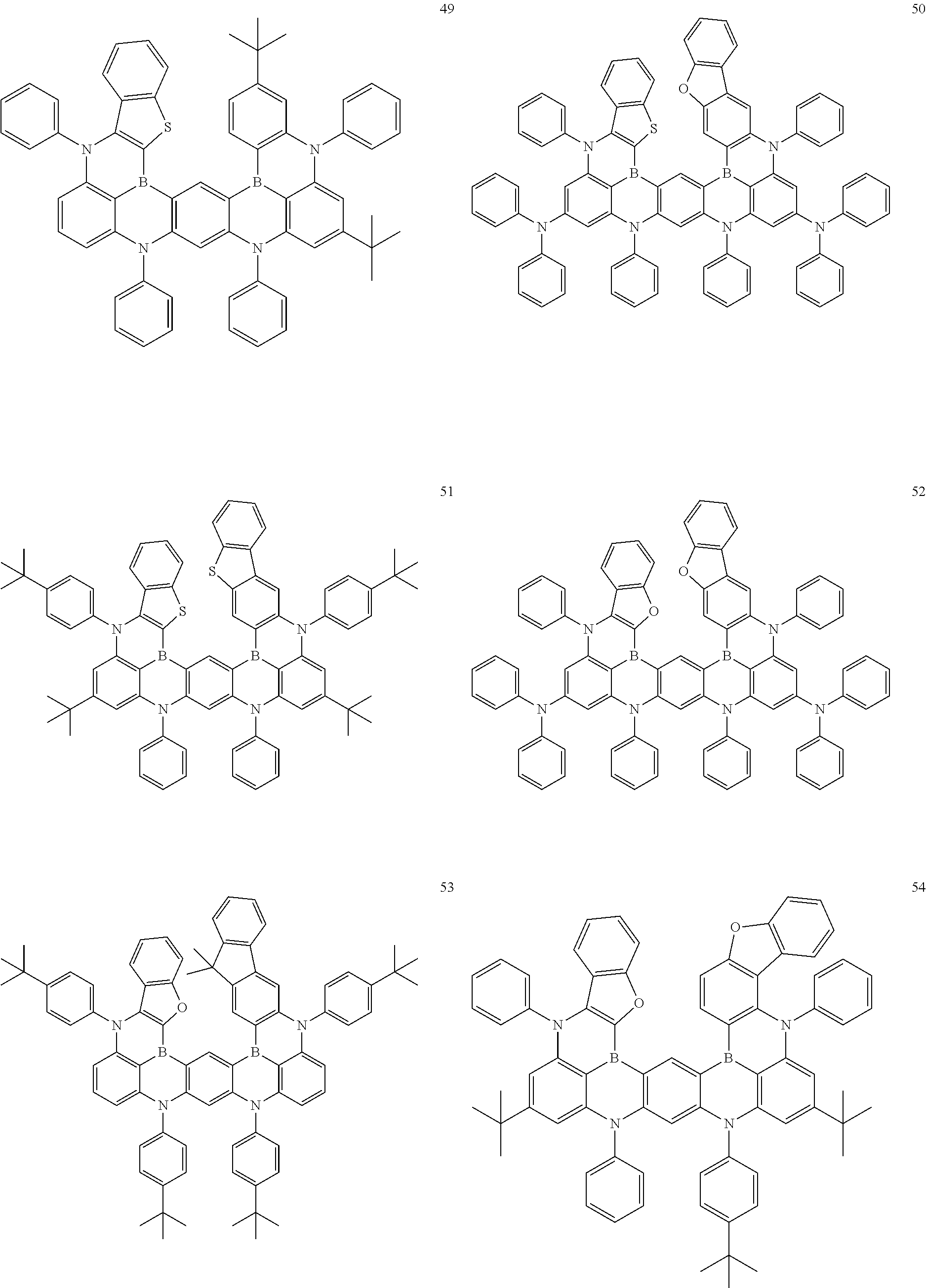

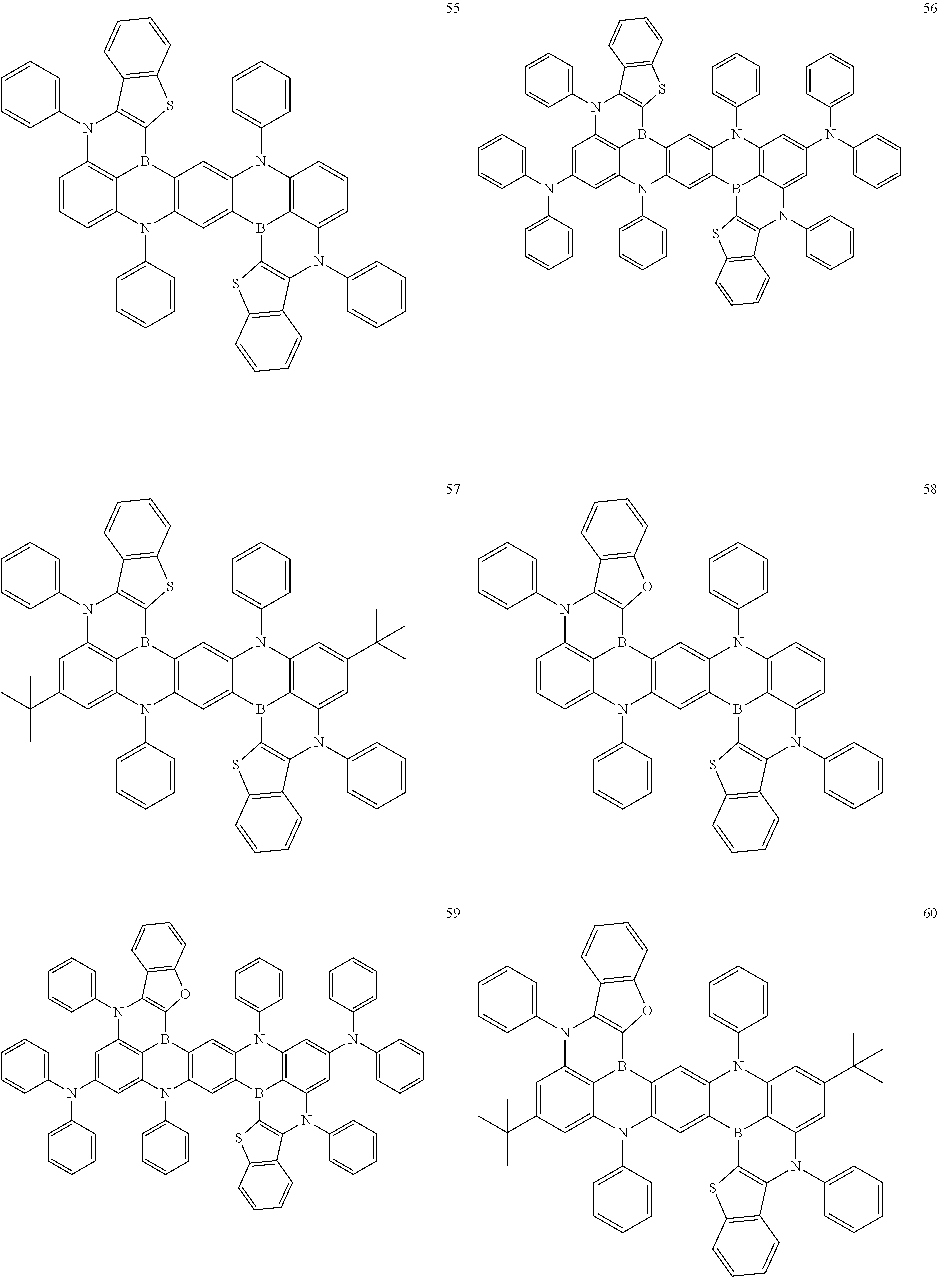

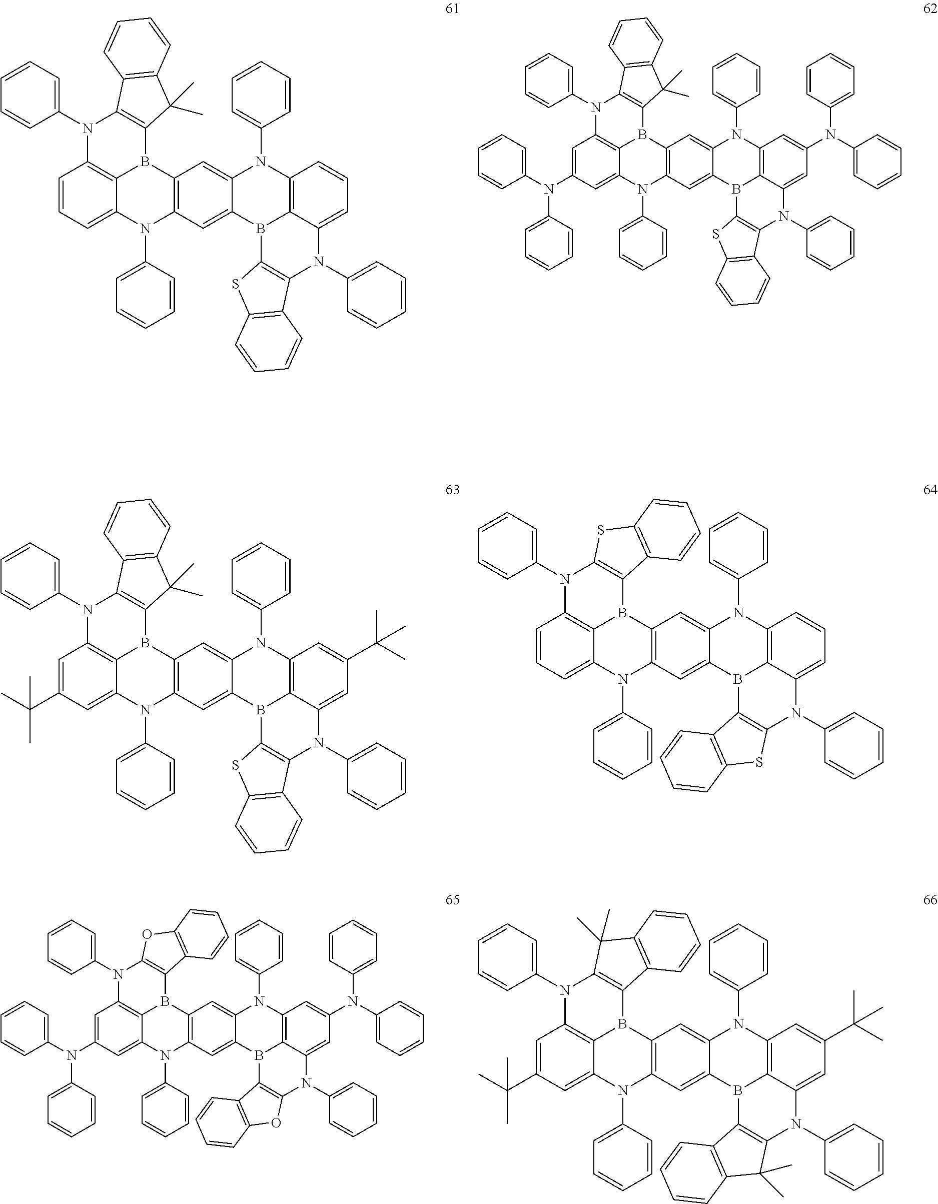

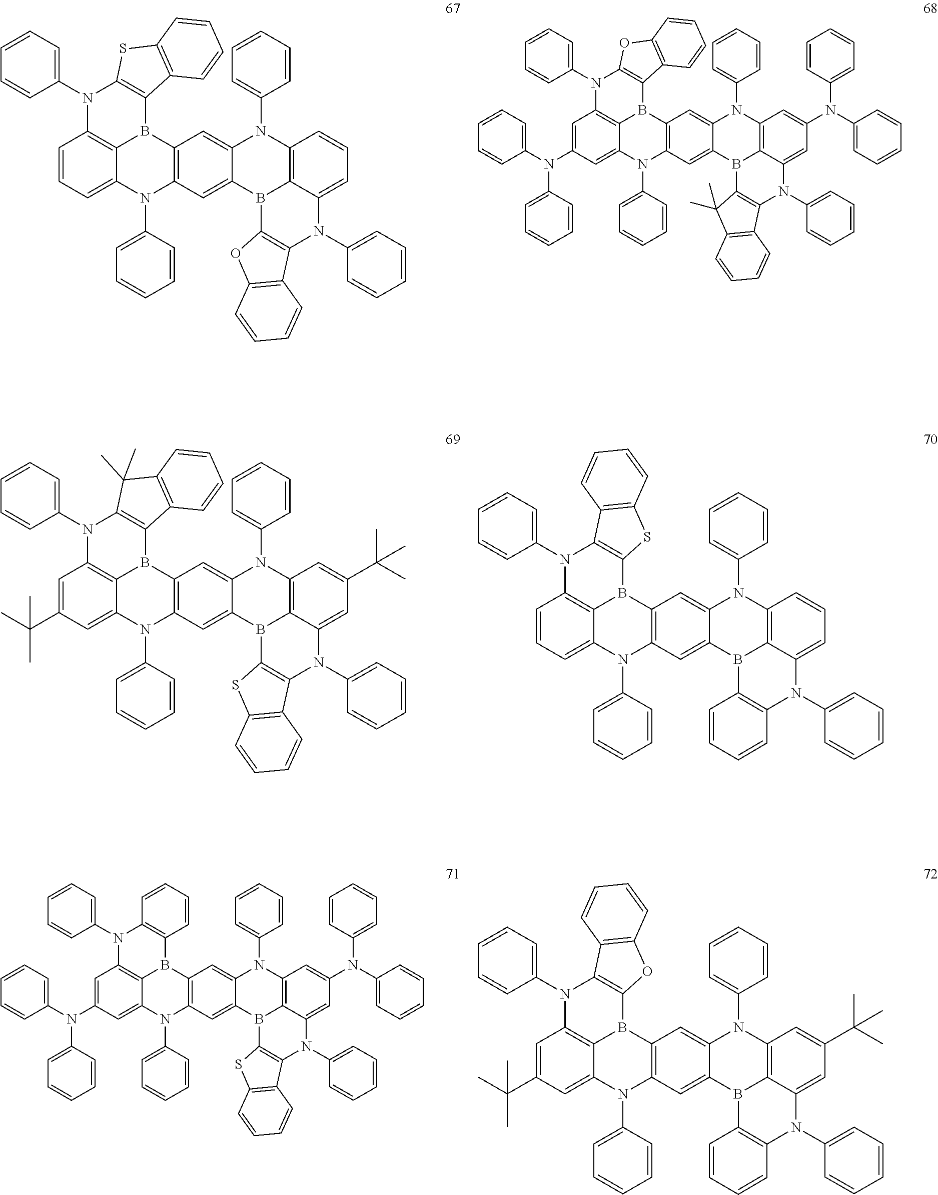

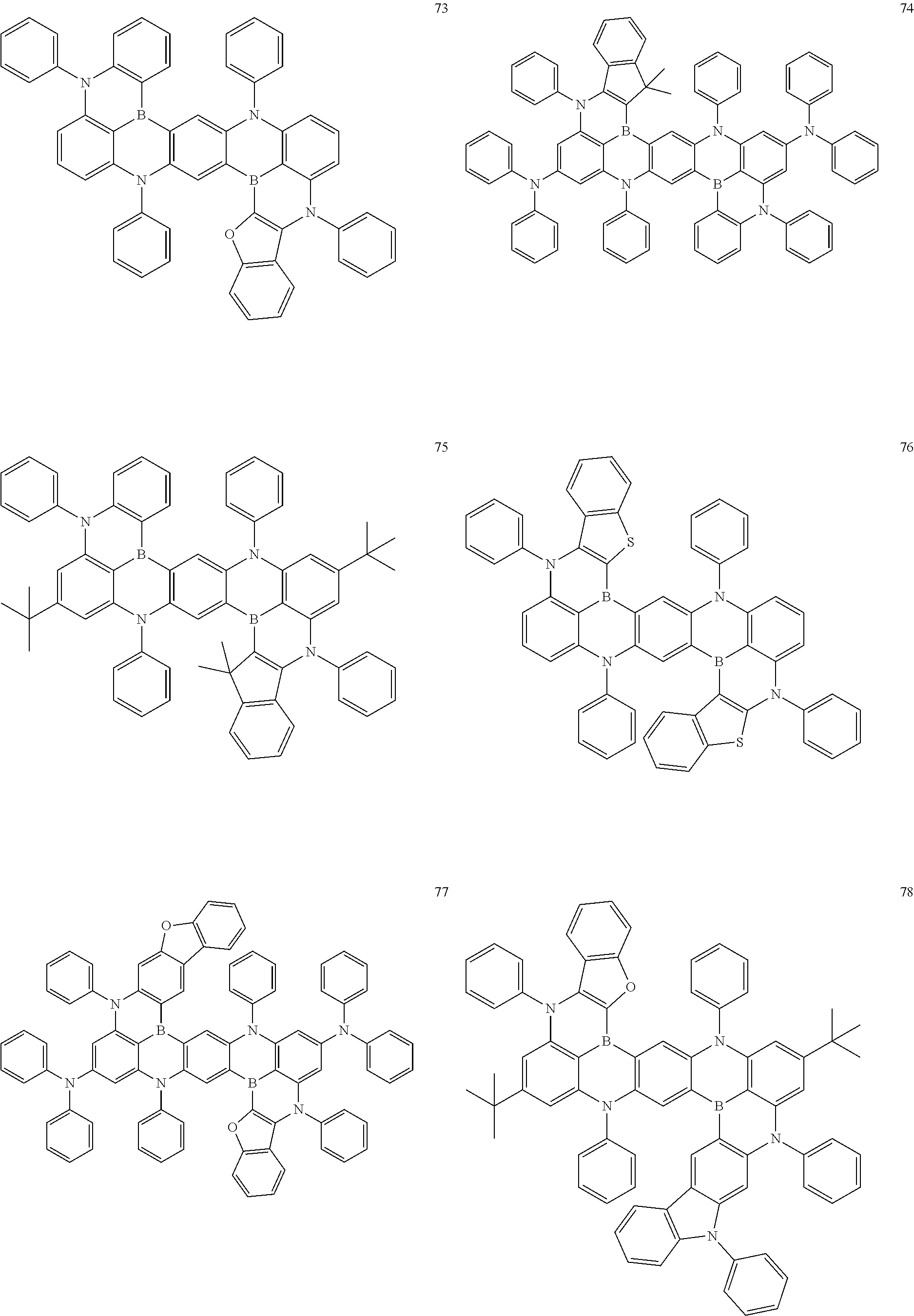

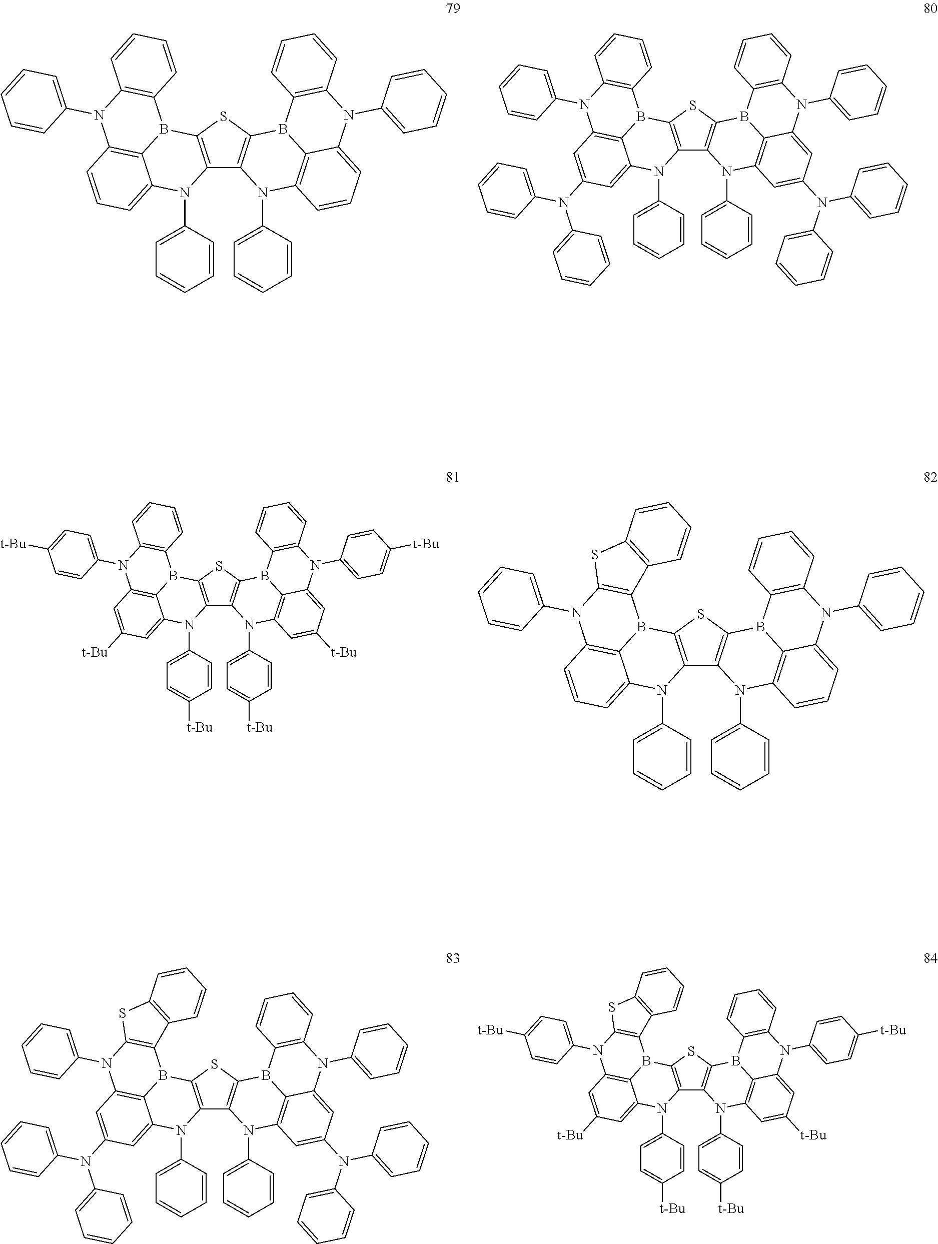

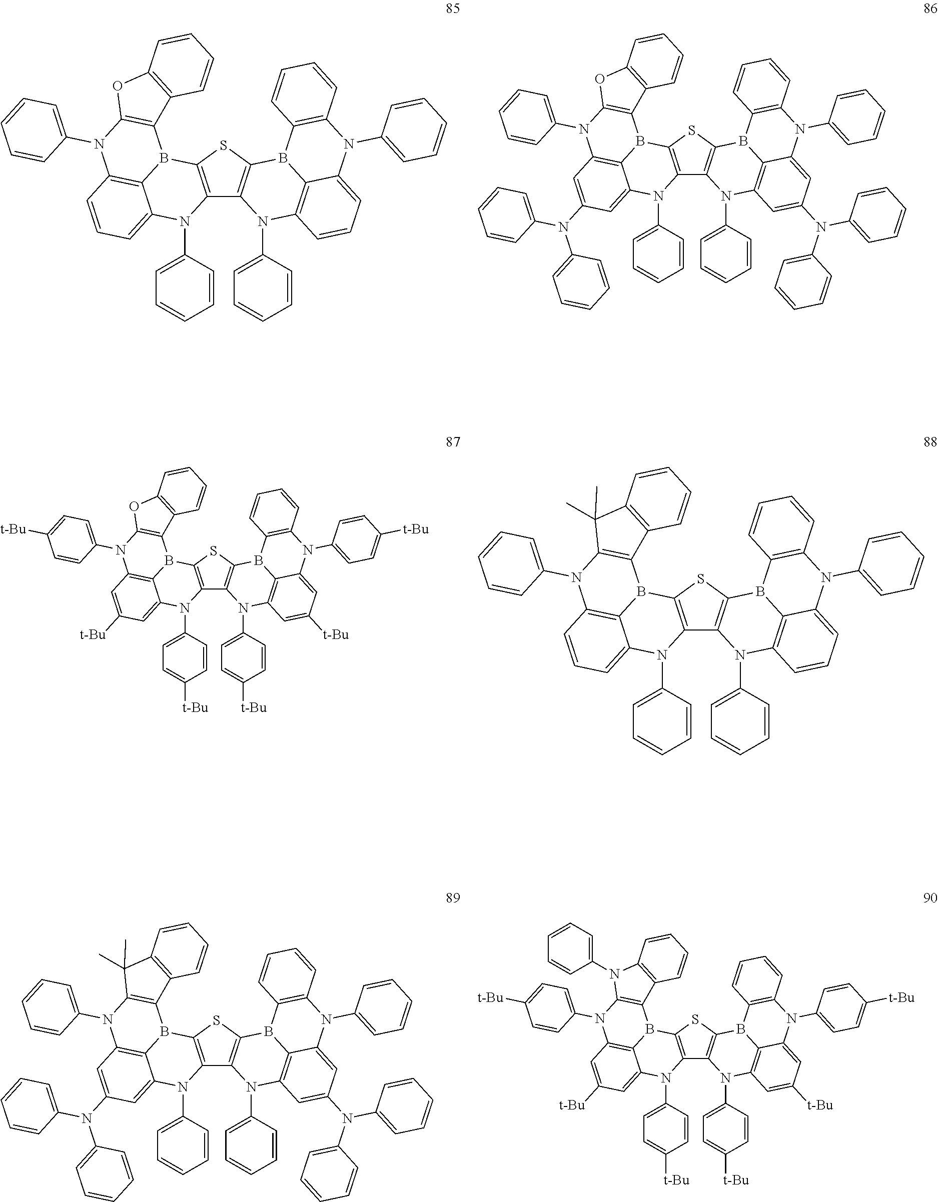

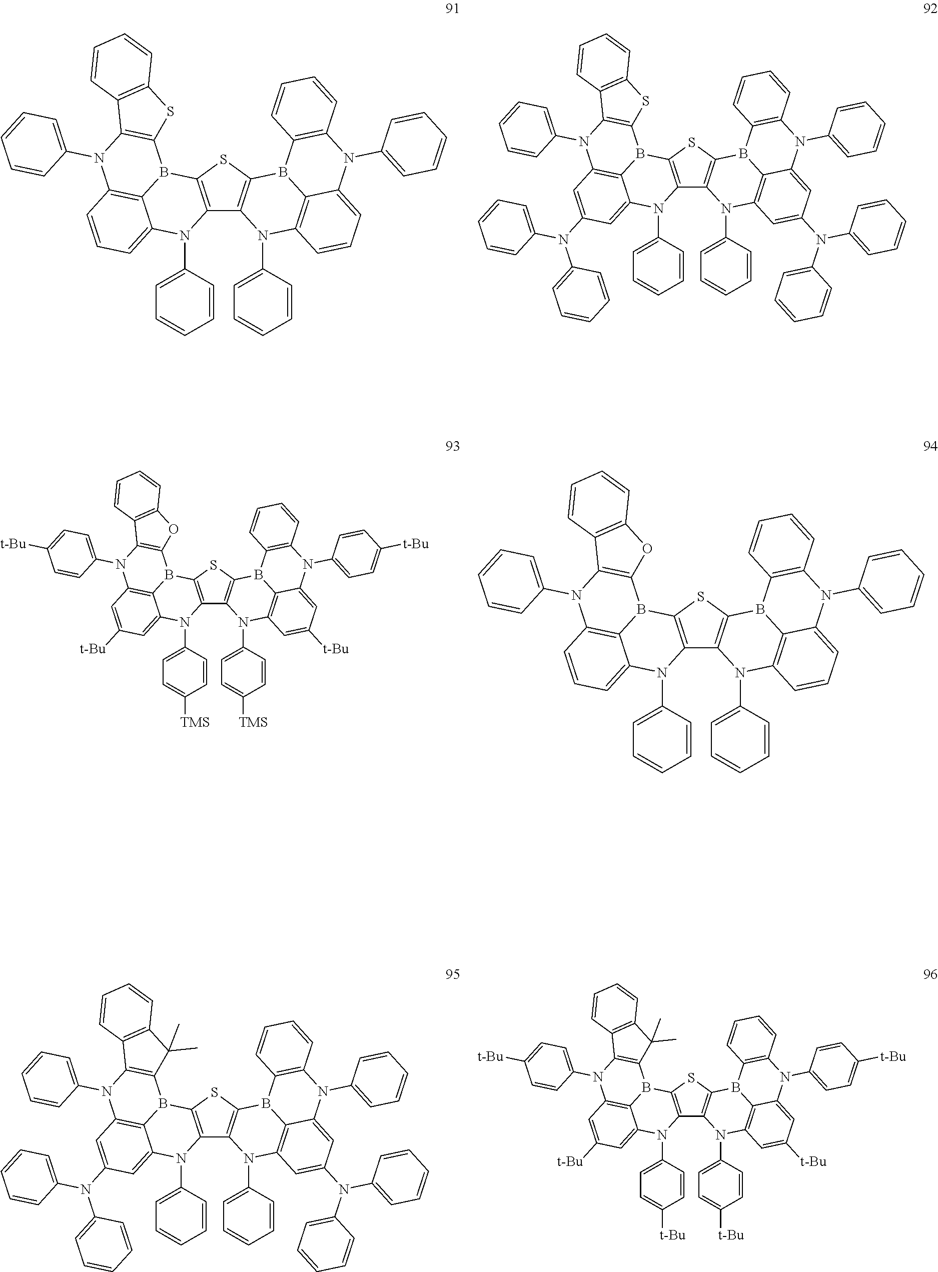

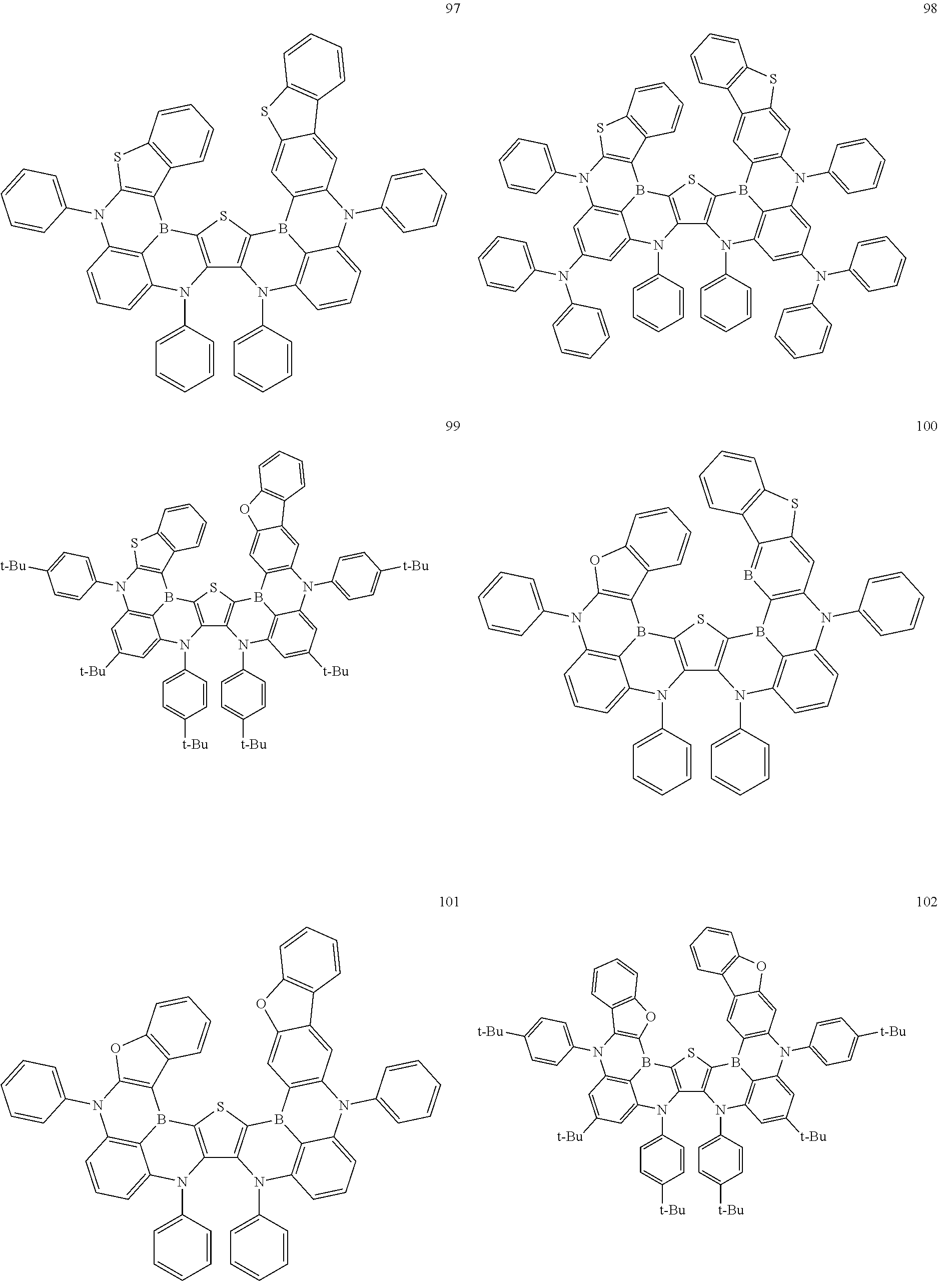

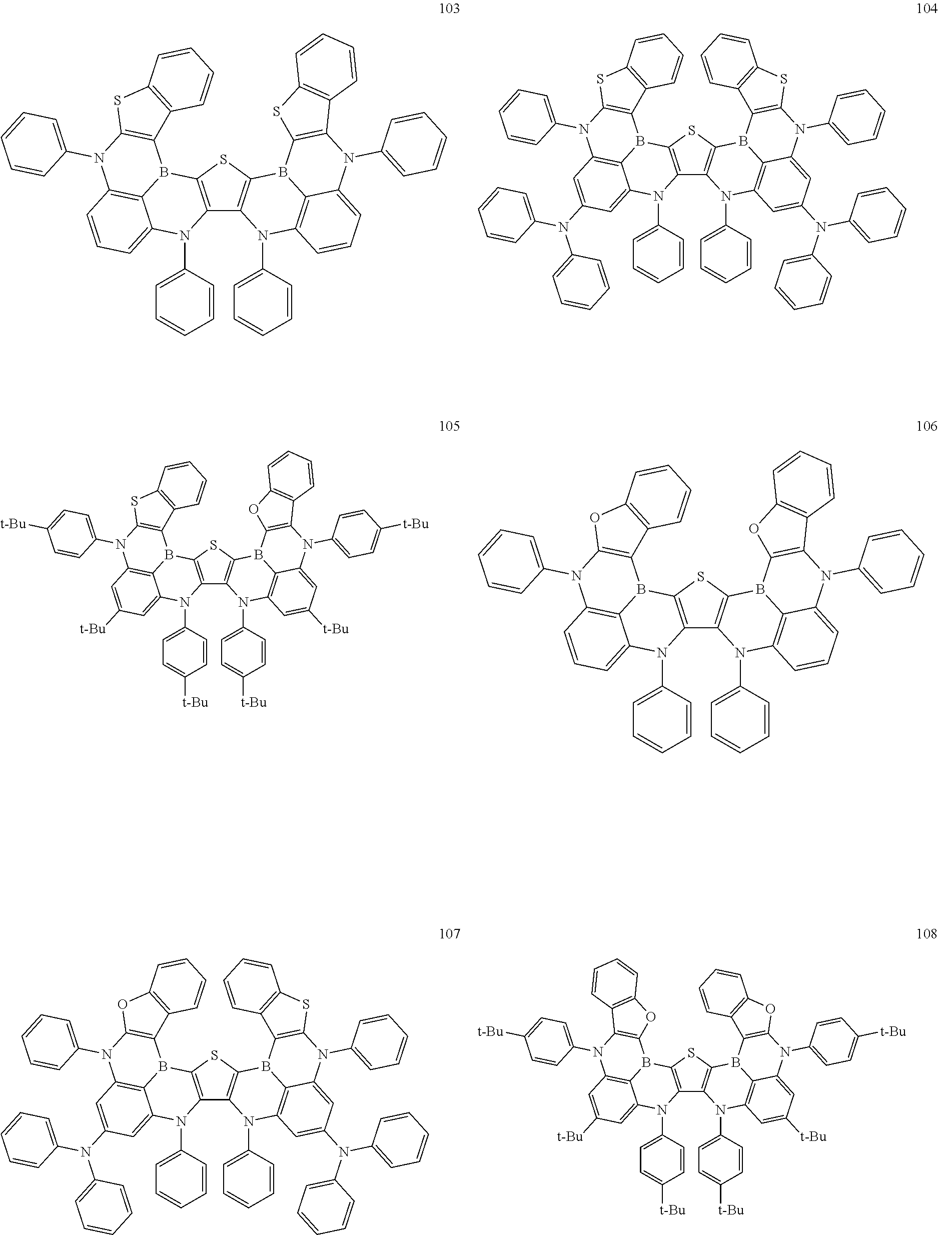

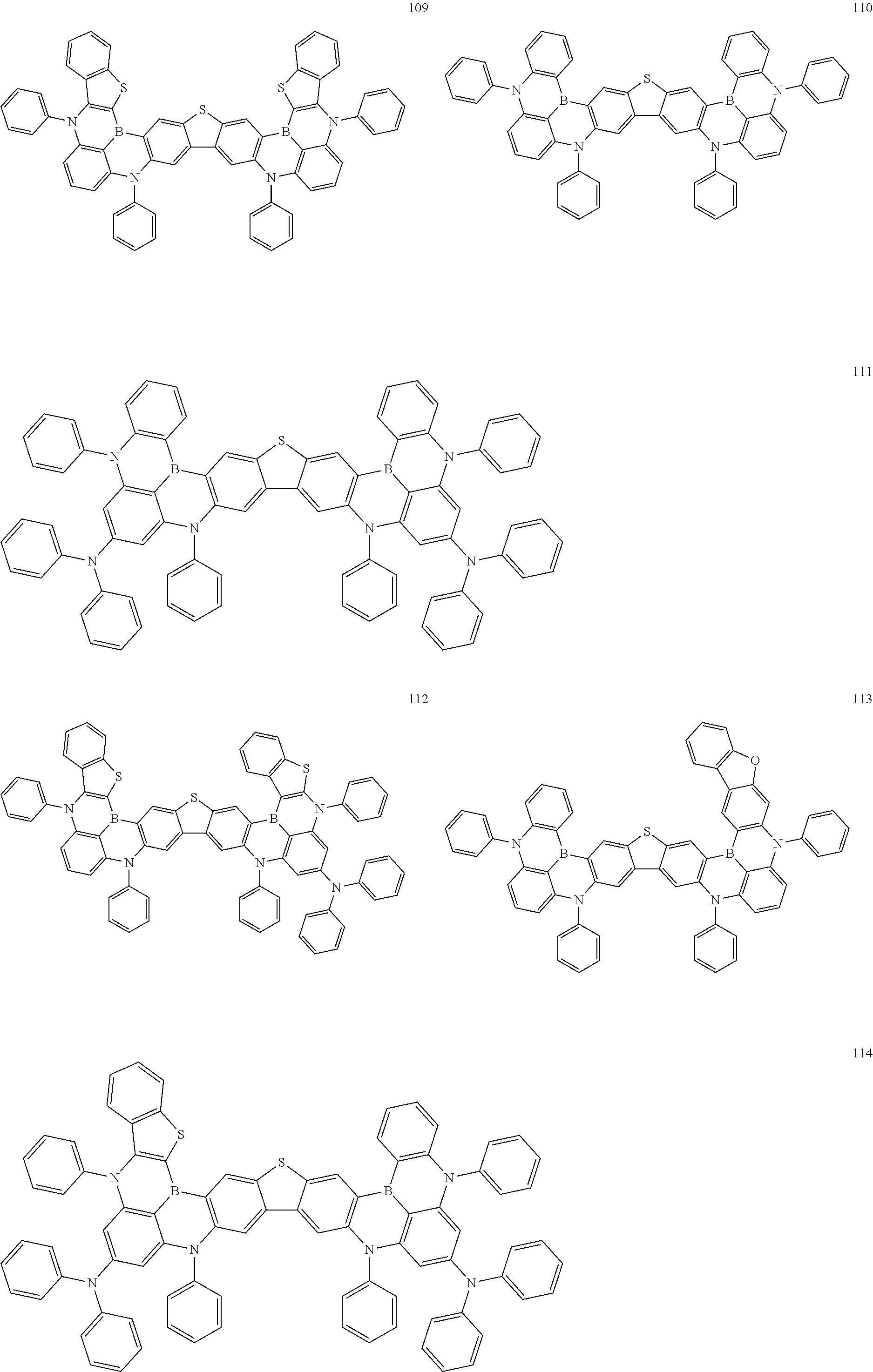

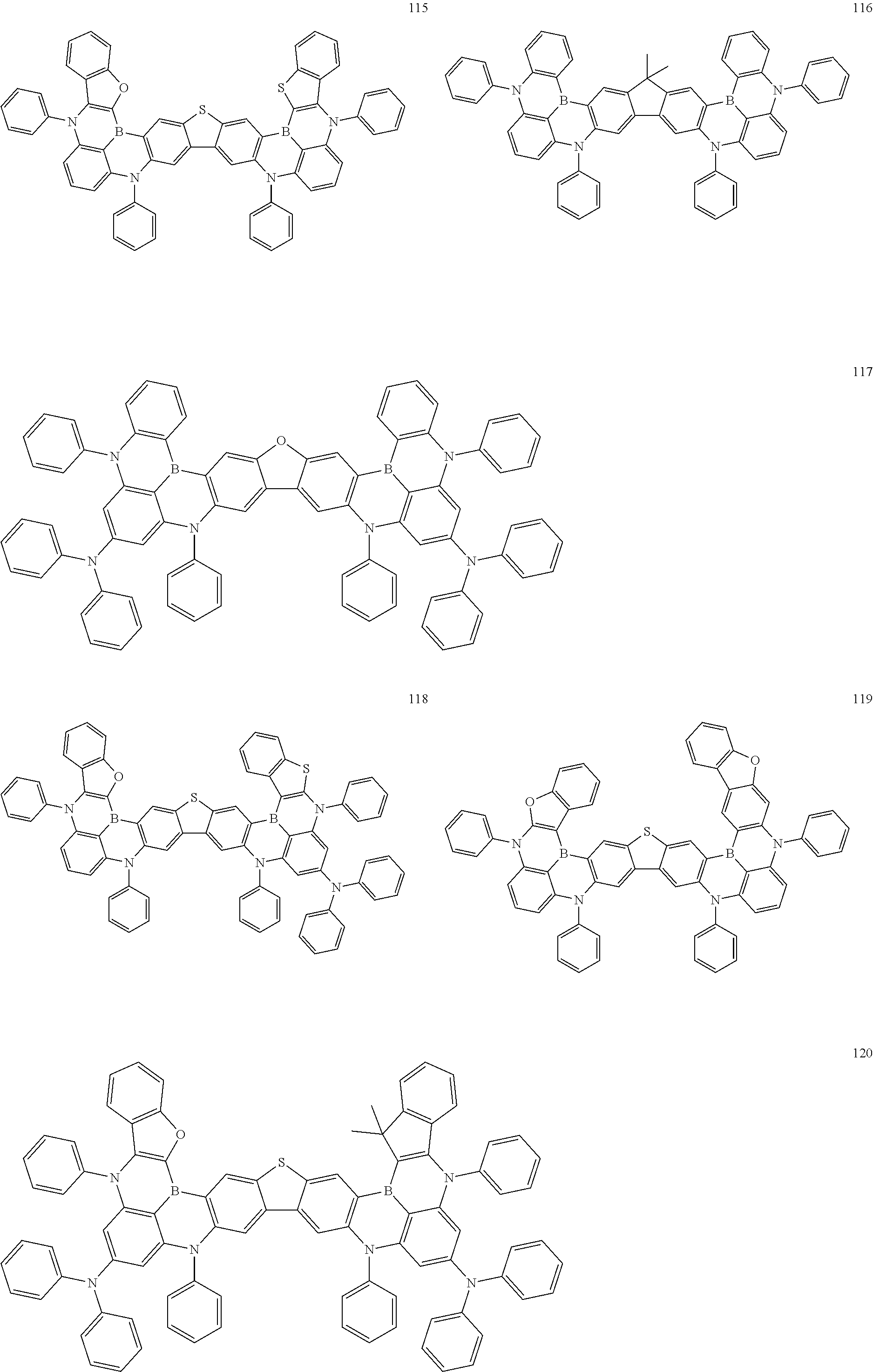

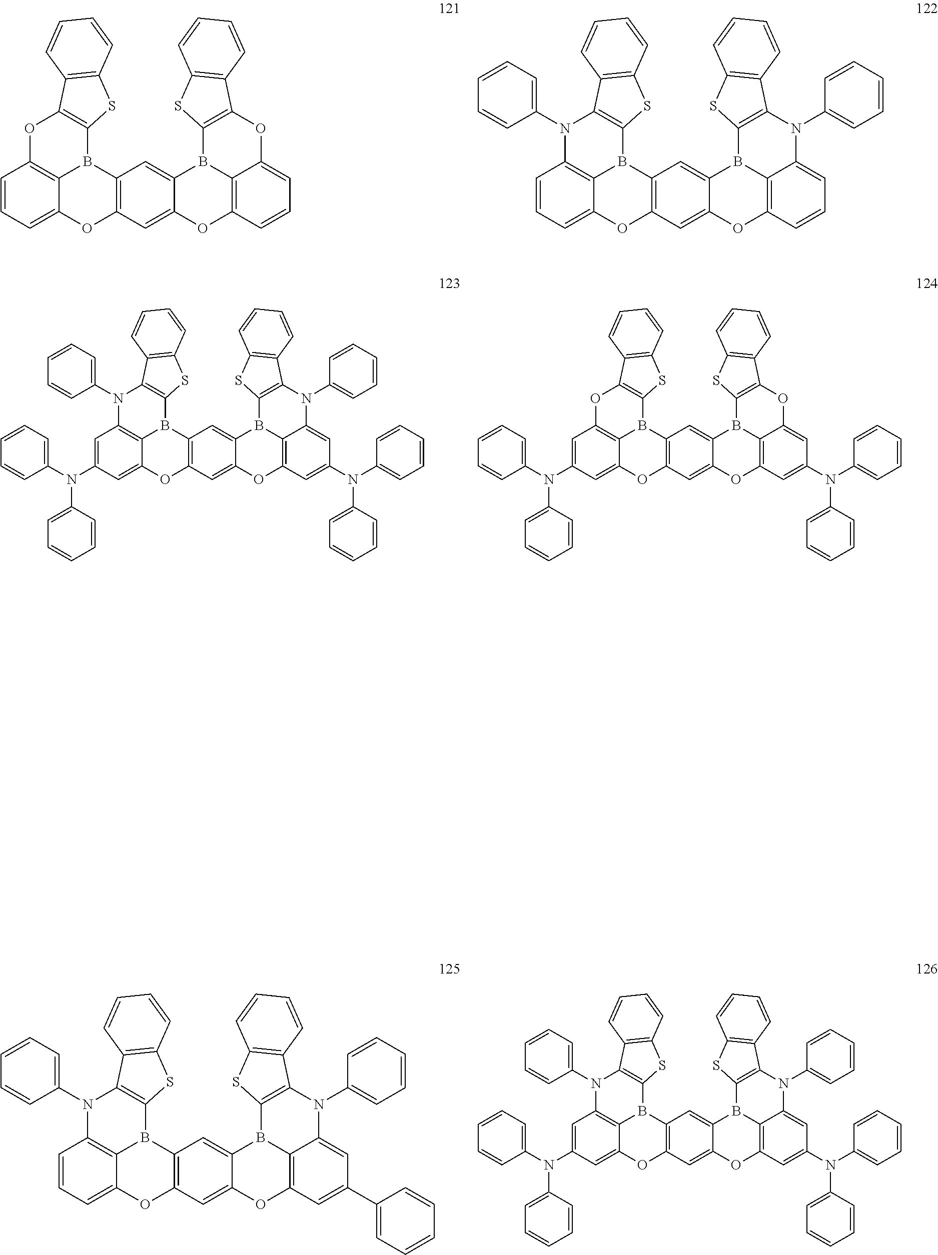

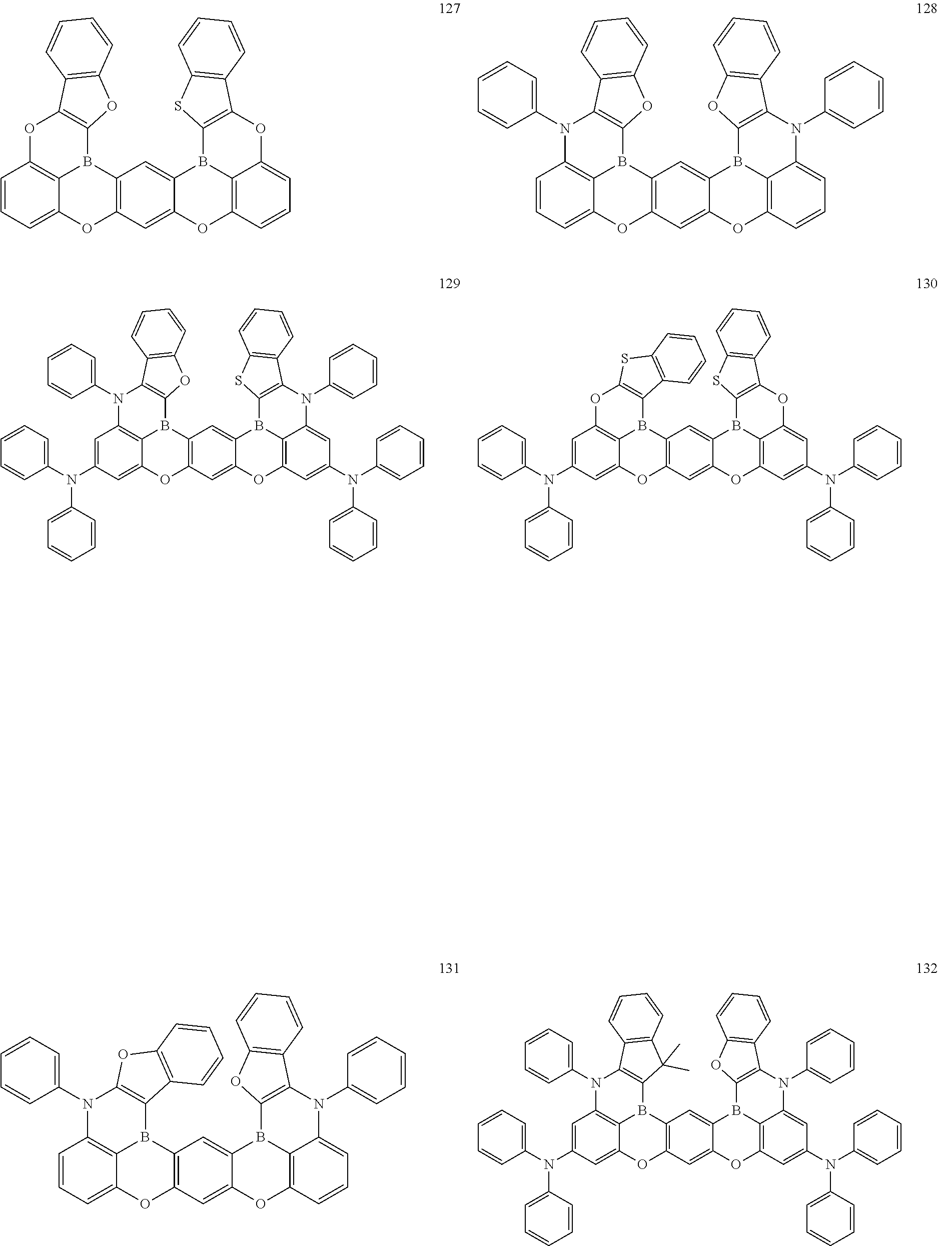

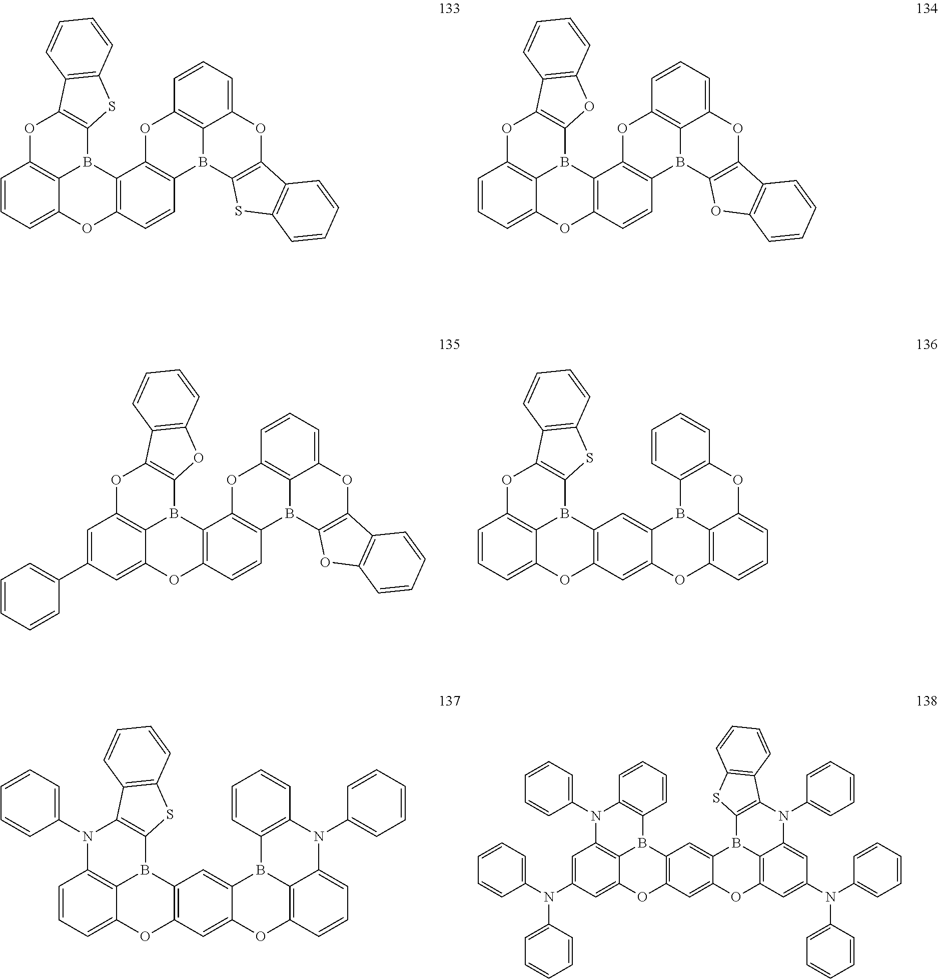

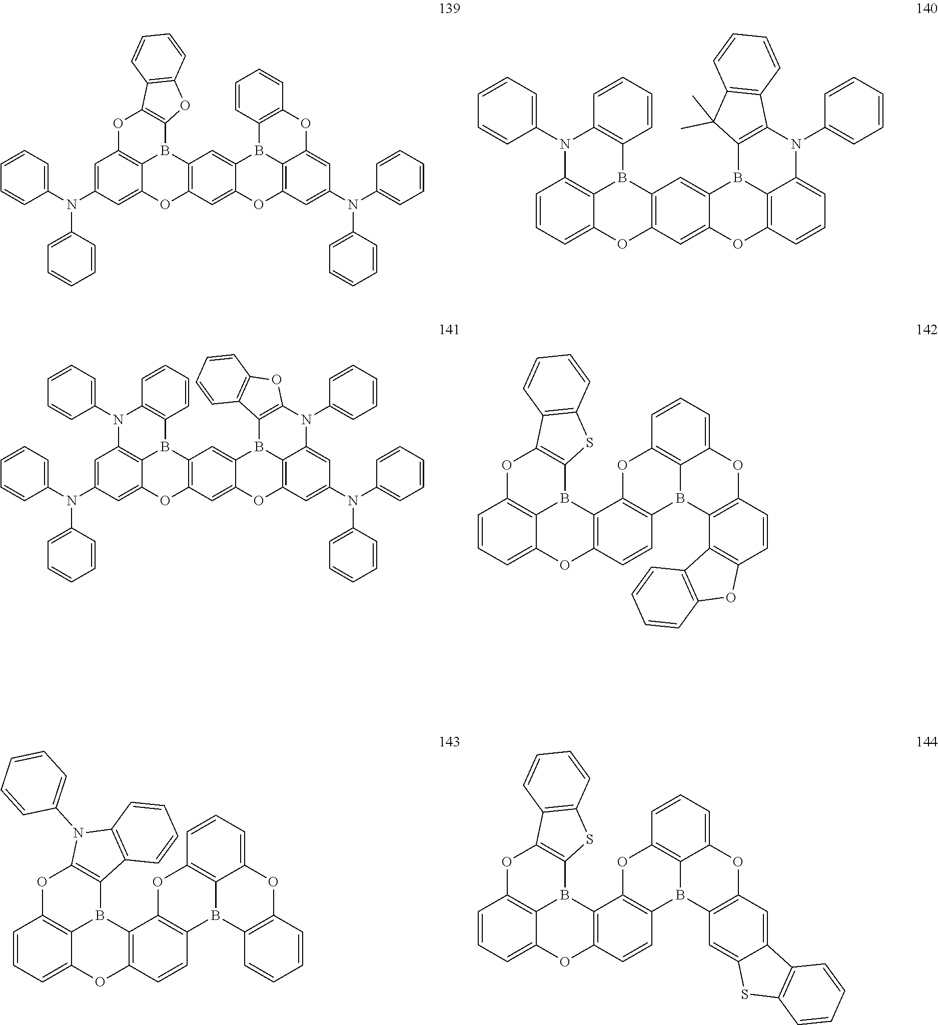

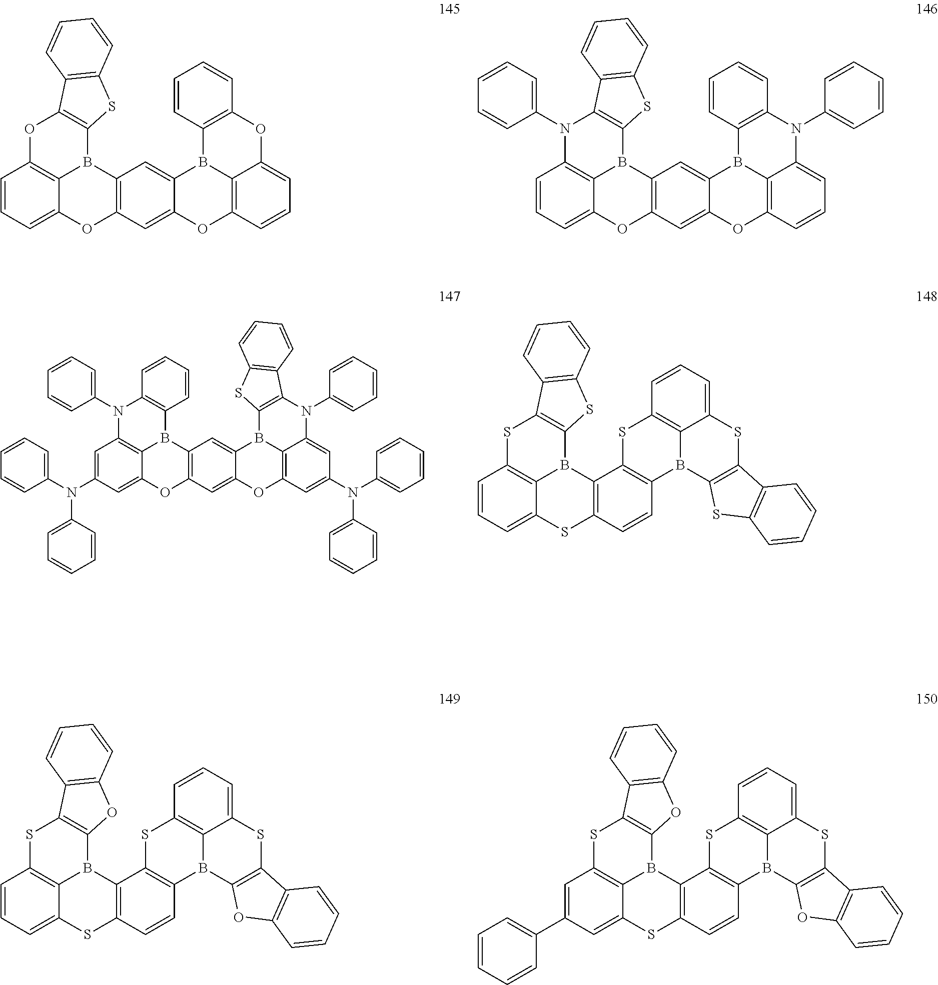

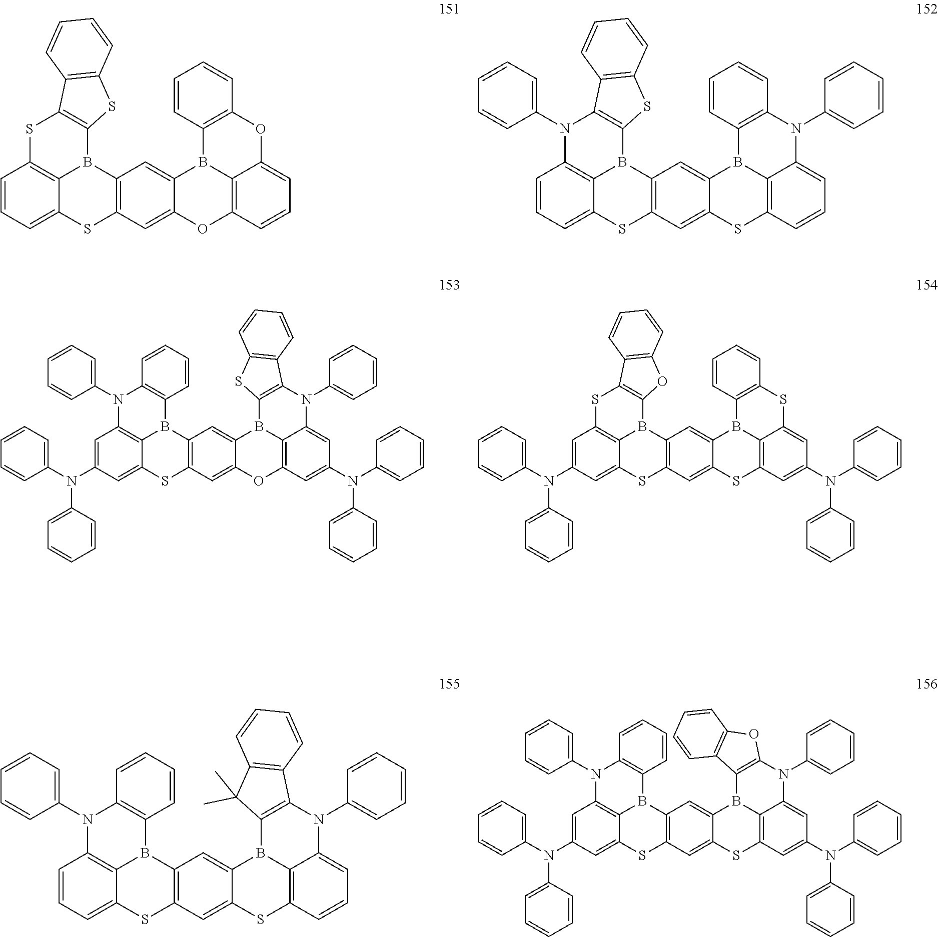

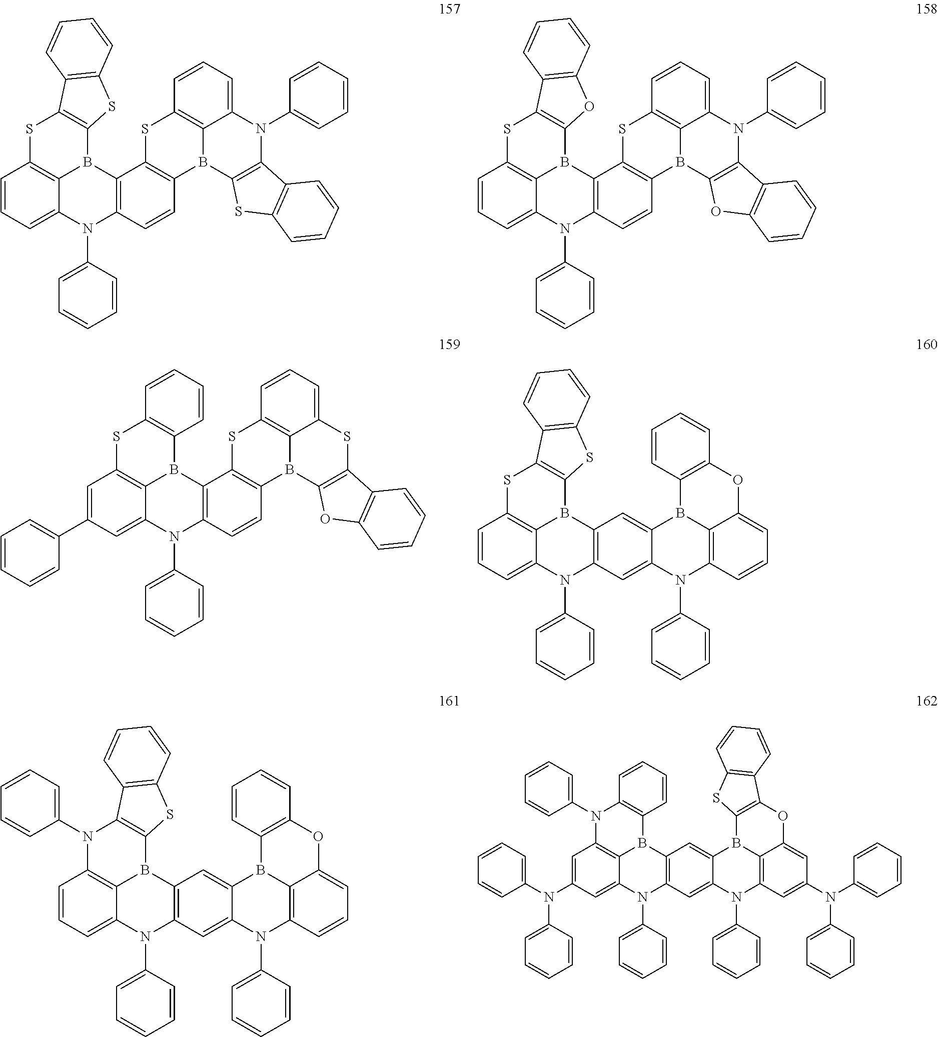

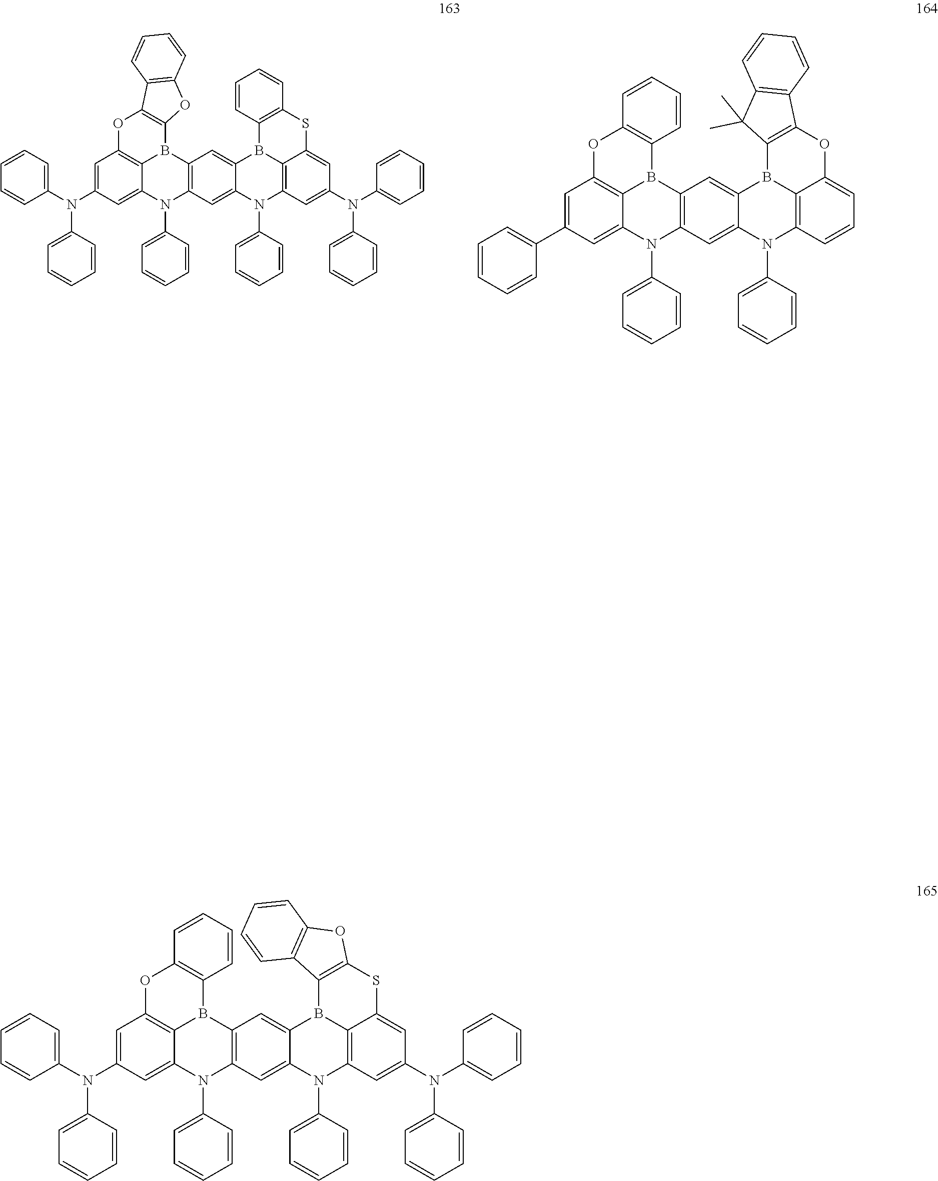 [SMILES: c1ccc(N(c2ccccc2)c2cc3c4c(c2)N(c2ccccc2)c2cc5c(cc2B4c2oc4ccccc4c2O3)B2c3ccccc3Sc3cc(N(c4ccccc4)c4ccccc4)cc(c32)N5c2ccccc2)cc1 ; CC1(C)C2=C(Oc3cccc4c3B2c2cc3c(cc2N4c2ccccc2)N(c2ccccc2)c2cc(-c4ccccc4)cc4c2B3c2ccccc2O4)c2ccccc21 ; c1ccc(N(c2ccccc2)c2cc3c4c(c2)N(c2ccccc2)c2cc5c(cc2B4c2ccccc2O3)B2c3c(cc(N(c4ccccc4)c4ccccc4)cc3N5c3ccccc3)Sc3oc4ccccc4c32)cc1]

The specific examples of the substituents defined above can be found in Compounds 1 to 165 but are not intended to limit the scope of the compound represented by Formula A-1 or A-2.

Like Compounds 1 to 165, polycyclic aromatic compounds containing B, P or P═O and having the substituents defined above can be used as organic light emitting materials whose intrinsic characteristics depend on the introduced substituents, particularly dopant materials for light emitting layers, to fabricate highly efficient organic electroluminescent devices.

More specifically, the host compound represented by Formula B can be selected from the following compounds:

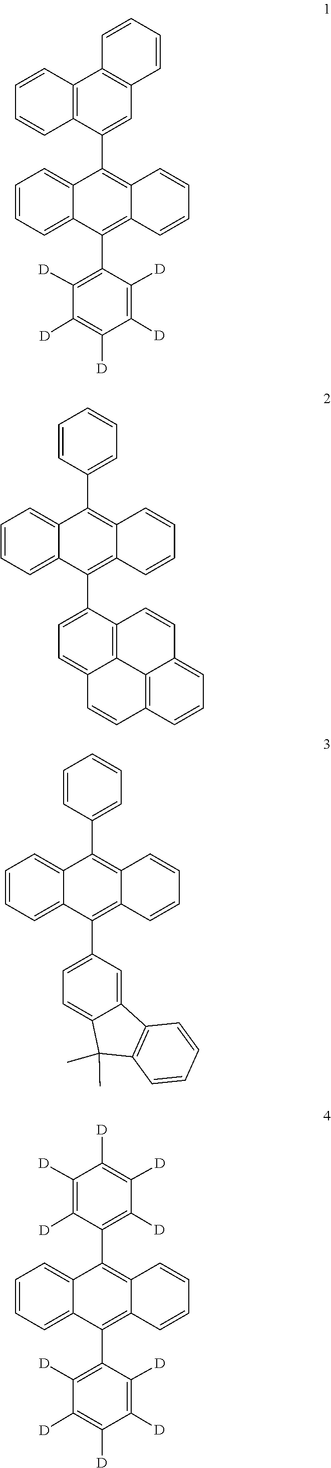

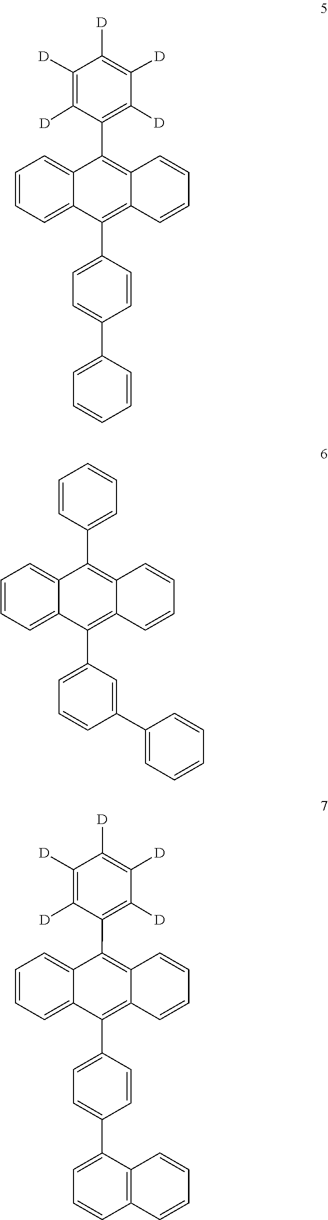

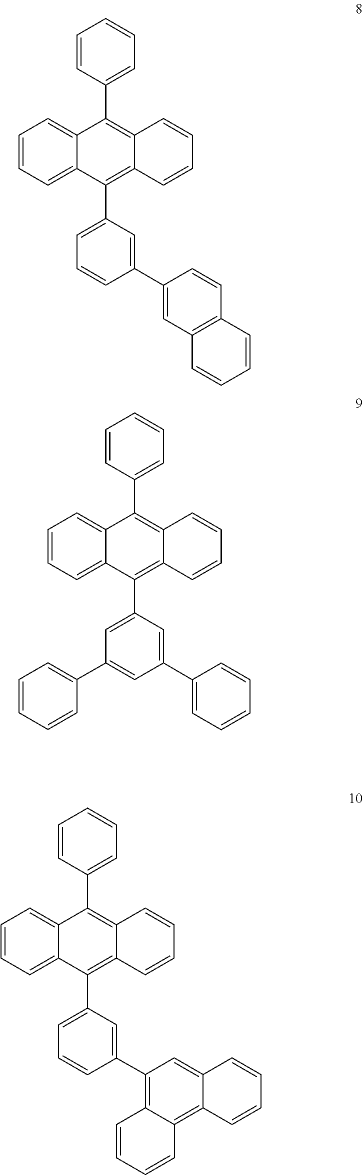

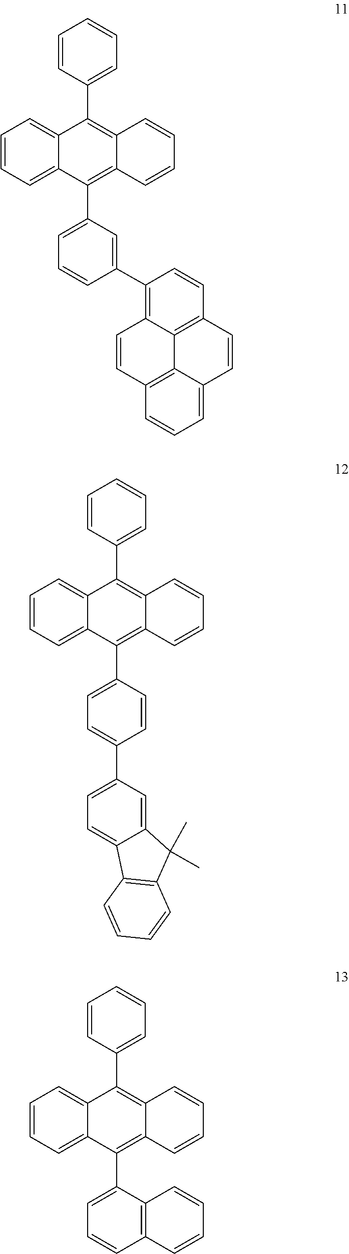

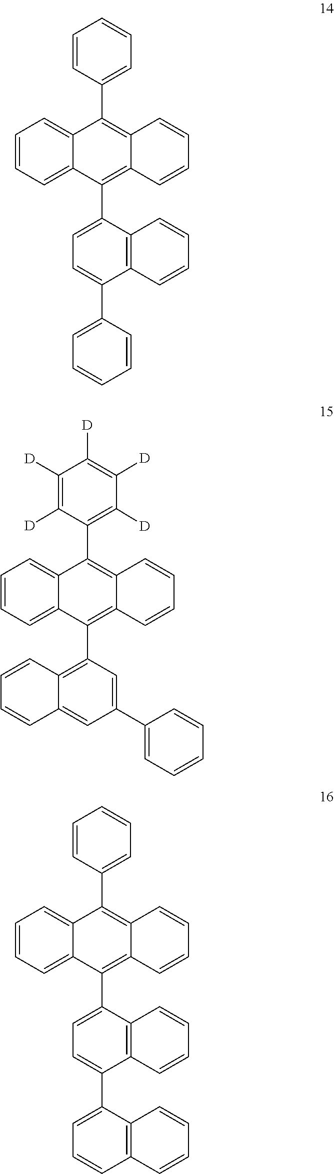

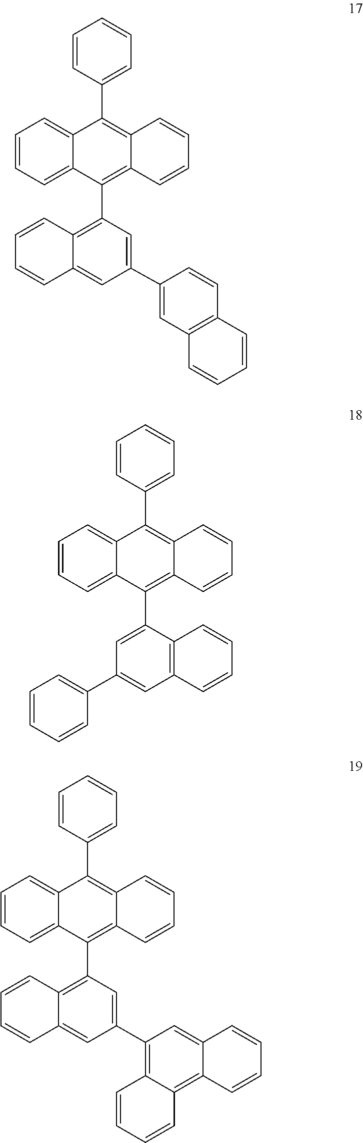

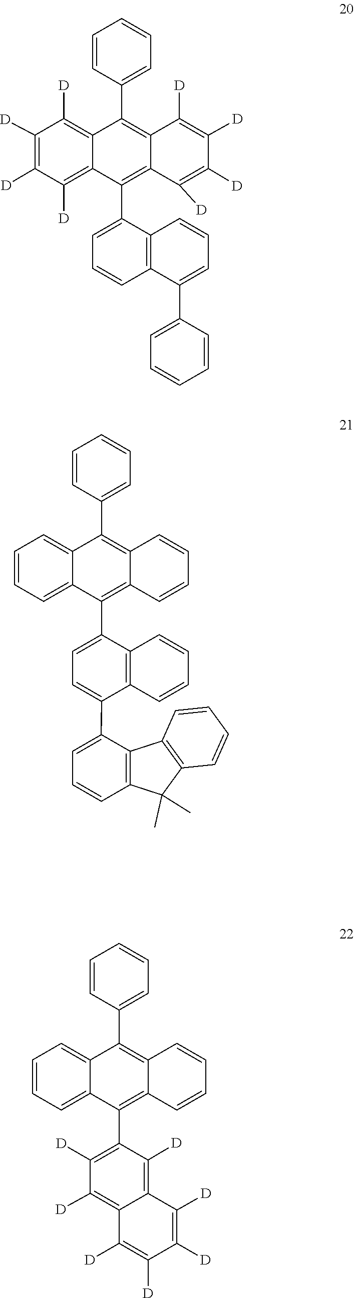

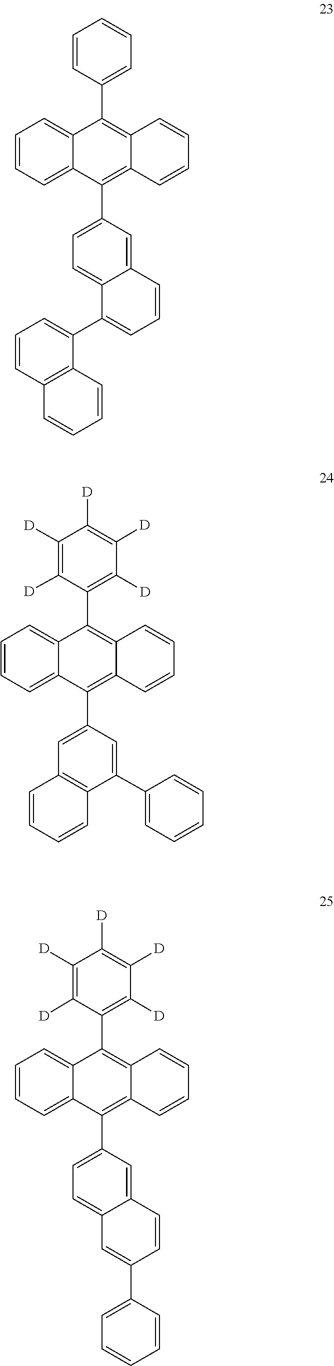

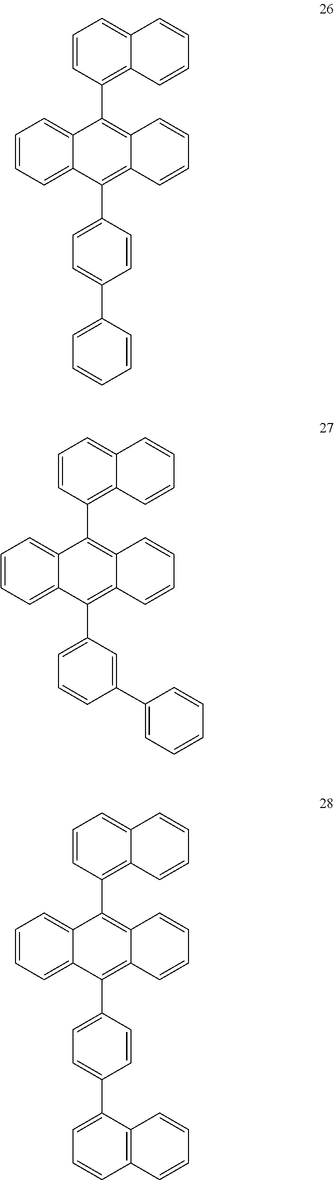

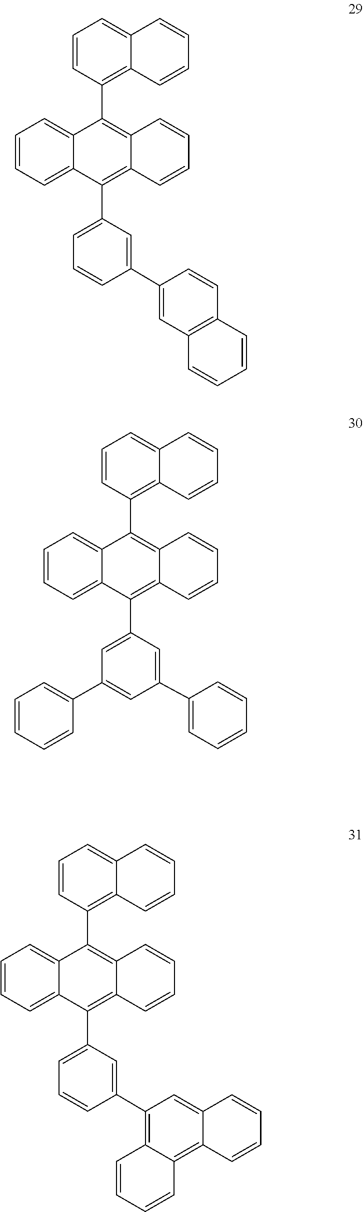

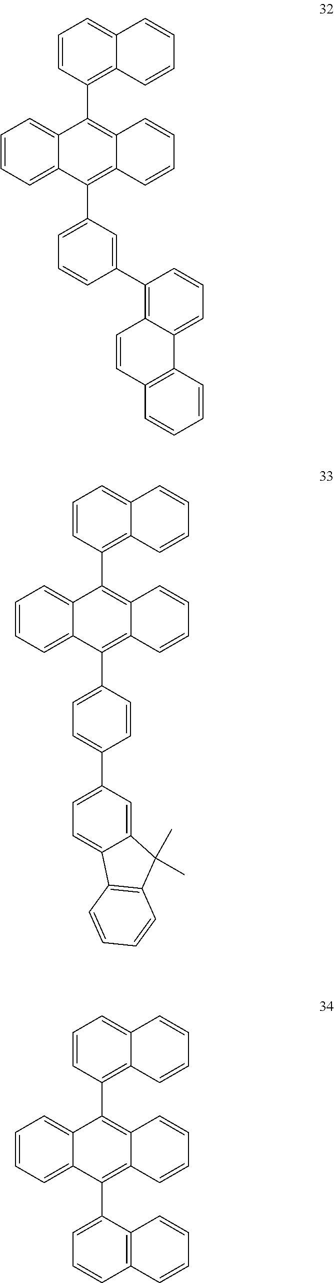

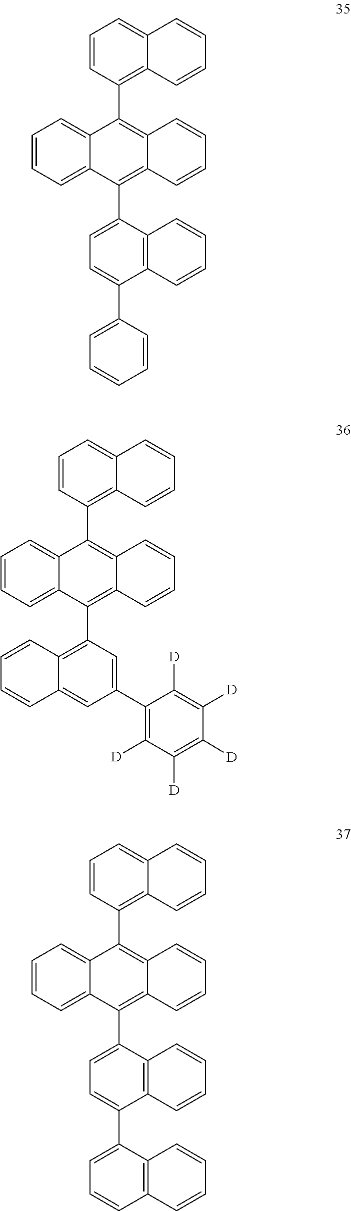

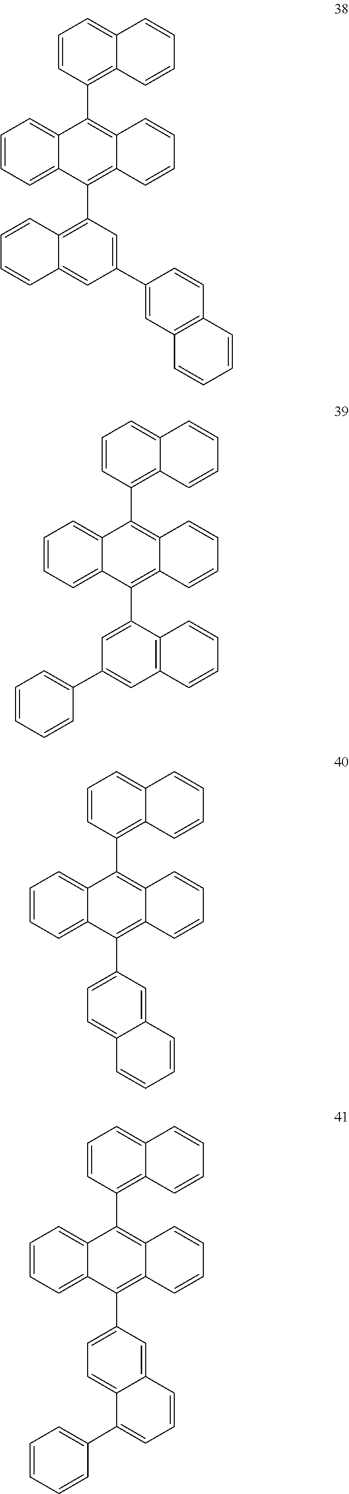

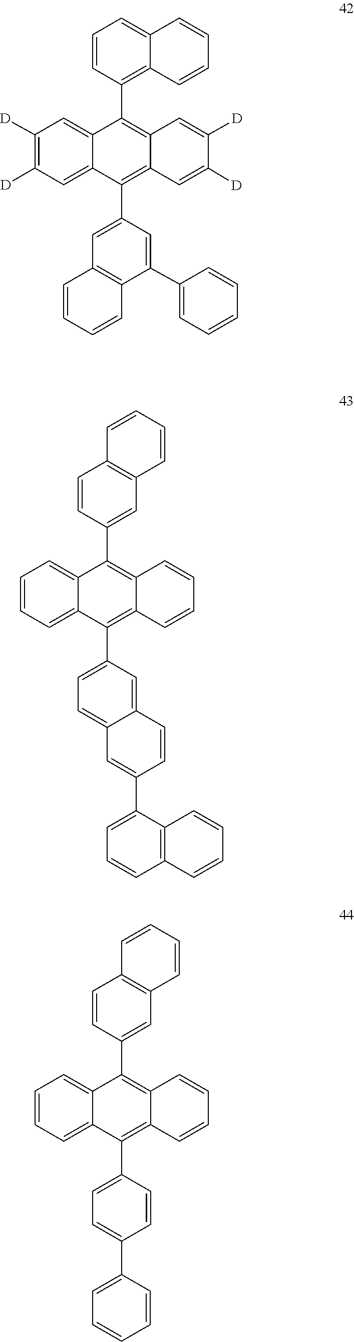

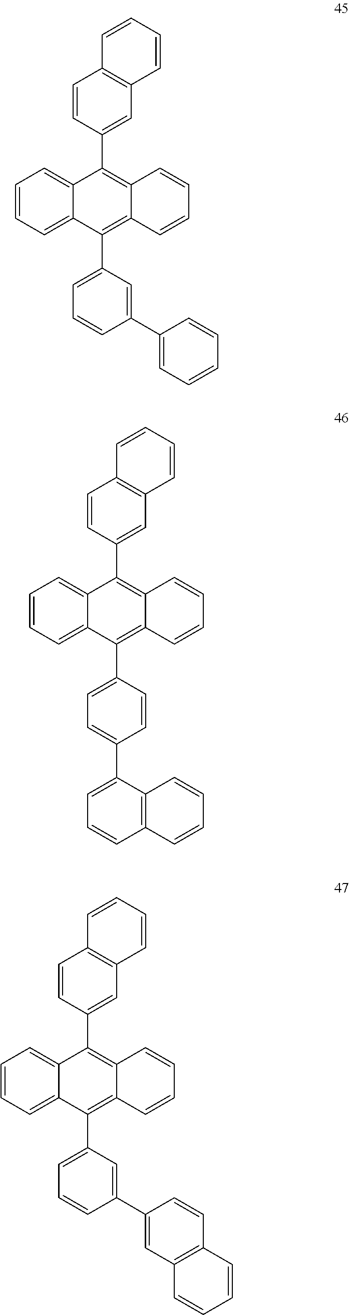

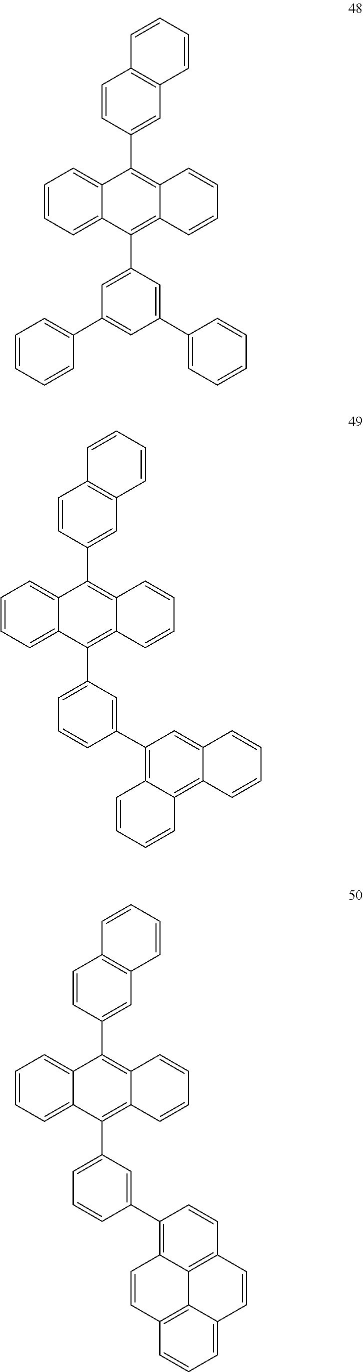

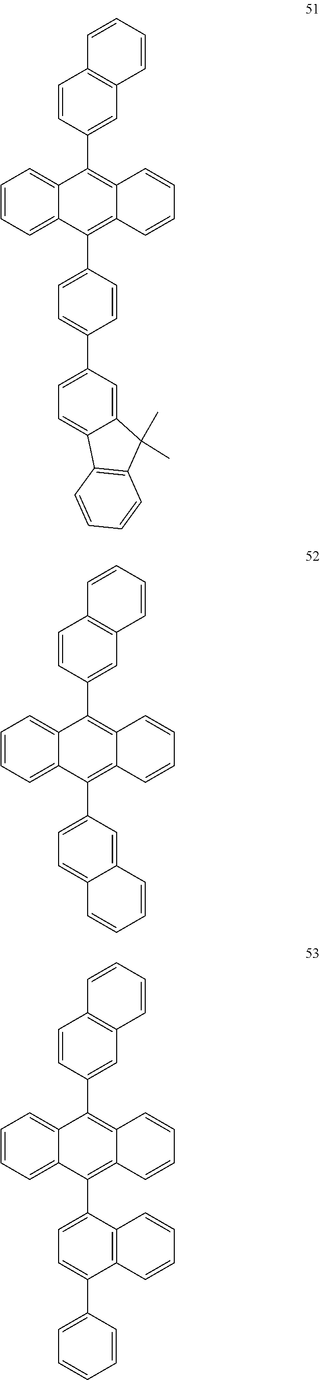

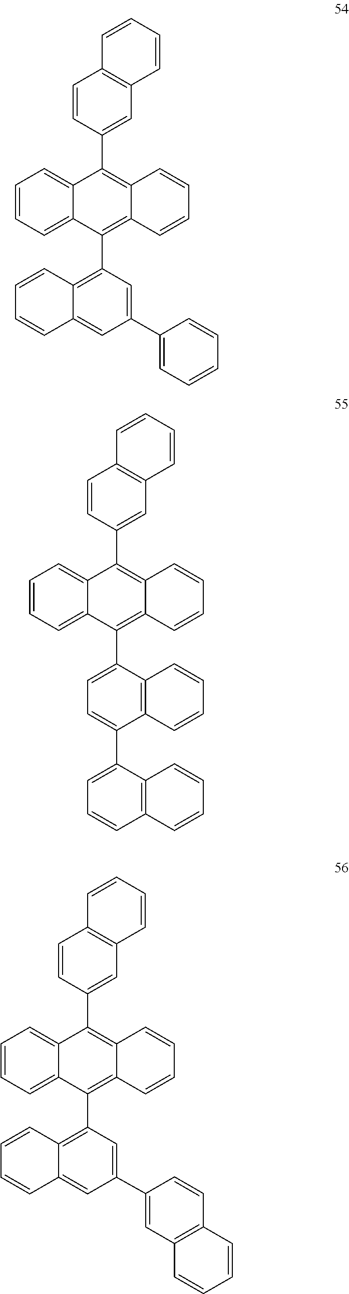

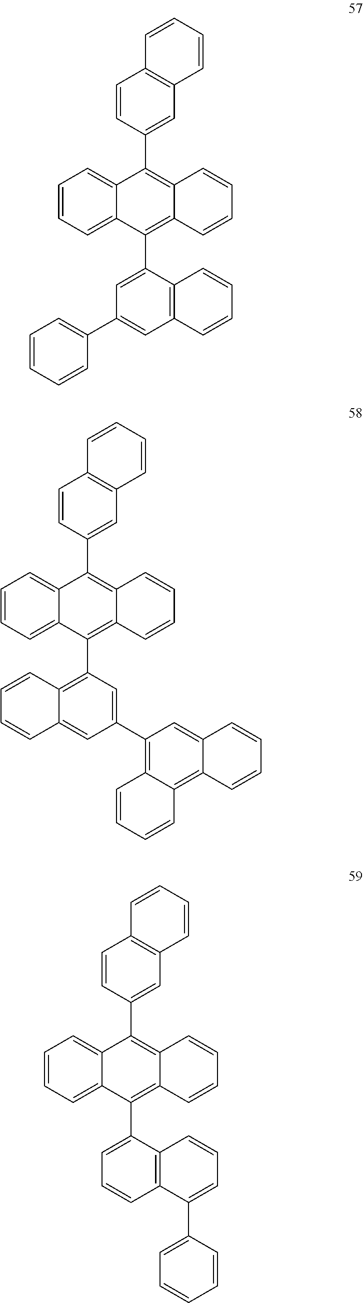

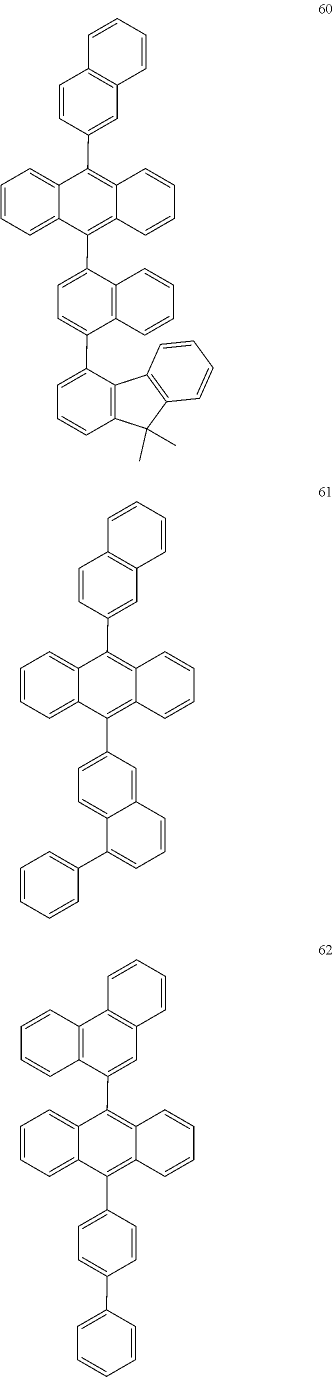

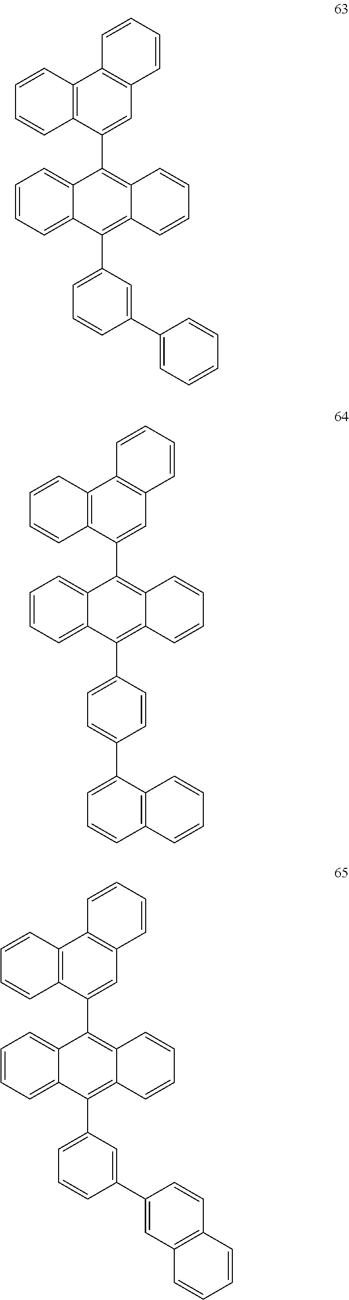

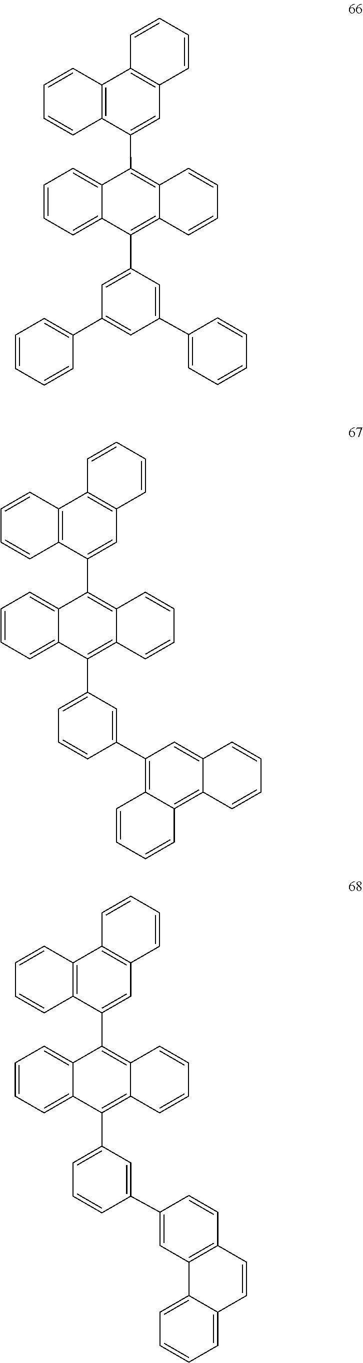

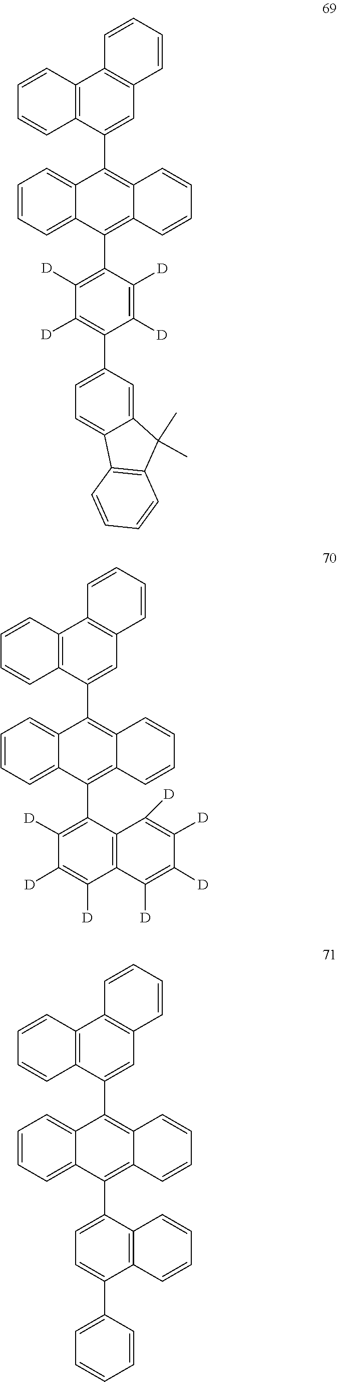

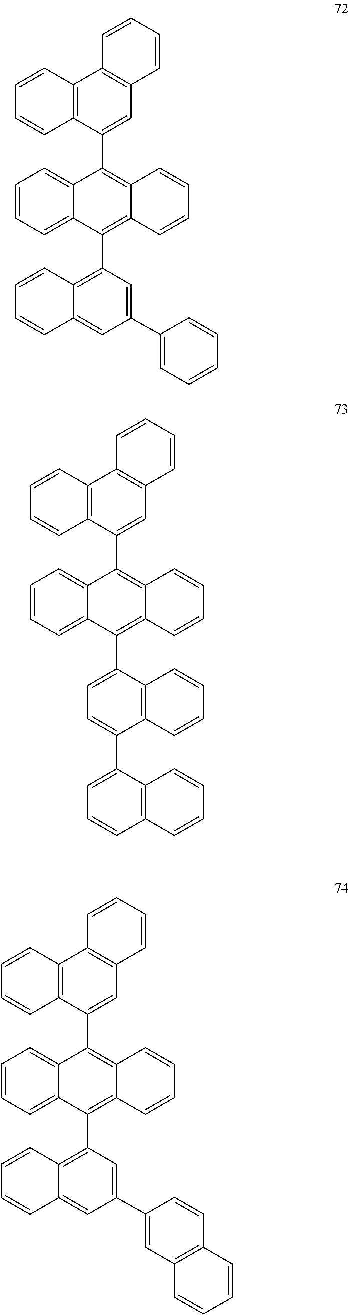

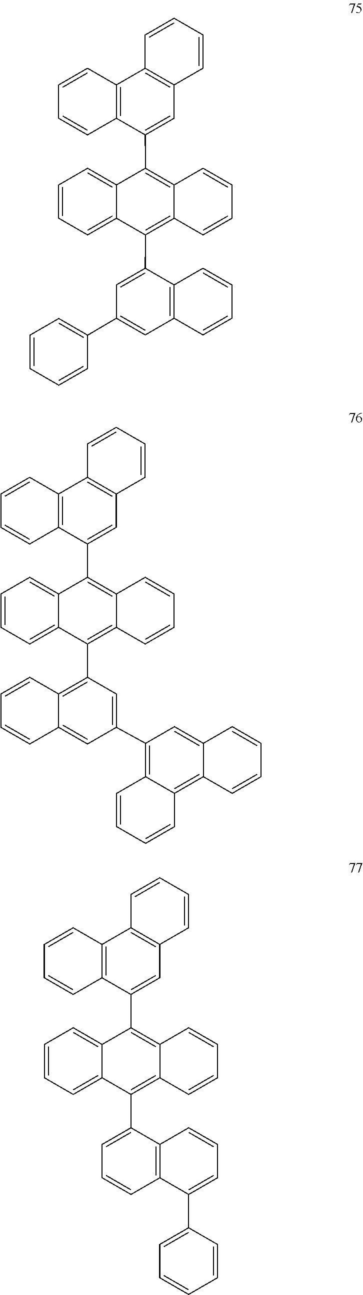

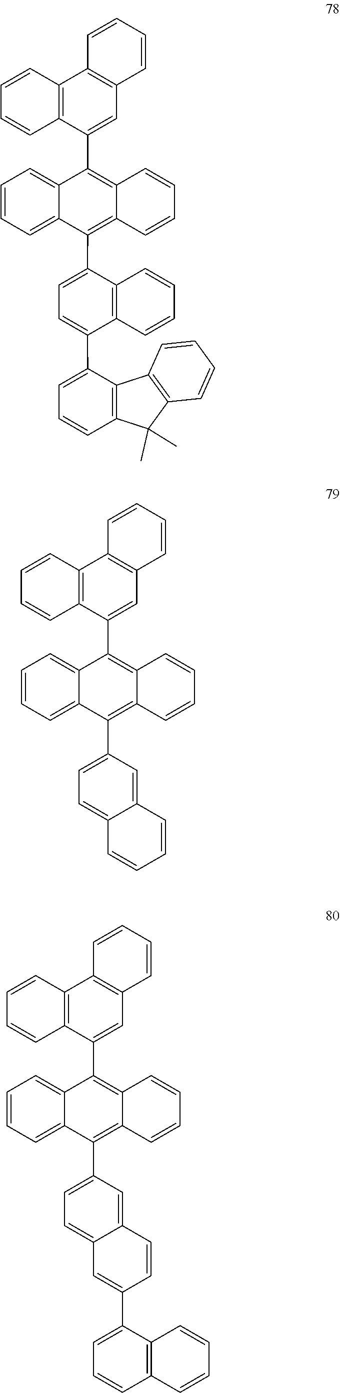

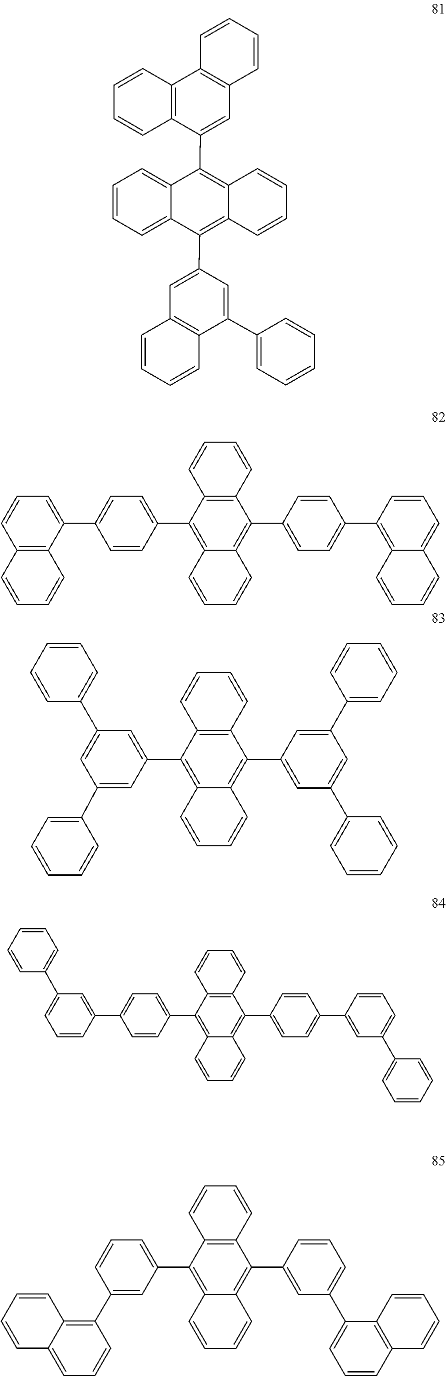

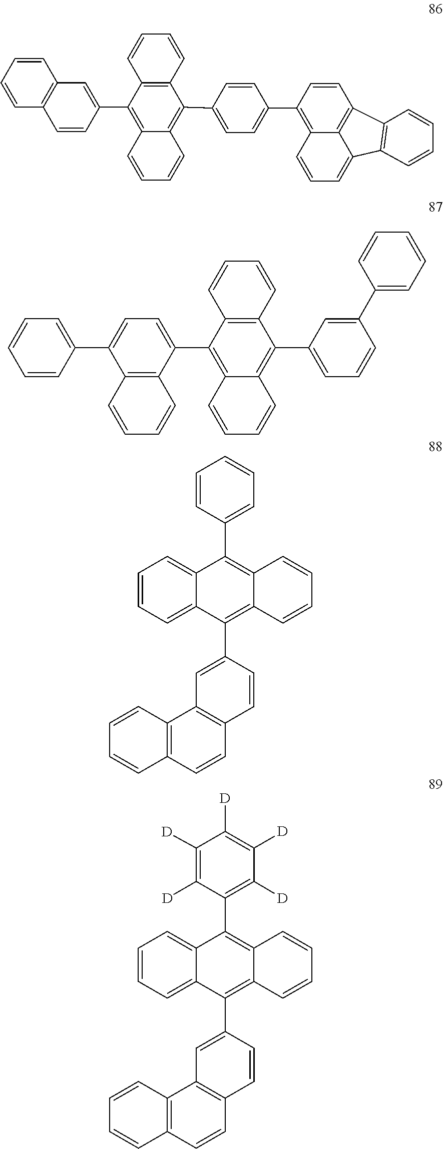

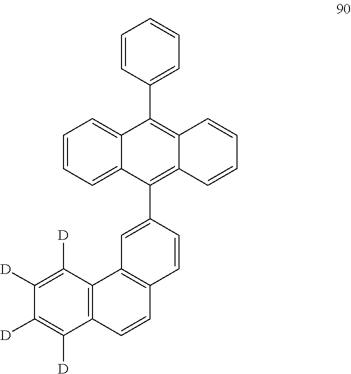 [SMILES: [2H]c1c([2H])c([2H])c2c(ccc3ccc(-c4c5ccccc5c(-c5ccccc5)c5ccccc45)cc32)c1[2H]]

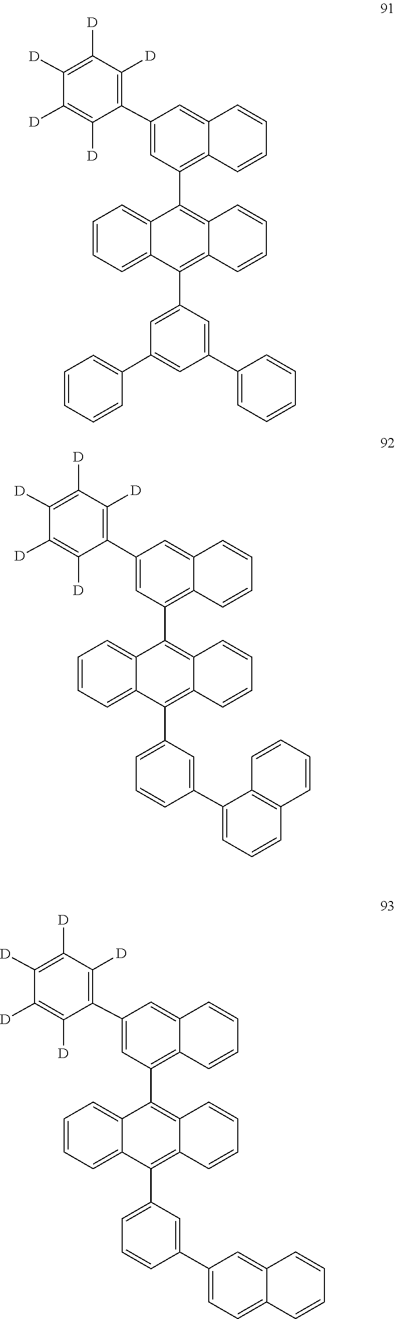

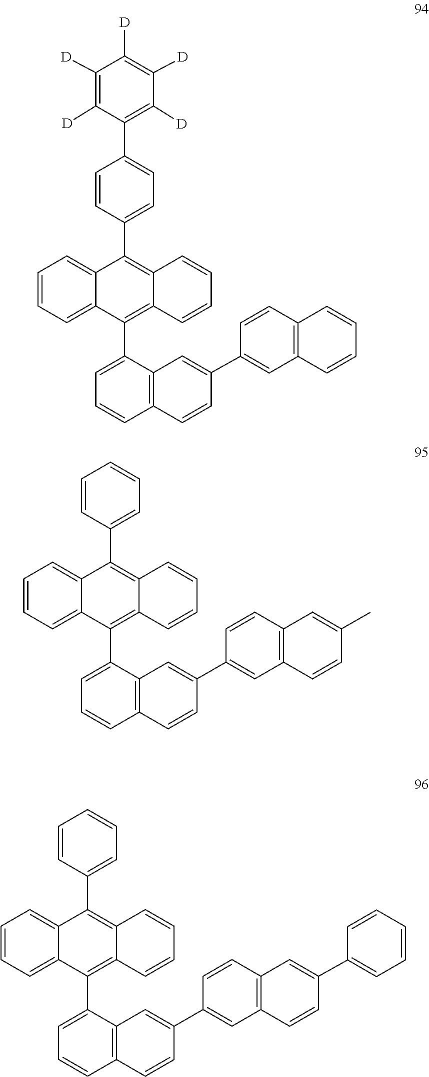

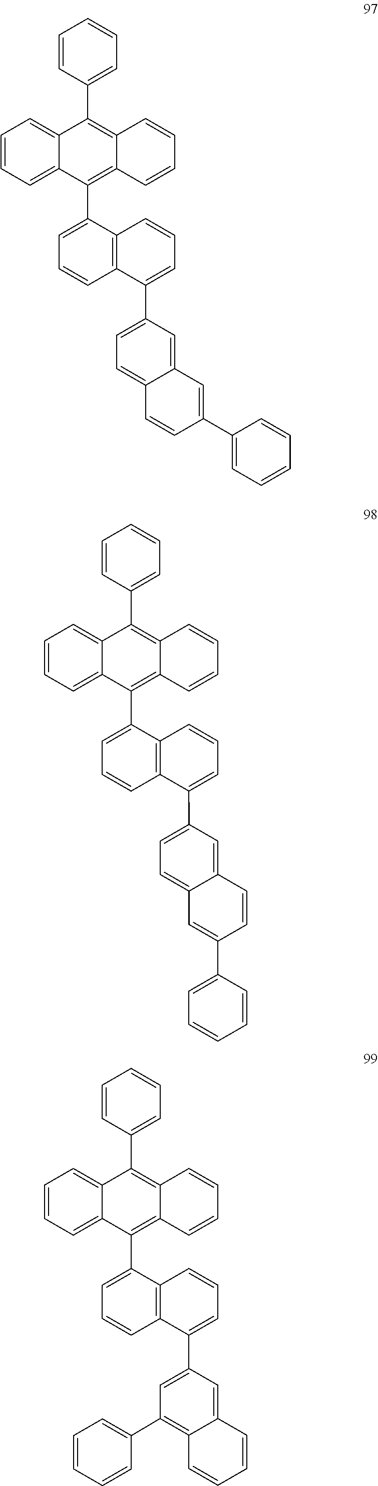

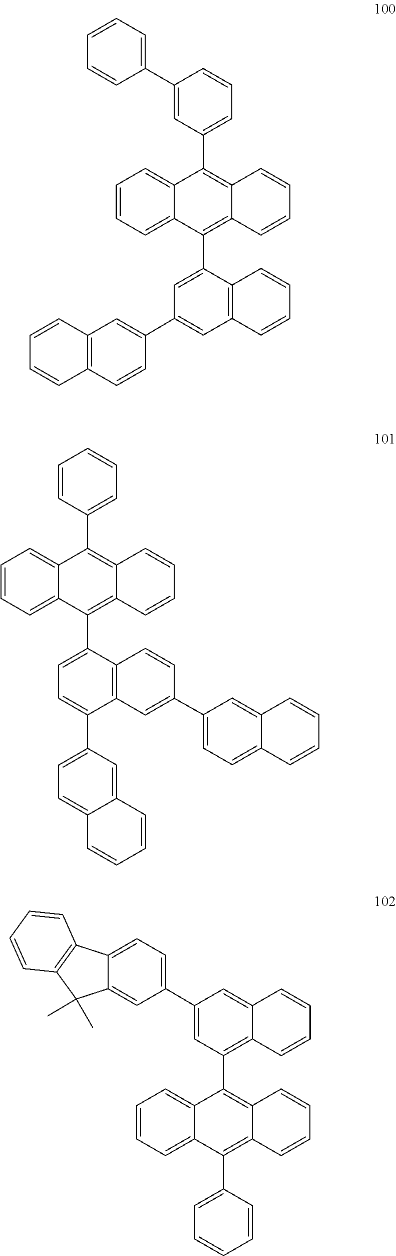

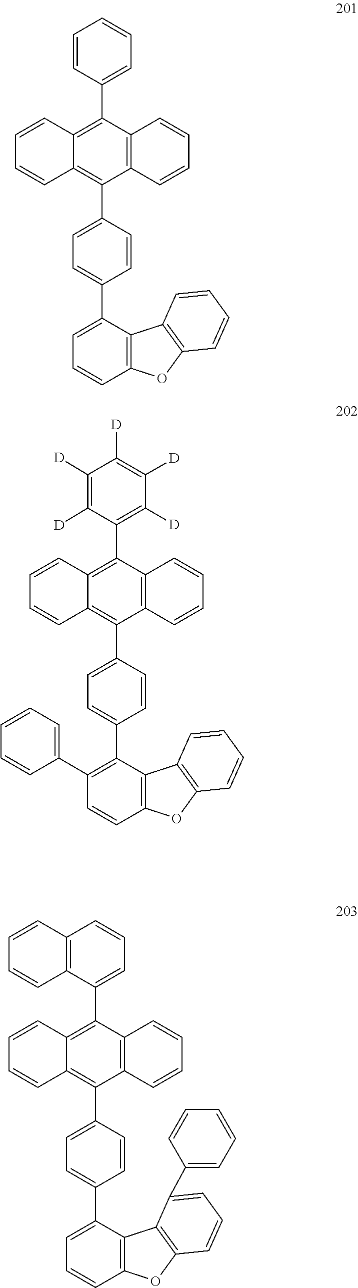

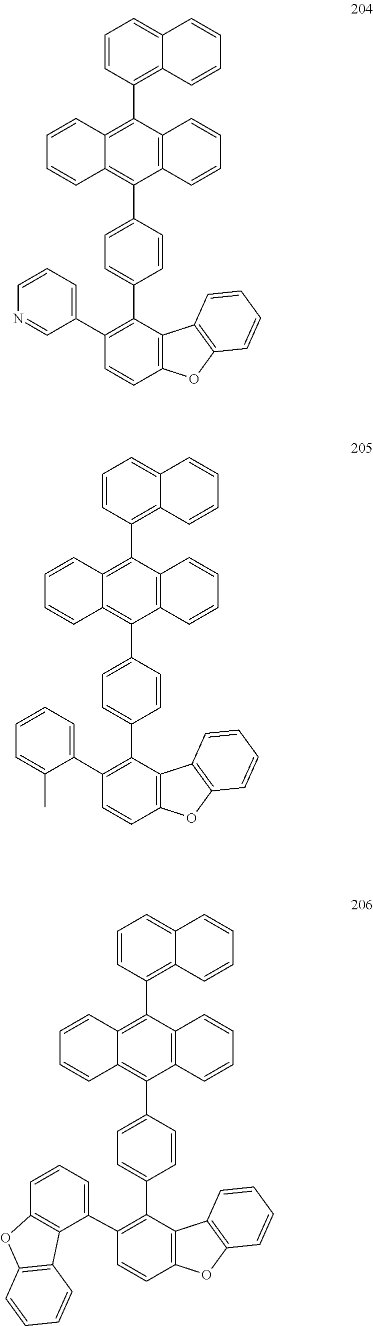 [SMILES: c1cncc(-c2ccc3oc4ccccc4c3c2-c2ccc(-c3c4ccccc4c(-c4cccc5ccccc45)c4ccccc34)cc2)c1 ; Cc1ccccc1-c1ccc2oc3ccccc3c2c1-c1ccc(-c2c3ccccc3c(-c3cccc4ccccc34)c3ccccc23)cc1 ; c1ccc2c(-c3c4ccccc4c(-c4ccc(-c5c(-c6cccc7oc8ccccc8c67)ccc6oc7ccccc7c56)cc4)c4ccccc34)cccc2c1]

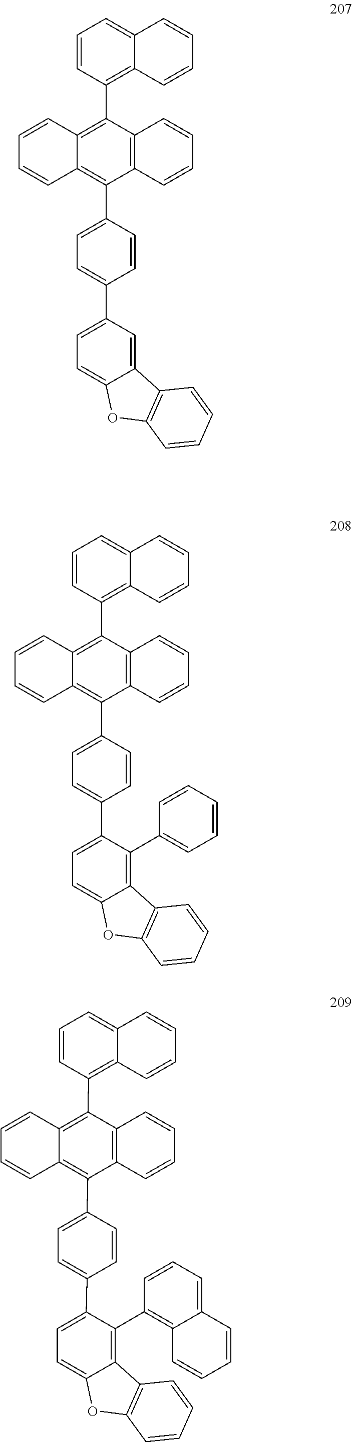 [SMILES: c1ccc2c(-c3c4ccccc4c(-c4ccc(-c5ccc6oc7ccccc7c6c5)cc4)c4ccccc34)cccc2c1 ; c1ccc(-c2c(-c3ccc(-c4c5ccccc5c(-c5cccc6ccccc56)c5ccccc45)cc3)ccc3oc4ccccc4c23)cc1 ; c1ccc2c(-c3c4ccccc4c(-c4ccc(-c5ccc6oc7ccccc7c6c5-c5cccc6ccccc56)cc4)c4ccccc34)cccc2c1]

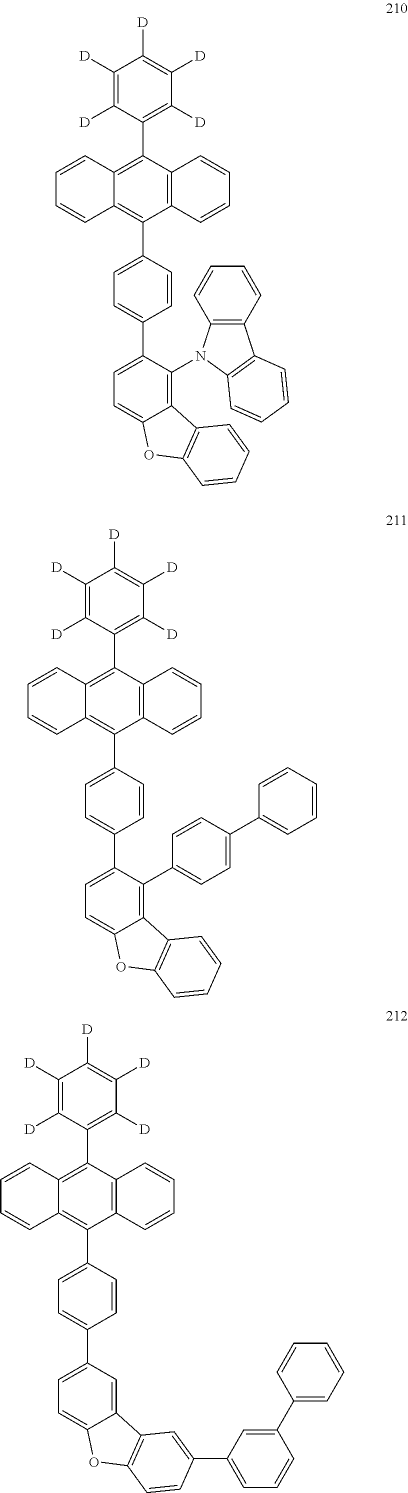 [SMILES: [2H]c1c([2H])c([2H])c(-c2c3ccccc3c(-c3ccc(-c4ccc5oc6ccccc6c5c4-n4c5ccccc5c5ccccc54)cc3)c3ccccc23)c([2H])c1[2H] ; [2H]c1c([2H])c([2H])c(-c2c3ccccc3c(-c3ccc(-c4ccc5oc6ccccc6c5c4-c4ccc(-c5ccccc5)cc4)cc3)c3ccccc23)c([2H])c1[2H] ; [2H]c1c([2H])c([2H])c(-c2c3ccccc3c(-c3ccc(-c4ccc5oc6ccc(-c7cccc(-c8ccccc8)c7)cc6c5c4)cc3)c3ccccc23)c([2H])c1[2H]]

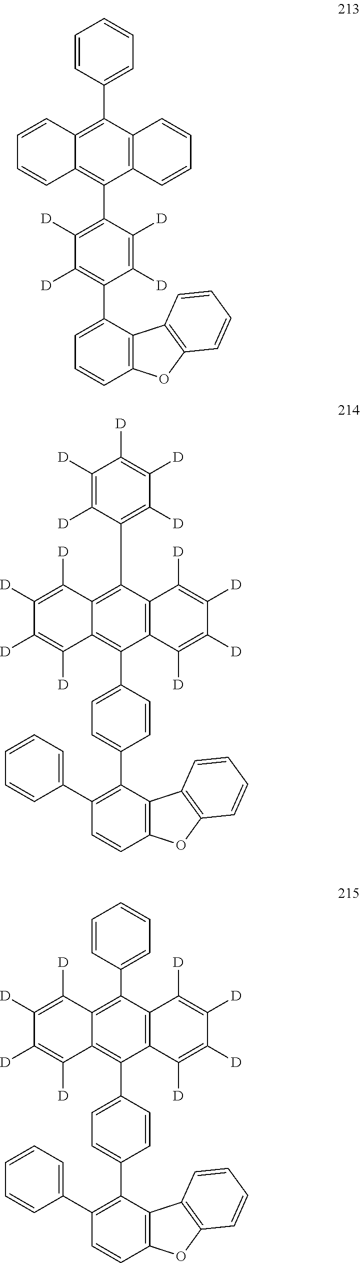

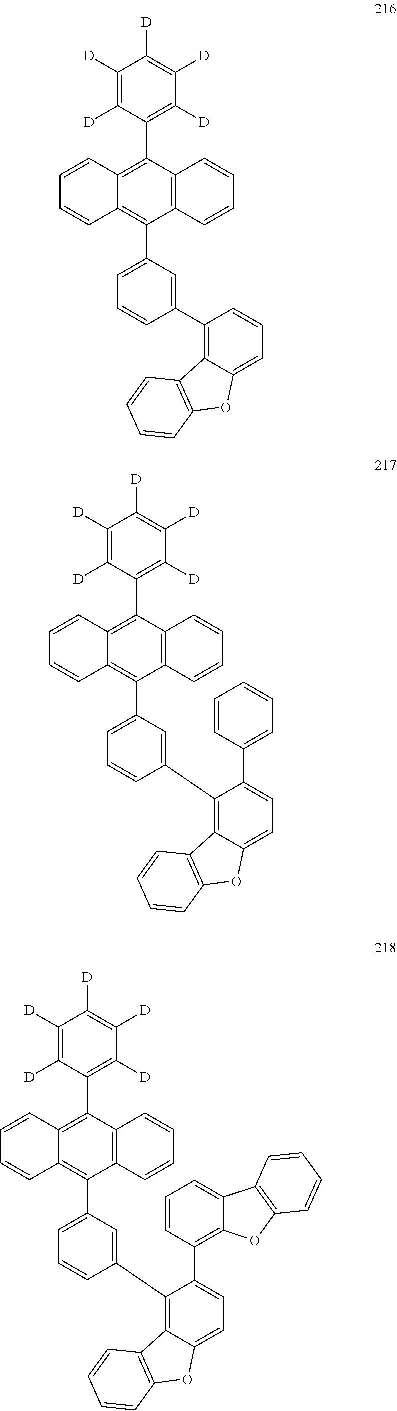

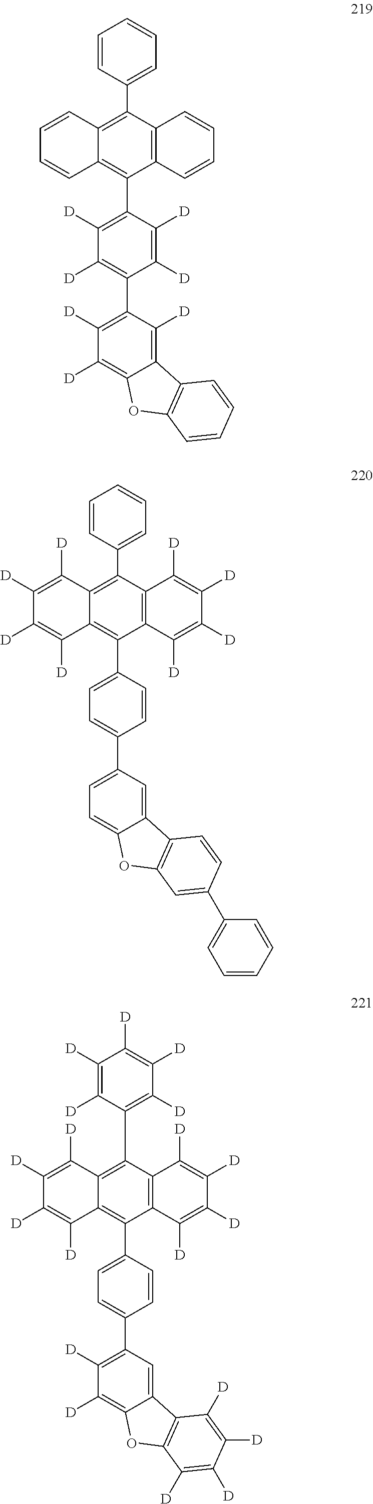 [SMILES: [2H]c1c([2H])c(-c2c3ccccc3c(-c3ccccc3)c3ccccc23)c([2H])c([2H])c1-c1c([2H])c([2H])c2oc3ccccc3c2c1[2H] ; [2H]c1c([2H])c([2H])c2c(-c3ccc(-c4ccc5oc6cc(-c7ccccc7)ccc6c5c4)cc3)c3c([2H])c([2H])c([2H])c([2H])c3c(-c3ccccc3)c2c1[2H] ; [2H]c1c([2H])c([2H])c(-c2c3c([2H])c([2H])c([2H])c([2H])c3c(-c3ccc(-c4cc5c(oc6c([2H])c([2H])c([2H])c([2H])c65)c([2H])c4[2H])cc3)c3c([2H])c([2H])c([2H])c([2H])c23)c([2H])c1[2H]]

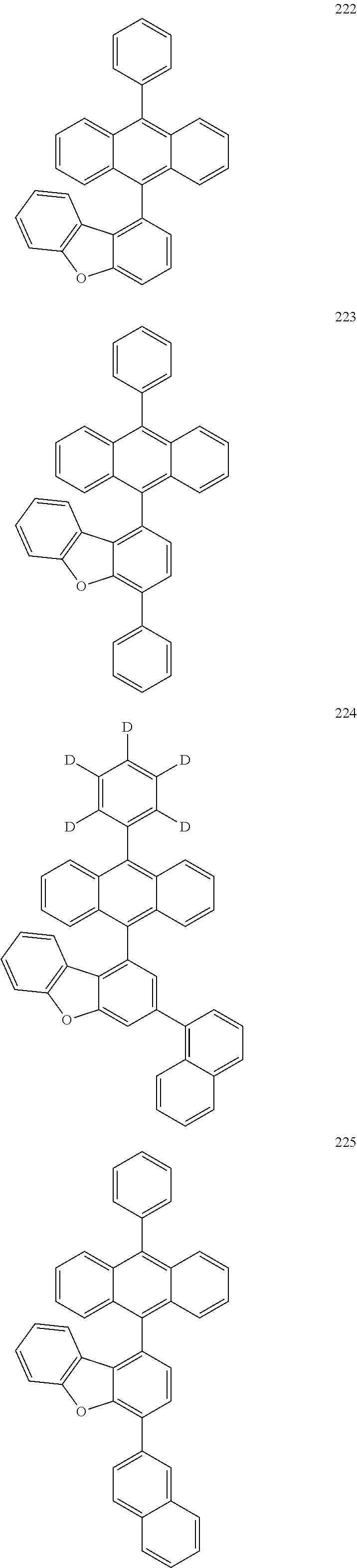

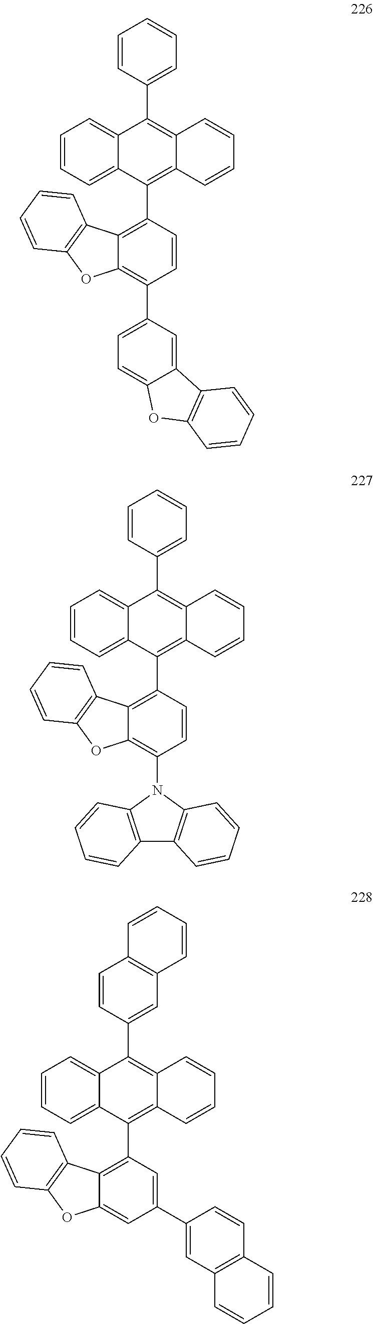 [SMILES: c1ccc(-c2c3ccccc3c(-c3ccc(-c4ccc5oc6ccccc6c5c4)c4oc5ccccc5c34)c3ccccc23)cc1 ; c1ccc(-c2c3ccccc3c(-c3ccc(-n4c5ccccc5c5ccccc54)c4oc5ccccc5c34)c3ccccc23)cc1 ; c1ccc2cc(-c3cc(-c4c5ccccc5c(-c5ccc6ccccc6c5)c5ccccc45)c4c(c3)oc3ccccc34)ccc2c1]

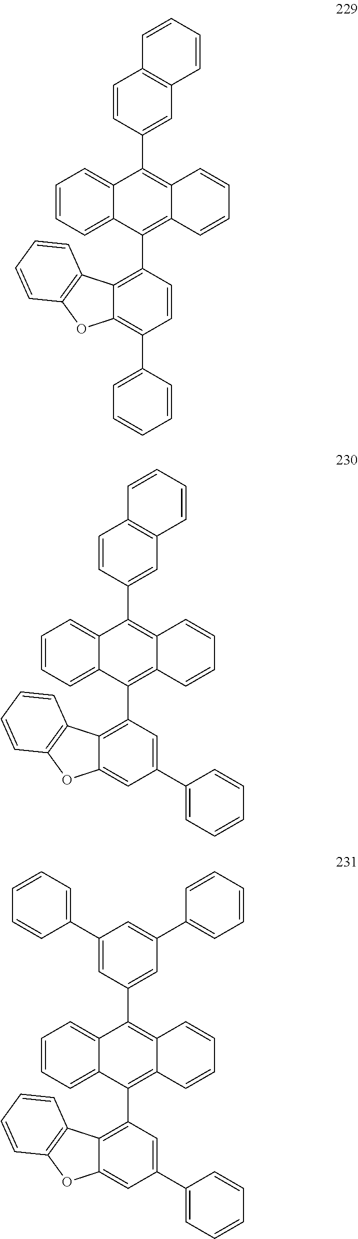

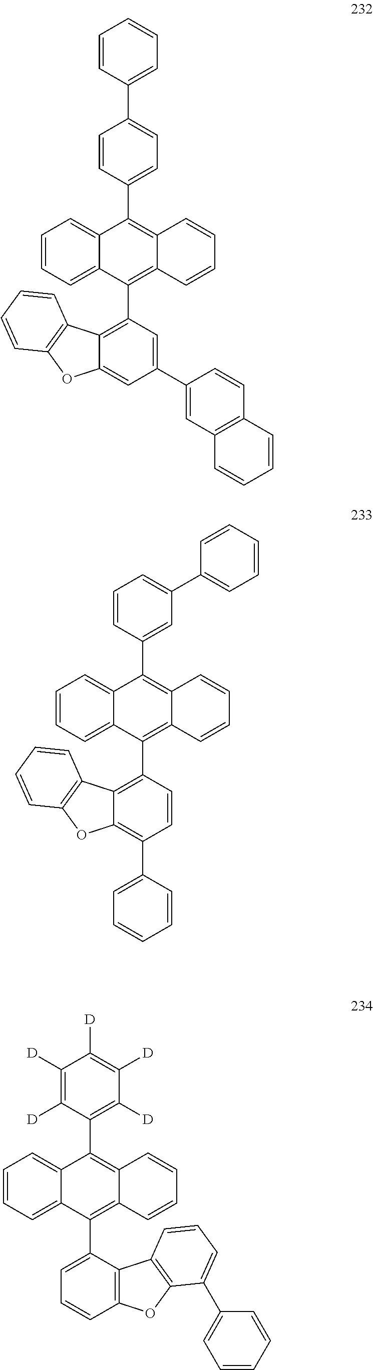

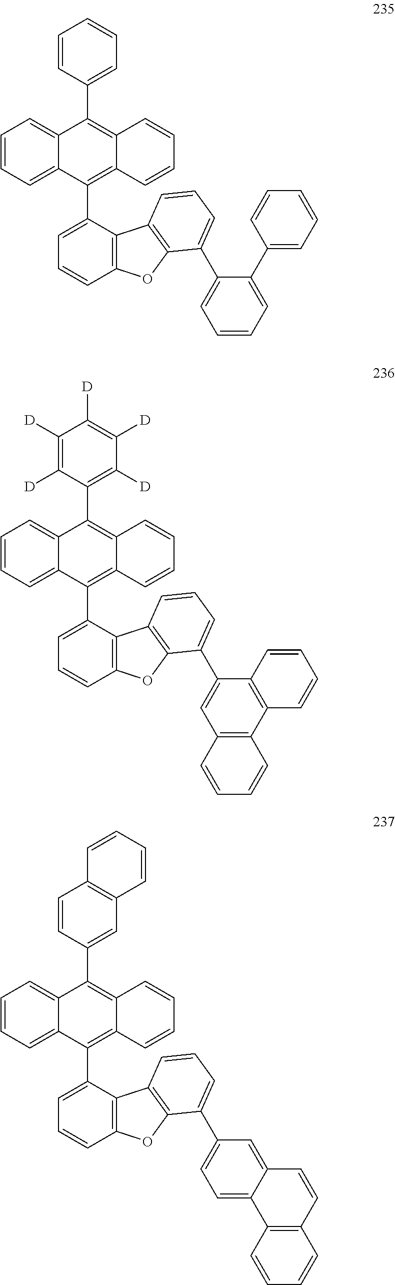 [SMILES: c1ccc(-c2ccccc2-c2cccc3c2oc2cccc(-c4c5ccccc5c(-c5ccccc5)c5ccccc45)c23)cc1 ; [2H]c1c([2H])c([2H])c(-c2c3ccccc3c(-c3cccc4oc5c(-c6cc7ccccc7c7ccccc67)cccc5c34)c3ccccc23)c([2H])c1[2H] ; c1ccc2cc(-c3c4ccccc4c(-c4cccc5oc6c(-c7ccc8c(ccc9ccccc98)c7)cccc6c45)c4ccccc34)ccc2c1]

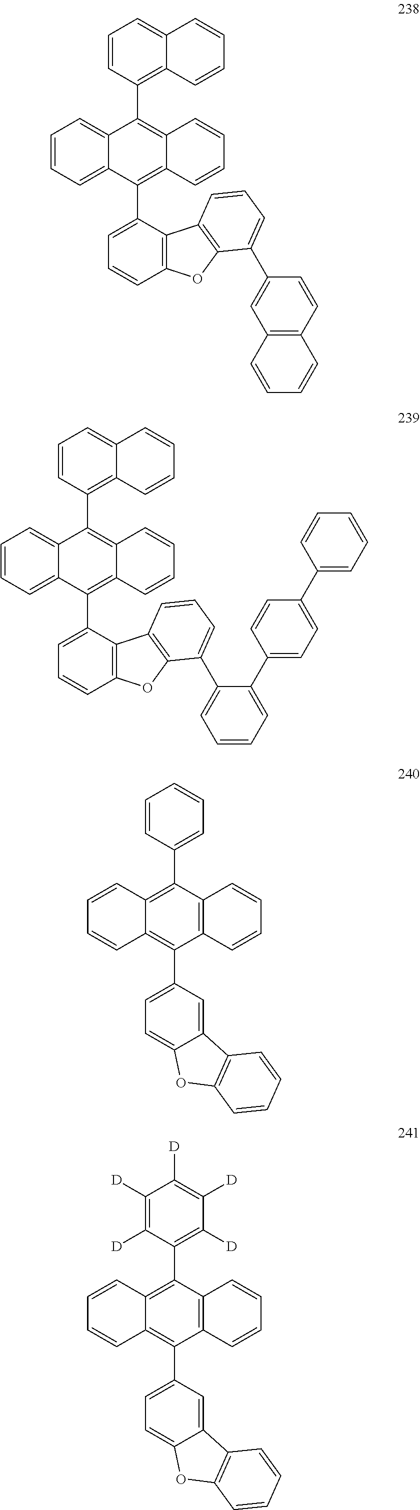 [SMILES: c1ccc2cc(-c3cccc4c3oc3cccc(-c5c6ccccc6c(-c6cccc7ccccc67)c6ccccc56)c34)ccc2c1 ; c1ccc(-c2ccc(-c3ccccc3-c3cccc4c3oc3cccc(-c5c6ccccc6c(-c6cccc7ccccc67)c6ccccc56)c34)cc2)cc1 ; c1ccc(-c2c3ccccc3c(-c3ccc4oc5ccccc5c4c3)c3ccccc23)cc1 ; [2H]c1c([2H])c([2H])c(-c2c3ccccc3c(-c3ccc4oc5ccccc5c4c3)c3ccccc23)c([2H])c1[2H]]

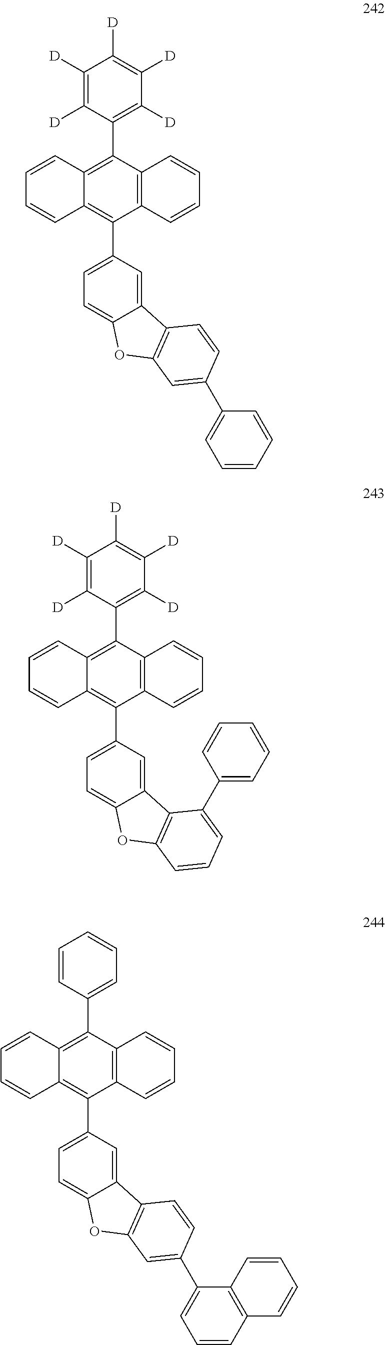 [SMILES: [2H]c1c([2H])c([2H])c(-c2c3ccccc3c(-c3ccc4oc5cc(-c6ccccc6)ccc5c4c3)c3ccccc23)c([2H])c1[2H] ; [2H]c1c([2H])c([2H])c(-c2c3ccccc3c(-c3ccc4oc5cccc(-c6ccccc6)c5c4c3)c3ccccc23)c([2H])c1[2H] ; c1ccc(-c2c3ccccc3c(-c3ccc4oc5cc(-c6cccc7ccccc67)ccc5c4c3)c3ccccc23)cc1]

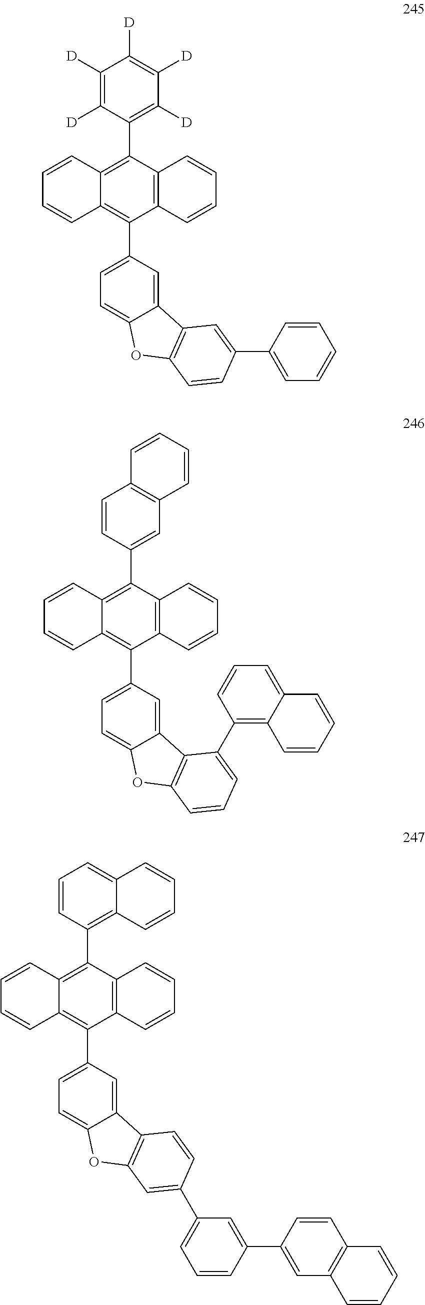 [SMILES: [2H]c1c([2H])c([2H])c(-c2c3ccccc3c(-c3ccc4oc5ccc(-c6ccccc6)cc5c4c3)c3ccccc23)c([2H])c1[2H] ; c1ccc2cc(-c3c4ccccc4c(-c4ccc5oc6cccc(-c7cccc8ccccc78)c6c5c4)c4ccccc34)ccc2c1 ; c1cc(-c2ccc3ccccc3c2)cc(-c2ccc3c(c2)oc2ccc(-c4c5ccccc5c(-c5cccc6ccccc56)c5ccccc45)cc23)c1]

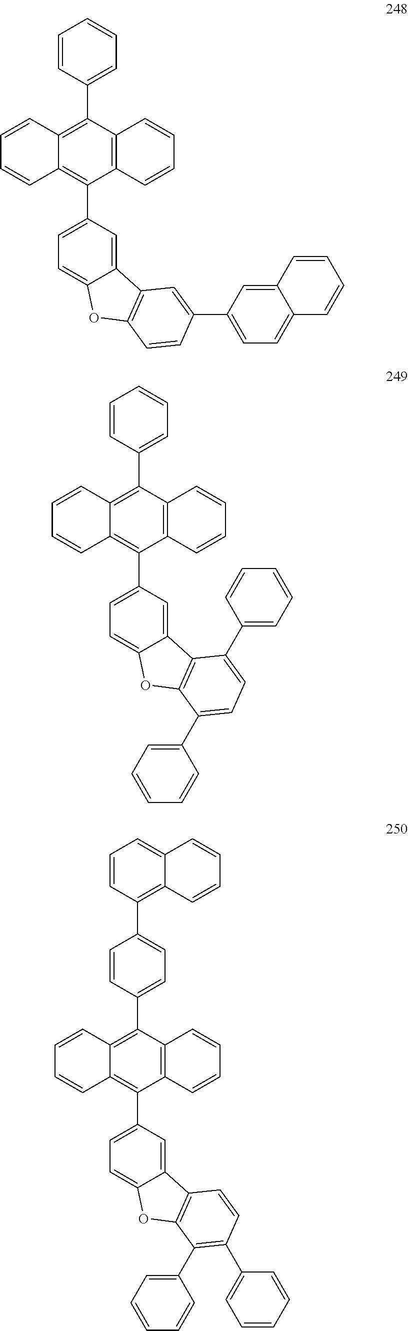

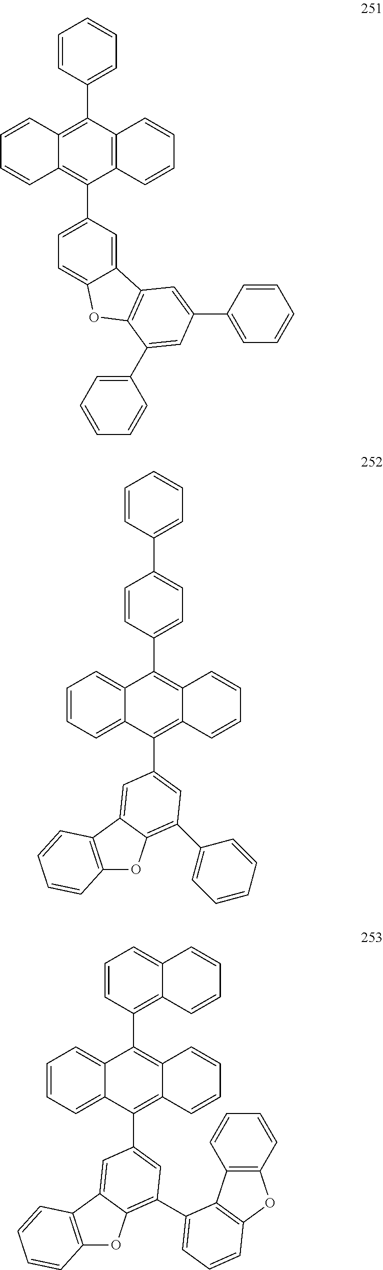

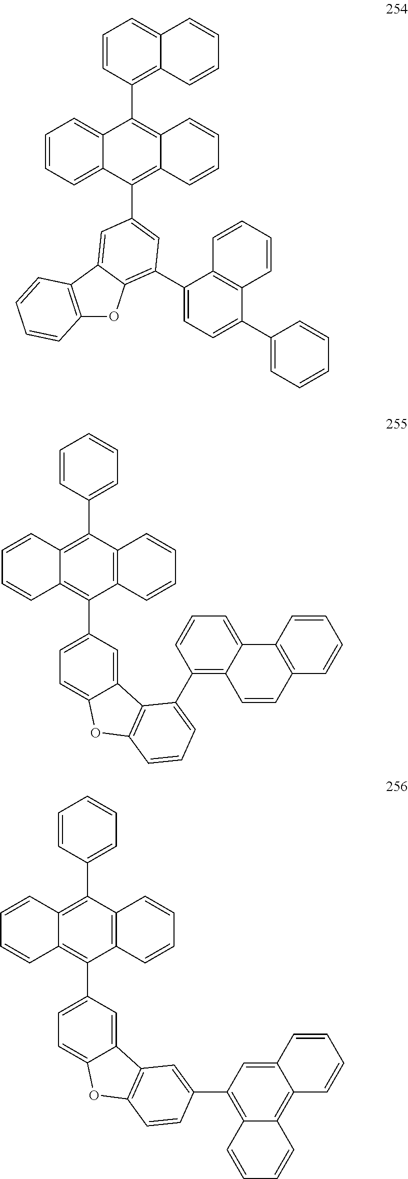 [SMILES: c1ccc(-c2ccc(-c3cc(-c4c5ccccc5c(-c5cccc6ccccc56)c5ccccc45)cc4c3oc3ccccc34)c3ccccc23)cc1 ; c1ccc(-c2c3ccccc3c(-c3ccc4oc5cccc(-c6cccc7c6ccc6ccccc67)c5c4c3)c3ccccc23)cc1 ; c1ccc(-c2c3ccccc3c(-c3ccc4oc5ccc(-c6cc7ccccc7c7ccccc67)cc5c4c3)c3ccccc23)cc1]

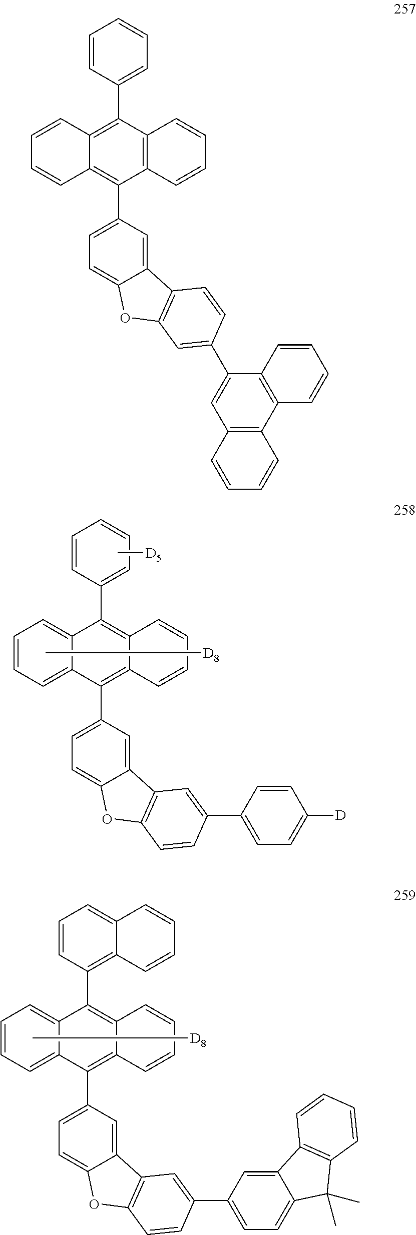

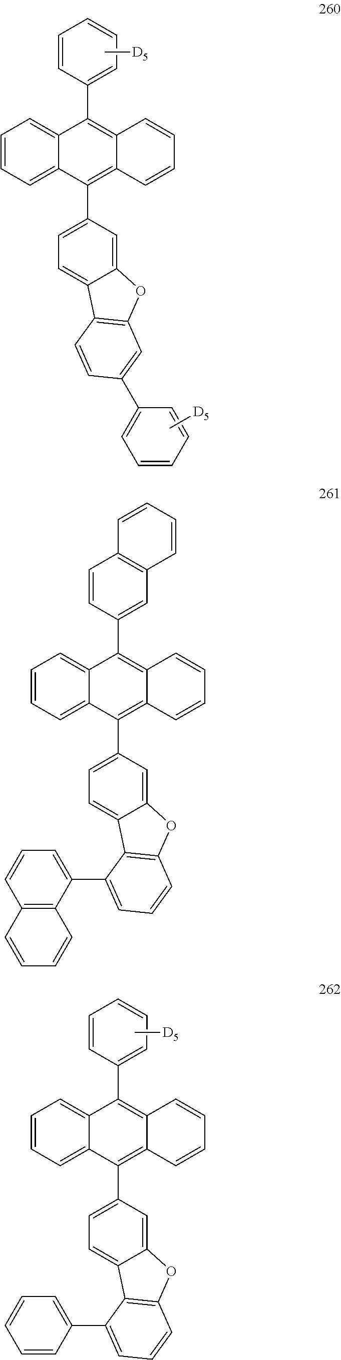

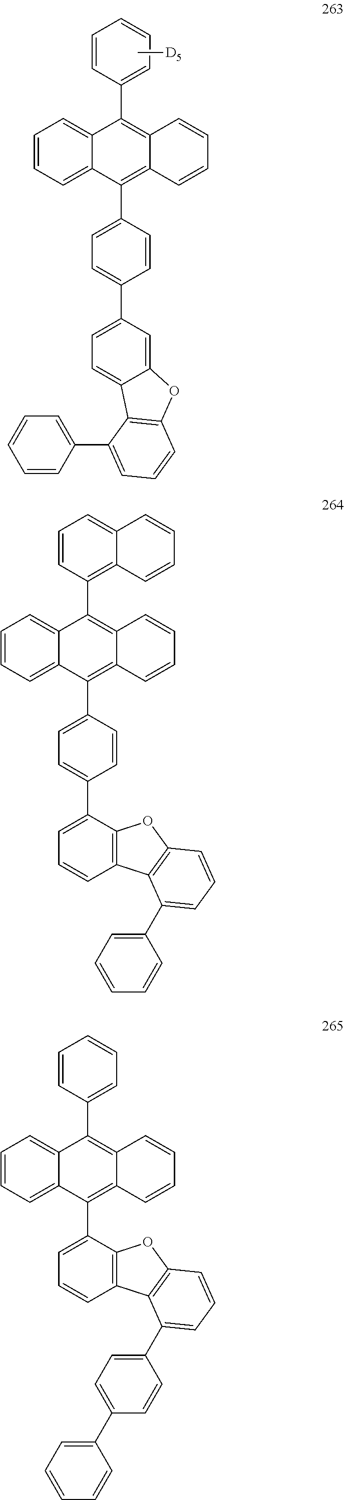

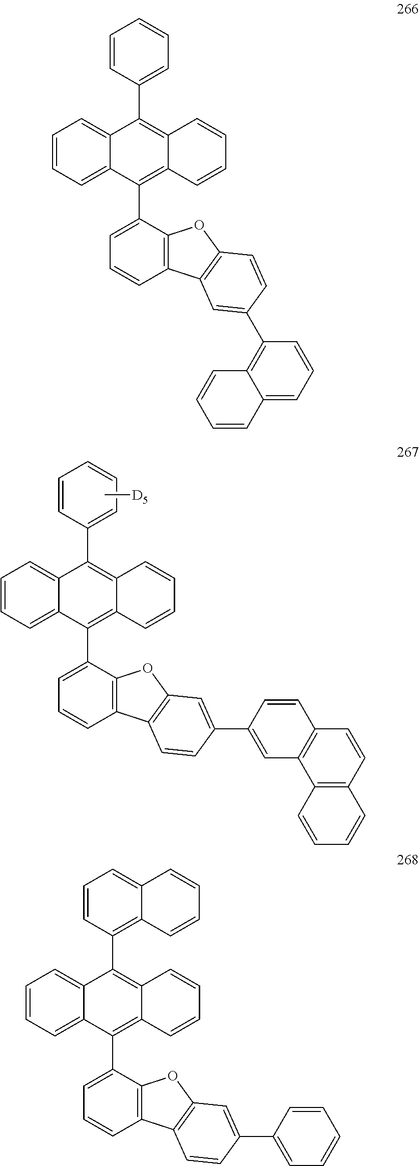

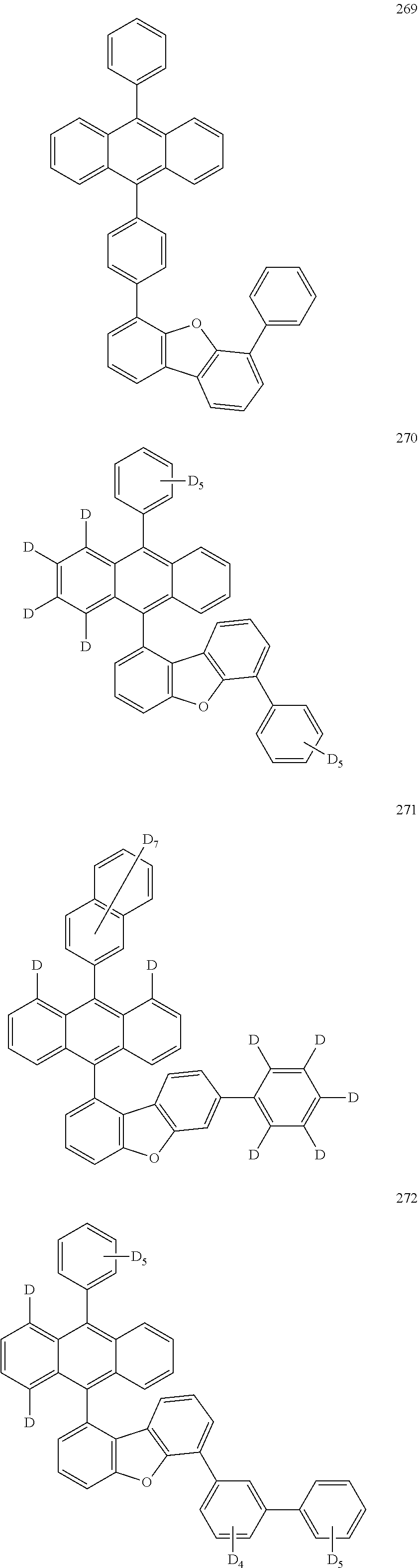

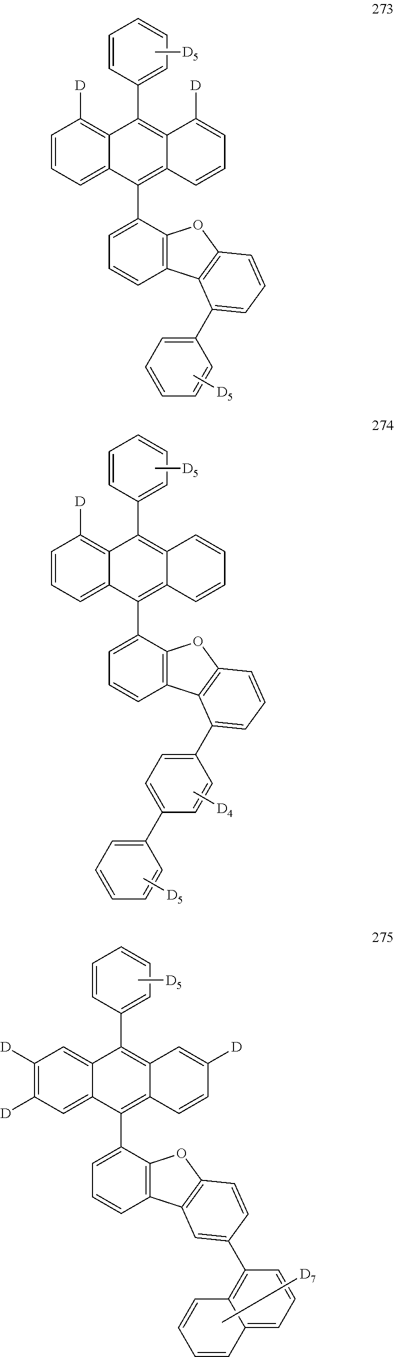

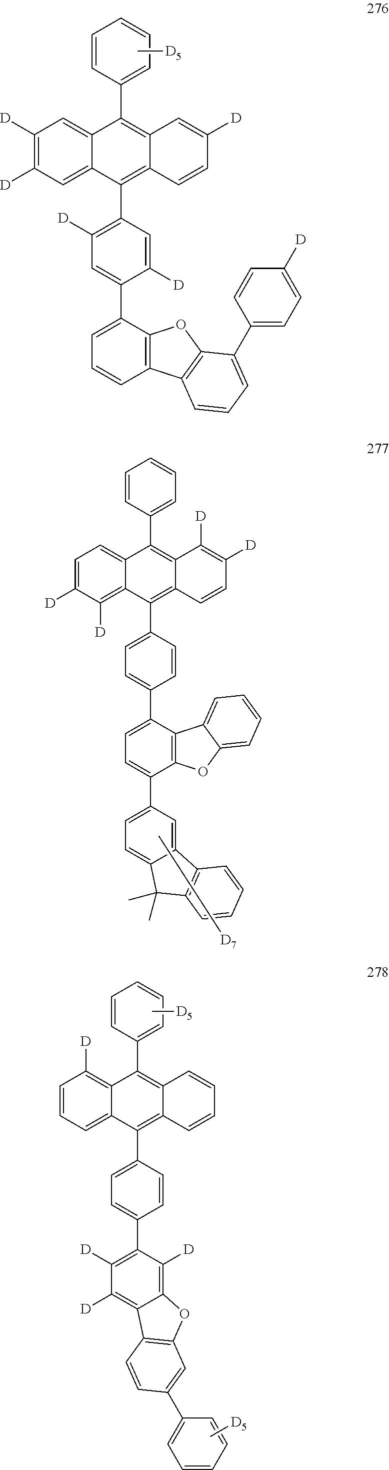

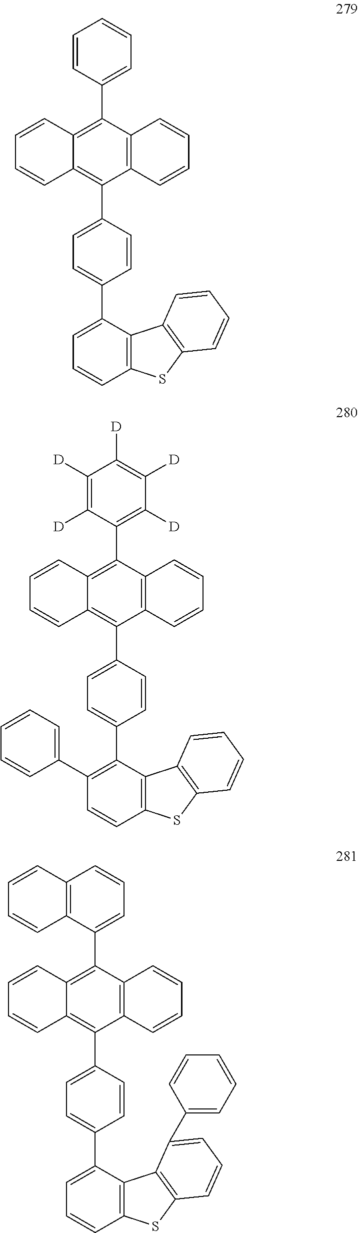

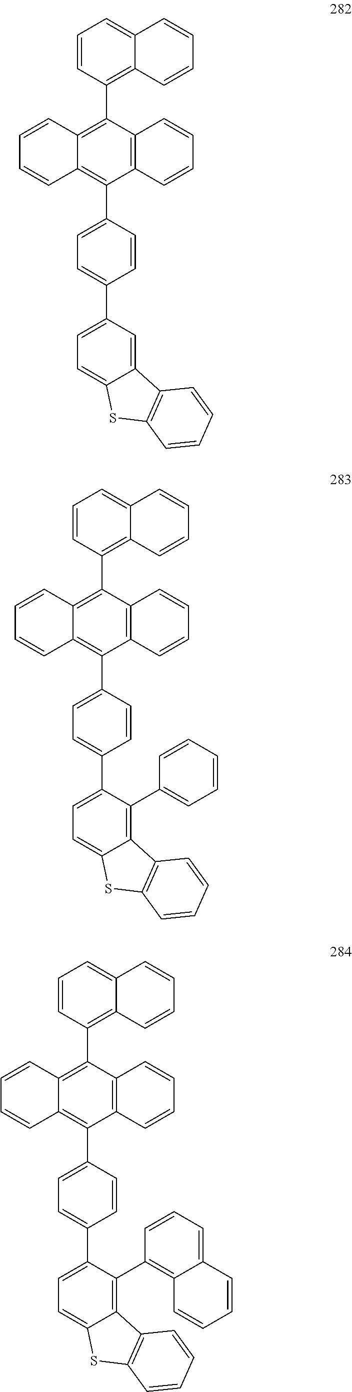

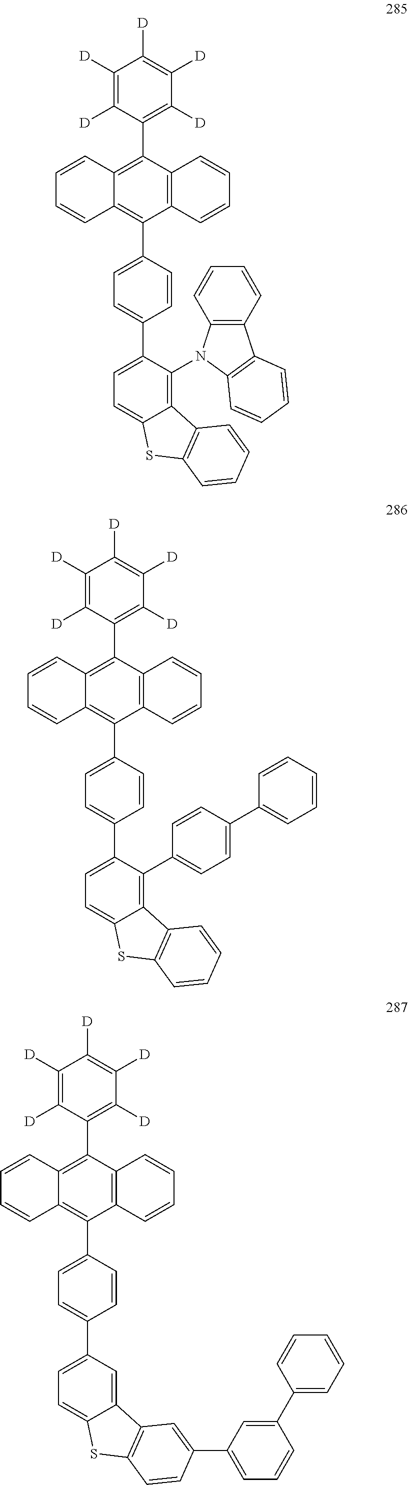 [SMILES: [2H]c1c([2H])c([2H])c(-c2c3ccccc3c(-c3ccc(-c4ccc5sc6ccccc6c5c4-n4c5ccccc5c5ccccc54)cc3)c3ccccc23)c([2H])c1[2H] ; [2H]c1c([2H])c([2H])c(-c2c3ccccc3c(-c3ccc(-c4ccc5sc6ccccc6c5c4-c4ccc(-c5ccccc5)cc4)cc3)c3ccccc23)c([2H])c1[2H] ; [2H]c1c([2H])c([2H])c(-c2c3ccccc3c(-c3ccc(-c4ccc5sc6ccc(-c7cccc(-c8ccccc8)c7)cc6c5c4)cc3)c3ccccc23)c([2H])c1[2H]]

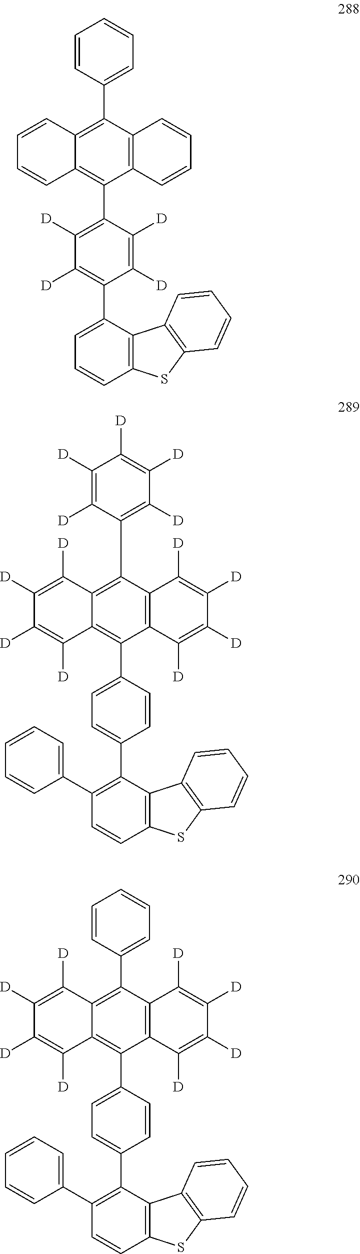

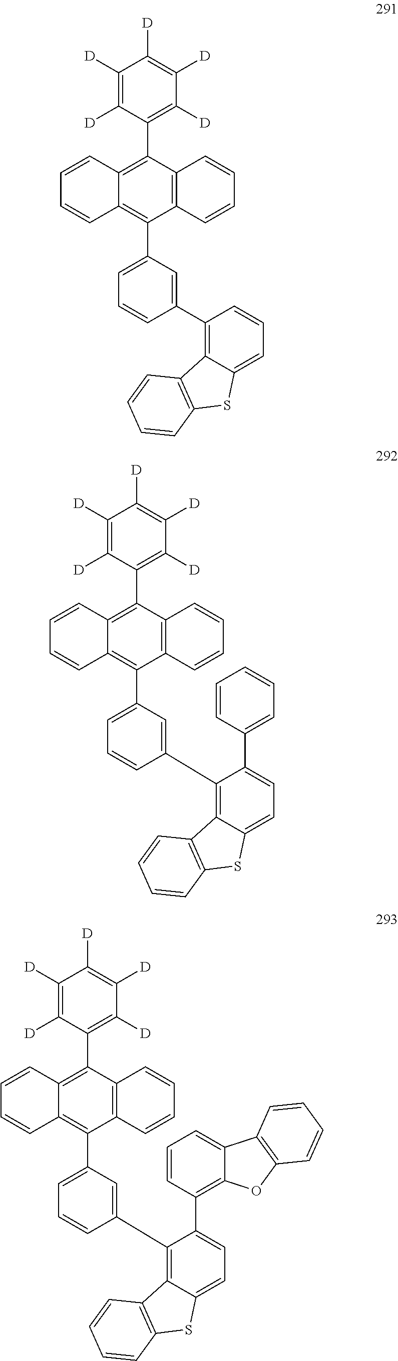

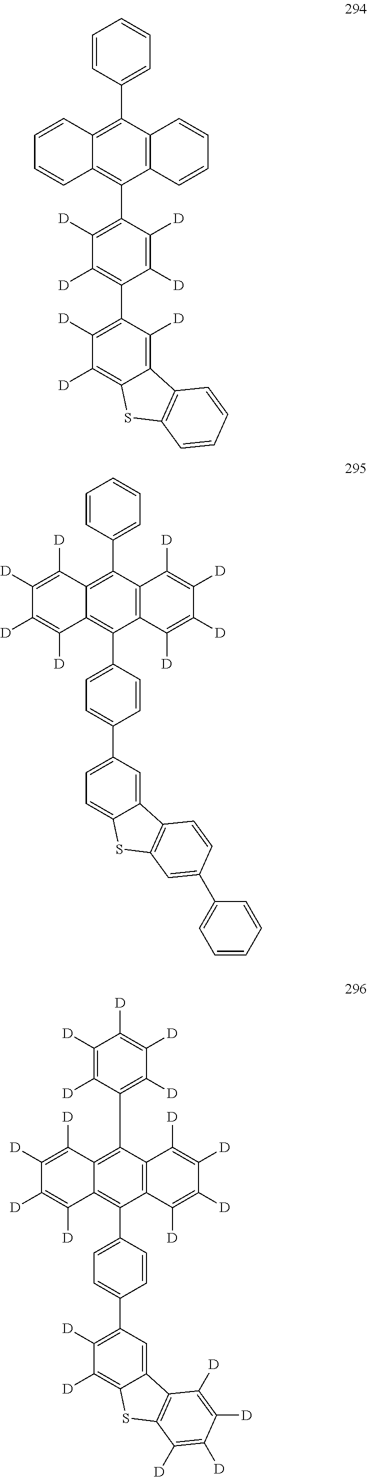 [SMILES: [2H]c1c([2H])c(-c2c3ccccc3c(-c3ccccc3)c3ccccc23)c([2H])c([2H])c1-c1c([2H])c([2H])c2sc3ccccc3c2c1[2H] ; [2H]c1c([2H])c([2H])c2c(-c3ccc(-c4ccc5sc6cc(-c7ccccc7)ccc6c5c4)cc3)c3c([2H])c([2H])c([2H])c([2H])c3c(-c3ccccc3)c2c1[2H] ; [2H]c1c([2H])c([2H])c(-c2c3c([2H])c([2H])c([2H])c([2H])c3c(-c3ccc(-c4cc5c(sc6c([2H])c([2H])c([2H])c([2H])c65)c([2H])c4[2H])cc3)c3c([2H])c([2H])c([2H])c([2H])c23)c([2H])c1[2H]]

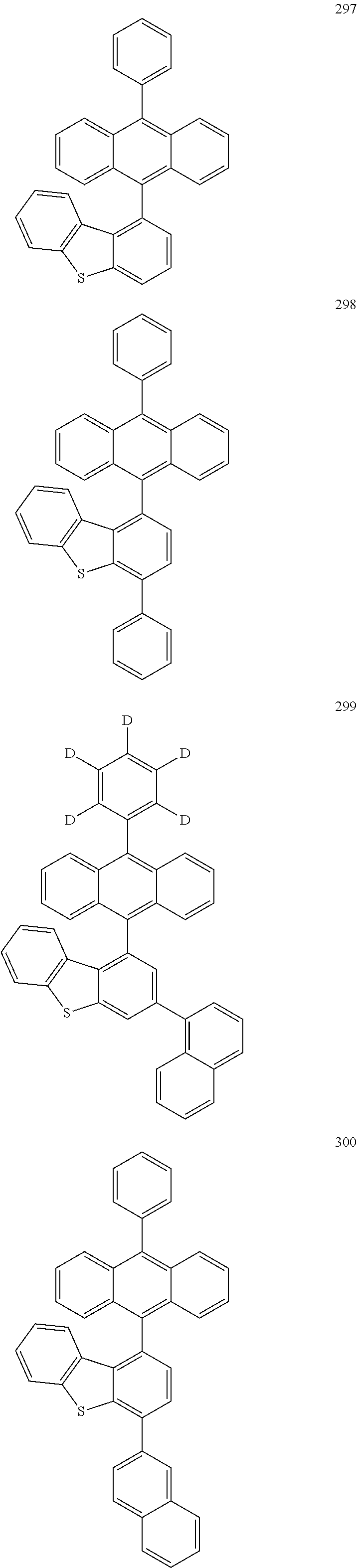

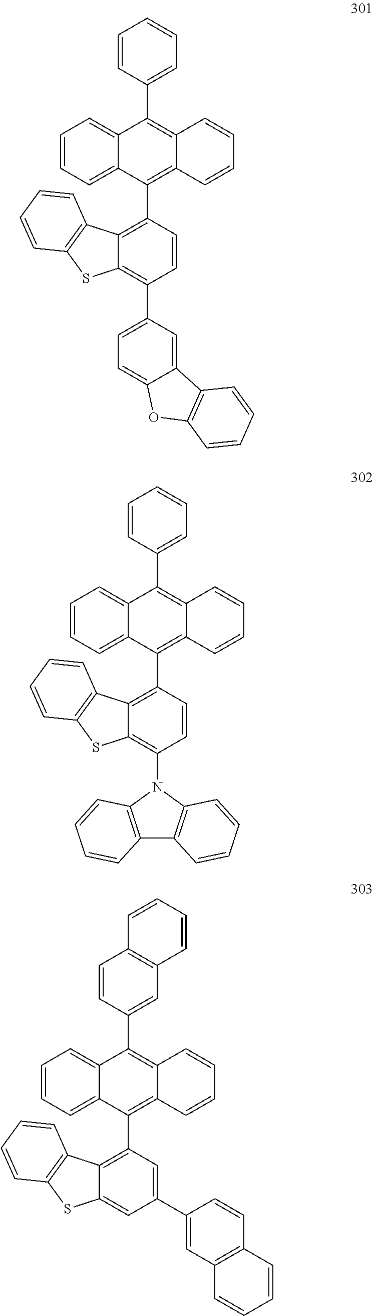 [SMILES: c1ccc(-c2c3ccccc3c(-c3ccc(-c4ccc5oc6ccccc6c5c4)c4sc5ccccc5c34)c3ccccc23)cc1 ; c1ccc(-c2c3ccccc3c(-c3ccc(-n4c5ccccc5c5ccccc54)c4sc5ccccc5c34)c3ccccc23)cc1 ; c1ccc2cc(-c3cc(-c4c5ccccc5c(-c5ccc6ccccc6c5)c5ccccc45)c4c(c3)sc3ccccc34)ccc2c1]

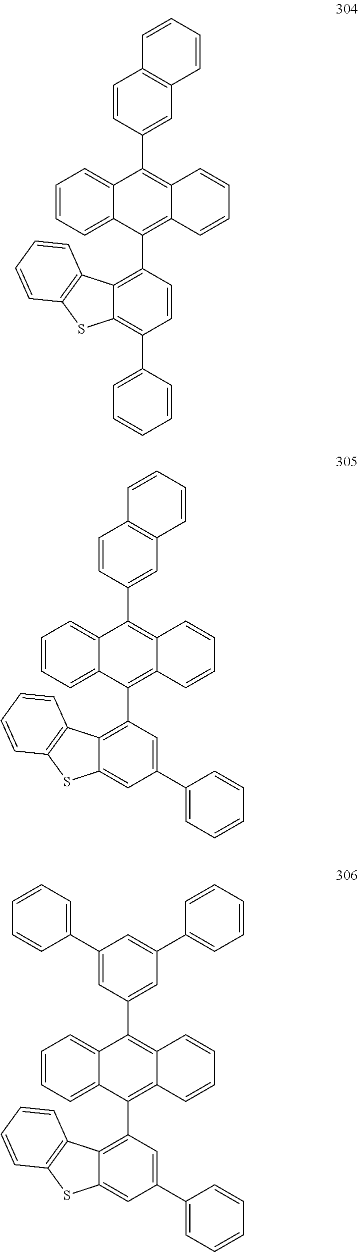

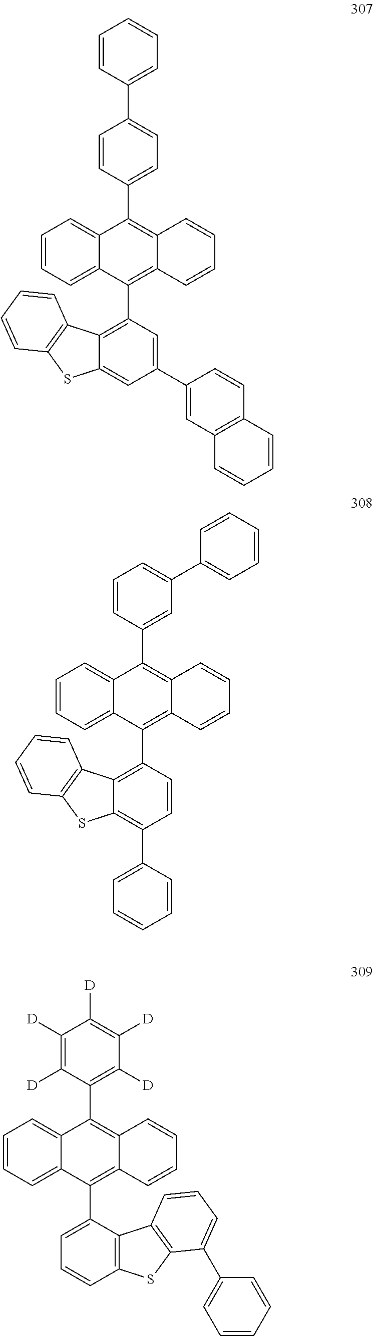

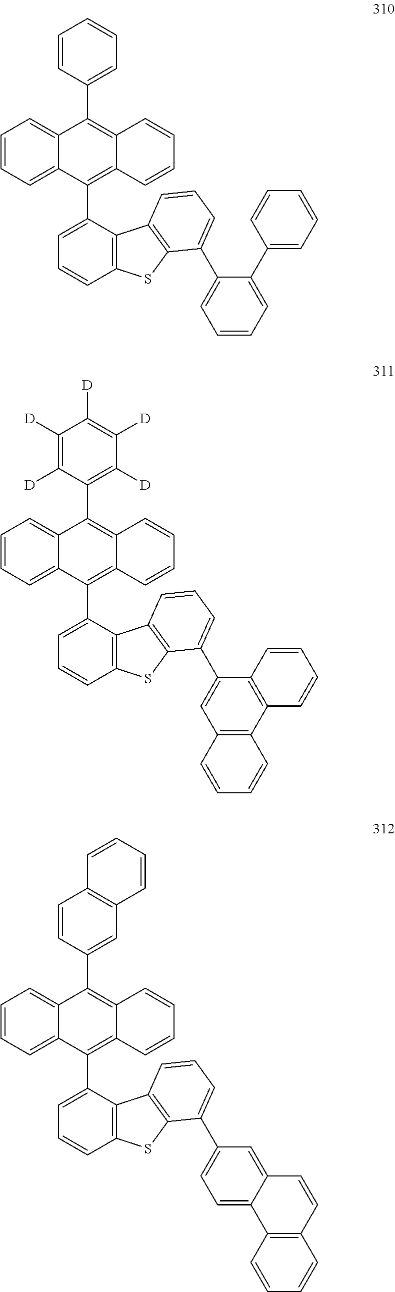 [SMILES: c1ccc(-c2ccccc2-c2cccc3c2sc2cccc(-c4c5ccccc5c(-c5ccccc5)c5ccccc45)c23)cc1 ; [2H]c1c([2H])c([2H])c(-c2c3ccccc3c(-c3cccc4sc5c(-c6cc7ccccc7c7ccccc67)cccc5c34)c3ccccc23)c([2H])c1[2H] ; c1ccc2cc(-c3c4ccccc4c(-c4cccc5sc6c(-c7ccc8c(ccc9ccccc98)c7)cccc6c45)c4ccccc34)ccc2c1]

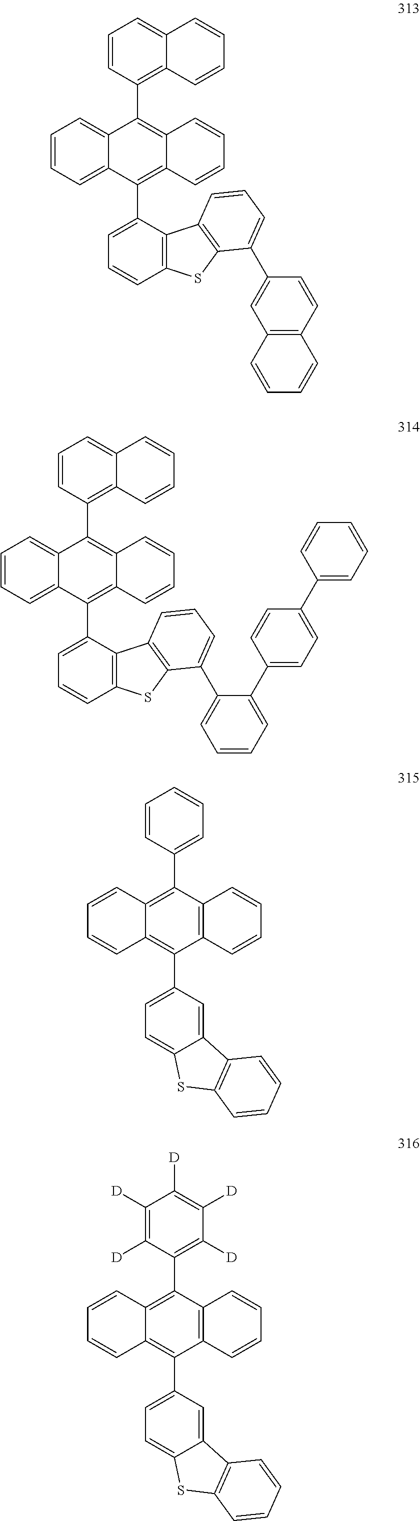 [SMILES: c1ccc2cc(-c3cccc4c3sc3cccc(-c5c6ccccc6c(-c6cccc7ccccc67)c6ccccc56)c34)ccc2c1 ; c1ccc(-c2ccc(-c3ccccc3-c3cccc4c3sc3cccc(-c5c6ccccc6c(-c6cccc7ccccc67)c6ccccc56)c34)cc2)cc1 ; c1ccc(-c2c3ccccc3c(-c3ccc4sc5ccccc5c4c3)c3ccccc23)cc1 ; [2H]c1c([2H])c([2H])c(-c2c3ccccc3c(-c3ccc4sc5ccccc5c4c3)c3ccccc23)c([2H])c1[2H]]

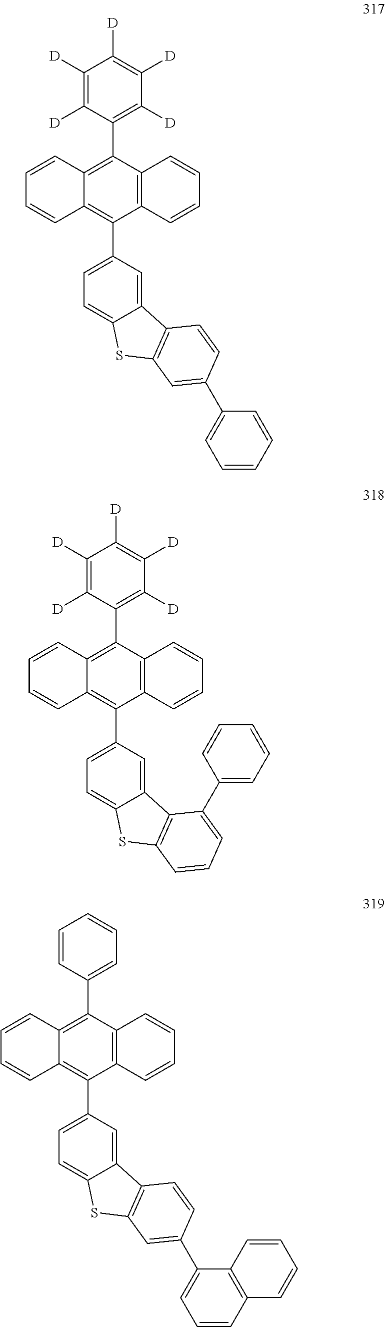 [SMILES: [2H]c1c([2H])c([2H])c(-c2c3ccccc3c(-c3ccc4sc5cc(-c6ccccc6)ccc5c4c3)c3ccccc23)c([2H])c1[2H] ; [2H]c1c([2H])c([2H])c(-c2c3ccccc3c(-c3ccc4sc5cccc(-c6ccccc6)c5c4c3)c3ccccc23)c([2H])c1[2H] ; c1ccc(-c2c3ccccc3c(-c3ccc4sc5cc(-c6cccc7ccccc67)ccc5c4c3)c3ccccc23)cc1]

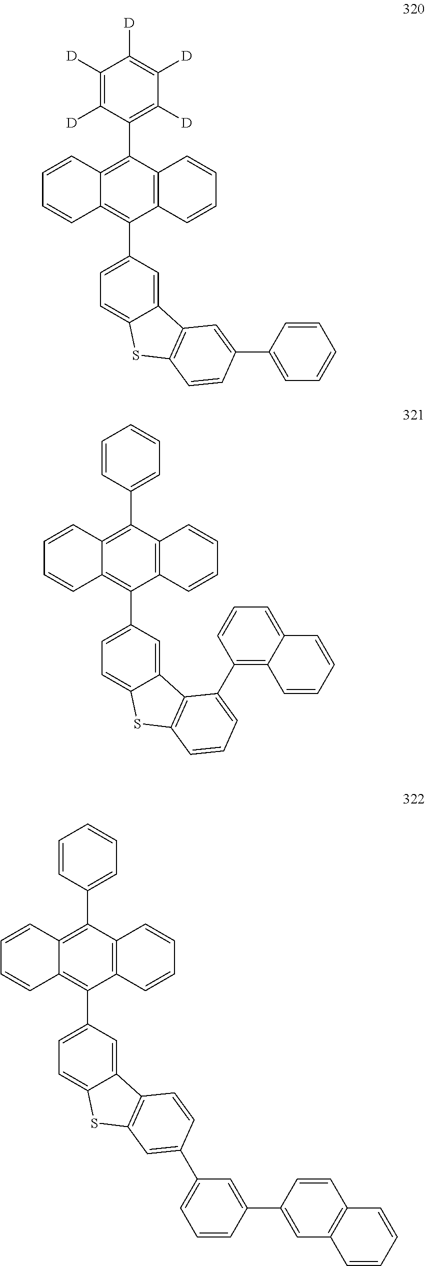 [SMILES: [2H]c1c([2H])c([2H])c(-c2c3ccccc3c(-c3ccc4sc5ccc(-c6ccccc6)cc5c4c3)c3ccccc23)c([2H])c1[2H] ; c1ccc(-c2c3ccccc3c(-c3ccc4sc5cccc(-c6cccc7ccccc67)c5c4c3)c3ccccc23)cc1 ; c1ccc(-c2c3ccccc3c(-c3ccc4sc5cc(-c6cccc(-c7ccc8ccccc8c7)c6)ccc5c4c3)c3ccccc23)cc1]

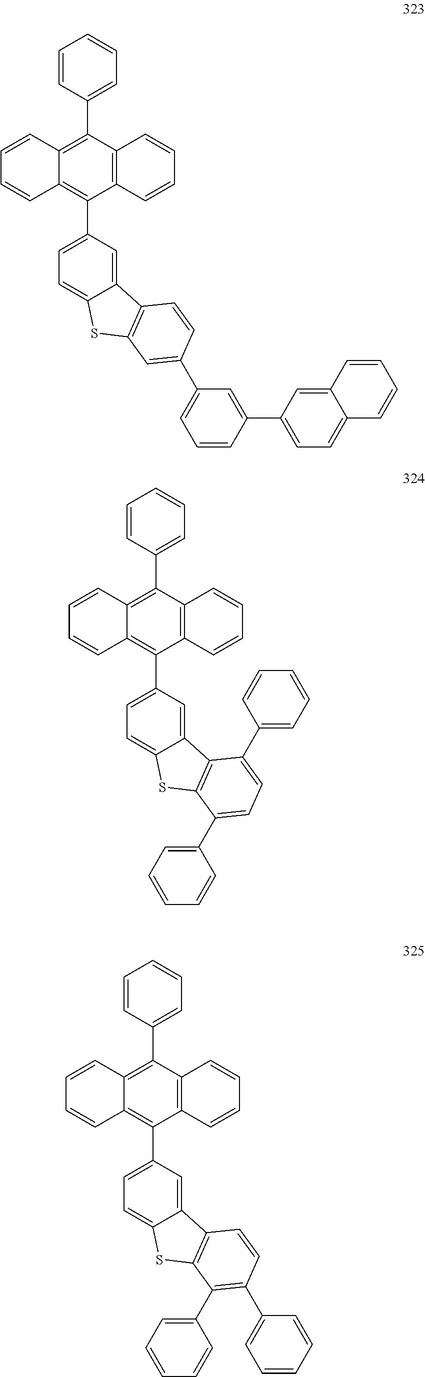 [SMILES: c1ccc(-c2c3ccccc3c(-c3ccc4sc5cc(-c6cccc(-c7ccc8ccccc8c7)c6)ccc5c4c3)c3ccccc23)cc1 ; c1ccc(-c2c3ccccc3c(-c3ccc4sc5c(-c6ccccc6)ccc(-c6ccccc6)c5c4c3)c3ccccc23)cc1 ; c1ccc(-c2ccc3c(sc4ccc(-c5c6ccccc6c(-c6ccccc6)c6ccccc56)cc43)c2-c2ccccc2)cc1]

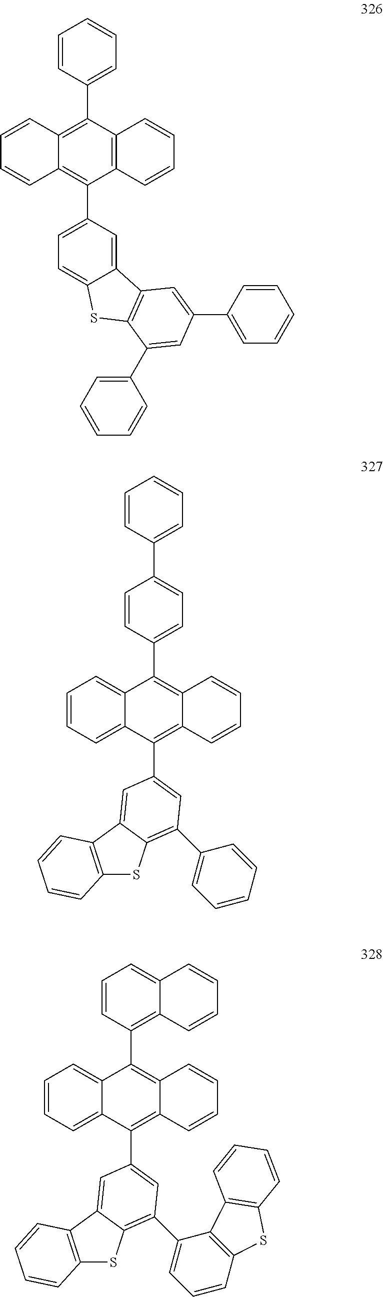 [SMILES: c1ccc(-c2cc(-c3ccccc3)c3sc4ccc(-c5c6ccccc6c(-c6ccccc6)c6ccccc56)cc4c3c2)cc1 ; c1ccc(-c2ccc(-c3c4ccccc4c(-c4cc(-c5ccccc5)c5sc6ccccc6c5c4)c4ccccc34)cc2)cc1 ; c1ccc2c(-c3c4ccccc4c(-c4cc(-c5cccc6sc7ccccc7c56)c5sc6ccccc6c5c4)c4ccccc34)cccc2c1]

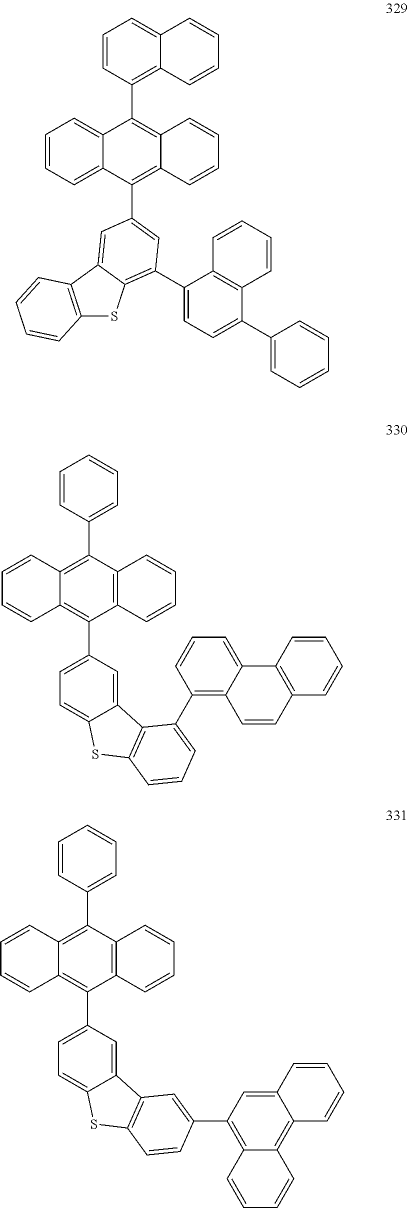 [SMILES: c1ccc(-c2ccc(-c3cc(-c4c5ccccc5c(-c5cccc6ccccc56)c5ccccc45)cc4c3sc3ccccc34)c3ccccc23)cc1 ; c1ccc(-c2c3ccccc3c(-c3ccc4sc5cccc(-c6cccc7c6ccc6ccccc67)c5c4c3)c3ccccc23)cc1 ; c1ccc(-c2c3ccccc3c(-c3ccc4sc5ccc(-c6cc7ccccc7c7ccccc67)cc5c4c3)c3ccccc23)cc1]

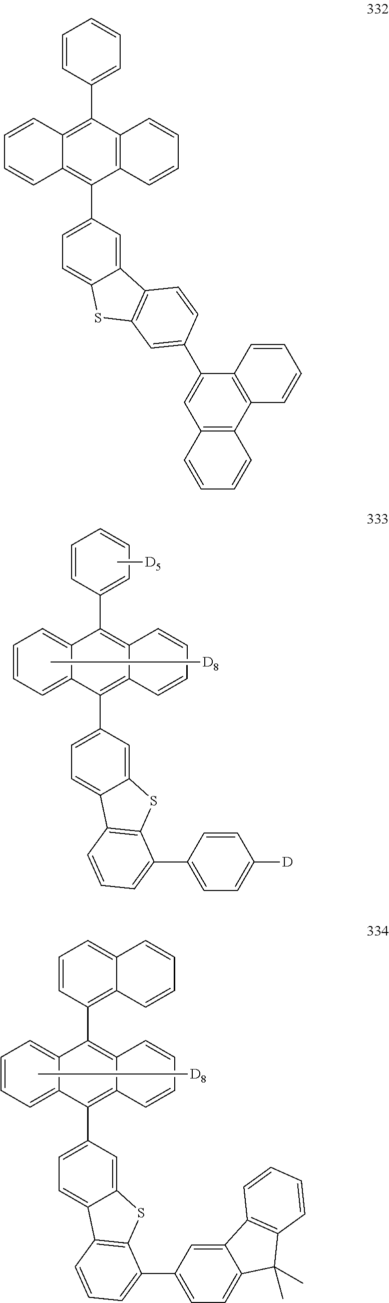

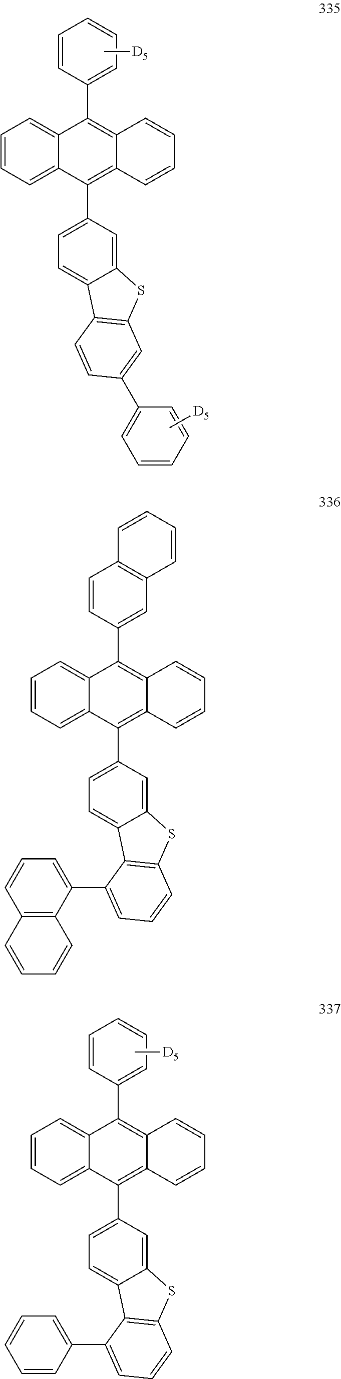

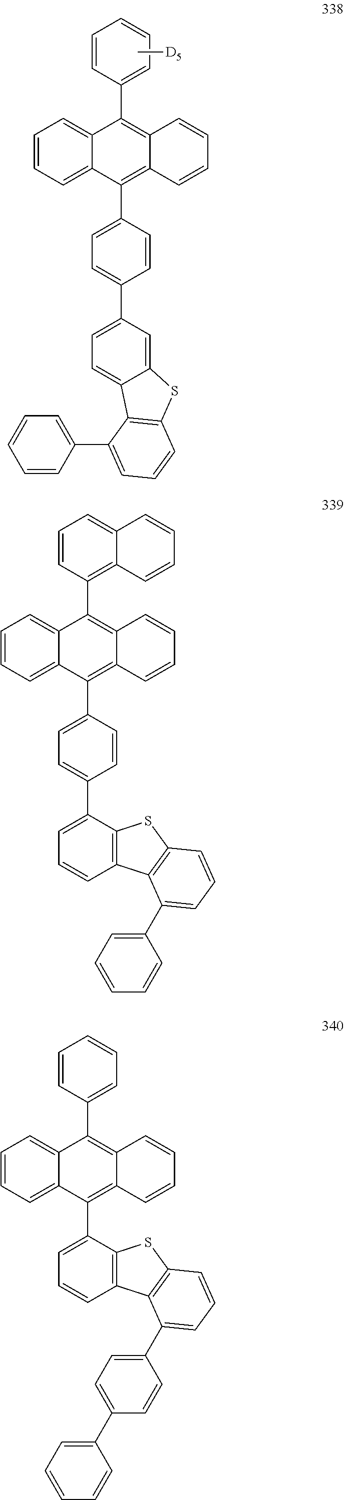

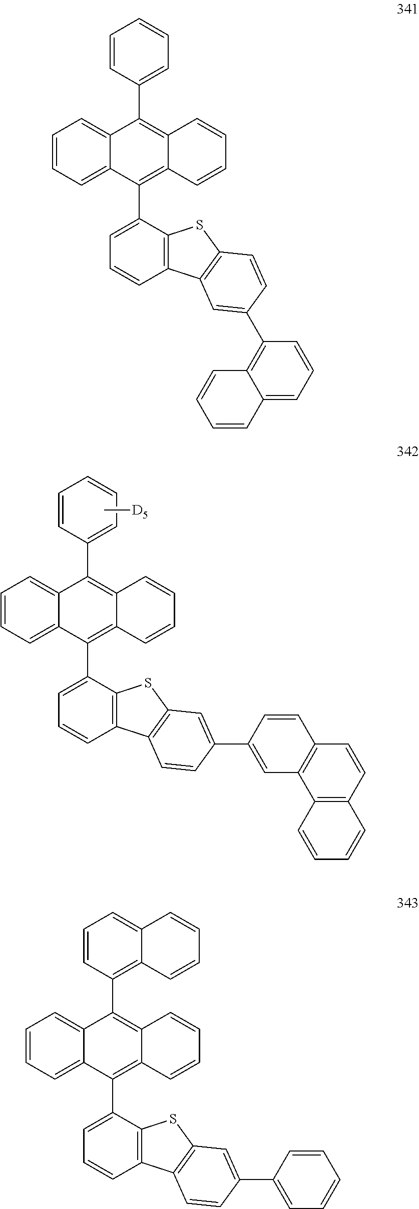

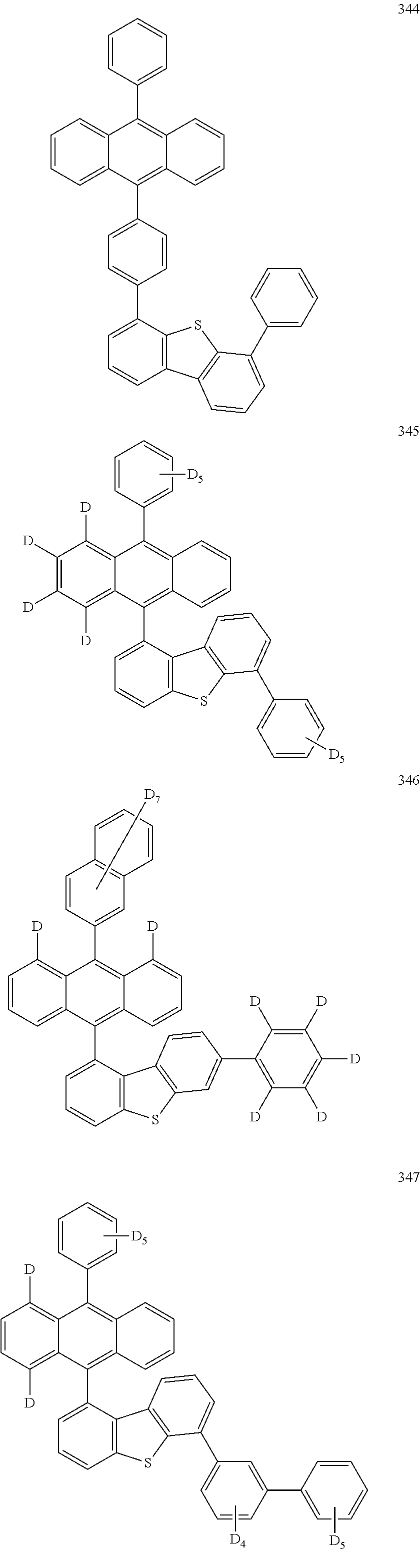

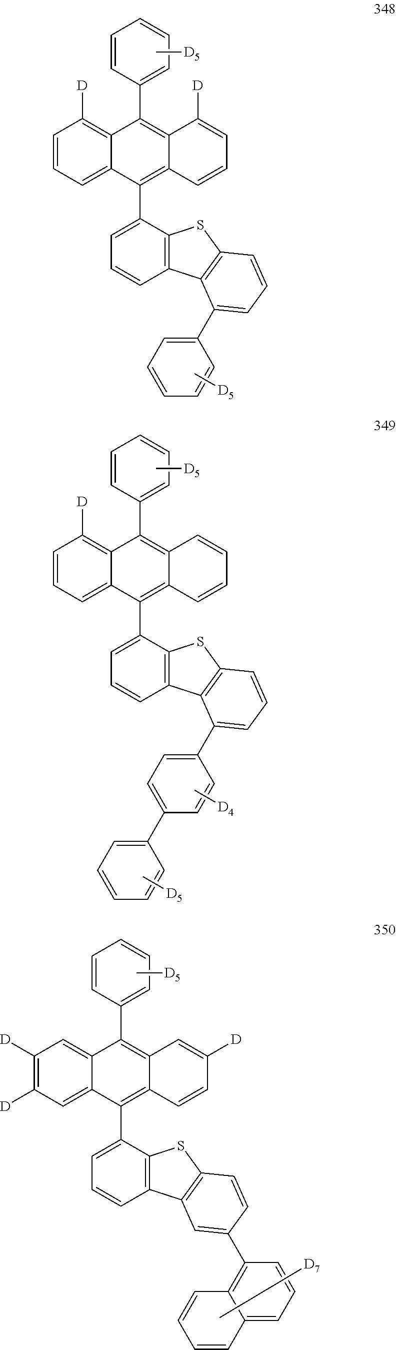

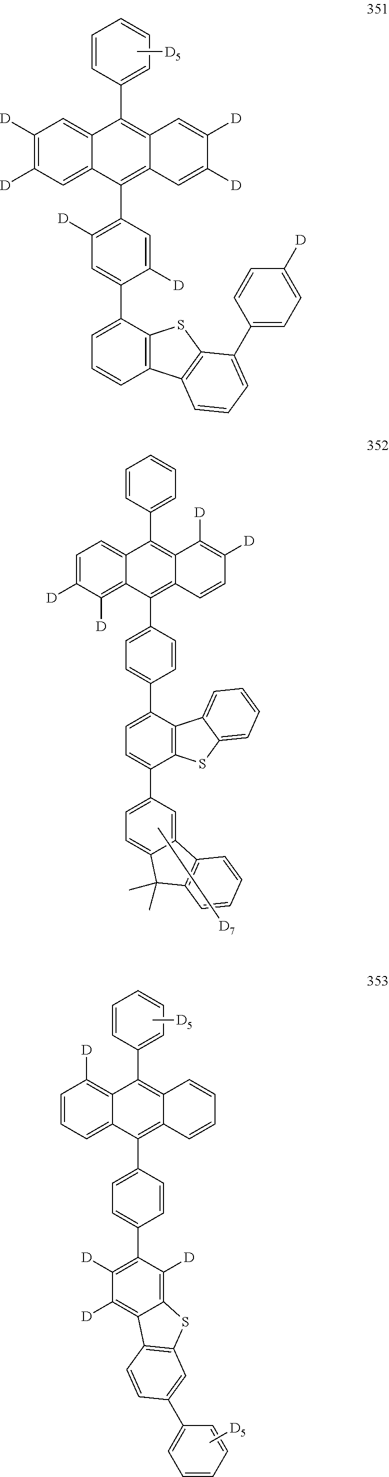

The specific examples of the substituents defined above can be found in these compounds but are not intended to limit the scope of the compound represented by Formula B.

According to one embodiment of the present invention, the organic electroluminescent device may have a structure in which one or more organic layers, including a light emitting layer, are arranged between a first electrode and a second electrode and may use the organic electroluminescent compound represented by Formula A-1 or A-2 as a dopant and the compound represented by Formula B as a host in the light emitting layer. The organic electroluminescent device of the present invention can be fabricated by a suitable method known in the art using suitable materials known in the art.

The organic layers may include at least one layer selected from a hole injecting layer, a hole transport layer, a functional layer having functions of both hole injection and hole transport, an electron transport layer, and an electron injecting layer, in addition to the light emitting layer.

Preferred structures of the organic layers of the organic electroluminescent device according to the present invention will be explained in more detail in the Examples section that follows.

A specific structure of the organic electroluminescent device according to one embodiment of the present invention, a method for fabricating the device, and materials for the organic layers are as follows.

First, an anode material is coated on a substrate to form an anode as the first electrode. The substrate may be any of those used in general electroluminescent devices. The substrate is preferably an organic substrate or a transparent plastic substrate that is excellent in transparency, surface smoothness, ease of handling, and waterproofness. A highly transparent and conductive metal oxide such as indium tin oxide (ITO), indium zinc oxide (IZO), tin oxide (SnO₂) or zinc oxide (ZnO) is used as the anode material.

A hole injecting material is coated on the anode by vacuum thermal evaporation or spin coating to form a hole injecting layer. Then, a hole transport material is coated on the hole injecting layer by vacuum thermal evaporation or spin coating to form a hole transport layer.

The hole injecting material is not specially limited so long as it is usually used in the art. Specific examples of such materials include 4,4′,4″-tris(2-naphthylphenyl-phenylamino)triphenylamine (2-TNATA), N,N′-diphenyl-N,N′-bis(3-methylphenyl)-1,1′-biphenyl-4,4′-diamine (TPD), N,N′-diphenyl-N,N′-bis [4-(phenyl-m-tolylamino)phenyl]biphenyl-4,4′-diamine (DNTPD), and hexaazatriphenylenehexacarbonitrile (HATCN).

The hole transport material is not specially limited so long as it is commonly used in the art. Examples of such materials include N,N′-bis(3-methylphenyl)-N,N′-diphenyl-[1,1-biphenyl]-4,4′-diamine (TPD) and N,N′-di(naphthalen-1-yl)-N,N′-diphenylbenzidine (α-NPD).

Subsequently, a hole auxiliary layer and the light emitting layer are sequentially laminated on the hole transport layer. A hole blocking layer may be optionally formed on the organic light emitting layer by vacuum thermal evaporation or spin coating. The hole blocking layer blocks holes from entering a cathode through the organic light emitting layer. This role of the hole blocking layer prevents the lifetime and efficiency of the device from deteriorating. A material having a very low highest occupied molecular orbital (HOMO) energy level is used for the hole blocking layer. The hole blocking material is not particularly limited so long as it has the ability to transport electrons and a higher ionization potential than the light emitting compounds. Representative examples of suitable hole blocking materials include BAlq, BCP, and TPBI.

Examples of materials for the hole blocking layer include, but are not limited to, BAlq, BCP, Bphen, TPBI, NTAZ, BeBq₂, OXD-7, and Liq.

An electron transport layer is deposited on the hole blocking layer by vacuum thermal evaporation or spin coating, and an electron injecting layer is formed thereon. A cathode metal is deposited on the electron injecting layer by vacuum thermal evaporation to form a cathode as the second electrode, completing the fabrication of the organic electroluminescent device.

For example, lithium (Li), magnesium (Mg), aluminum (Al), aluminum-lithium (Al—Li), calcium (Ca), magnesium-indium (Mg—In) or magnesium-silver (Mg—Ag) may be used as the metal for the formation of the cathode. The organic electroluminescent device may be of top emission type. In this case, a transmissive material such as ITO or IZO may be used to form the cathode.

A material for the electron transport layer functions to stably transport electrons injected from the cathode. The electron transport material may be any of those known in the art and examples thereof include, but are not limited to, quinoline derivatives, particularly tris(8-quinolinolate)aluminum (Alq3), TAZ, Balq, beryllium bis(benzoquinolin-10-olate (Bebq2), and oxadiazole derivatives such as PBD, BMD, and BND.

Each of the organic layers can be formed by a monomolecular deposition or solution process. According to the monomolecular deposition process, the material for each layer is evaporated under heat and vacuum or reduced pressure to form the layer in the form of a thin film. According to the solution process, the material for each layer is mixed with a suitable solvent, and then the mixture is formed into a thin film by a suitable method, such as ink-jet printing, roll-to-roll coating, screen printing, spray coating, dip coating or spin coating.

The organic electroluminescent device of the present invention can be used in a display or lighting system selected from flat panel displays, flexible displays, monochromatic flat panel lighting systems, white flat panel lighting systems, flexible monochromatic lighting systems, and flexible white lighting systems.

The present invention will be explained more specifically with reference to the following examples. However, it will be obvious to those skilled in the art that these examples are in no way intended to limit the scope of the invention.

### Synthesis Example 1. Synthesis of Compound 1

### Synthesis Example 1-1. Synthesis of Intermediate 1-a

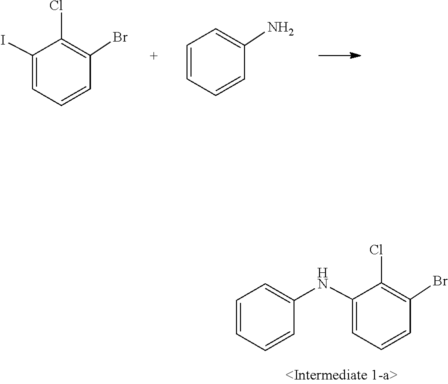 [SMILES: Clc1c(Br)cccc1I ; Nc1ccccc1 ; Clc1c(Br)cccc1Nc1ccccc1]

3.3 g (16 mmol) of 1-bromo-2-chloro-3-iodobenzene, 5.8 g (16 mmol) of aniline, 0.1 g (1 mmol) of palladium acetate, 3 g (32 mmol) of sodium tert-butoxide, 0.2 g (1 mmol) of bis(diphenylphosphino)-1,1′-binaphthyl, and 45 mL of toluene were placed in a reactor. The mixture was stirred under reflux for 24 h. After completion of the reaction, the reaction mixture was filtered. The filtrate was concentrated and purified by column chromatography to afford 3.6 g of Intermediate 1-a (yield 80%).

### Synthesis Example 1-2. Synthesis of Intermediate 1-b

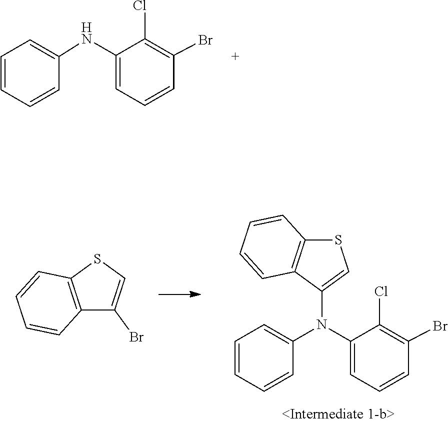 [SMILES: Clc1c(Br)cccc1Nc1ccccc1 ; Brc1csc2ccccc12 ; Clc1c(Br)cccc1N(c1ccccc1)c1csc2ccccc12]

27.7 g (98 mmol) of Intermediate 1-a, 20.9 g (98 mmol) of 3-bromobenzothiophene, 0.5 g (2 mmol) of palladium acetate, 18.9 g (196 mmol) of sodium tert-butoxide, 0.8 g (4 mmol) of tri-tert-butylphosphine, and 200 mL of toluene were placed in a reactor. The mixture was stirred under reflux for 5 h. After completion of the reaction, the reaction mixture was filtered. The filtrate was concentrated and purified by column chromatography to afford 29.3 g of Intermediate 1-b (yield 72%).

### Synthesis Example 1-3. Synthesis of Intermediate 1-c

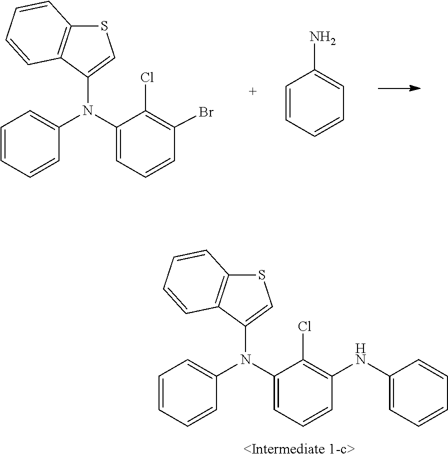 [SMILES: Clc1c(Br)cccc1N(c1ccccc1)c1csc2ccccc12 ; Nc1ccccc1 ; Clc1c(Nc2ccccc2)cccc1N(c1ccccc1)c1csc2ccccc12]

Intermediate 1-c (yield 82%) was synthesized in the same manner as in Synthesis Example 1-1, except that Intermediate 1-b was used instead of 1-bromo-2-chloro-3-iodobenzene.

### Synthesis Example 1-4. Synthesis of Intermediate 1-d

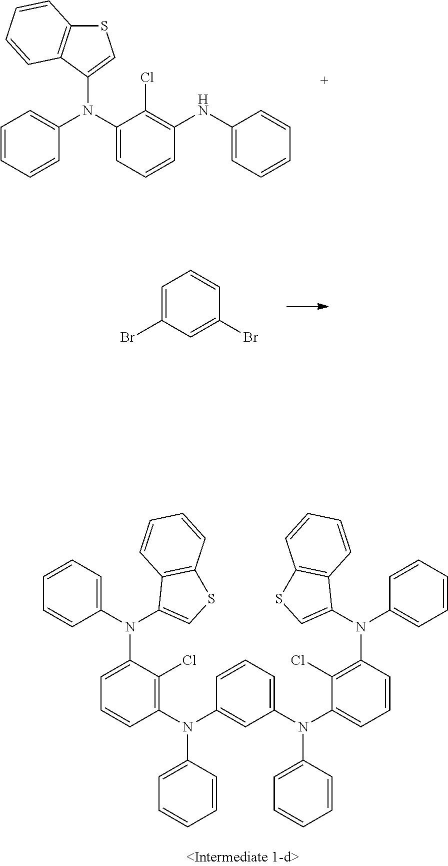 [SMILES: Clc1c(Nc2ccccc2)cccc1N(c1ccccc1)c1csc2ccccc12 ; Brc1cccc(Br)c1 ; Clc1c(N(c2ccccc2)c2cccc(N(c3ccccc3)c3cccc(N(c4ccccc4)c4csc5ccccc45)c3Cl)c2)cccc1N(c1ccccc1)c1csc2ccccc12]

30 g (70 mmol) of Intermediate 1-c, 8.3 g (35 mmol) of 1,3-dibromobenzene, 1.3 g (1 mmol) of tris(dibenzylideneacetone)dipalladium(0), 13.5 g (290 mmol) of sodium tert-butoxide, 1.4 g (7 mmol) of tri-tert-butylphosphine, and 150 mL of toluene were placed in a reactor. The mixture was stirred under reflux for 5 h. After completion of the reaction, the reaction mixture was filtered. The filtrate was concentrated and purified by column chromatography to afford 19.5 g of Intermediate 1-d (yield 60%).

### Synthesis Example 1-5. Synthesis of Compound 1

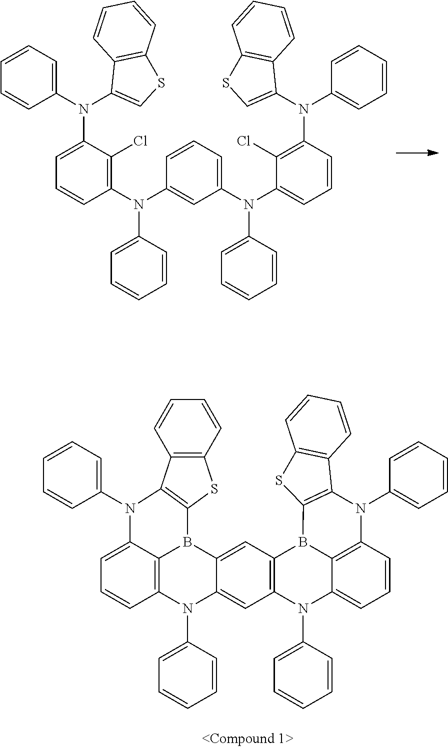 [SMILES: Clc1c(N(c2ccccc2)c2cccc(N(c3ccccc3)c3cccc(N(c4ccccc4)c4csc5ccccc45)c3Cl)c2)cccc1N(c1ccccc1)c1csc2ccccc12 ; c1ccc(N2c3cc4c(cc3B3c5sc6ccccc6c5N(c5ccccc5)c5cccc2c53)B2c3sc5ccccc5c3N(c3ccccc3)c3cccc(c32)N4c2ccccc2)cc1]

16 g (17.2 mmol) of Intermediate 1-d and 250 mL of tert-butylbenzene were placed in a reactor and 66 mL (68 mmol) of tert-butyllithium was added dropwise thereto at −78° C. After dropwise addition, the mixture was stirred at 60° C. for 3 h. Pentane was distilled off under reduced pressure. 17 g (68 mmol) of boron tribromide was added dropwise at −50° C. After stirring at room temperature for 3 h, 12 g of N,N-diisopropylethylamine was added dropwise at −78° C. The resulting mixture was stirred at room temperature until heat was no longer emitted, followed by stirring at 120° C. for 4 h. After completion of the reaction, the reaction mixture was added with an aqueous sodium acetate solution at room temperature, stirred, and extracted with ethyl acetate. The organic layer was hot filtered through silica gel/toluene and recrystallized from dichloromethane and acetone to give 3.0 g of Compound 1 (yield 20%).

MS (MALDI-TOF): m/z 874.26 [M+]

### Synthesis Example 2. Synthesis of Compound 5

### Synthesis Example 2-1. Synthesis of Intermediate 2-a

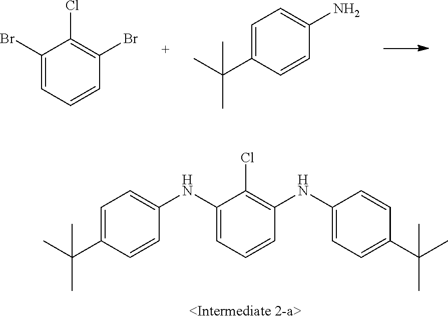 [SMILES: Clc1c(Br)cccc1Br ; CC(C)(C)c1ccc(N)cc1 ; CC(C)(C)c1ccc(Nc2cccc(Nc3ccc(C(C)(C)C)cc3)c2Cl)cc1]

Intermediate 2-a (yield 82%) was synthesized in the same manner as in Synthesis Example 1-1, except that 1,3-dibromo-2-chlorobenzene and 4-tert-butylaniline were used instead of 1-bromo-2-chloro-3-iodobenzene and aniline, respectively.

### Synthesis Example 2-2. Synthesis of Intermediate 2-b

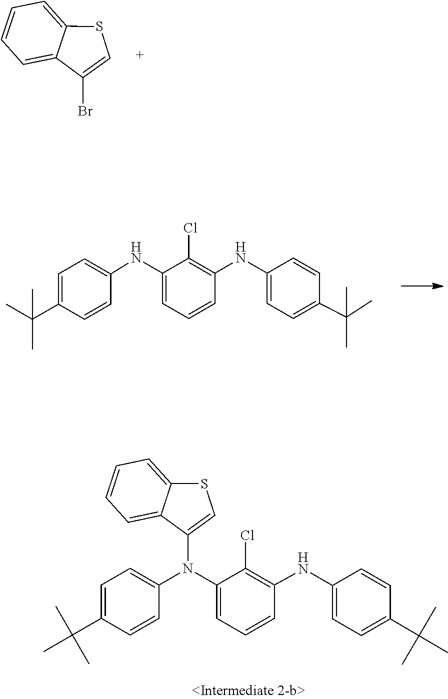

Intermediate 2-b (yield 67%) was synthesized in the same manner as in Synthesis Example 1-2, except that Intermediate 2-a was used instead of Intermediate 1-a.

### Synthesis Example 2-3. Synthesis of Compound 5

Compound 5 (yield 22%) was synthesized in the same manner as in Synthesis Examples 1-4 and 1-5, except that Intermediate 2-b was used instead of Intermediate 1-c in Synthesis Example 1-4.

MS (MALDI-TOF): m/z 1098.51 [M⁺]

### Synthesis Example 3. Synthesis of Compound 14

### Synthesis Example 3-1. Synthesis of Intermediate 3-a

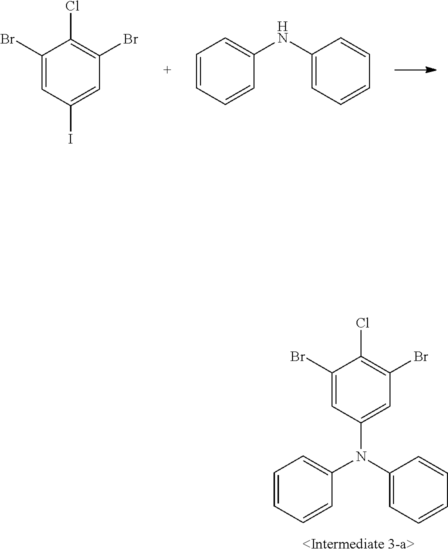 [SMILES: Clc1c(Br)cc(I)cc1Br ; c1ccc(Nc2ccccc2)cc1 ; Clc1c(Br)cc(N(c2ccccc2)c2ccccc2)cc1Br]

Intermediate 3-a (yield 50%) was synthesized in the same manner as in Synthesis Example 1-2, except that diphenylamine and 1-chloro-2,6-dibromo-4-iodobenzene were used instead of Intermediate 1-a and 3-bromobenzothiophene, respectively.

### Synthesis Example 3-2. Synthesis of Compound 14

Compound 14 (yield 22%) was synthesized in the same manner as in Synthesis Examples 1-1 to 1-5, except that Intermediate 3-a was used instead of 1-bromo-2-chloro-3-iodobenzene in Synthesis Example 1-1 and 3-bromobenzofuran was used instead of 3-bromobenzothiophene in Synthesis Example 1-2.

MS (MALDI-TOF): m/z 1176.45 [M⁺]

### Synthesis Example 4. Synthesis of Compound 17

Compound 17 (yield 20%) was synthesized in the same manner as in Synthesis Examples 1-1 to 1-5, except that 1,3-dibromo-5(tert-butyl)-2-chlorobenzene and 1-naphthylamine were used instead of 1-bromo-2-chloro-3-iodobenzene and aniline in Synthesis Example 1-1, respectively, and 3-bromobenzofuran was used instead of 3-bromobenzothiophene in Synthesis Example 1-2.

MS (MALDI-TOF): m/z 1054.46 [M⁺]

### Synthesis Example 5. Synthesis of Compound 25

### Synthesis Example 5-1. Synthesis of Intermediate 5-a

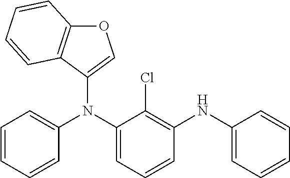 [SMILES: Clc1c(Nc2ccccc2)cccc1N(c1ccccc1)c1coc2ccccc12]

<Intermediate 5-a>

Intermediate 5-a (yield 78%) was synthesized in the same manner as in Synthesis Examples 1-1 to 1-3, except that 3-bromobenzofuran was used instead of 3-bromobenzothiophene in Synthesis Example 1-2.

### Synthesis Example 5-2. Synthesis of Intermediate 5-b

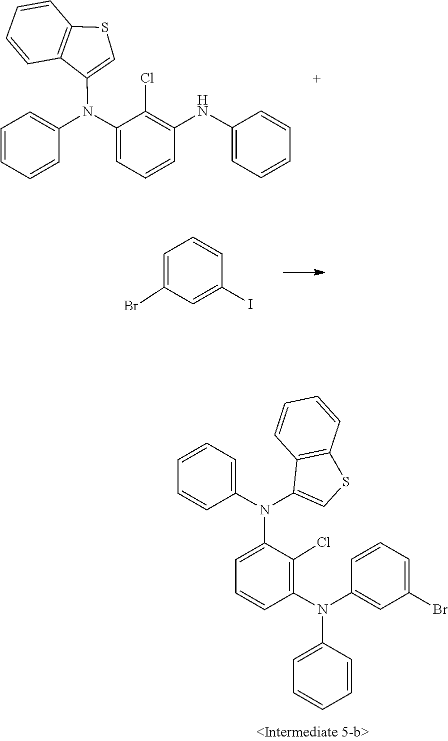 [SMILES: Clc1c(Nc2ccccc2)cccc1N(c1ccccc1)c1csc2ccccc12 ; Brc1cccc(I)c1 ; Clc1c(N(c2ccccc2)c2cccc(Br)c2)cccc1N(c1ccccc1)c1csc2ccccc12]

Intermediate 5-b (yield 64%) was synthesized in the same manner as in Synthesis Example 1-4, except that 1-bromo-3-iodobenzene was used instead of 1,3-dibromobenzene.

### Synthesis Example 5-3. Synthesis of Compound 25

Compound 25 (yield 17%) was synthesized in the same manner as in Synthesis Examples 1-4 and 1-5, except that Intermediate 5-a and Intermediate 5-b were used instead of Intermediate 1-c and 1,3-dibromobenzene in Synthesis Example 1-4, respectively.

MS (MALDI-TOF): m/z 858.28 [M⁺]

### Synthesis Example 6. Synthesis of Compound 45

### Synthesis Example 6-1. Synthesis of Intermediate 6-a

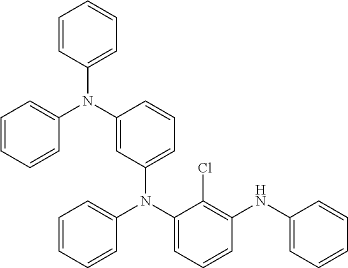 [SMILES: Clc1c(Nc2ccccc2)cccc1N(c1ccccc1)c1cccc(N(c2ccccc2)c2ccccc2)c1]

<Intermediate 6-a>

Intermediate 6-a (yield 80%) was synthesized in the same manner as in Synthesis Examples 1-1 to 1-3, except that 3-bromotriphenylamine was used instead of 3-bromobenzothiophene in Synthesis Example 1-2.

### Synthesis Example 6-2. Synthesis of Compound 45

Compound 45 (yield 20%) was synthesized in the same manner as in Synthesis Examples 1-4 and 1-5, except that Intermediate 6-a and Intermediate 5-b were used instead of Intermediate 1-c and 1,3-dibromobenzene in Synthesis Example 1-4, respectively.

MS (MALDI-TOF): m/z 985.36 [M⁺]

### Synthesis Example 7. Synthesis of Compound 79

### Synthesis Example 7-1. Synthesis of Compound 79

Compound 79 (yield 21%) was synthesized in the same manner as in Synthesis Examples 1-1, 1-3, 1-4, and 1-5, except that diphenylamine was used instead of aniline in Synthesis Example 1-1 and 2,5-dibromothiophene was used instead of 1,3-dibromobenzene in Synthesis Example 1-4.

MS (MALDI-TOF): m/z 768.27 [M⁺]

### Synthesis Example 8. Synthesis of Compound 161

### Synthesis Example 8-1. Synthesis of Intermediate 8-a

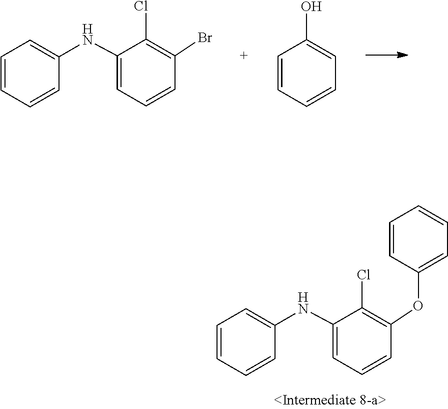 [SMILES: Clc1c(Br)cccc1Nc1ccccc1 ; Oc1ccccc1 ; Clc1c(Nc2ccccc2)cccc1Oc1ccccc1]

42.4 g (150 mmol) of Intermediate 1-a, 31.2 g (160 mmol) of phenol, 45.7 g (300 mmol) of potassium carbonate, and 250 mL of NMP were placed in a reactor. The mixture was stirred under reflux at 160° C. for 12 h. After completion of the reaction, the reaction mixture was cooled to room temperature. NMP was distilled off under reduced pressure, followed by extraction with water and ethyl acetate. The organic layer was concentrated under reduced pressure and purified by column chromatography to afford 26.6 g of Intermediate 8-a (yield 60%).

### Synthesis Example 8-2. Synthesis of Compound 161

Compound 161 (yield 16%) was synthesized in the same manner as in Synthesis Examples 1-4 and 1-5, except that Intermediate 8-a and Intermediate 5-b were used instead of Intermediate 1-c and 1,3-dibromobenzene in Synthesis Example 1-4, respectively.

MS (MALDI-TOF): m/z 743.24 [M⁺]

### Examples 1 to 21: Fabrication of Organic Light Emitting Diodes

ITO glass was patterned to have a light emitting area of 2 mm×2 mm, followed by cleaning. After the cleaned ITO glass was mounted in a vacuum chamber, DNTPD (700 Å) and α-NPD (300 Å) were deposited in this order on the ITO glass. The compounds shown in Table 1 were mixed (97:3) and used to form a 250 Å thick light emitting layer. Thereafter, the compound of Formula E-1 was used to form a 300 Å thick electron transport layer on the light emitting layer. Liq was used to form a 10 Å electron injecting layer on the electron transport layer. Al was deposited on the electron injecting layer to form a 1000 Å cathode, completing the fabrication of an organic electroluminescent device. The characteristics of the organic electroluminescent device were measured at 10 mA/cm².

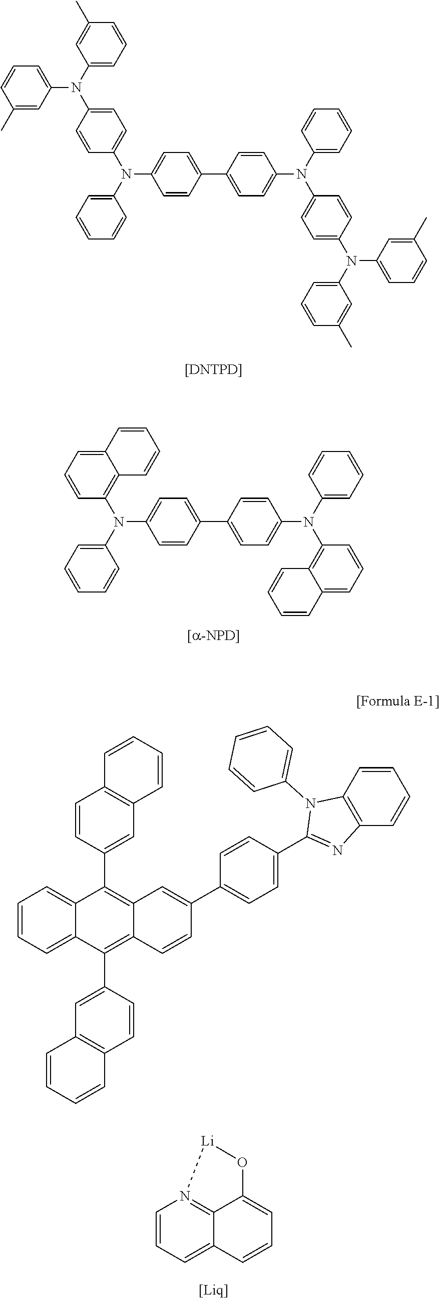

### Comparative Examples 1 to 6

Organic electroluminescent devices were fabricated in the same manner as in Examples 1-21, except that BD1 or BD2 were used instead of the dopant compound to form a light emitting layer. The luminescent properties of the organic electroluminescent devices were measured at 10 mA/cm². The structures of BD1 and BD2 are as follow:

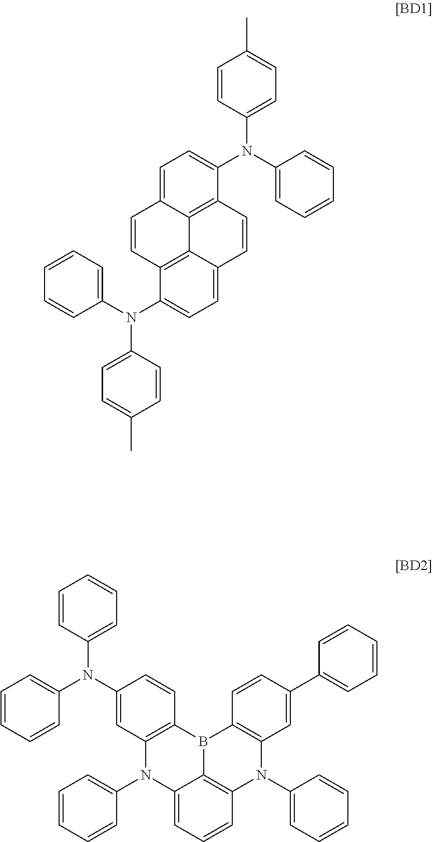 [SMILES: Cc1ccc(N(c2ccccc2)c2ccc3ccc4c(N(c5ccccc5)c5ccc(C)cc5)ccc5ccc2c3c54)cc1 ; c1ccc(-c2ccc3c(c2)N(c2ccccc2)c2cccc4c2B3c2ccc(N(c3ccccc3)c3ccccc3)cc2N4c2ccccc2)cc1]

TABLE 1

| | | | | External quantum | |
|---|---|---|---|---|---|
| Example No. | Host | Dopant | Voltage (V) | efficiency (%) | T97 (h) |
| Example 1 | Compound 7 | Formula 1 | 3.7 | 8.7 | 168 |
| Example 2 | Compound 234 | Formula 1 | 3.6 | 8.8 | 175 |
| Example 3 | Compound 241 | Formula 1 | 3.7 | 8.8 | 178 |
| Example 4 | Compound 270 | Formula 1 | 3.6 | 8.9 | 182 |
| Example 5 | Compound 14 | Formula 5 | 3.8 | 8.6 | 163 |
| Example 6 | Compound 270 | Formula 5 | 3.7 | 8.7 | 173 |
| Example 7 | Compound 18 | Formula 14 | 3.9 | 8.4 | 161 |
| Example 8 | Compound 216 | Formula 14 | 3.8 | 8.5 | 172 |
| Example 9 | Compound 316 | Formula 14 | 3.9 | 8.5 | 170 |
| Example 10 | Compound 14 | Formula 17 | 3.7 | 8.5 | 157 |
| Example 11 | Compound 241 | Formula 17 | 3.8 | 8.6 | 169 |
| Example 12 | Compound 7 | Formula 25 | 3.8 | 8.4 | 153 |
| Example 13 | Compound 316 | Formula 25 | 3.8 | 8.6 | 166 |
| Example 14 | Compound 234 | Formula 45 | 3.8 | 8.4 | 155 |
| Example 15 | Compound 241 | Formula 45 | 3.8 | 8.5 | 168 |
| Example 16 | Compound 270 | Formula 45 | 3.7 | 8.5 | 170 |
| Example 17 | Compound 18 | Formula 79 | 3.8 | 8.1 | 150 |
| Example 18 | Compound 316 | Formula 79 | 3.8 | 8.2 | 165 |
| Example 19 | Compound 18 | Formula 161 | 3.9 | 8.3 | 146 |
| Example 20 | Compound 241 | Formula 161 | 3.8 | 8.5 | 163 |
| Example 21 | Compound 270 | Formula 161 | 3.8 | 8.6 | 165 |
| Comparative | Compound 7 | BD 1 | 4.3 | 5.5 | 88 |
| Example 1 | | | | | |
| Comparative | Compound 216 | BD 1 | 4.2 | 5.6 | 94 |
| Example 2 | | | | | |
| Comparative | Compound 234 | BD 1 | 4.2 | 5.6 | 98 |
| Example 3 | | | | | |
| Comparative | Compound 7 | BD 2 | 4.2 | 5.8 | 101 |
| Example 4 | | | | | |
| Comparative | Compound 216 | BD 2 | 4.1 | 6.0 | 110 |
| Example 5 | | | | | |
| Comparative | Compound 234 | BD 2 | 4.1 | 6.0 | 113 |
| Example 6 | | | | | |

The organic electroluminescent devices of Examples 1-21, each of which employed the dopant and host compounds shown in Table 1 for the light emitting layer, were driven at low voltages and showed high external quantum efficiencies and greatly improved lifetimes compared to the organic electroluminescent devices of Comparative Examples 1-6, each of which employed BD1 or BD2 as a dopant compound.

What is claimed is:

1. An organic electroluminescent device comprising a first electrode, a second electrode opposite to the first electrode, and a light emitting layer interposed between the first and second electrodes wherein the light emitting layer comprises (i) a compound represented by Formula A-1: 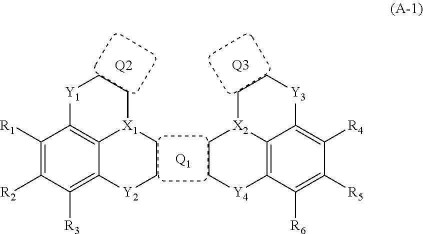
wherein Q₁ to Q₃ are identical to or different from each other and are each independently a substituted or unsubstituted C₆-C₅₀ aromatic hydrocarbon ring or a substituted or unsubstituted C₂-C₅₀ heteroaromatic ring, X₁ and X₂ are identical to or different from each other and are each independently selected from B, P, and P═O, Y₁ to Y₄ are identical to or different from each other and are each independently selected from NR₇, CR₈R₉, O, S, Se, and SiR₁₀R₁₁, R₁ to R₁₁ are identical to or different from each other and are each independently selected from hydrogen, deuterium, substituted or unsubstituted C₁-C₃₀ alkyl, substituted or unsubstituted C₆-C₅₀ aryl, substituted or unsubstituted C₃-C₃₀ cycloalkyl, substituted or unsubstituted C₂-C₅₀ heteroaryl, substituted or unsubstituted C₁-C₃₀ alkoxy, substituted or unsubstituted C₆-C₃₀ aryloxy, substituted or unsubstituted C₁-C₃₀ alkylthioxy, substituted or unsubstituted C₅-C₃₀ arylthioxy, substituted or unsubstituted C₁-C₃₀ alkylamine, substituted or unsubstituted C₅-C₃₀ arylamine, substituted or unsubstituted C₁-C₃₀ alkylsilyl, substituted or unsubstituted C₅-C₃₀ arylsilyl, nitro, cyano, and halogen, with the proviso that R₁ and R₂ are optionally linked to each other to form an alicyclic or aromatic monocyclic or polycyclic ring, R₂ and R₃ are optionally linked to each other to form an alicyclic or aromatic monocyclic or polycyclic ring, R₄ and R₅ are optionally linked to each other to form an alicyclic or aromatic monocyclic or polycyclic ring, R₅ and R₆ are optionally linked to each other to form an alicyclic or aromatic monocyclic or polycyclic ring, each of R₇ to R₁₁ is optionally bonded to Q₁, Q₂, Q₃, R₁, R₂, R₃, R₄, R₅ or R₆ to form an alicyclic or aromatic monocyclic or polycyclic ring, R₈ and R₉ are optionally linked to each other to form an alicyclic or aromatic monocyclic or polycyclic ring, and R₁₀ and R₁₁ are optionally linked to each other to form an alicyclic or aromatic monocyclic or polycyclic ring, and/or
a compound represented by Formula A-2: 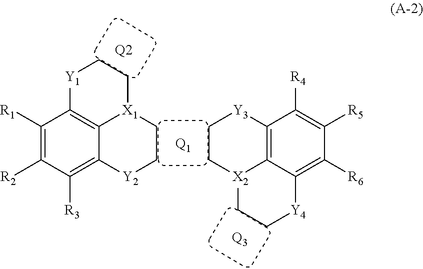
wherein Q₁ to Q₃, X₁, X₂, Yu to Y₄, and R₁ to R₁₁ are as defined in Formula A-1, and
(ii) a compound represented by Formula B: 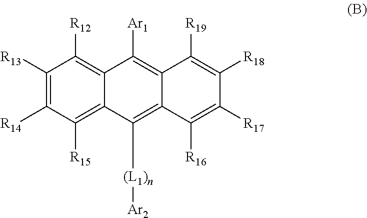
wherein R₁₂ to R₁₉ are identical to or different from each other and are each independently selected from hydrogen, deuterium, substituted or unsubstituted C₁-C₃₀ alkyl, substituted or unsubstituted C₆-C₅₀ aryl, substituted or unsubstituted C₂-C₅₀ heteroaryl, substituted or unsubstituted C₁-C₃₀ alkylsilyl, substituted or unsubstituted C₅-C₃₀ arylsilyl, cyano, and halogen, Ar₁ and Ar₂ are identical to or different from each other and are each independently selected from substituted or unsubstituted C₆-C₅₀ aryl and substituted or unsubstituted C₂-C₅₀ heteroaryl, L₁ is a single bond or is selected from substituted or unsubstituted C₆-C₂₀ arylene and substituted or unsubstituted C₂-C₂₀ heteroarylene, n is an integer from 1 to 3, provided that when n is 2 or more, the linkers L₁ are identical to or different from each other.

2. The organic electroluminescent device according to claim 1, wherein Q₁ in each of Formulae A-1 and A-2 is represented by one of the following structures 1 to 8: 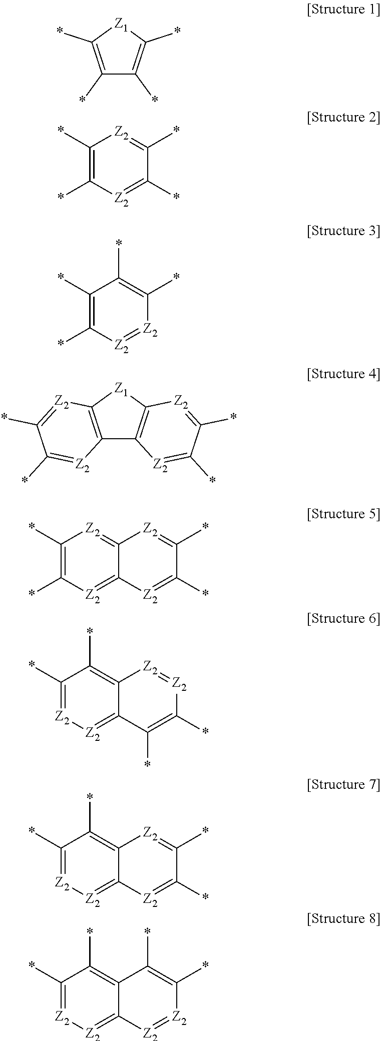
wherein each Z₁ is O, S, CRR′ or SiRR′, the moieties Z₂ are identical to or different from each other and are each independently CR″ or N, R, R′, and R″ are identical to or different from each other and are each independently selected from hydrogen, deuterium, substituted or unsubstituted C₁-C₃₀ alkyl, substituted or unsubstituted C₆-C₅₀ aryl, substituted or unsubstituted C₃-C₃₀ cycloalkyl, substituted or unsubstituted C₂-C₅₀ heteroaryl, substituted or unsubstituted C₁-C₃₀ alkoxy, substituted or unsubstituted C₆-C₃₀ aryloxy, substituted or unsubstituted C₁-C₃₀ alkylthioxy, substituted or unsubstituted C₅-C₃₀ arylthioxy, substituted or unsubstituted C₁-C₃₀ alkylamine, substituted or unsubstituted C₅-C₃₀ arylamine, substituted or unsubstituted C₁-C₃₀ alkylsilyl, substituted or unsubstituted C₅-C₃₀ arylsilyl, nitro, cyano, and halogen, and the asterisks (*) indicate sites at which Q₁ is bonded to X₁, X₂, Y₂, and Y₄ in Formula A-1 or X₁, X₂, Y₂, and Y₃ in Formula A-2.

3. The organic electroluminescent device according to claim 1, wherein Q₂ and Q₃ in each of Formulae A-1 and A-2 are each independently represented by one of the following structures 9 to 13: 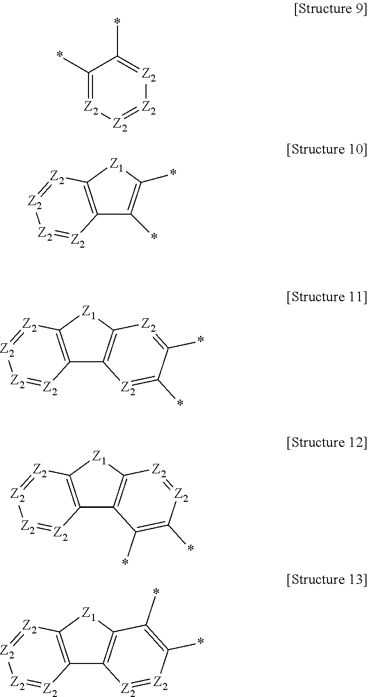
wherein each Z₁ is O, S, CRR′ or SiRR′, the moieties Z₂ are identical to or different from each other and are each independently CR″ or N, R, R′, and R″ are identical to or different from each other and are each independently selected from hydrogen, deuterium, substituted or unsubstituted C₁-C₃₀ alkyl, substituted or unsubstituted C₆-C₅₀ aryl, substituted or unsubstituted C₃-C₃₀ cycloalkyl, substituted or unsubstituted C₂-C₅₀ heteroaryl, substituted or unsubstituted C₁-C₃₀ alkoxy, substituted or unsubstituted C₆-C₃₀ aryloxy, substituted or unsubstituted C₁-C₃₀ alkylthioxy, substituted or unsubstituted C₅-C₃₀ arylthioxy, substituted or unsubstituted C₁-C₃₀ alkylamine, substituted or unsubstituted C₅-C₃₀ arylamine, substituted or unsubstituted C₁-C₃₀ alkylsilyl, substituted or unsubstituted C₅-C₃₀ arylsilyl, nitro, cyano, and halogen, and the asterisks (*) indicate sites at which Q₂ is bonded to X₁ and Y₁ and Q₃ is bonded to X₂ and Y₃ in Formula A-1 or Q₂ is bonded to X₁ and Y₁ and Q₃ is bonded to X₂ and Y₄ in Formula A-2.

4. The organic electroluminescent device according to claim 1, wherein the compound represented by Formula B is represented by Formula B-1: 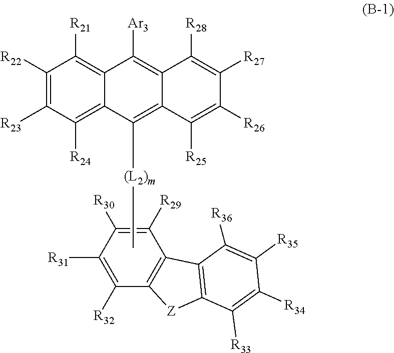
wherein R₂₁ to R₃₆ are identical to or different from each other and are each independently selected from hydrogen, deuterium, substituted or unsubstituted C₁-C₃₀ alkyl, substituted or unsubstituted C₃-C₃₀ cycloalkyl, substituted or unsubstituted C₆-C₅₀ aryl, substituted or unsubstituted C₂-C₅₀ heteroaryl, substituted or unsubstituted C₁-C₃₀ alkylsilyl, substituted or unsubstituted C₅-C₃₀ arylsilyl, cyano, and halogen, Ara is substituted or unsubstituted C₆-C₅₀ aryl or substituted or unsubstituted C₂-C₅₀ heteroaryl, Z is an oxygen (O) or sulfur (S) atom, L₂ is a single bond or is substituted or unsubstituted C₆-C₂₀ arylene or substituted or unsubstituted C₂-C₂₀ heteroarylene, m is an integer from 1 to 3, provided that when m is 2 or more, the linkers L₂ are identical to or different from each other.

5. The organic electroluminescent device according to claim 1, wherein the compound represented by Formula A-1 or A-2 is selected from the following compounds 1 to 165:

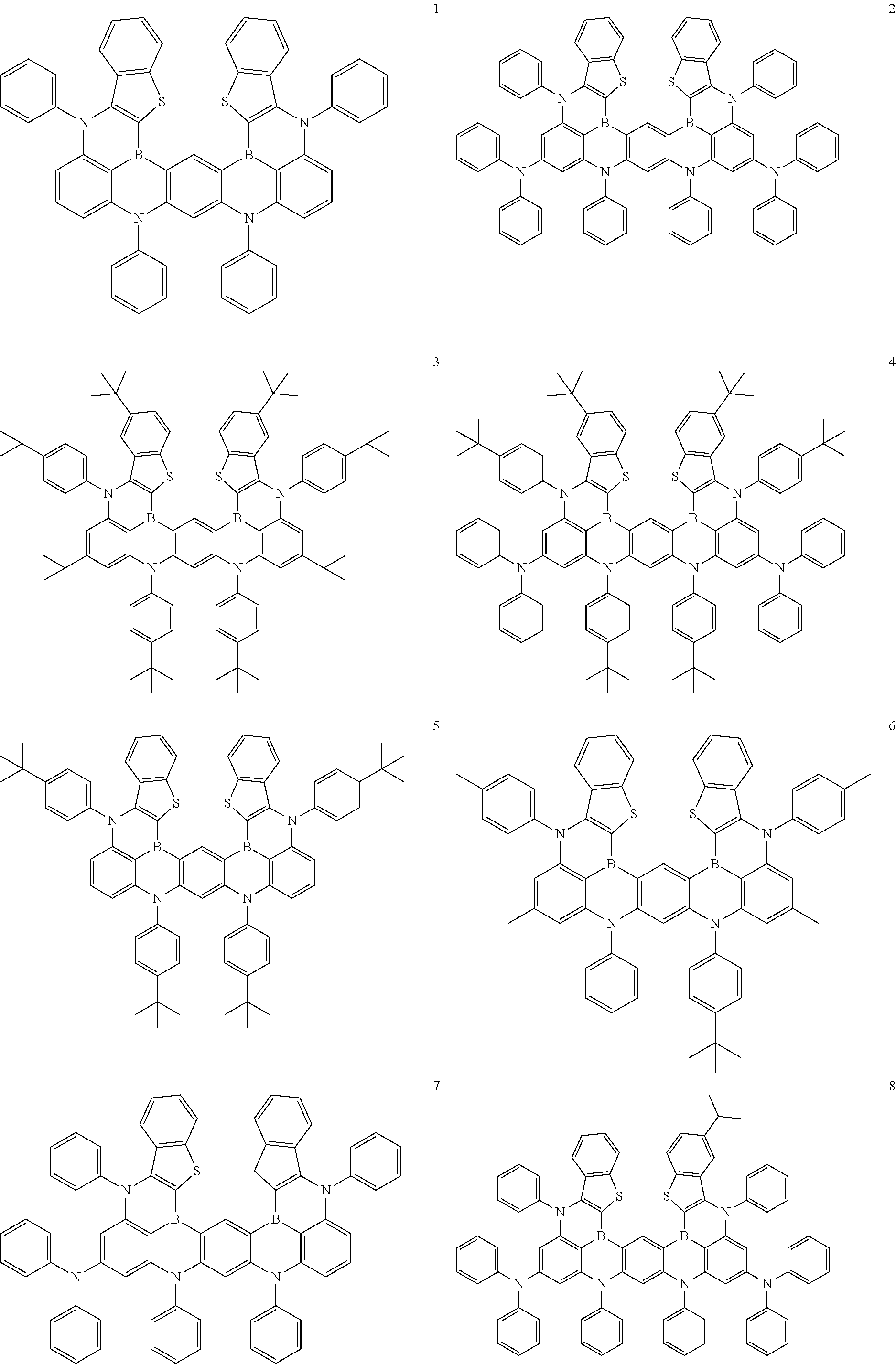

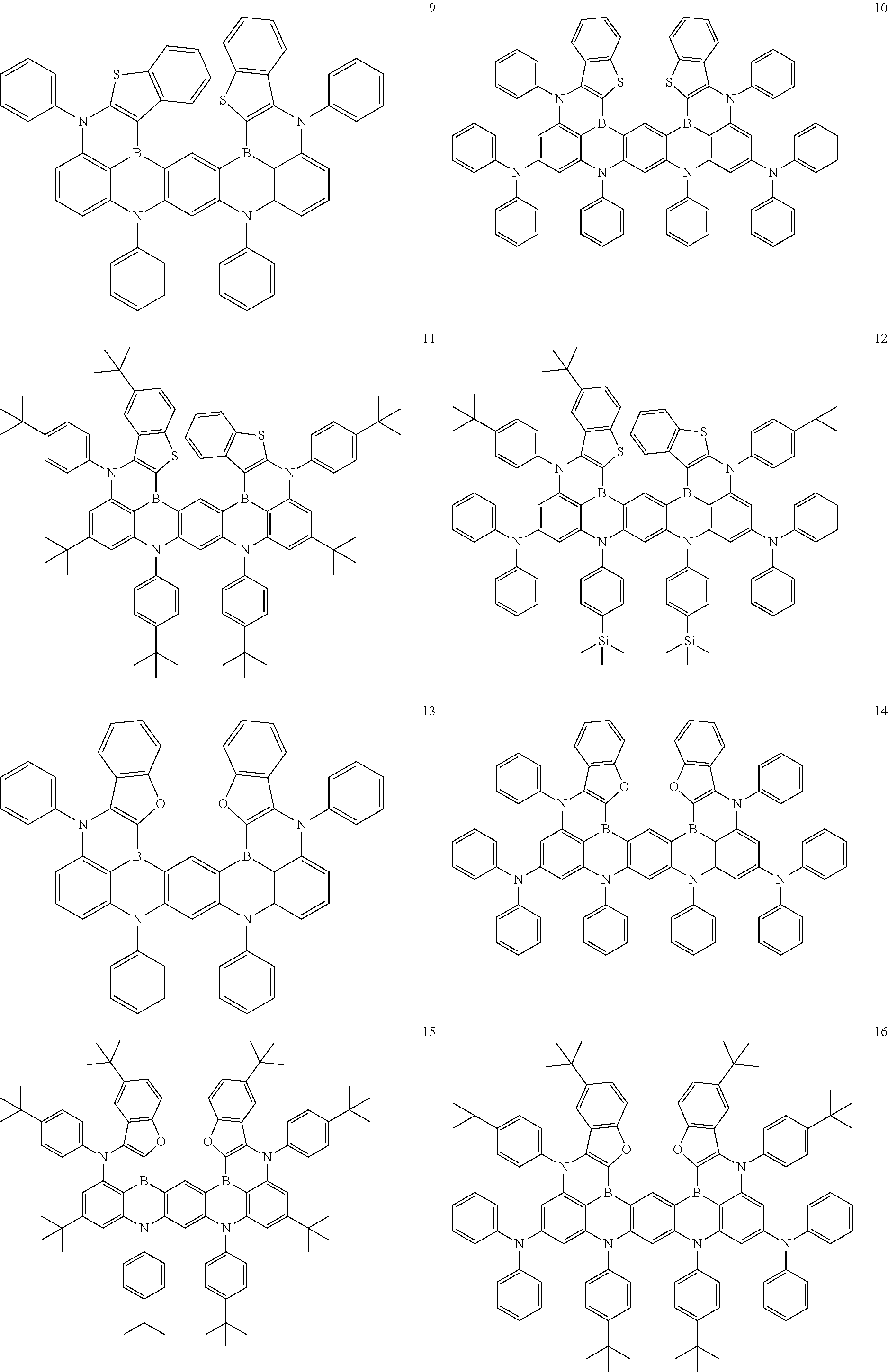

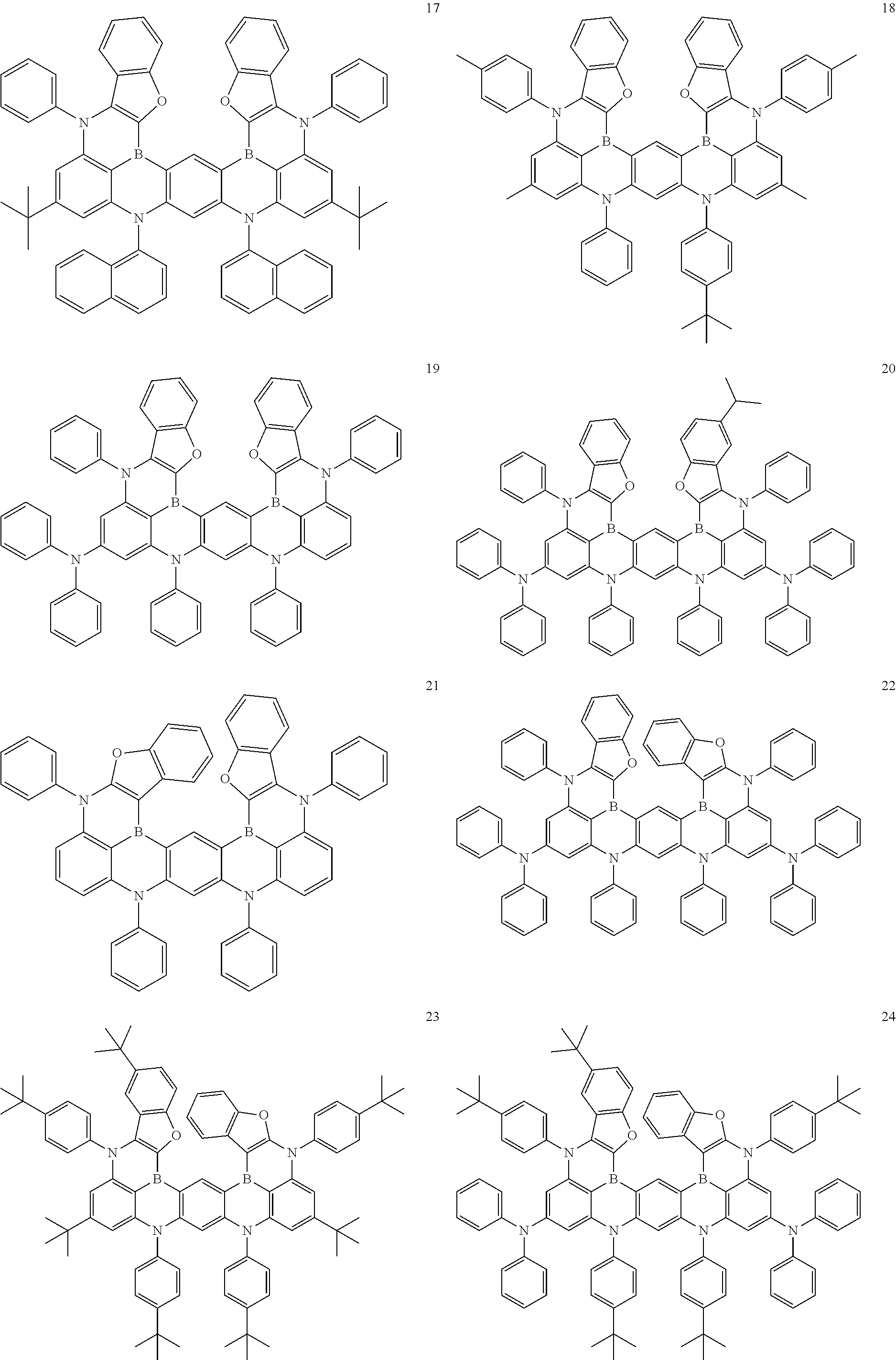

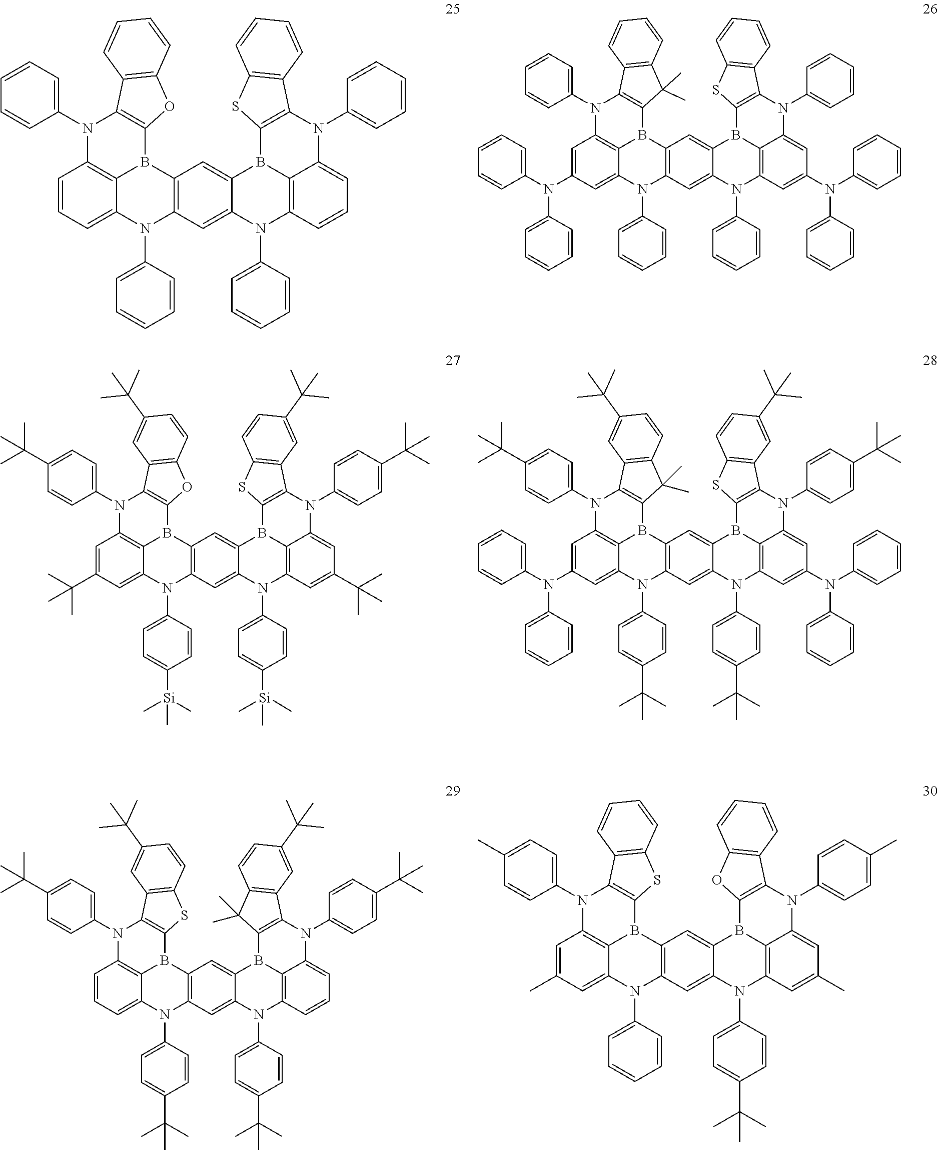

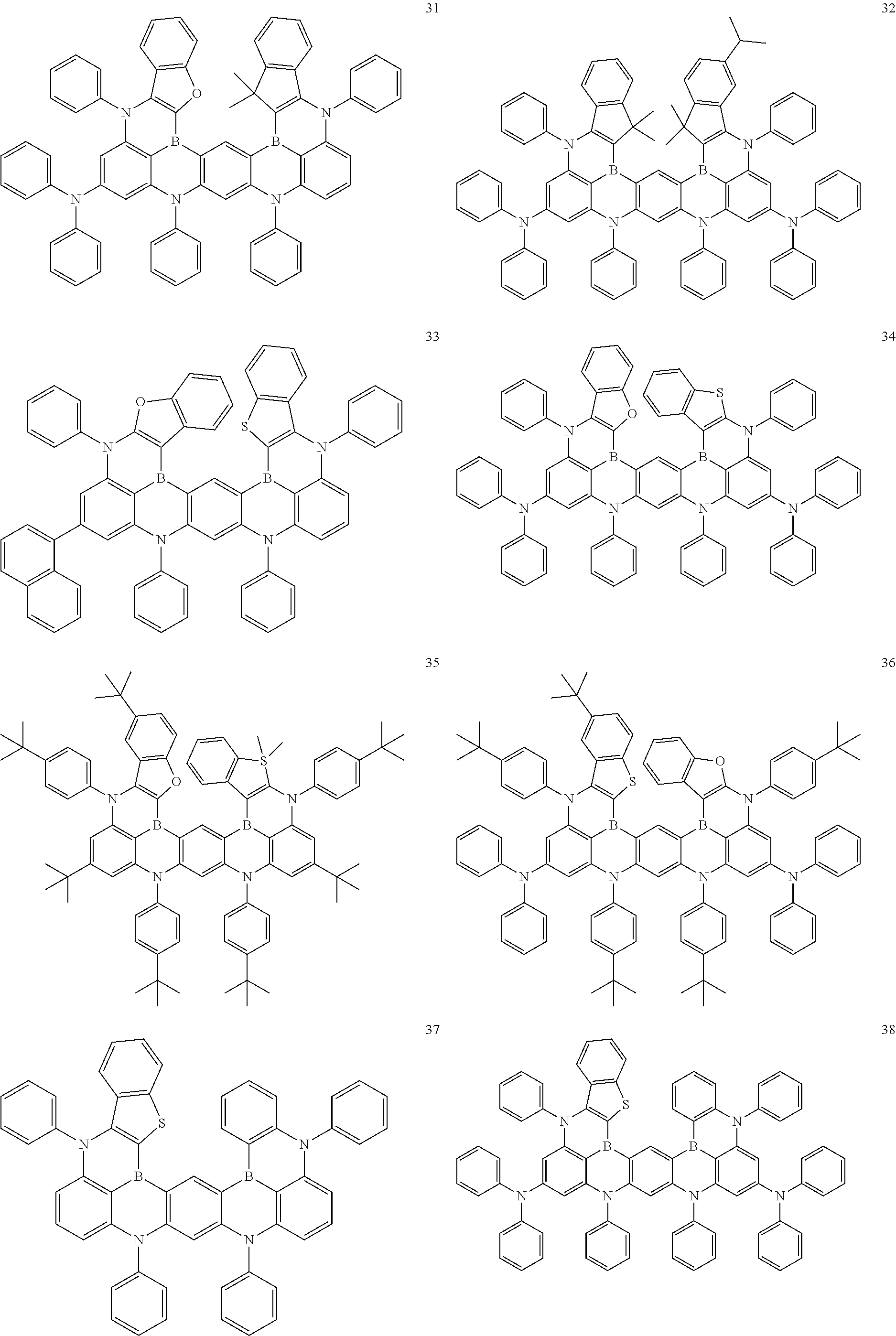

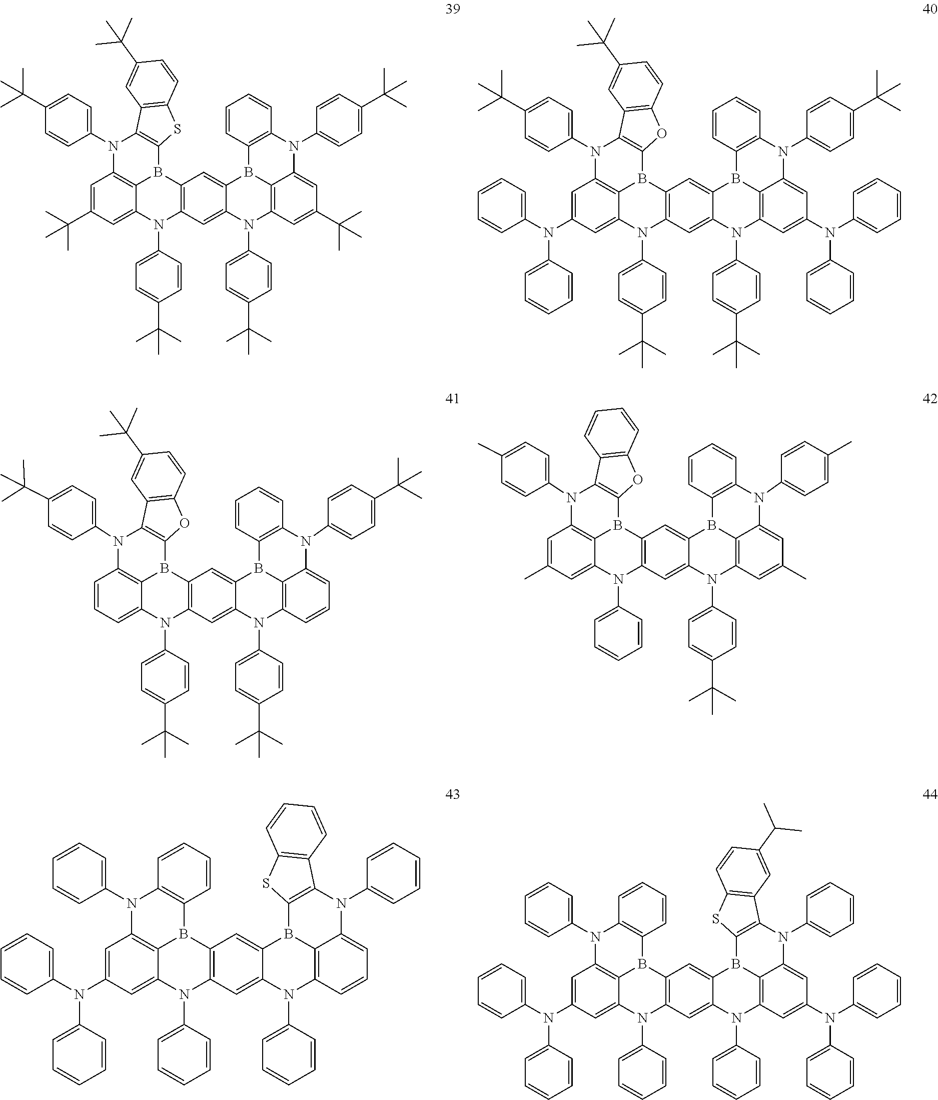

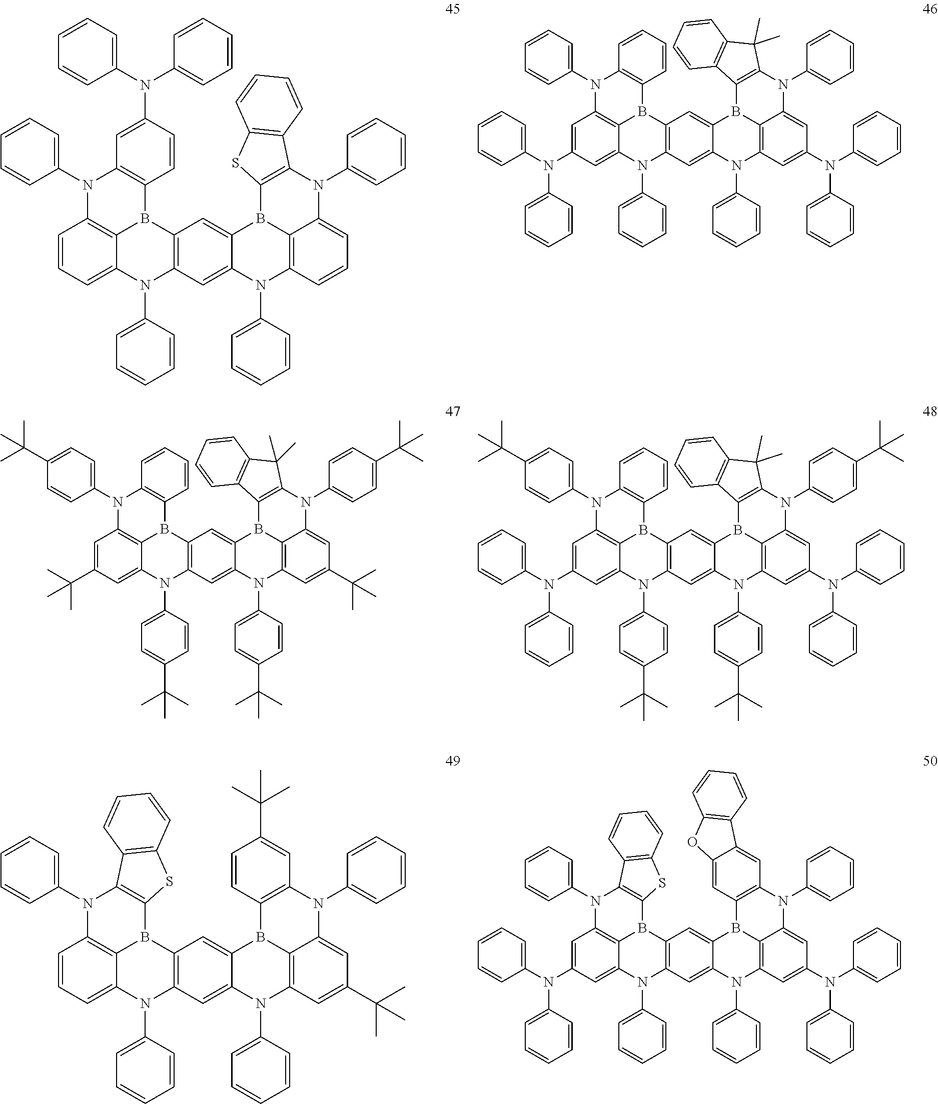

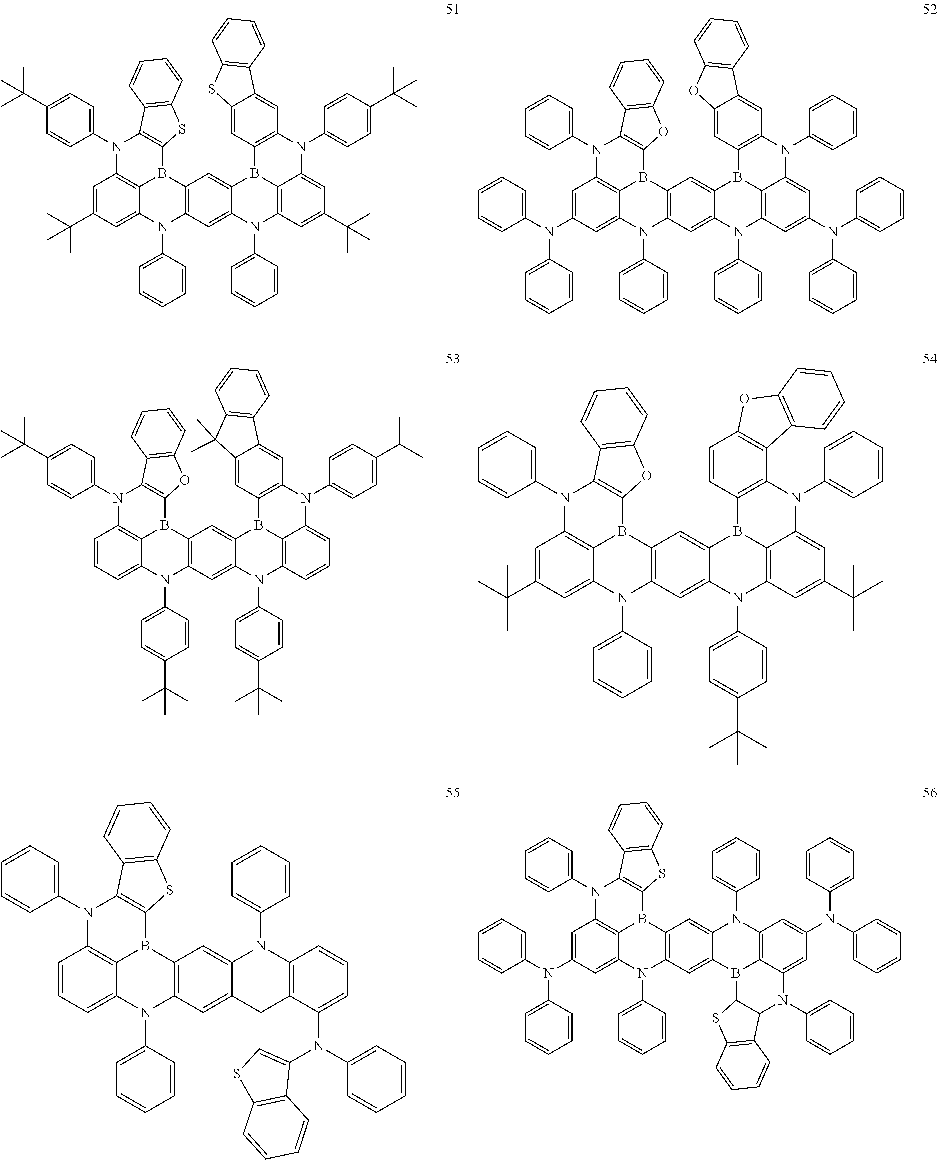

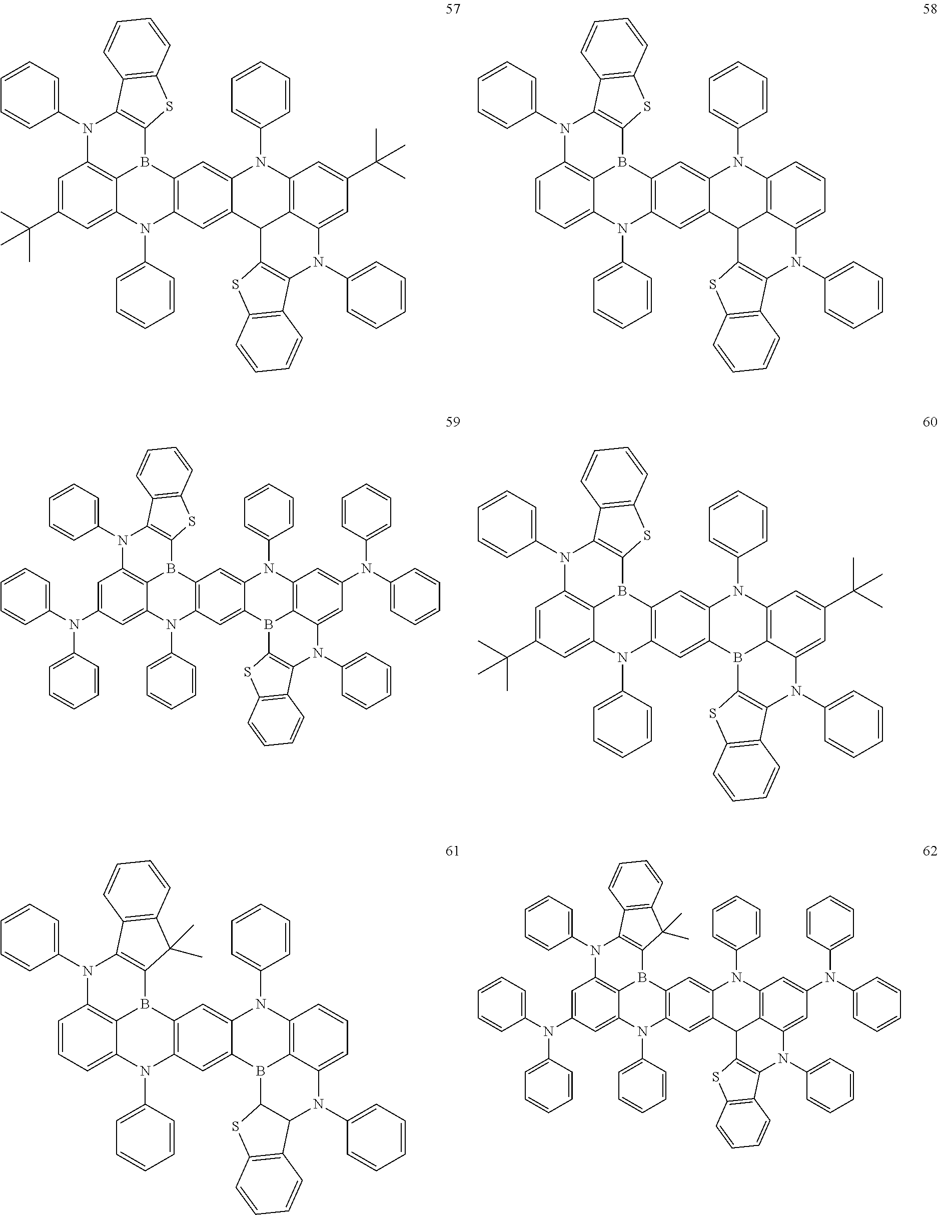

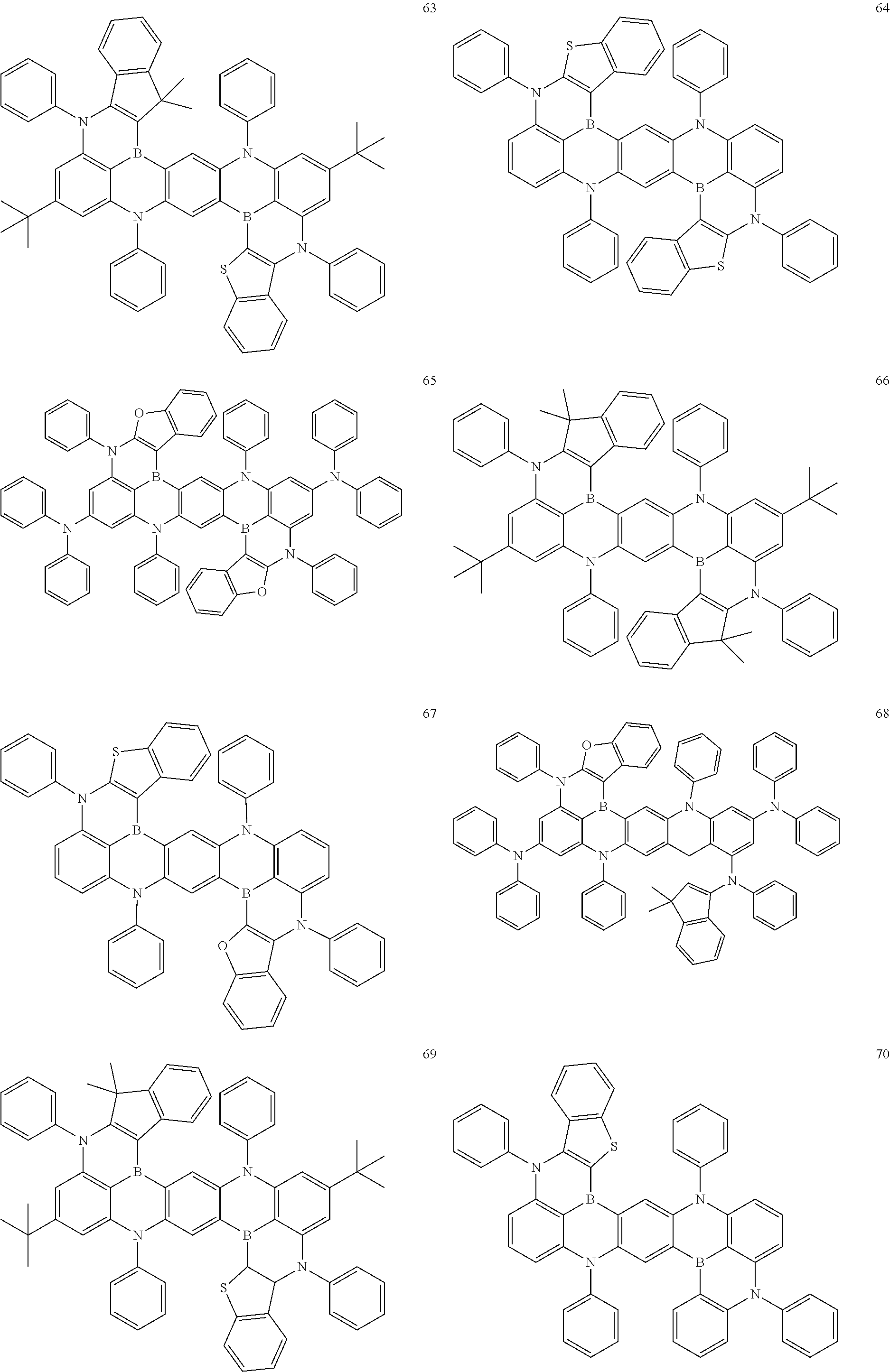

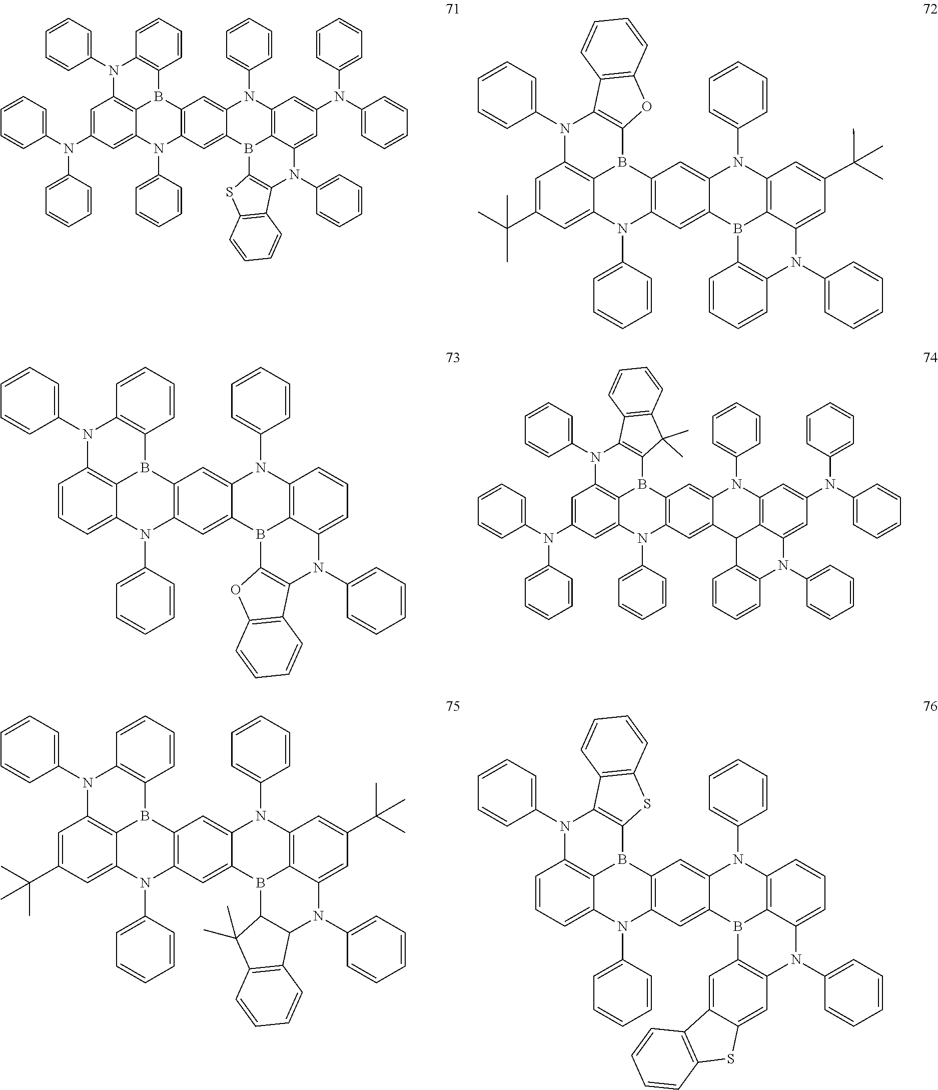

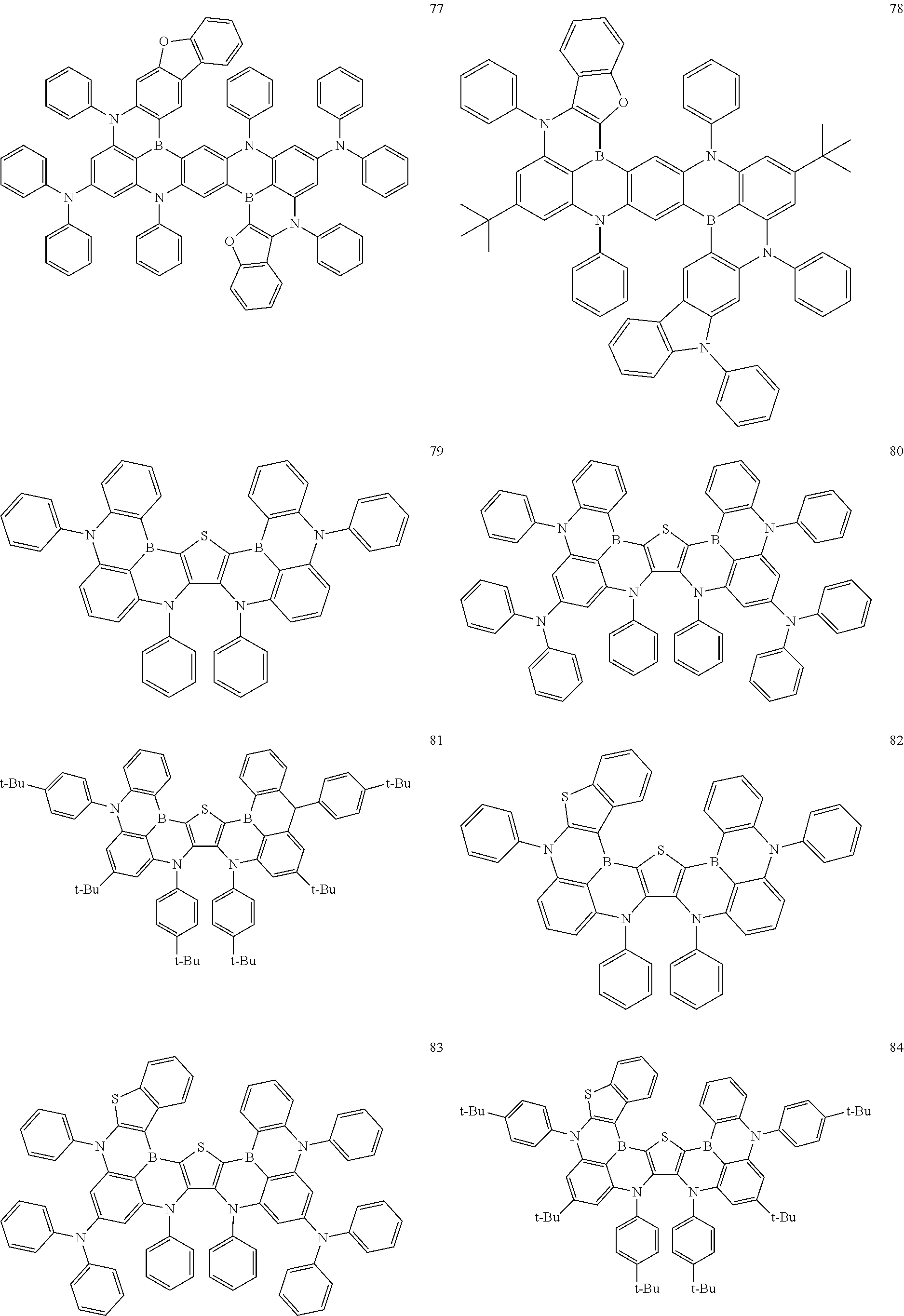

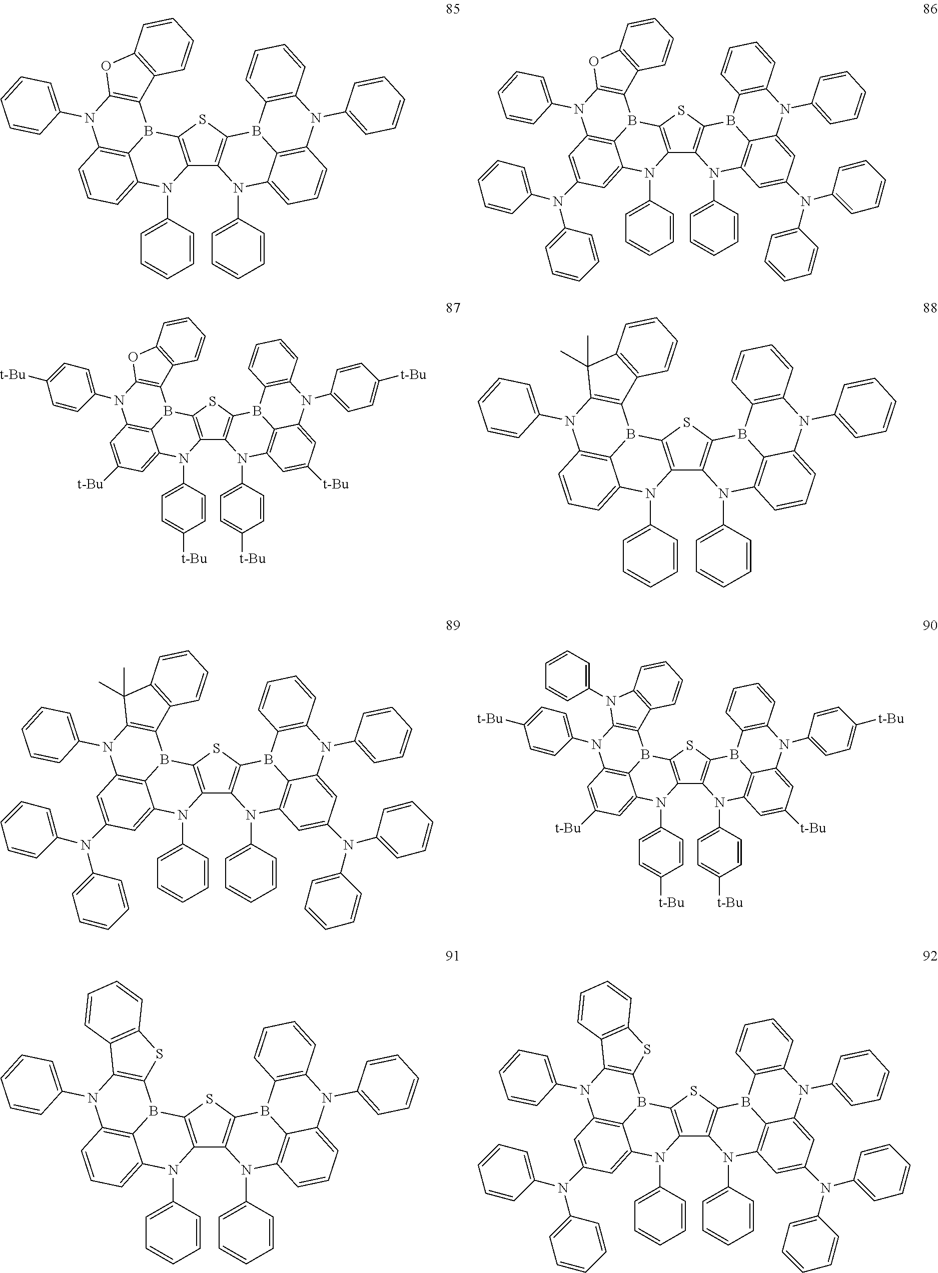

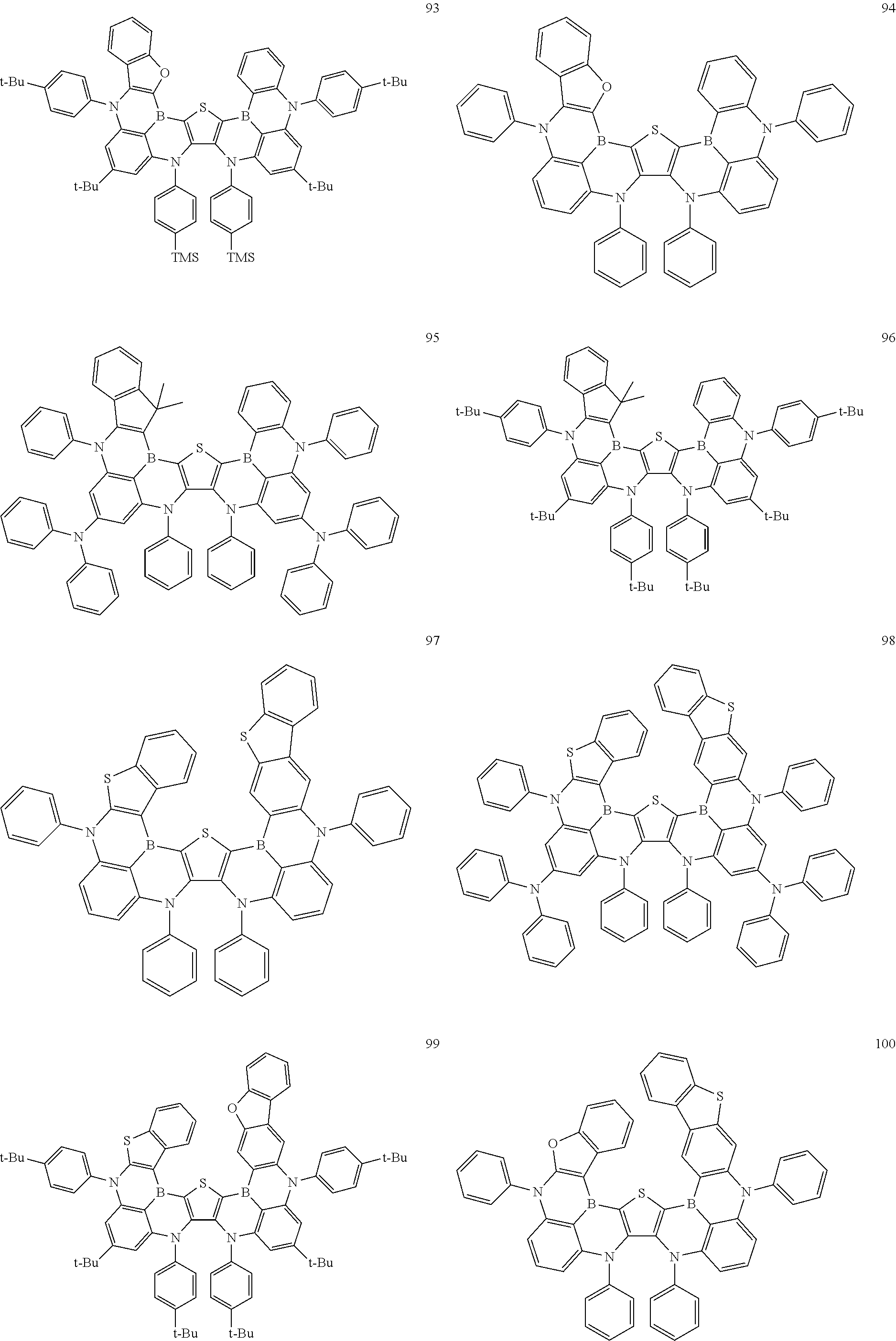

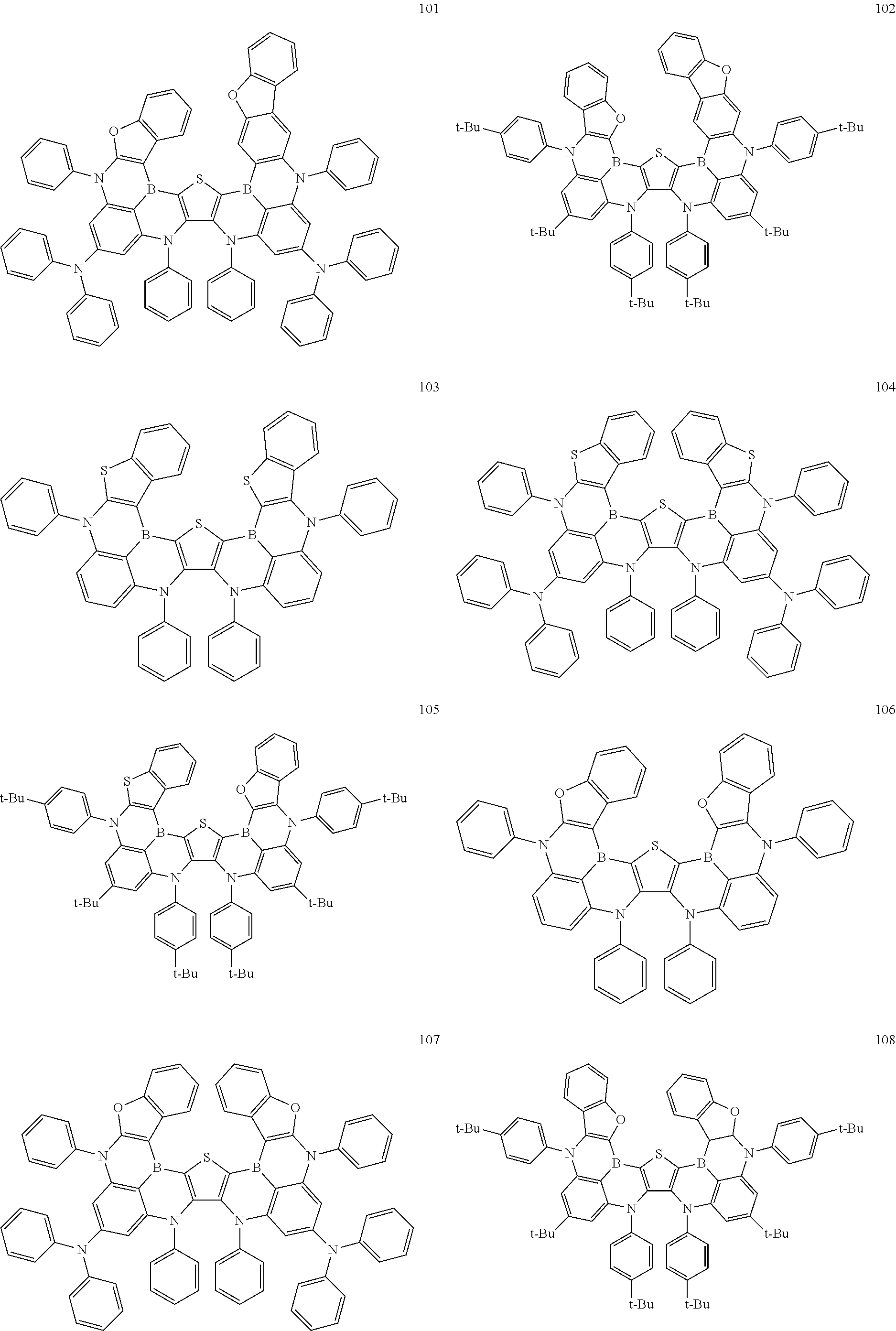

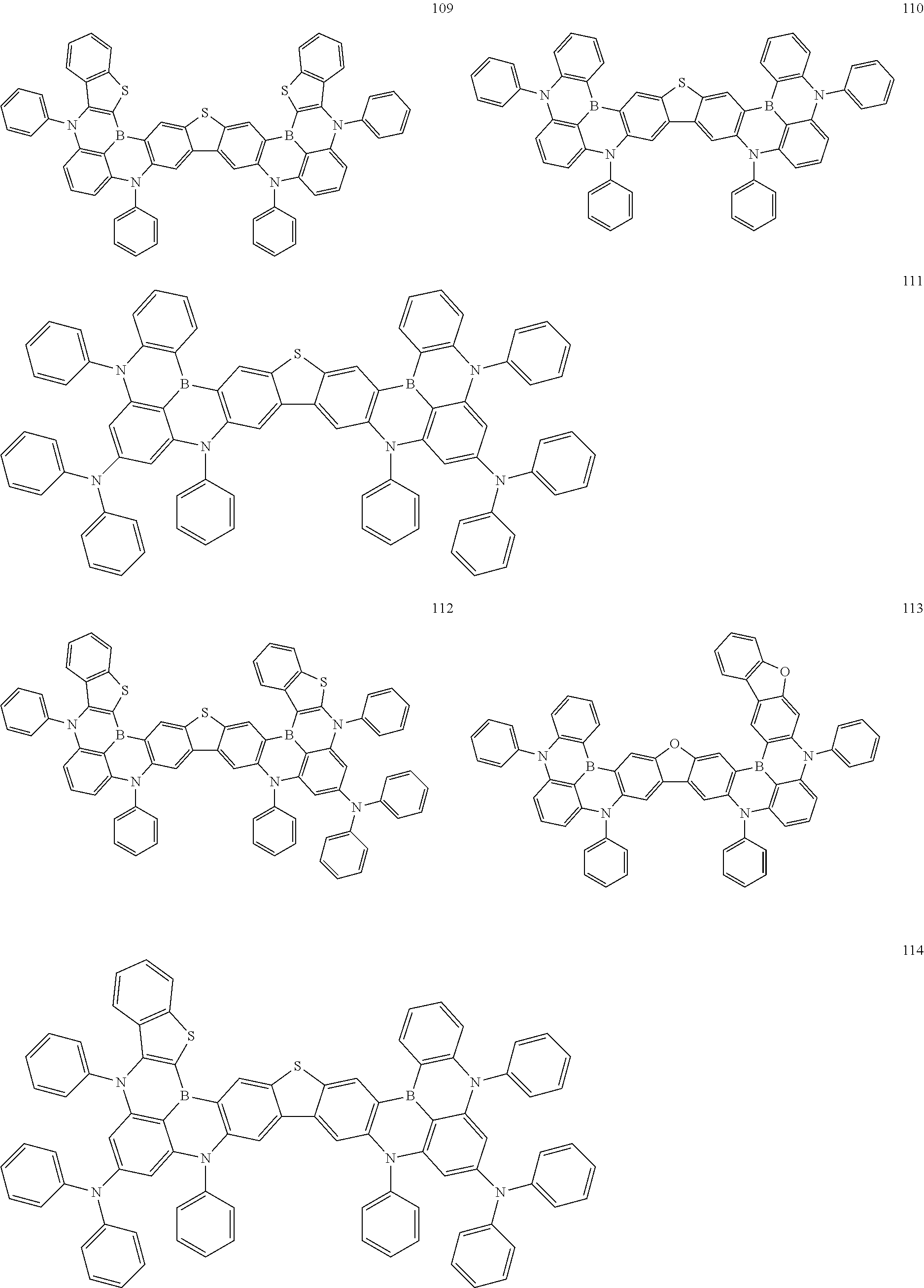

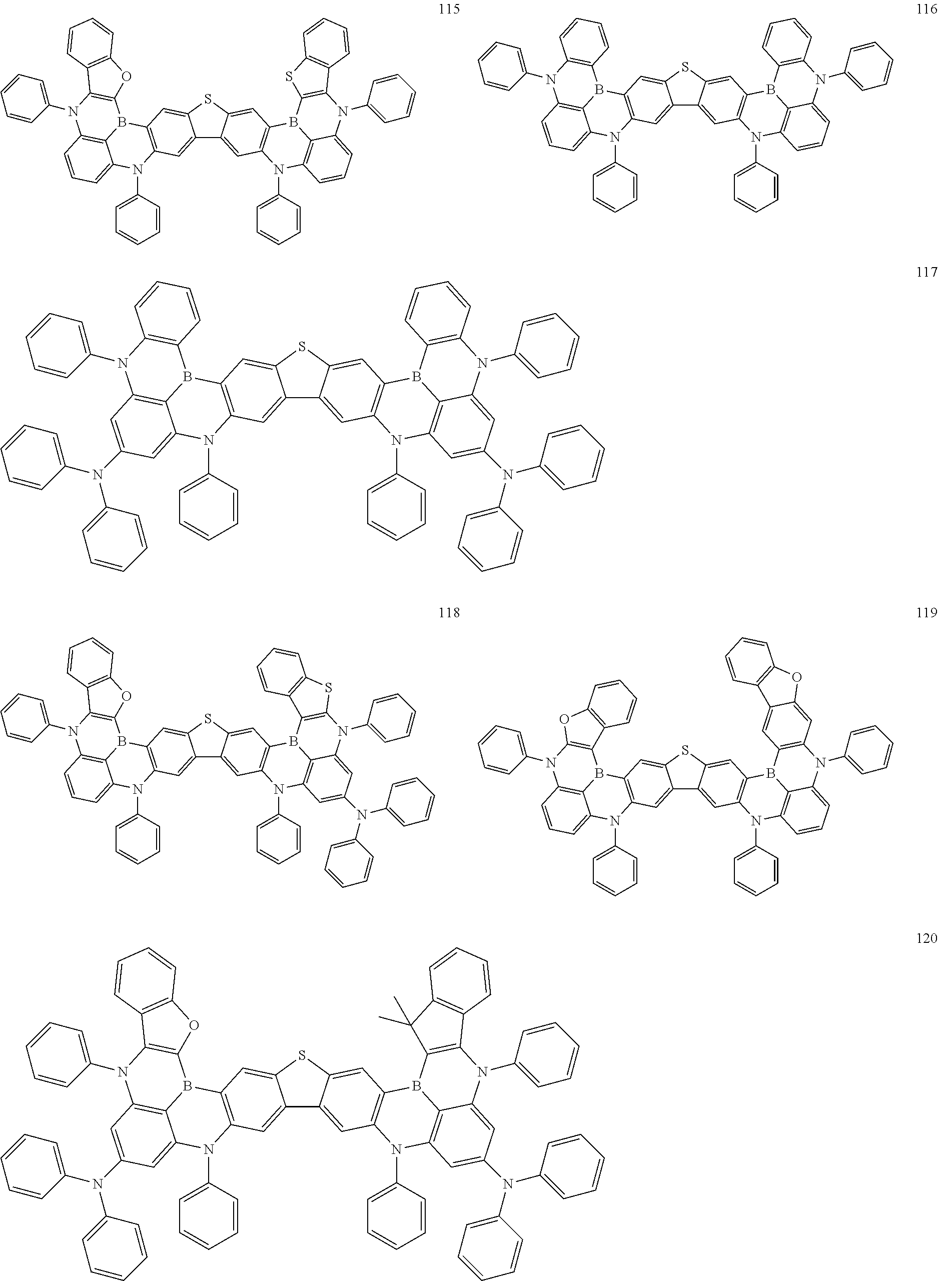

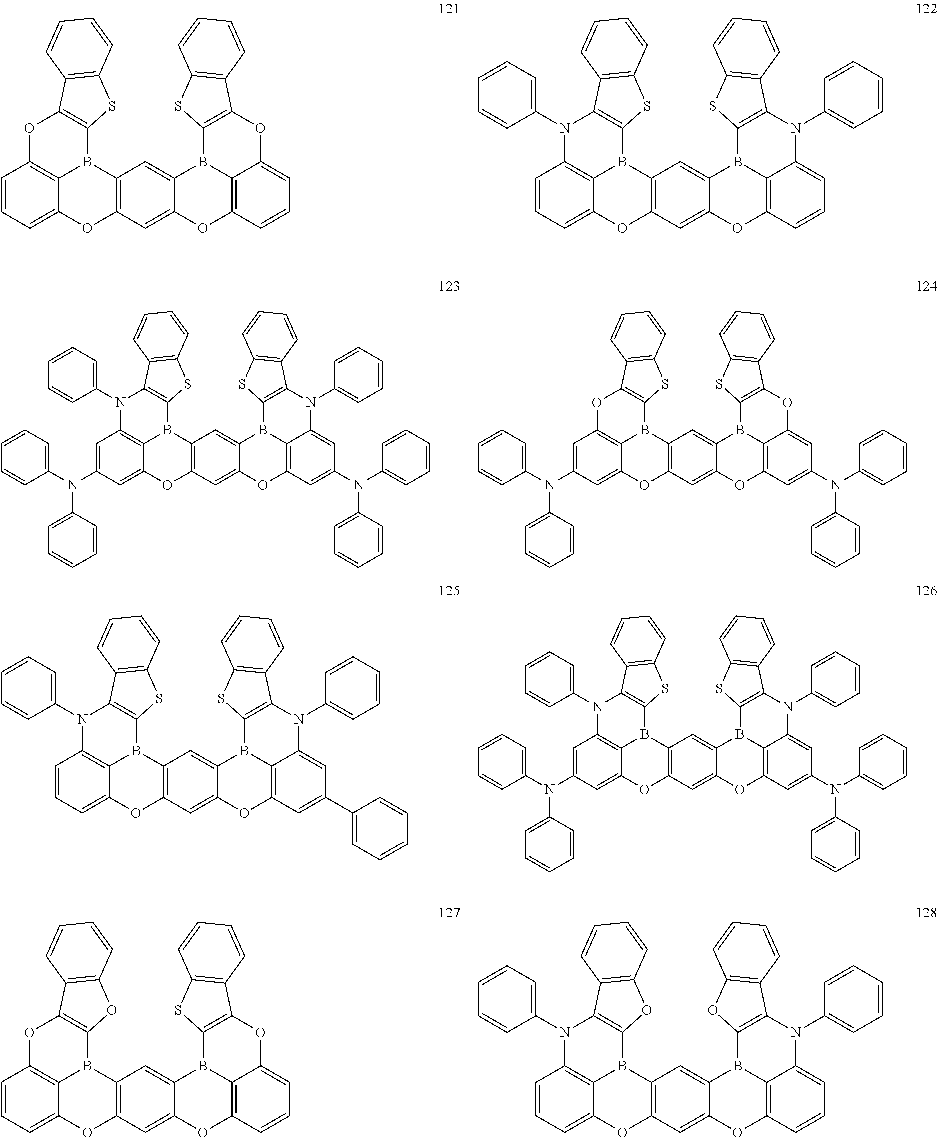

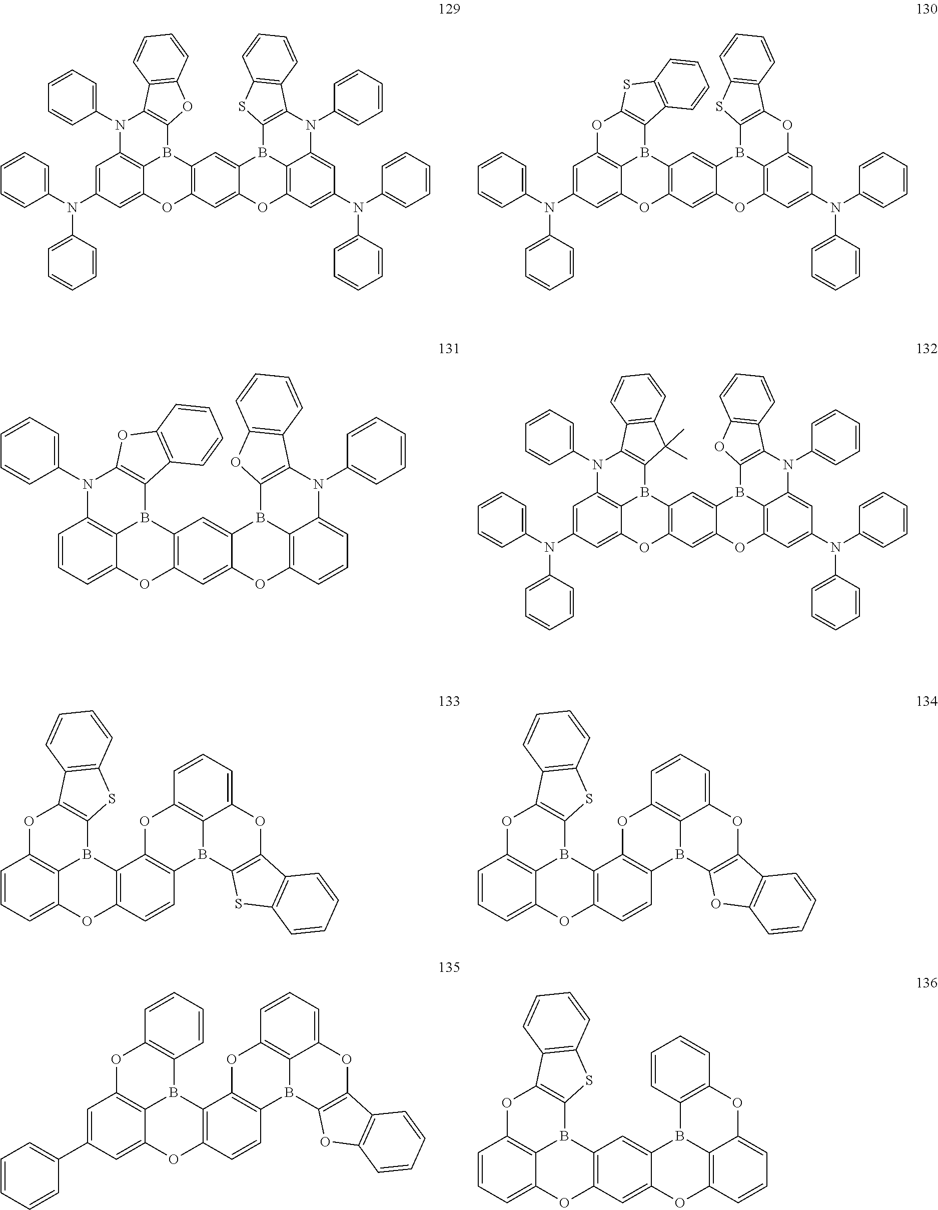

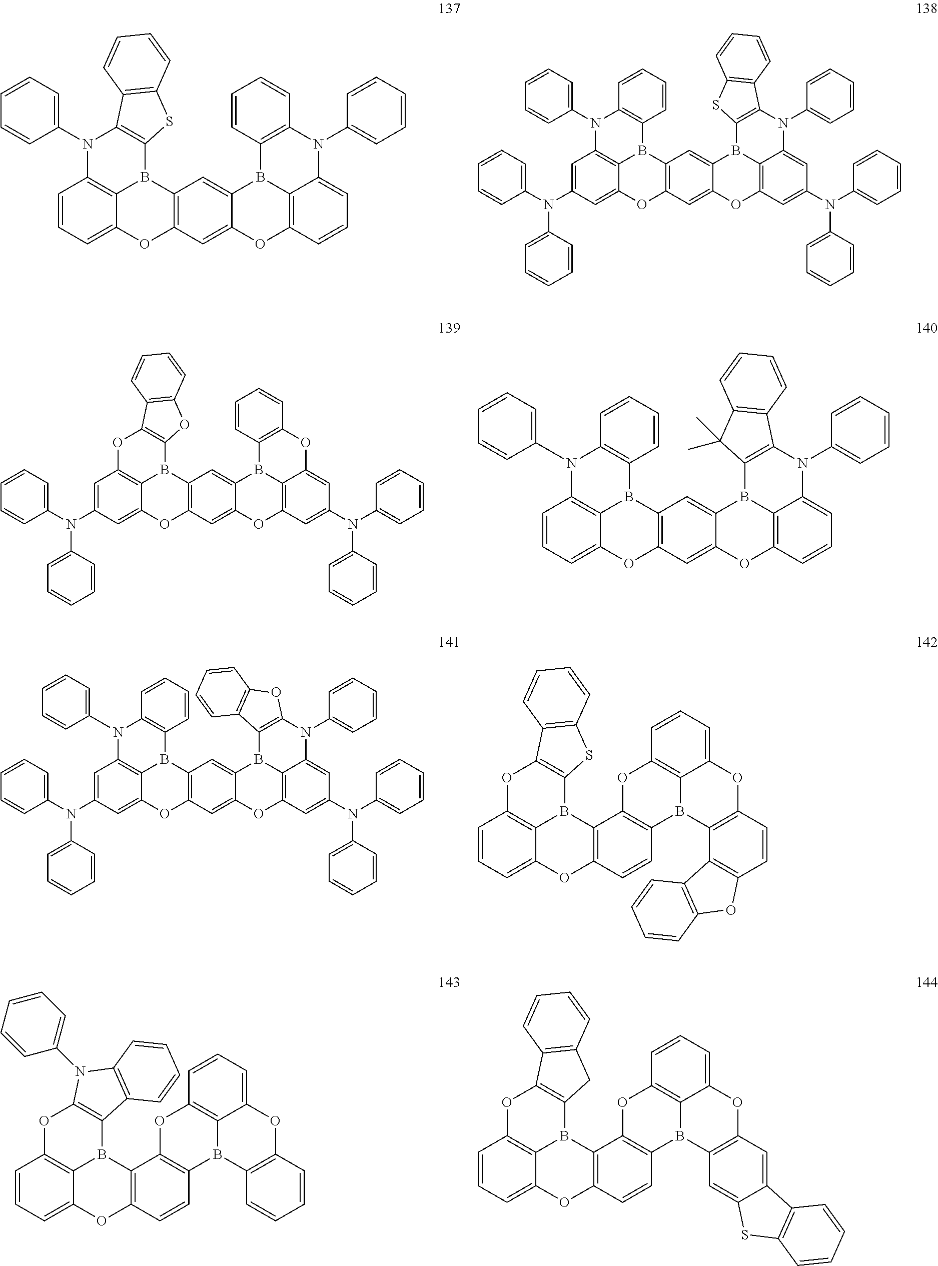

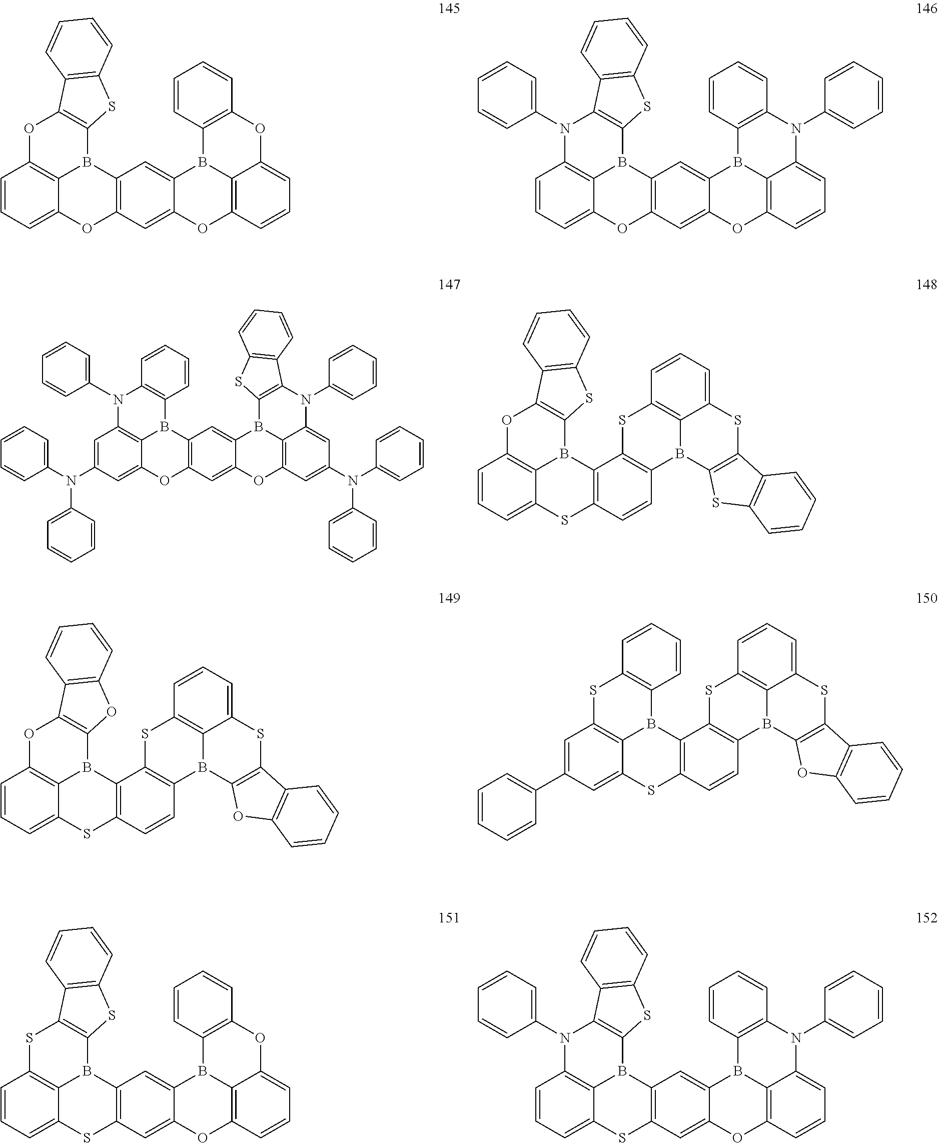

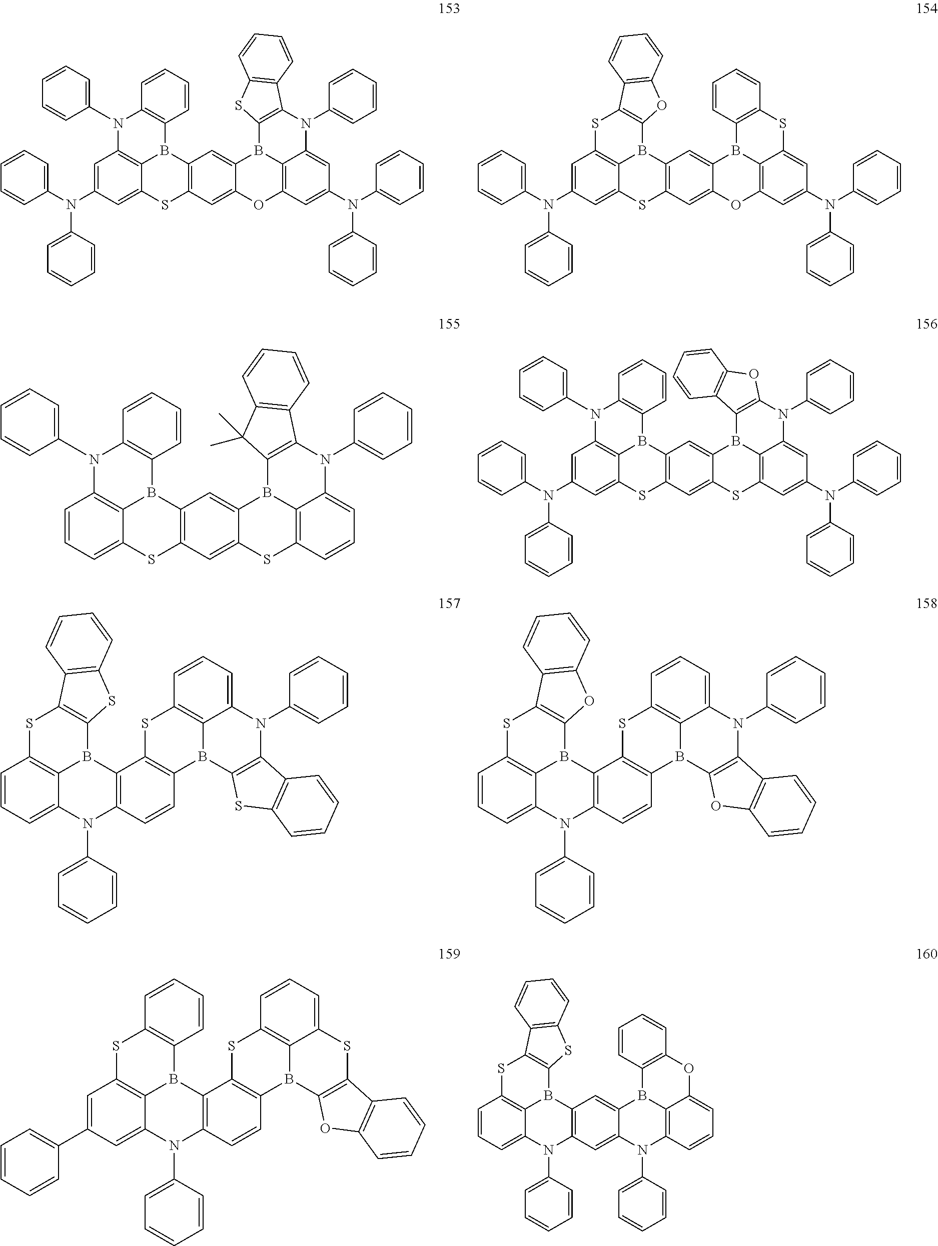

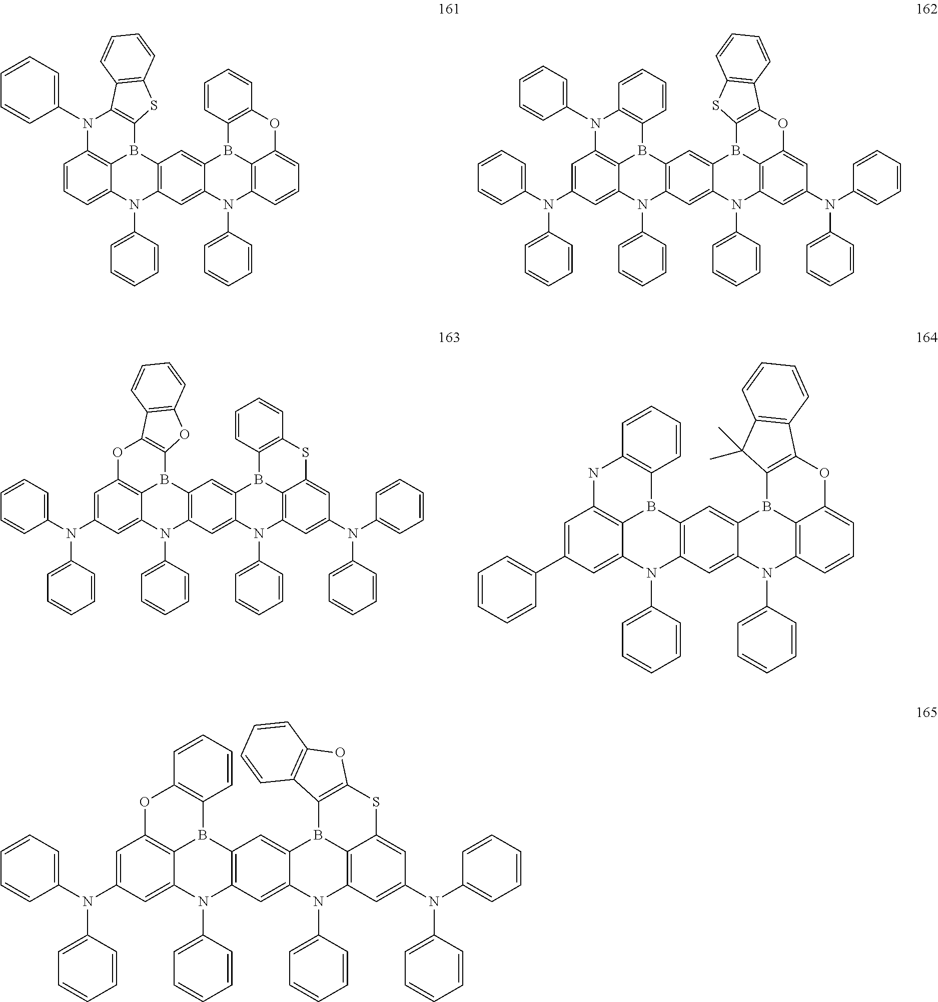

6. The organic electroluminescent device according to claim 1, wherein the compound represented by Formula B is selected from the following compounds:

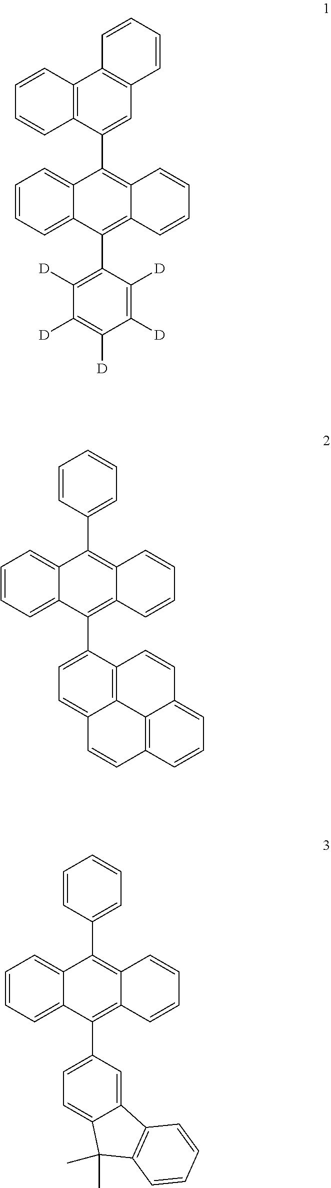

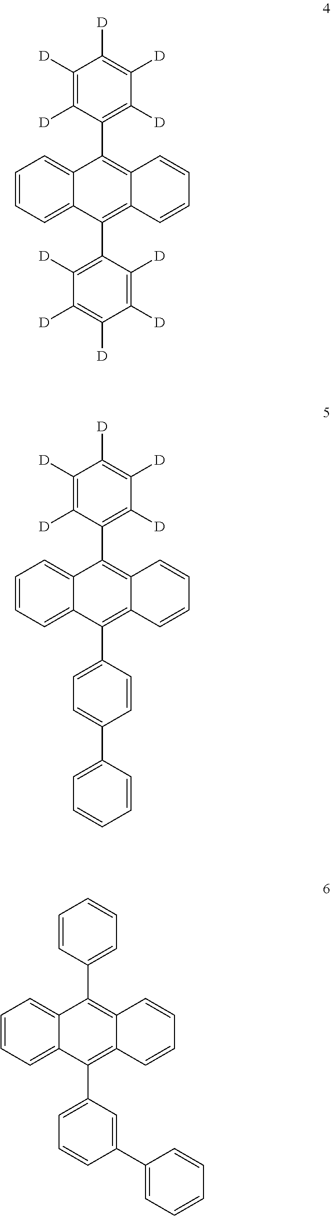

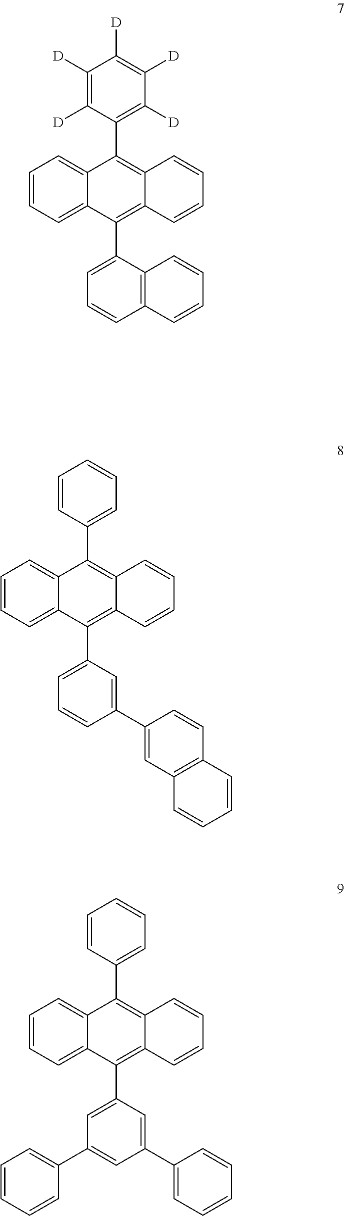

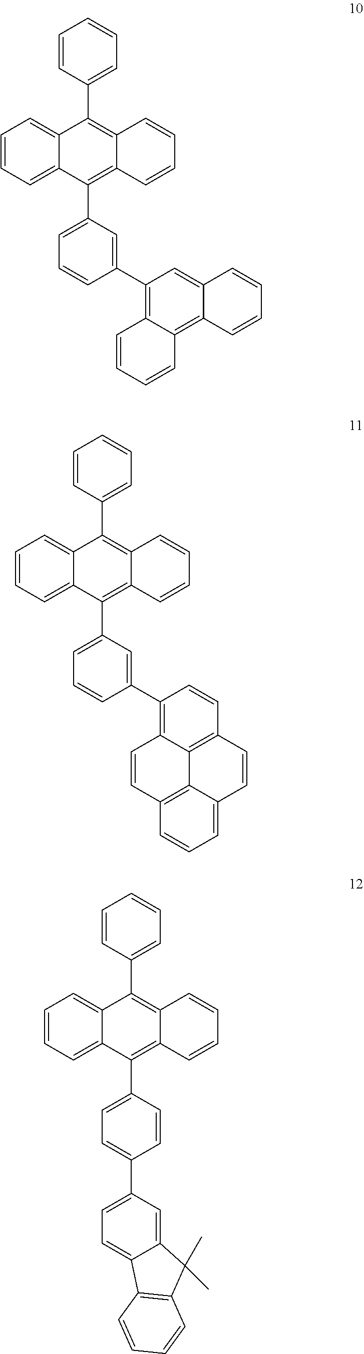

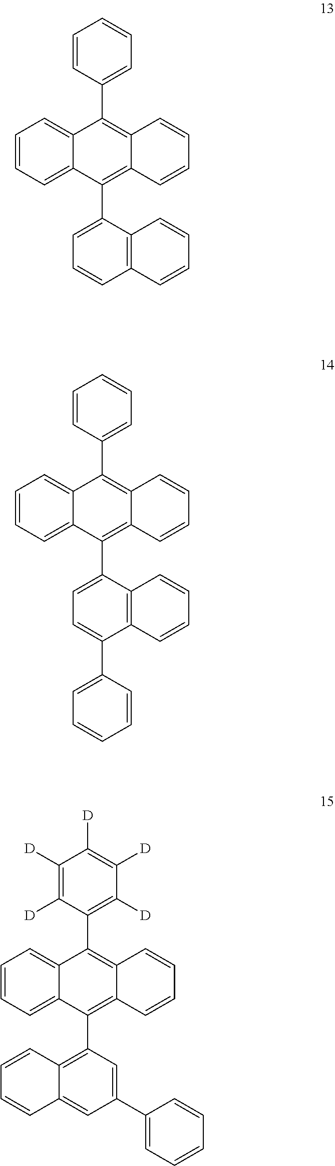

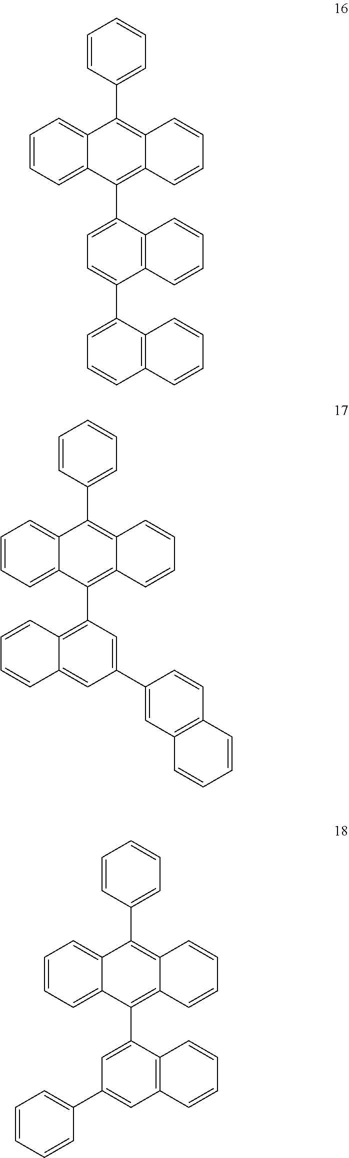

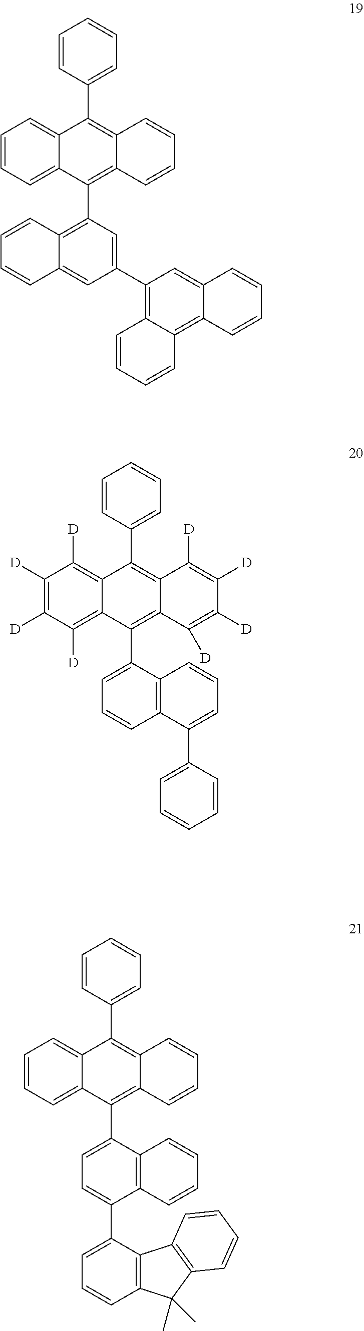

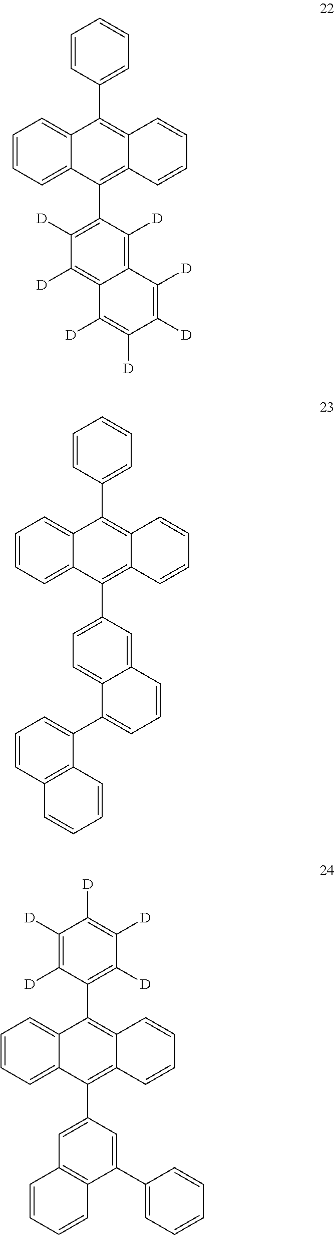

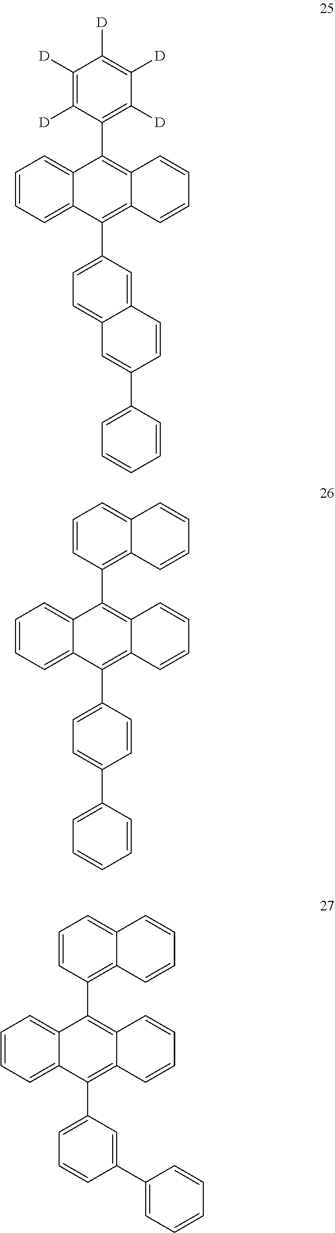

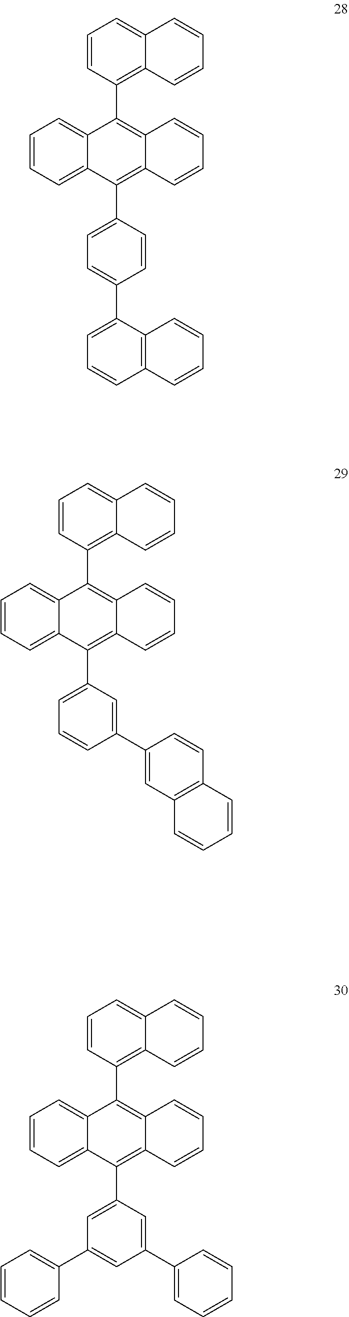

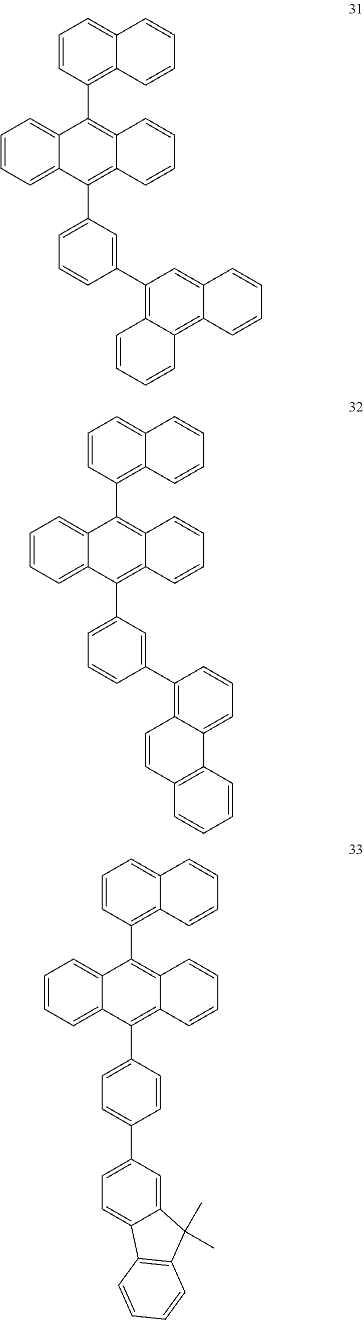

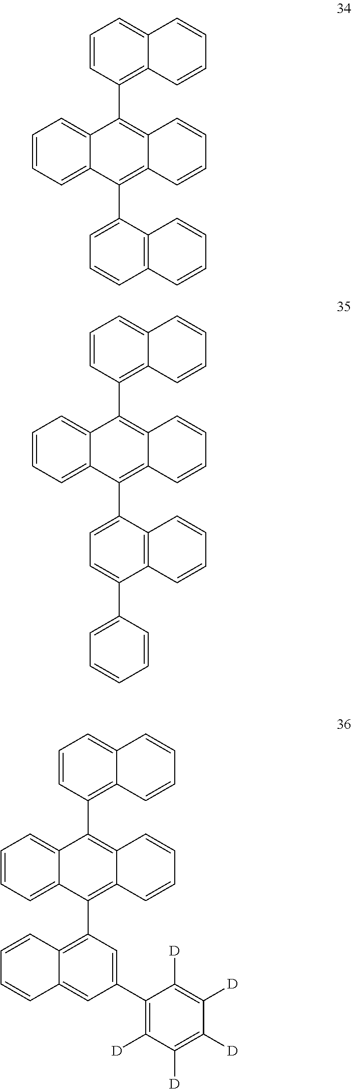

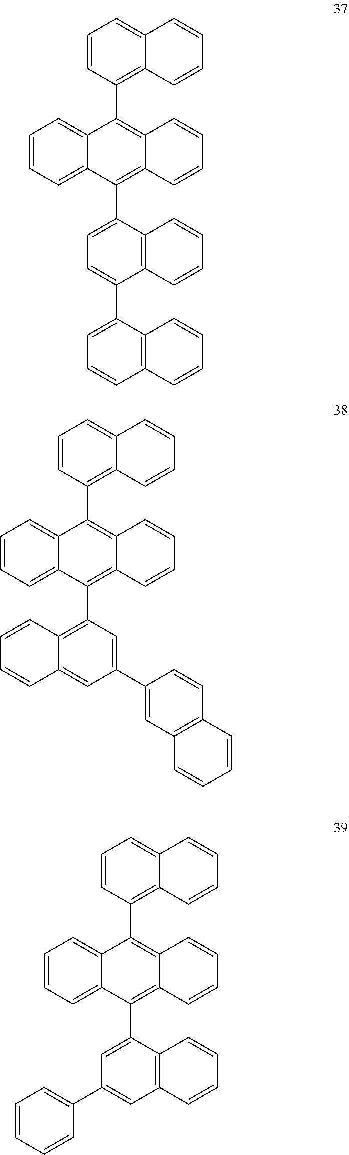

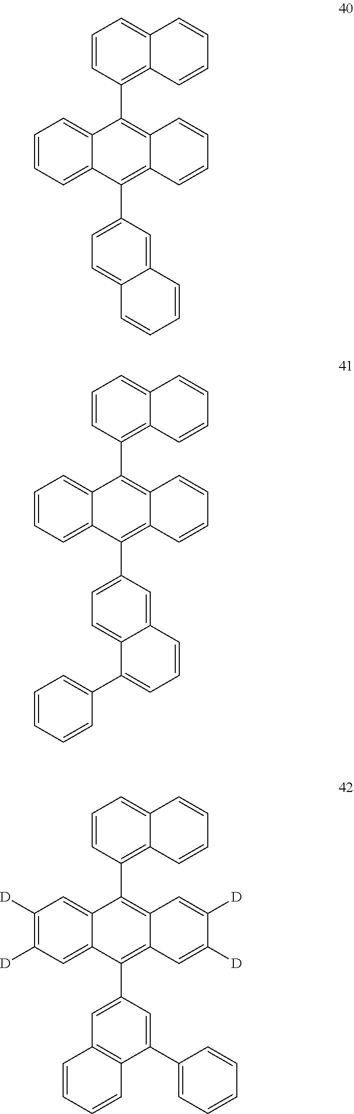

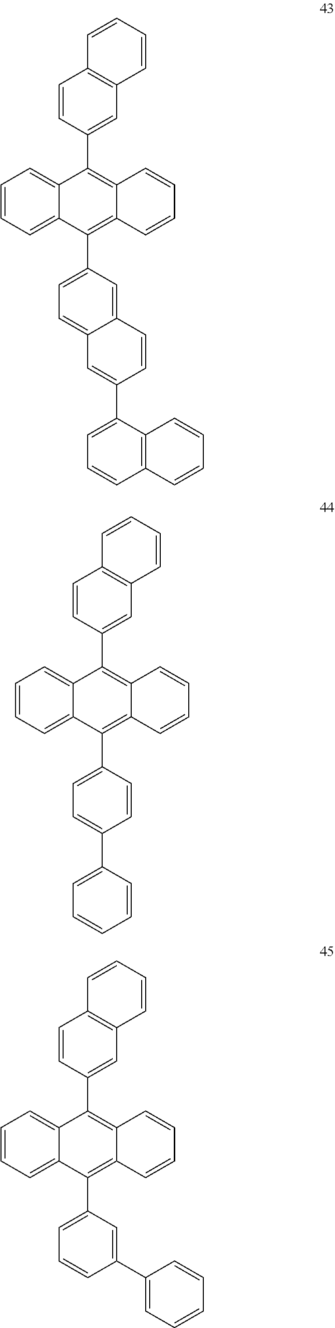

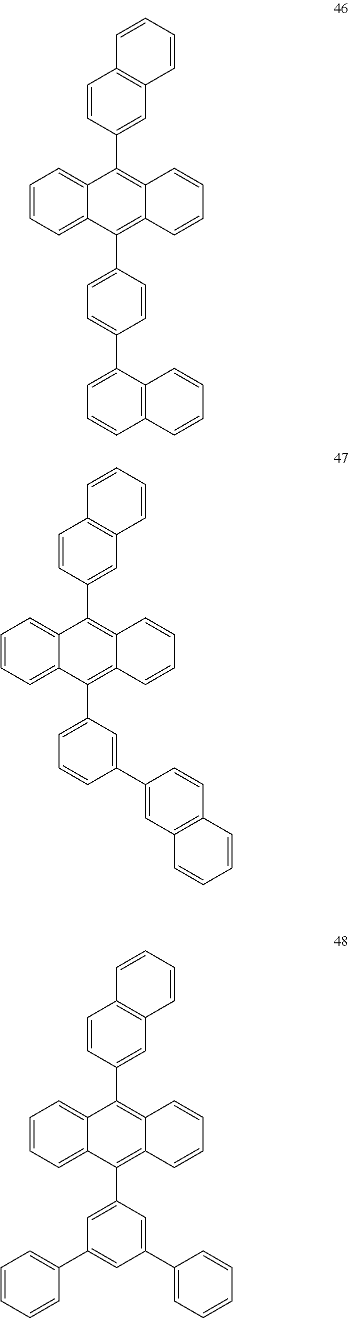

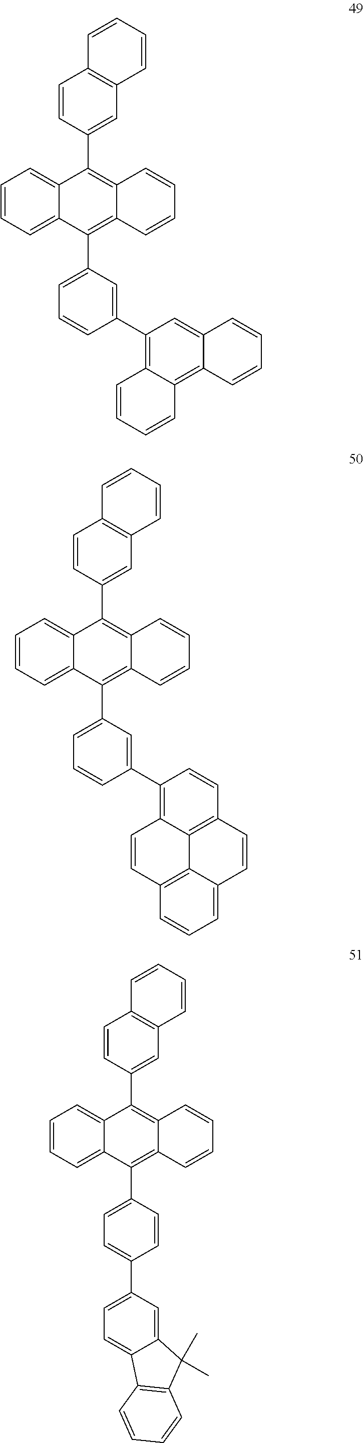

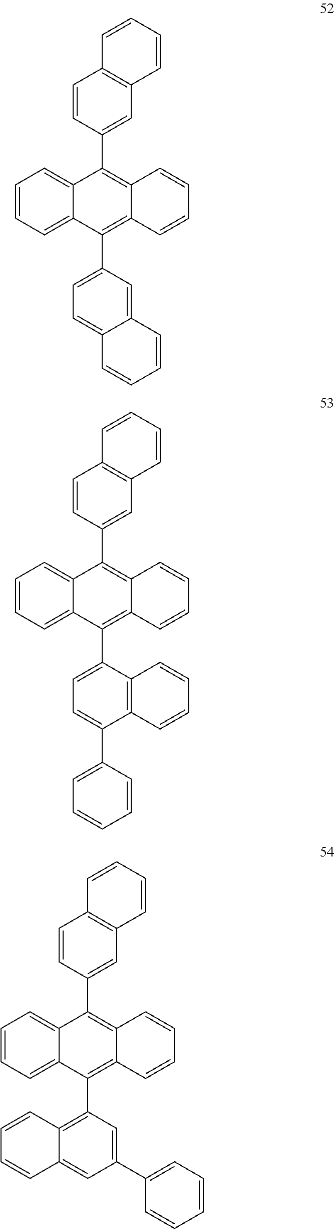

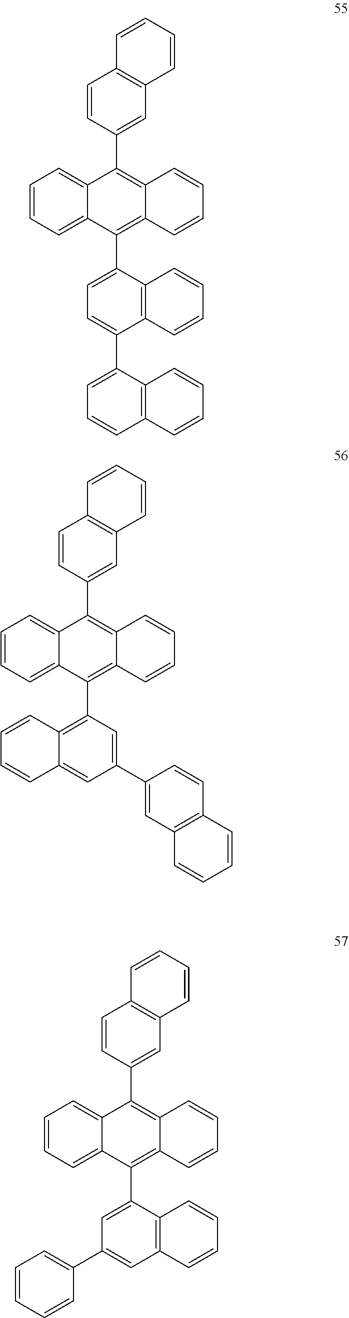

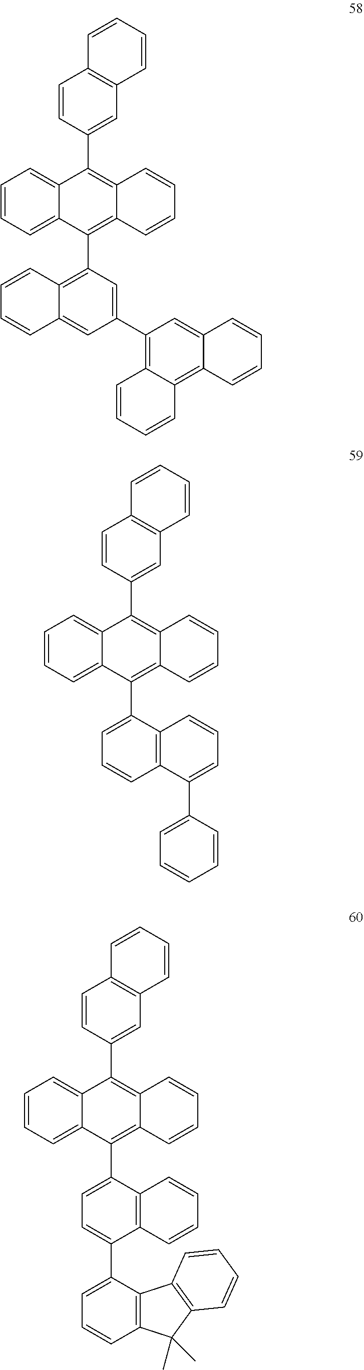

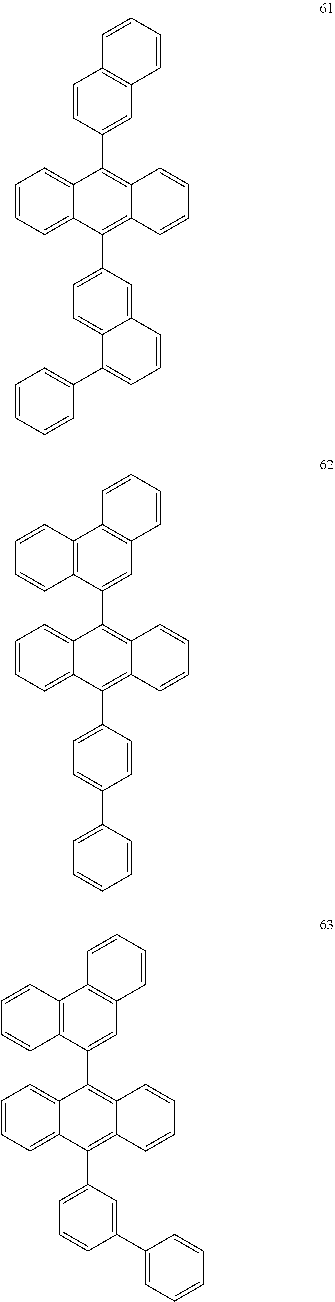

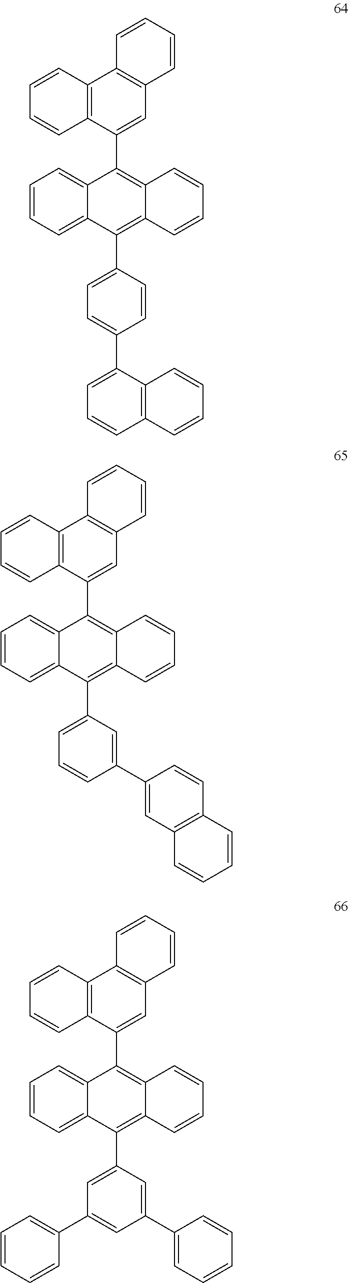

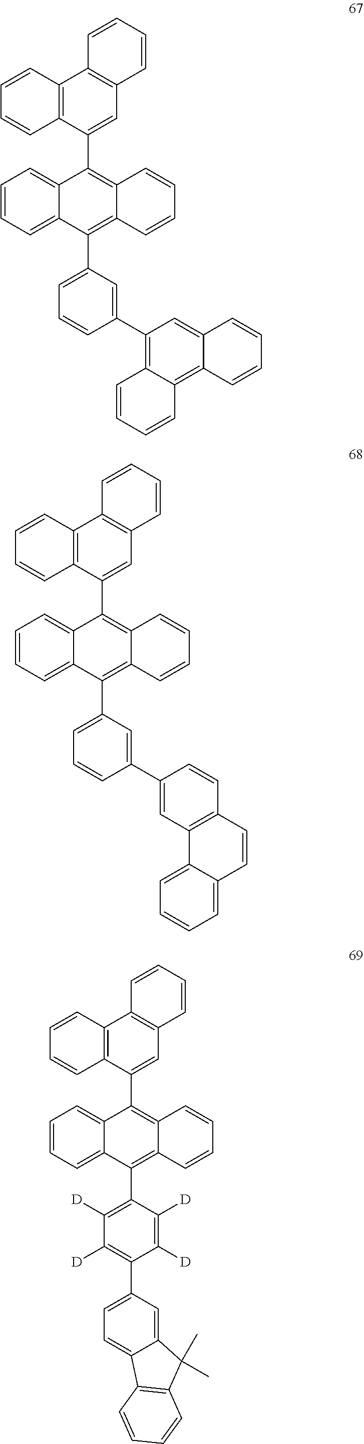

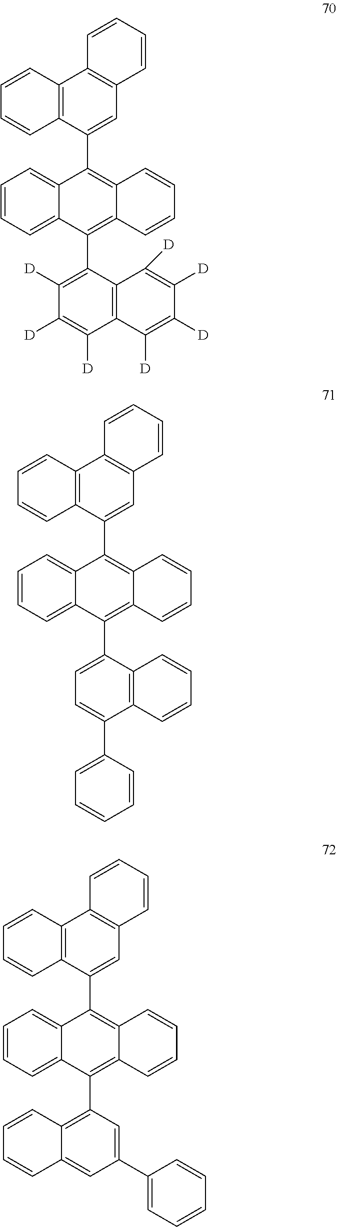

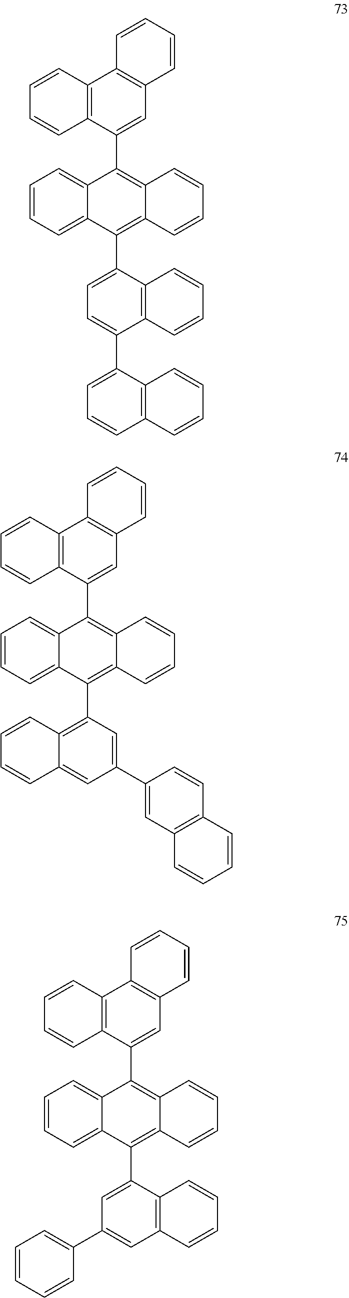

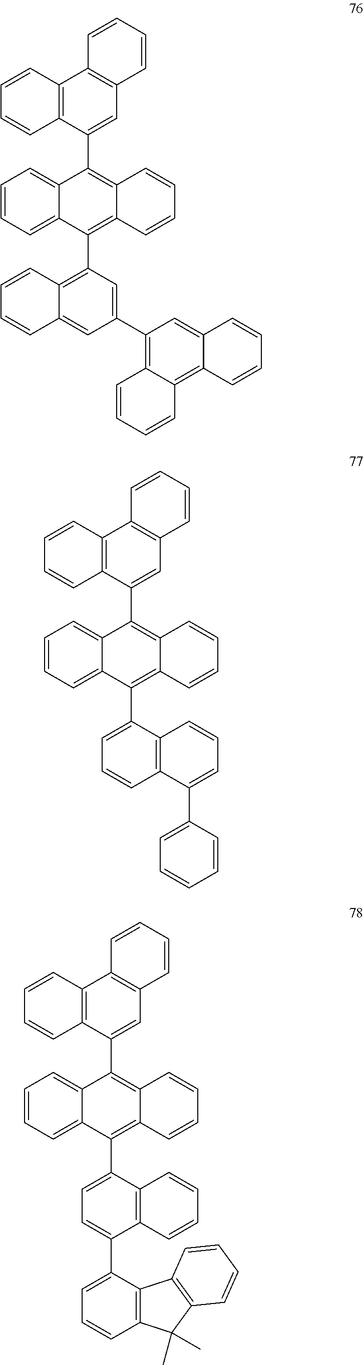

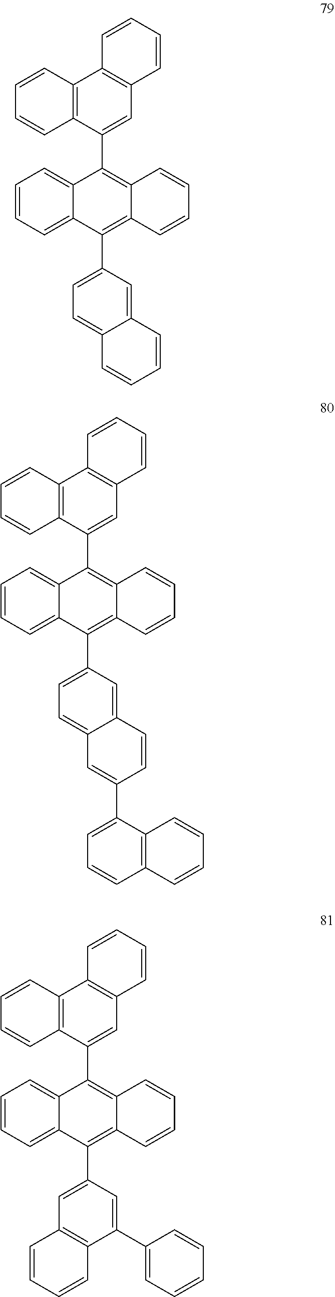

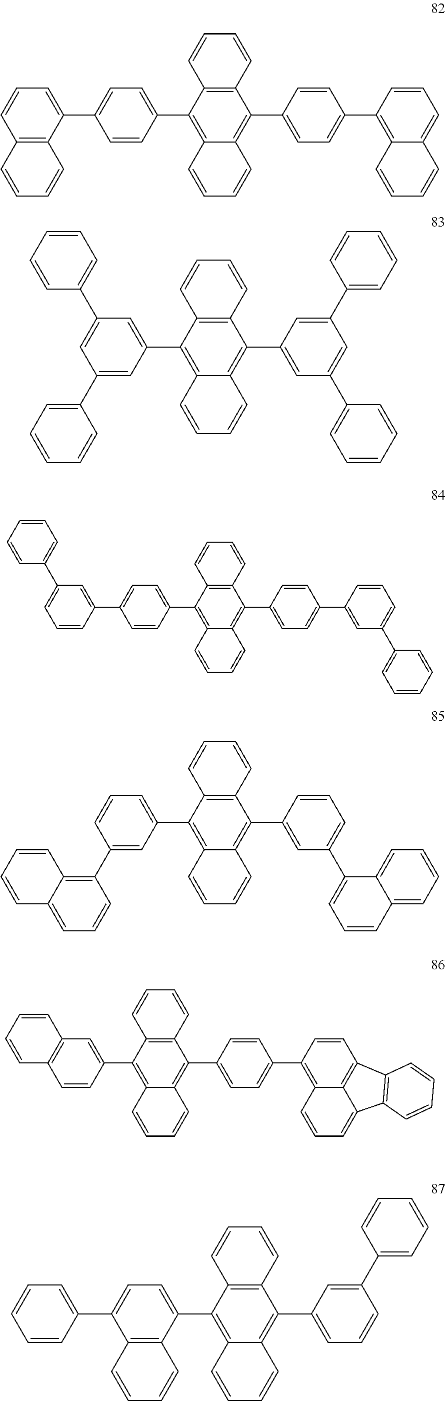

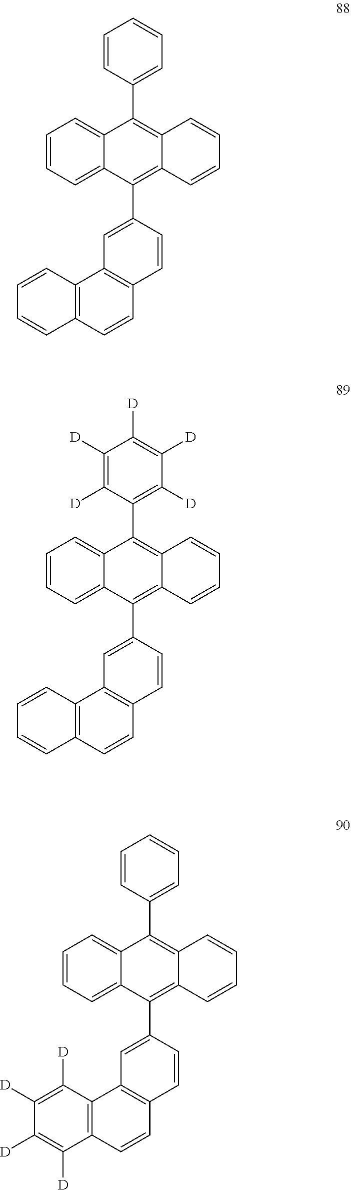

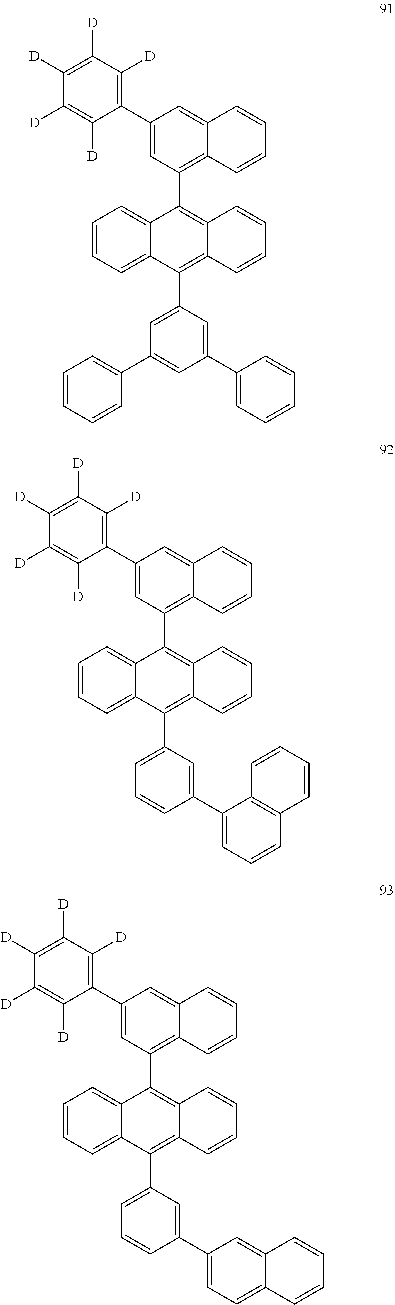

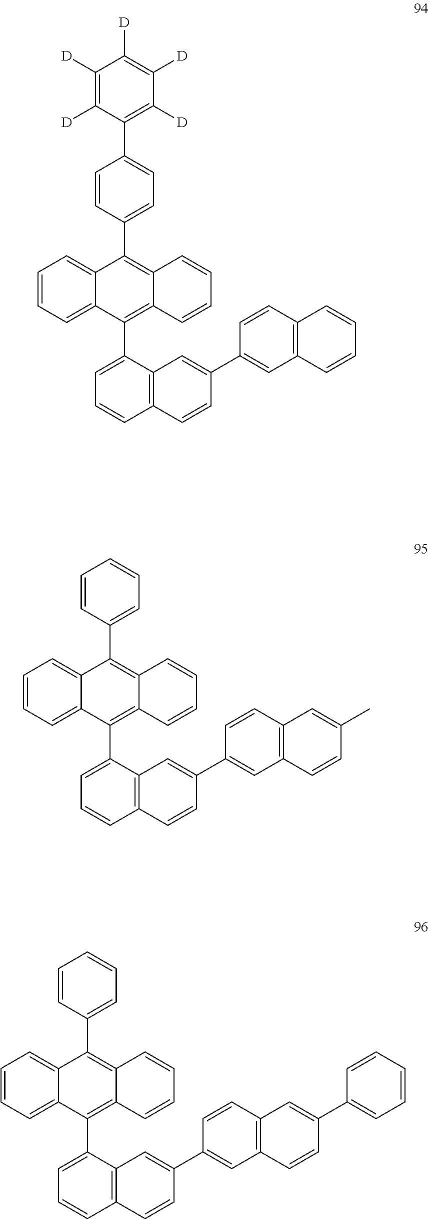

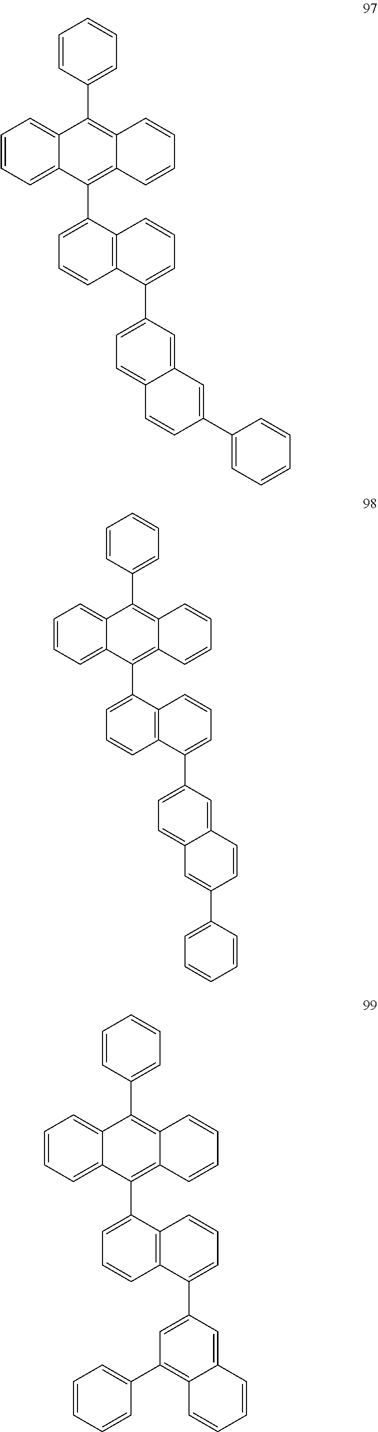

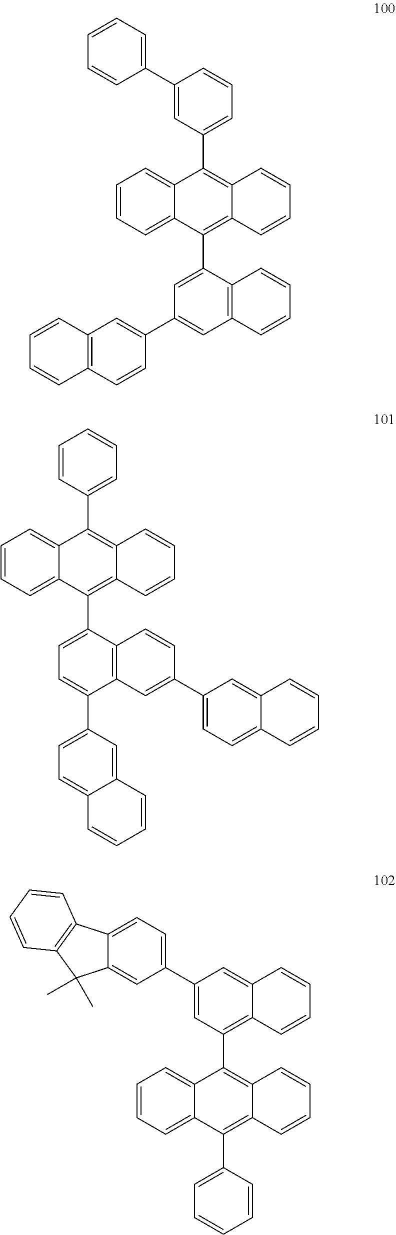

7. The organic electroluminescent device according to claim 1, wherein the compound represented by Formula B is selected from the following compounds:

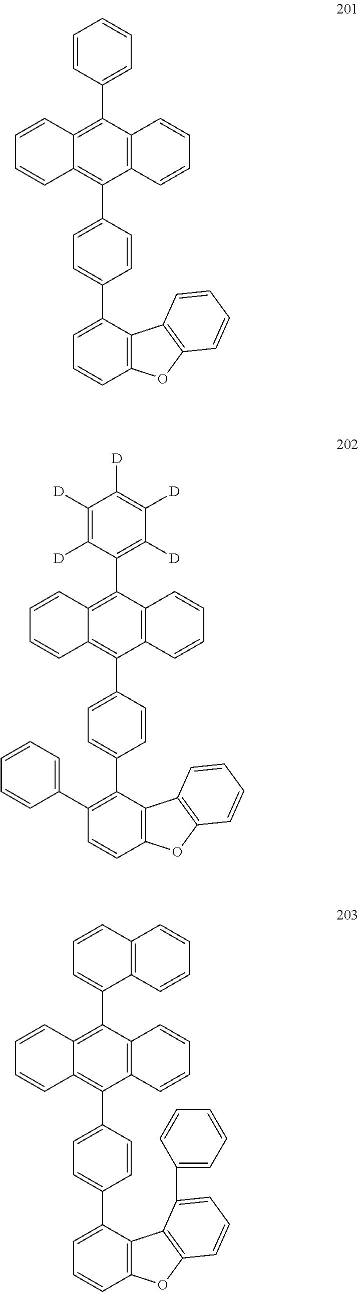 [SMILES: c1ccc(-c2c3ccccc3c(-c3ccc(-c4cccc5oc6ccccc6c45)cc3)c3ccccc23)cc1 ; [2H]c1c([2H])c([2H])c(-c2c3ccccc3c(-c3ccc(-c4c(-c5ccccc5)ccc5oc6ccccc6c45)cc3)c3ccccc23)c([2H])c1[2H] ; c1ccc(-c2cccc3oc4cccc(-c5ccc(-c6c7ccccc7c(-c7cccc8ccccc78)c7ccccc67)cc5)c4c23)cc1]

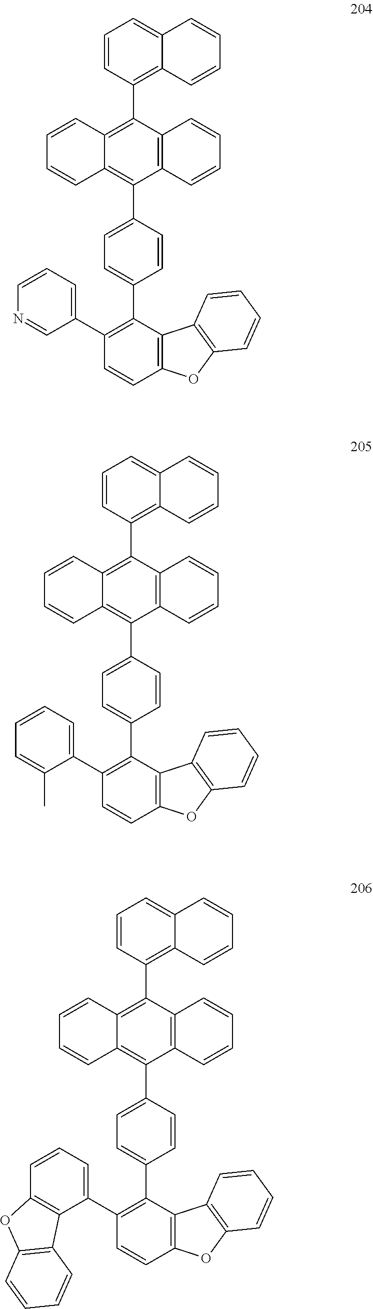 [SMILES: c1cncc(-c2ccc3oc4ccccc4c3c2-c2ccc(-c3c4ccccc4c(-c4cccc5ccccc45)c4ccccc34)cc2)c1 ; Cc1ccccc1-c1ccc2oc3ccccc3c2c1-c1ccc(-c2c3ccccc3c(-c3cccc4ccccc34)c3ccccc23)cc1 ; c1ccc2c(-c3c4ccccc4c(-c4ccc(-c5c(-c6cccc7oc8ccccc8c67)ccc6oc7ccccc7c56)cc4)c4ccccc34)cccc2c1]

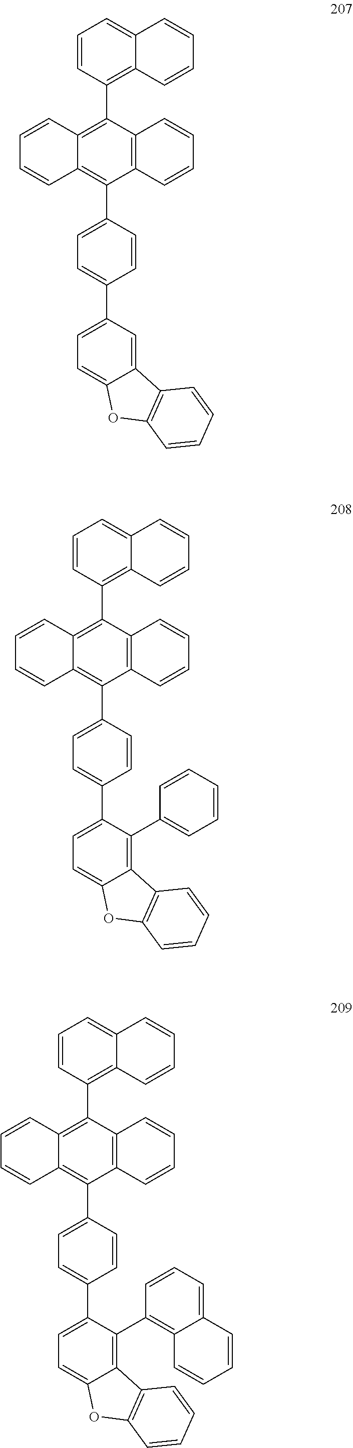 [SMILES: c1ccc2c(-c3c4ccccc4c(-c4ccc(-c5ccc6oc7ccccc7c6c5)cc4)c4ccccc34)cccc2c1 ; c1ccc(-c2c(-c3ccc(-c4c5ccccc5c(-c5cccc6ccccc56)c5ccccc45)cc3)ccc3oc4ccccc4c23)cc1 ; c1ccc2c(-c3c4ccccc4c(-c4ccc(-c5ccc6oc7ccccc7c6c5-c5cccc6ccccc56)cc4)c4ccccc34)cccc2c1]

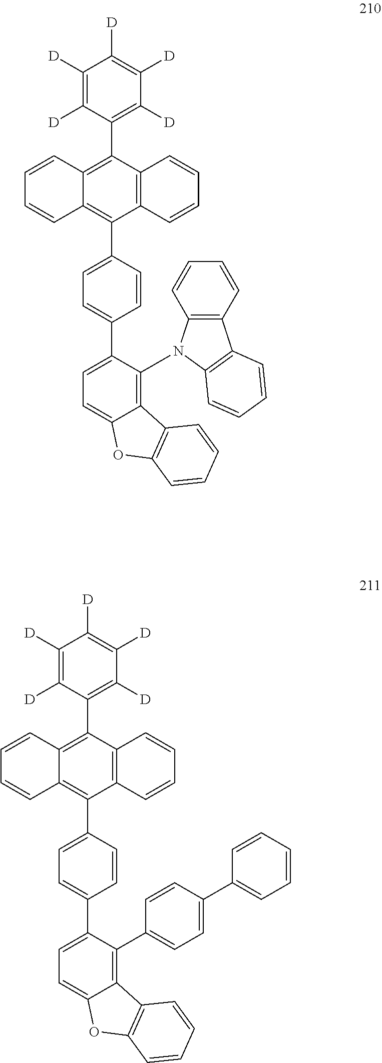 [SMILES: [2H]c1c([2H])c([2H])c(-c2c3ccccc3c(-c3ccc(-c4ccc5oc6ccccc6c5c4-n4c5ccccc5c5ccccc54)cc3)c3ccccc23)c([2H])c1[2H] ; [2H]c1c([2H])c([2H])c(-c2c3ccccc3c(-c3ccc(-c4ccc5oc6ccccc6c5c4-c4ccc(-c5ccccc5)cc4)cc3)c3ccccc23)c([2H])c1[2H]]

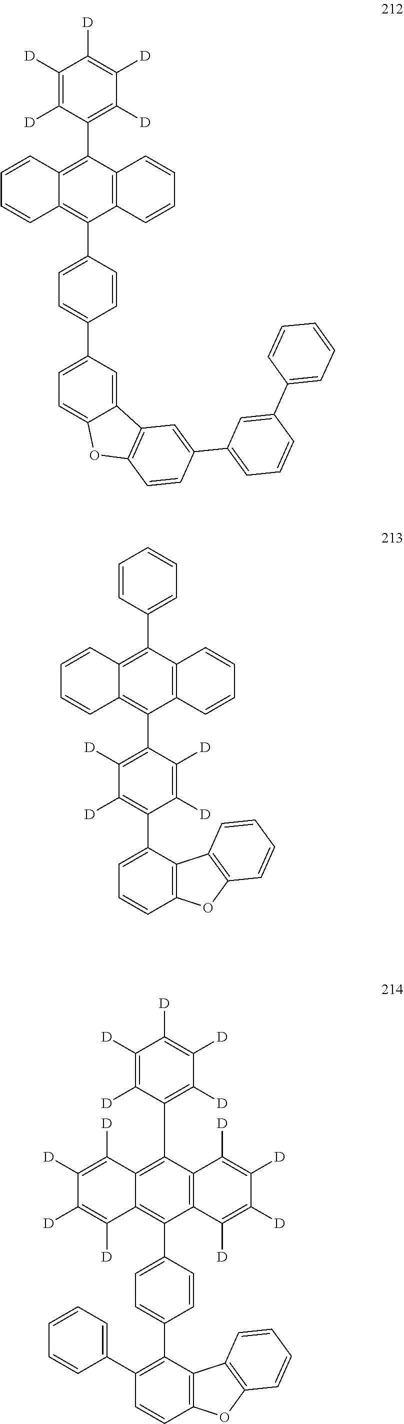 [SMILES: [2H]c1c([2H])c([2H])c(-c2c3ccccc3c(-c3ccc(-c4ccc5oc6ccc(-c7cccc(-c8ccccc8)c7)cc6c5c4)cc3)c3ccccc23)c([2H])c1[2H] ; [2H]c1c([2H])c(-c2cccc3oc4ccccc4c23)c([2H])c([2H])c1-c1c2ccccc2c(-c2ccccc2)c2ccccc12 ; [2H]c1c([2H])c([2H])c(-c2c3c([2H])c([2H])c([2H])c([2H])c3c(-c3ccc(-c4c(-c5ccccc5)ccc5oc6ccccc6c45)cc3)c3c([2H])c([2H])c([2H])c([2H])c23)c([2H])c1[2H]]

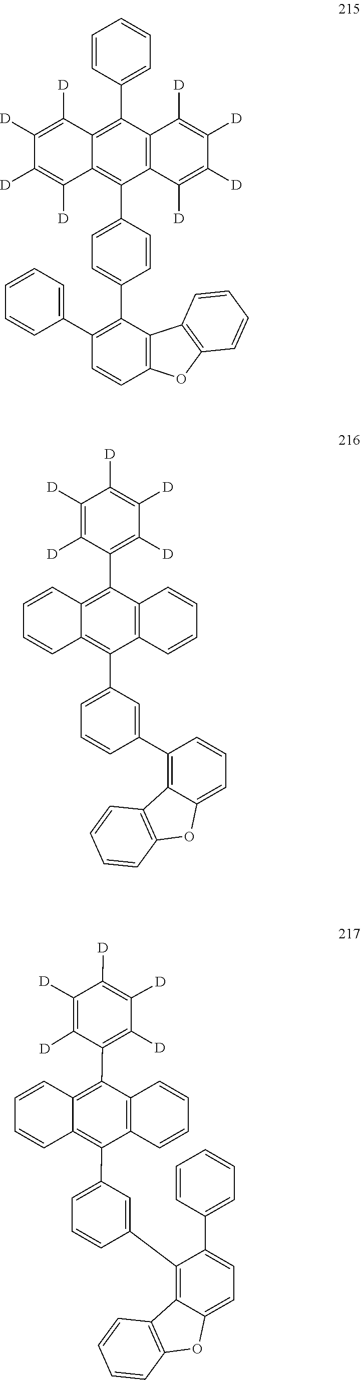 [SMILES: [2H]c1c([2H])c([2H])c2c(-c3ccc(-c4c(-c5ccccc5)ccc5oc6ccccc6c45)cc3)c3c([2H])c([2H])c([2H])c([2H])c3c(-c3ccccc3)c2c1[2H] ; [2H]c1c([2H])c([2H])c(-c2c3ccccc3c(-c3cccc(-c4cccc5oc6ccccc6c45)c3)c3ccccc23)c([2H])c1[2H] ; [2H]c1c([2H])c([2H])c(-c2c3ccccc3c(-c3cccc(-c4c(-c5ccccc5)ccc5oc6ccccc6c45)c3)c3ccccc23)c([2H])c1[2H]]

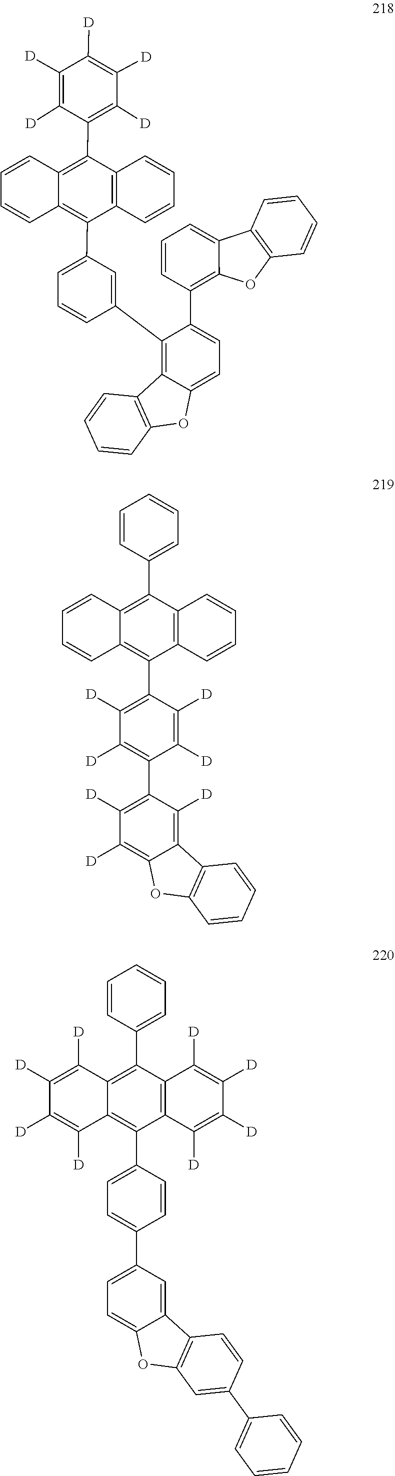

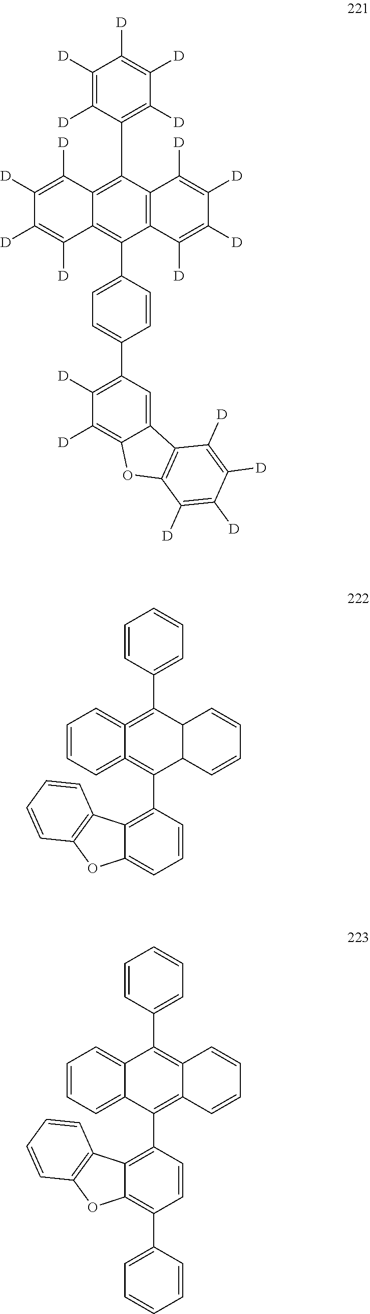

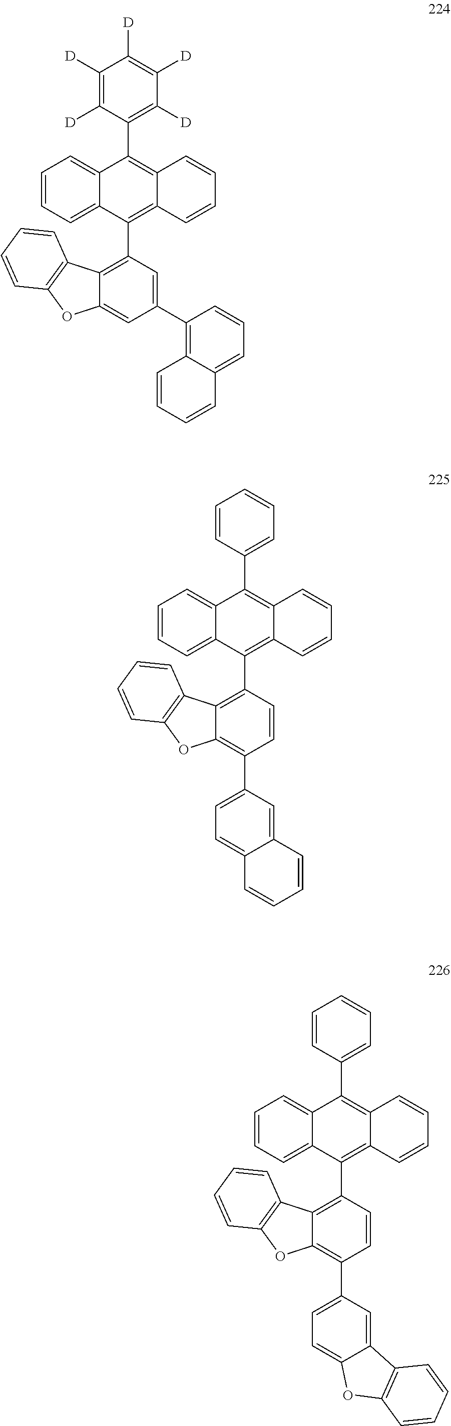 [SMILES: [2H]c1c([2H])c([2H])c(-c2c3ccccc3c(-c3cc(-c4cccc5ccccc45)cc4oc5ccccc5c34)c3ccccc23)c([2H])c1[2H] ; c1ccc(-c2c3ccccc3c(-c3ccc(-c4ccc5ccccc5c4)c4oc5ccccc5c34)c3ccccc23)cc1 ; c1ccc(-c2c3ccccc3c(-c3ccc(-c4ccc5oc6ccccc6c5c4)c4oc5ccccc5c34)c3ccccc23)cc1]

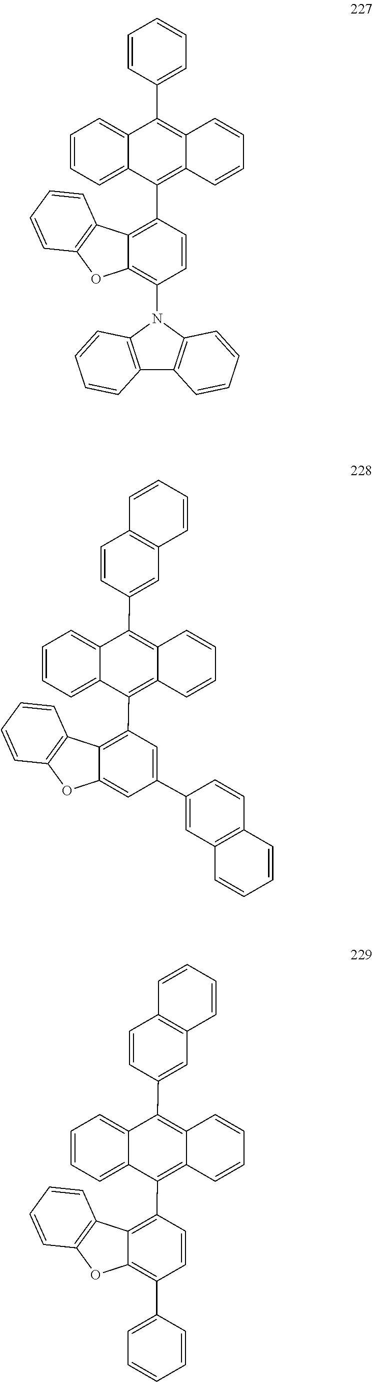 [SMILES: c1ccc(-c2c3ccccc3c(-c3ccc(-n4c5ccccc5c5ccccc54)c4oc5ccccc5c34)c3ccccc23)cc1 ; c1ccc2cc(-c3cc(-c4c5ccccc5c(-c5ccc6ccccc6c5)c5ccccc45)c4c(c3)oc3ccccc34)ccc2c1 ; c1ccc(-c2ccc(-c3c4ccccc4c(-c4ccc5ccccc5c4)c4ccccc34)c3c2oc2ccccc23)cc1]

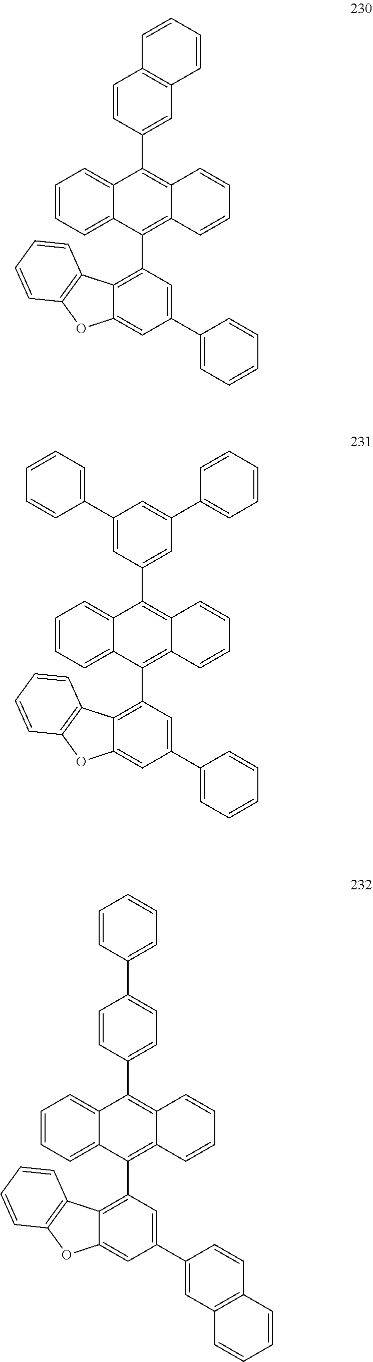 [SMILES: c1ccc(-c2cc(-c3c4ccccc4c(-c4ccc5ccccc5c4)c4ccccc34)c3c(c2)oc2ccccc23)cc1 ; c1ccc(-c2cc(-c3ccccc3)cc(-c3c4ccccc4c(-c4cc(-c5ccccc5)cc5oc6ccccc6c45)c4ccccc34)c2)cc1 ; c1ccc(-c2ccc(-c3c4ccccc4c(-c4cc(-c5ccc6ccccc6c5)cc5oc6ccccc6c45)c4ccccc34)cc2)cc1]

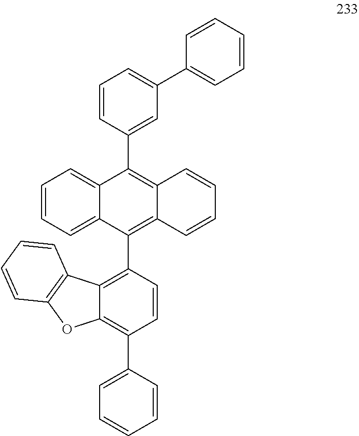 [SMILES: c1ccc(-c2cccc(-c3c4ccccc4c(-c4ccc(-c5ccccc5)c5oc6ccccc6c45)c4ccccc34)c2)cc1]

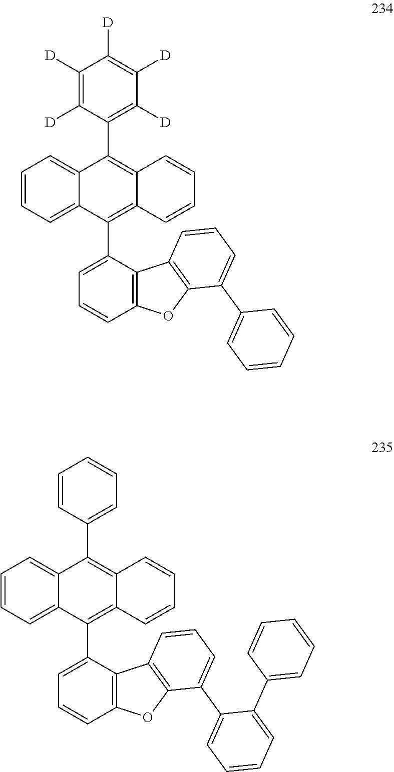 [SMILES: [2H]c1c([2H])c([2H])c(-c2c3ccccc3c(-c3cccc4oc5c(-c6ccccc6)cccc5c34)c3ccccc23)c([2H])c1[2H] ; c1ccc(-c2ccccc2-c2cccc3c2oc2cccc(-c4c5ccccc5c(-c5ccccc5)c5ccccc45)c23)cc1]

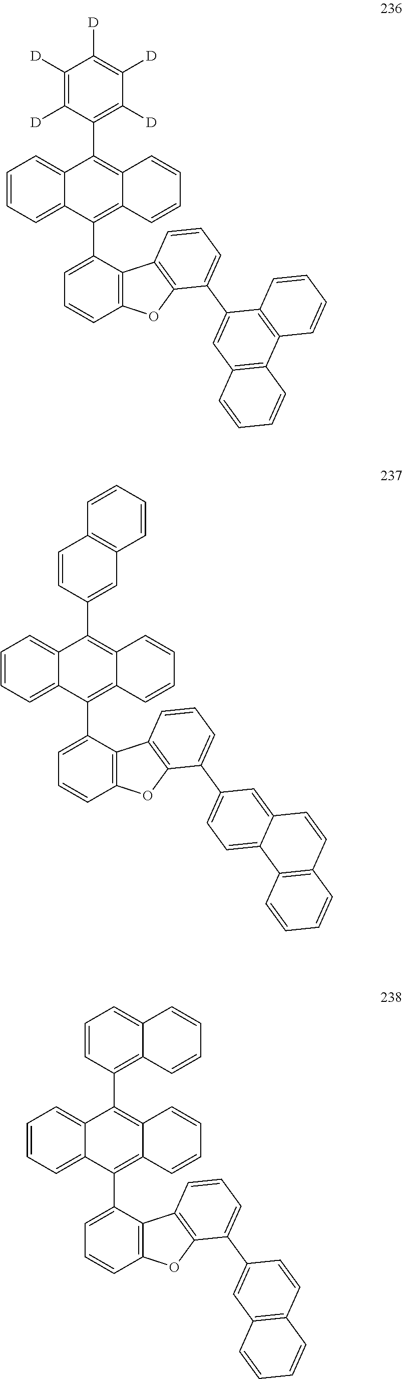 [SMILES: [2H]c1c([2H])c([2H])c(-c2c3ccccc3c(-c3cccc4oc5c(-c6cc7ccccc7c7ccccc67)cccc5c34)c3ccccc23)c([2H])c1[2H] ; c1ccc2cc(-c3c4ccccc4c(-c4cccc5oc6c(-c7ccc8c(ccc9ccccc98)c7)cccc6c45)c4ccccc34)ccc2c1 ; c1ccc2cc(-c3cccc4c3oc3cccc(-c5c6ccccc6c(-c6cccc7ccccc67)c6ccccc56)c34)ccc2c1]

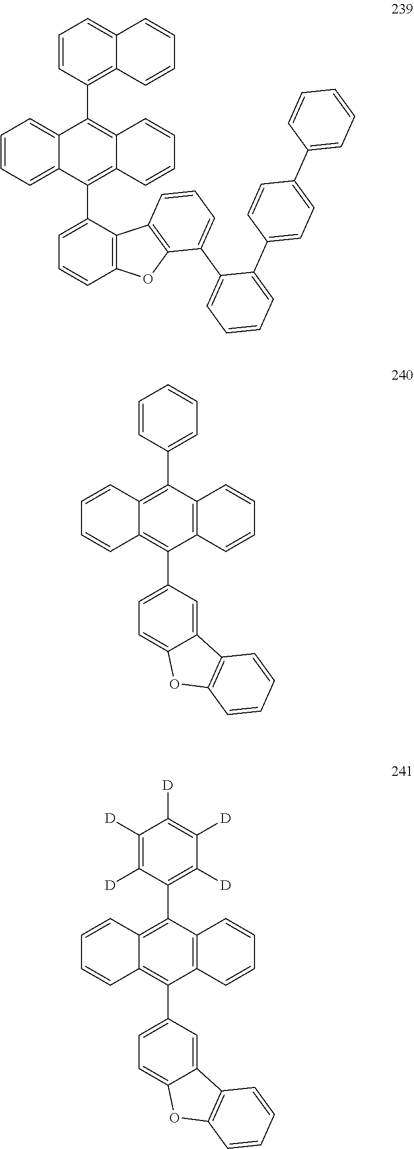 [SMILES: c1ccc(-c2ccc(-c3ccccc3-c3cccc4c3oc3cccc(-c5c6ccccc6c(-c6cccc7ccccc67)c6ccccc56)c34)cc2)cc1 ; c1ccc(-c2c3ccccc3c(-c3ccc4oc5ccccc5c4c3)c3ccccc23)cc1 ; [2H]c1c([2H])c([2H])c(-c2c3ccccc3c(-c3ccc4oc5ccccc5c4c3)c3ccccc23)c([2H])c1[2H]]

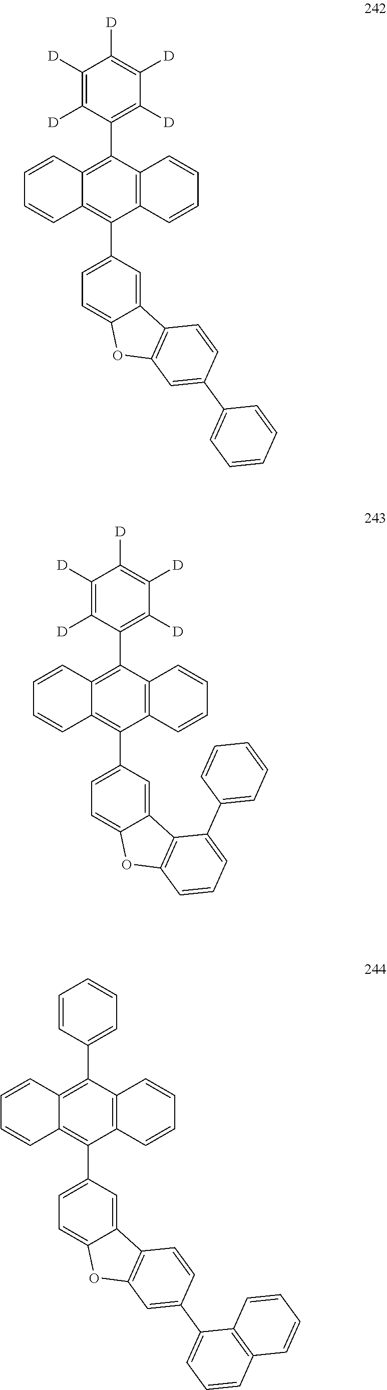 [SMILES: [2H]c1c([2H])c([2H])c(-c2c3ccccc3c(-c3ccc4oc5cc(-c6ccccc6)ccc5c4c3)c3ccccc23)c([2H])c1[2H] ; [2H]c1c([2H])c([2H])c(-c2c3ccccc3c(-c3ccc4oc5cccc(-c6ccccc6)c5c4c3)c3ccccc23)c([2H])c1[2H] ; c1ccc(-c2c3ccccc3c(-c3ccc4oc5cc(-c6cccc7ccccc67)ccc5c4c3)c3ccccc23)cc1]

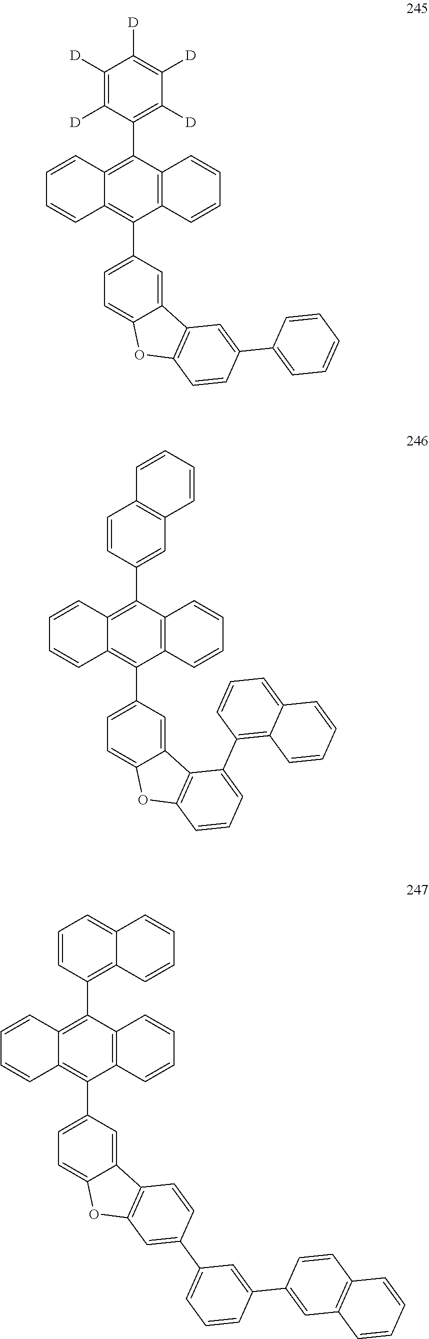 [SMILES: [2H]c1c([2H])c([2H])c(-c2c3ccccc3c(-c3ccc4oc5ccc(-c6ccccc6)cc5c4c3)c3ccccc23)c([2H])c1[2H] ; c1ccc2cc(-c3c4ccccc4c(-c4ccc5oc6cccc(-c7cccc8ccccc78)c6c5c4)c4ccccc34)ccc2c1 ; c1cc(-c2ccc3ccccc3c2)cc(-c2ccc3c(c2)oc2ccc(-c4c5ccccc5c(-c5cccc6ccccc56)c5ccccc45)cc23)c1]

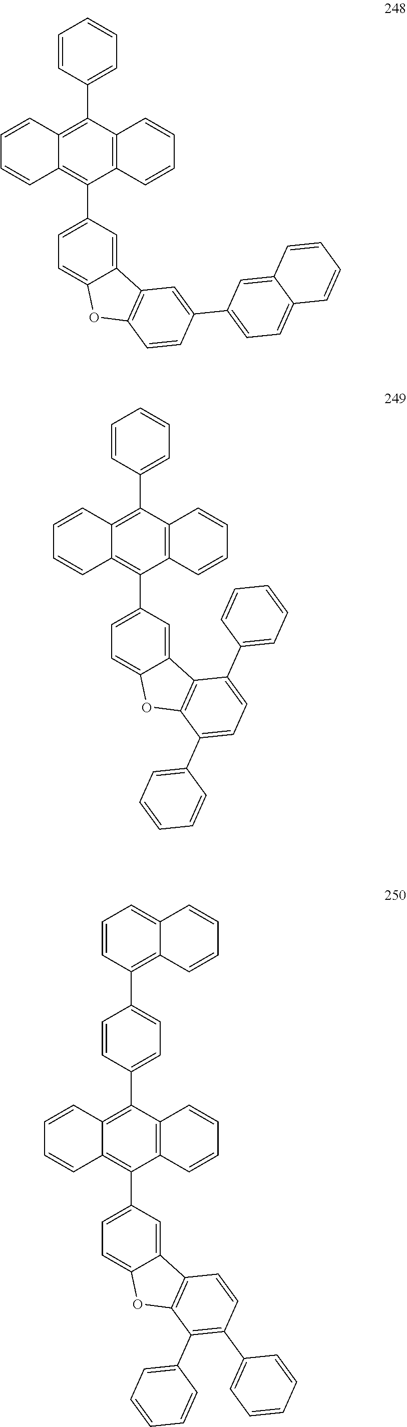 [SMILES: c1ccc(-c2c3ccccc3c(-c3ccc4oc5ccc(-c6ccc7ccccc7c6)cc5c4c3)c3ccccc23)cc1 ; c1ccc(-c2c3ccccc3c(-c3ccc4oc5c(-c6ccccc6)ccc(-c6ccccc6)c5c4c3)c3ccccc23)cc1 ; c1ccc(-c2ccc3c(oc4ccc(-c5c6ccccc6c(-c6ccc(-c7cccc8ccccc78)cc6)c6ccccc56)cc43)c2-c2ccccc2)cc1]

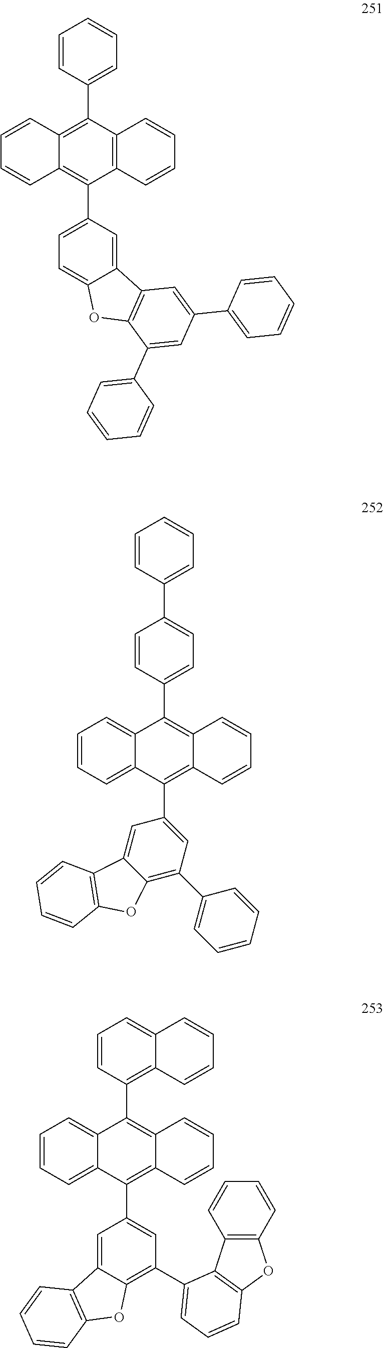 [SMILES: c1ccc(-c2cc(-c3ccccc3)c3oc4ccc(-c5c6ccccc6c(-c6ccccc6)c6ccccc56)cc4c3c2)cc1 ; c1ccc(-c2ccc(-c3c4ccccc4c(-c4cc(-c5ccccc5)c5oc6ccccc6c5c4)c4ccccc34)cc2)cc1 ; c1ccc2c(-c3c4ccccc4c(-c4cc(-c5cccc6oc7ccccc7c56)c5oc6ccccc6c5c4)c4ccccc34)cccc2c1]

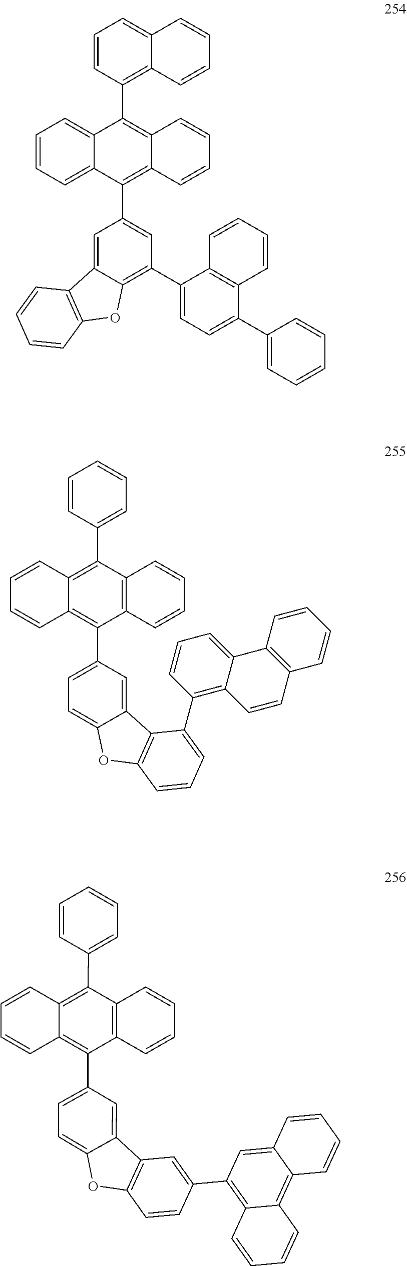 [SMILES: c1ccc(-c2ccc(-c3cc(-c4c5ccccc5c(-c5cccc6ccccc56)c5ccccc45)cc4c3oc3ccccc34)c3ccccc23)cc1 ; c1ccc(-c2c3ccccc3c(-c3ccc4oc5cccc(-c6cccc7c6ccc6ccccc67)c5c4c3)c3ccccc23)cc1 ; c1ccc(-c2c3ccccc3c(-c3ccc4oc5ccc(-c6cc7ccccc7c7ccccc67)cc5c4c3)c3ccccc23)cc1]

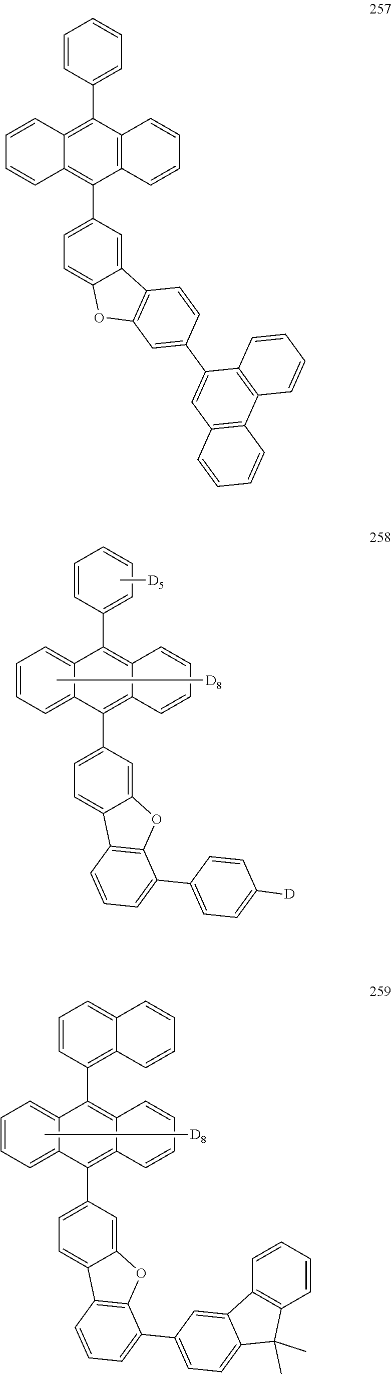

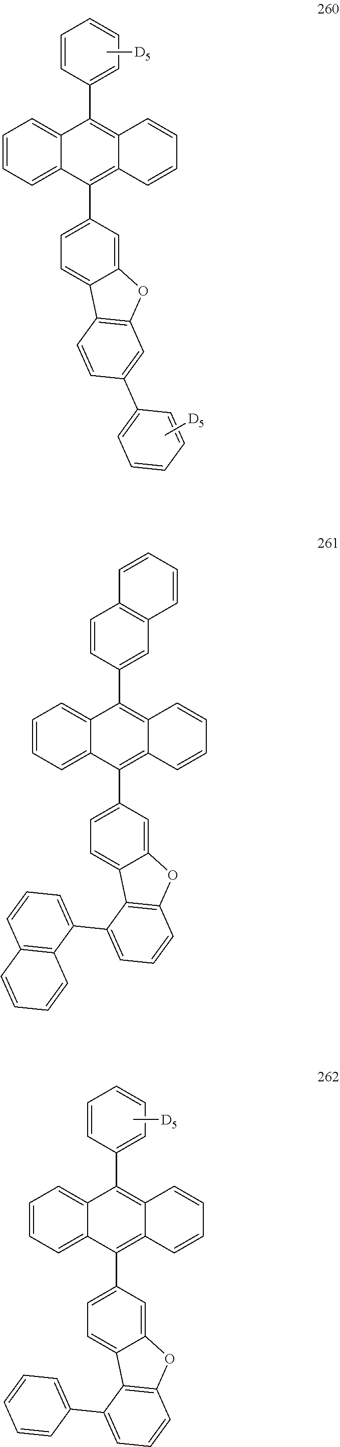

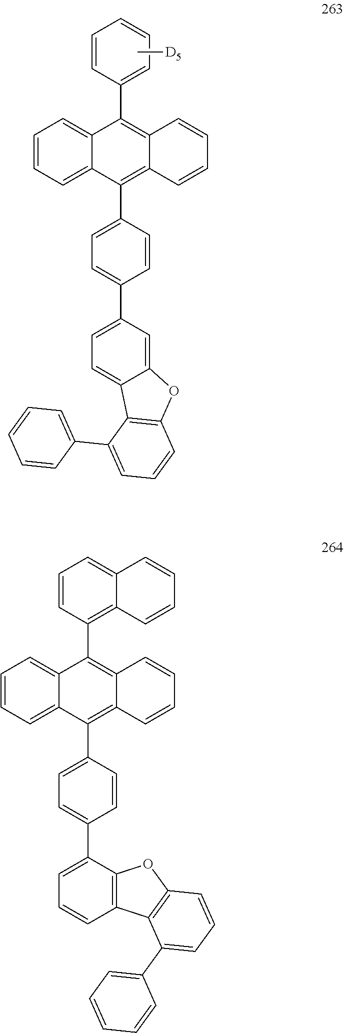

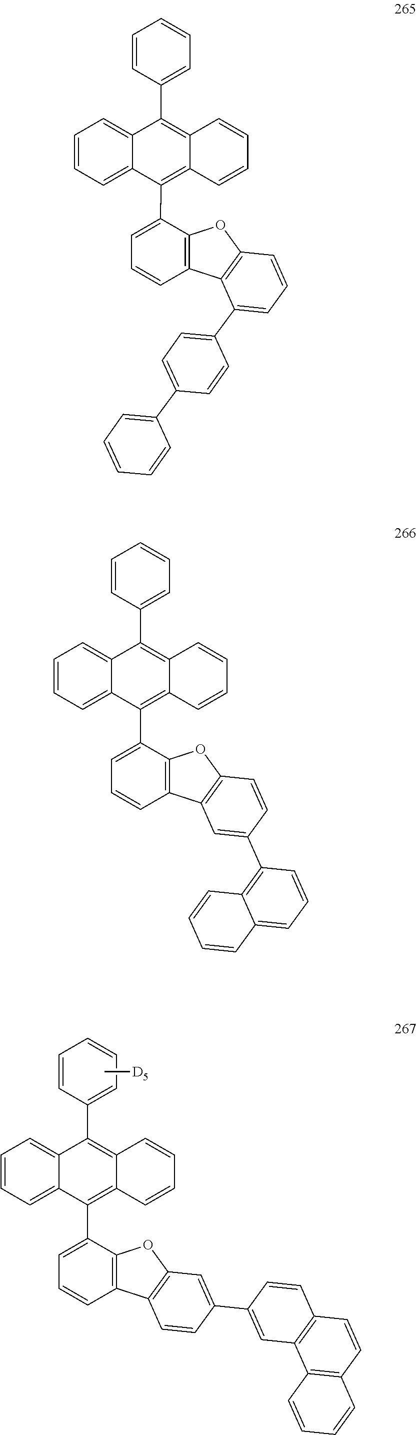

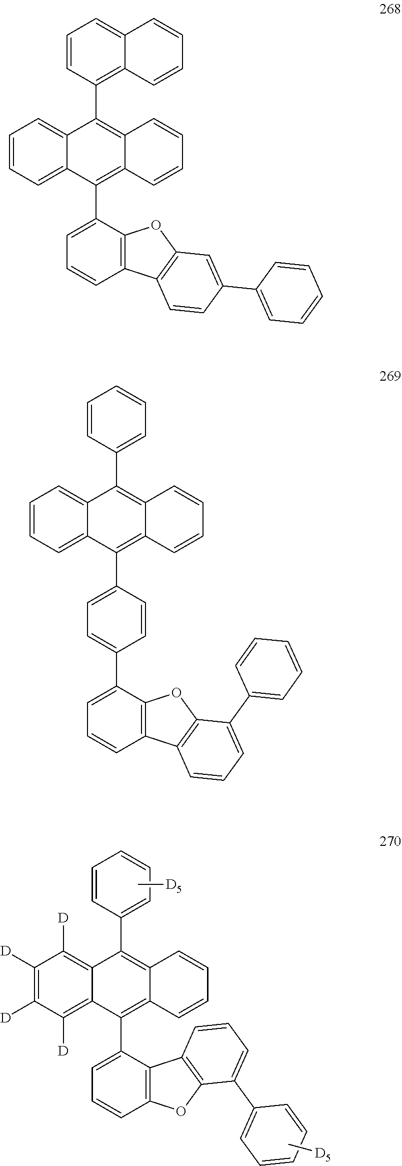

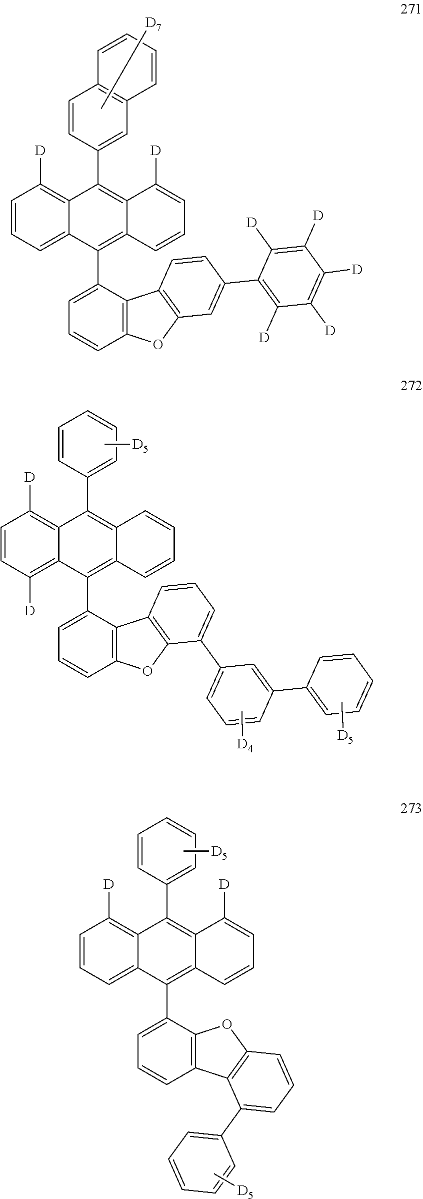

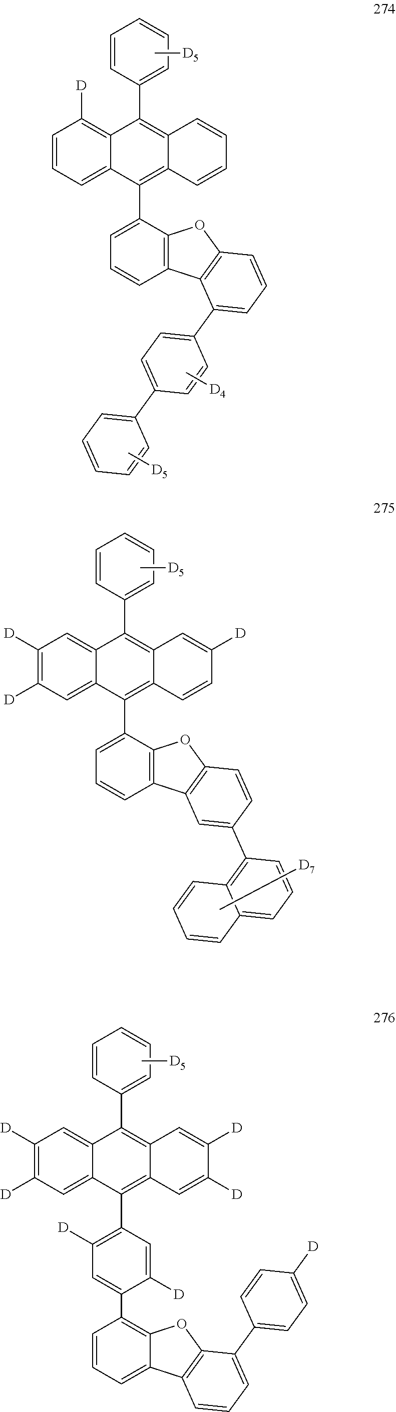

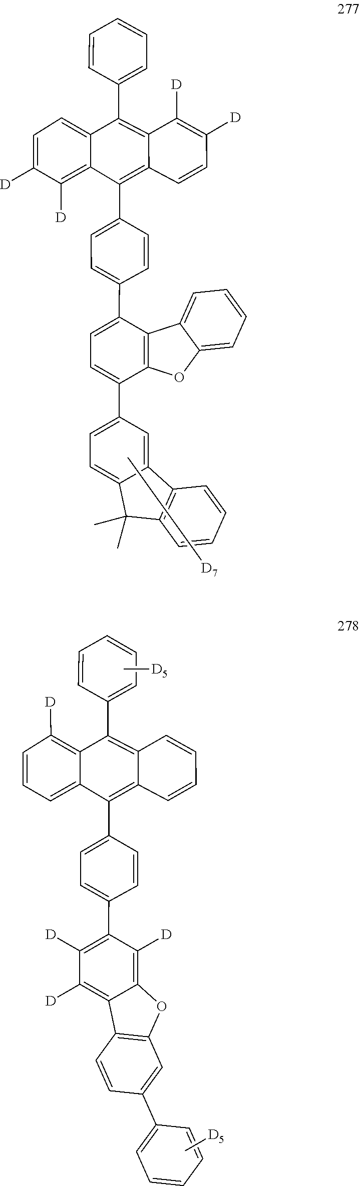

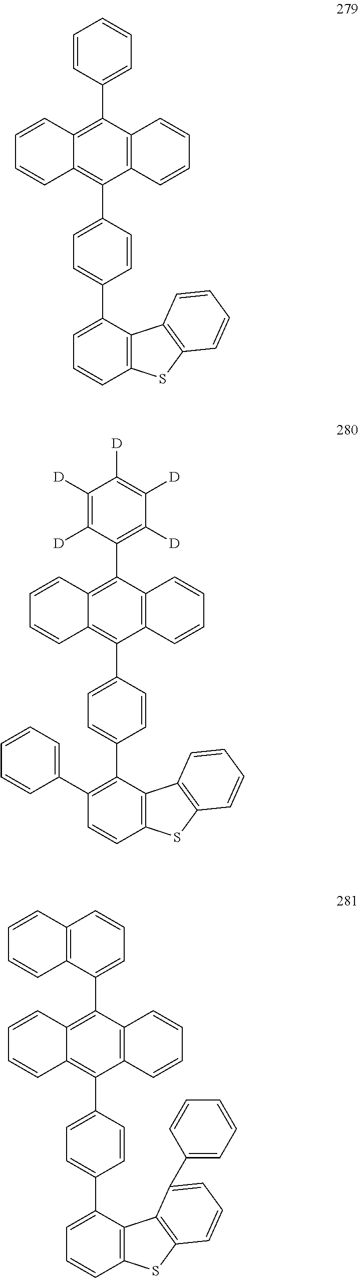 [SMILES: c1ccc(-c2c3ccccc3c(-c3ccc(-c4cccc5sc6ccccc6c45)cc3)c3ccccc23)cc1 ; [2H]c1c([2H])c([2H])c(-c2c3ccccc3c(-c3ccc(-c4c(-c5ccccc5)ccc5sc6ccccc6c45)cc3)c3ccccc23)c([2H])c1[2H] ; c1ccc(-c2cccc3sc4cccc(-c5ccc(-c6c7ccccc7c(-c7cccc8ccccc78)c7ccccc67)cc5)c4c23)cc1]

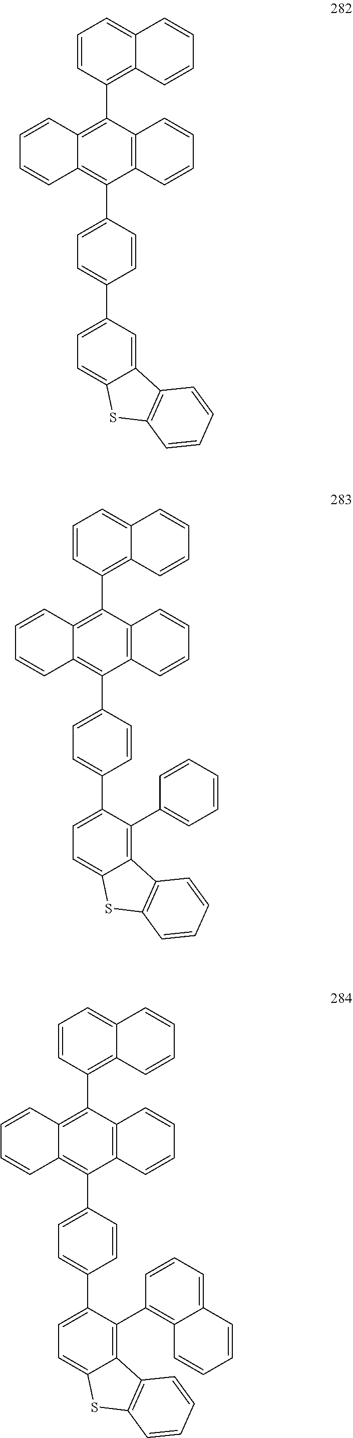 [SMILES: c1ccc2c(-c3c4ccccc4c(-c4ccc(-c5ccc6sc7ccccc7c6c5)cc4)c4ccccc34)cccc2c1 ; c1ccc(-c2c(-c3ccc(-c4c5ccccc5c(-c5cccc6ccccc56)c5ccccc45)cc3)ccc3sc4ccccc4c23)cc1 ; c1ccc2c(-c3c4ccccc4c(-c4ccc(-c5ccc6sc7ccccc7c6c5-c5cccc6ccccc56)cc4)c4ccccc34)cccc2c1]

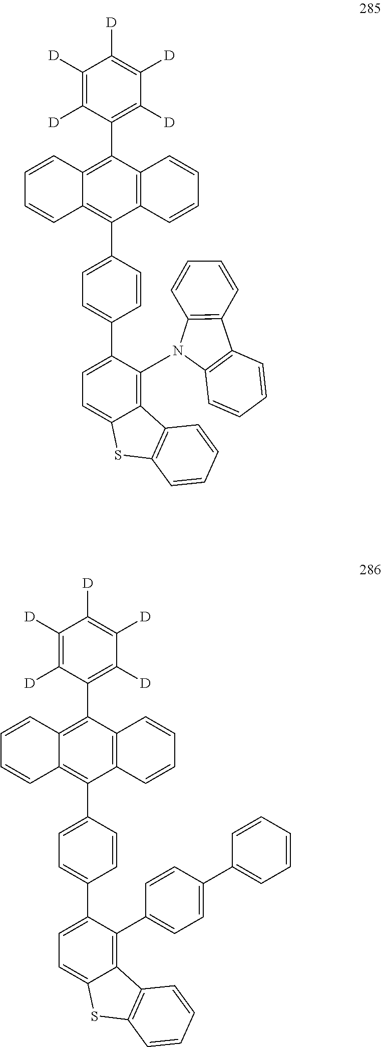 [SMILES: [2H]c1c([2H])c([2H])c(-c2c3ccccc3c(-c3ccc(-c4ccc5sc6ccccc6c5c4-n4c5ccccc5c5ccccc54)cc3)c3ccccc23)c([2H])c1[2H] ; [2H]c1c([2H])c([2H])c(-c2c3ccccc3c(-c3ccc(-c4ccc5sc6ccccc6c5c4-c4ccc(-c5ccccc5)cc4)cc3)c3ccccc23)c([2H])c1[2H]]

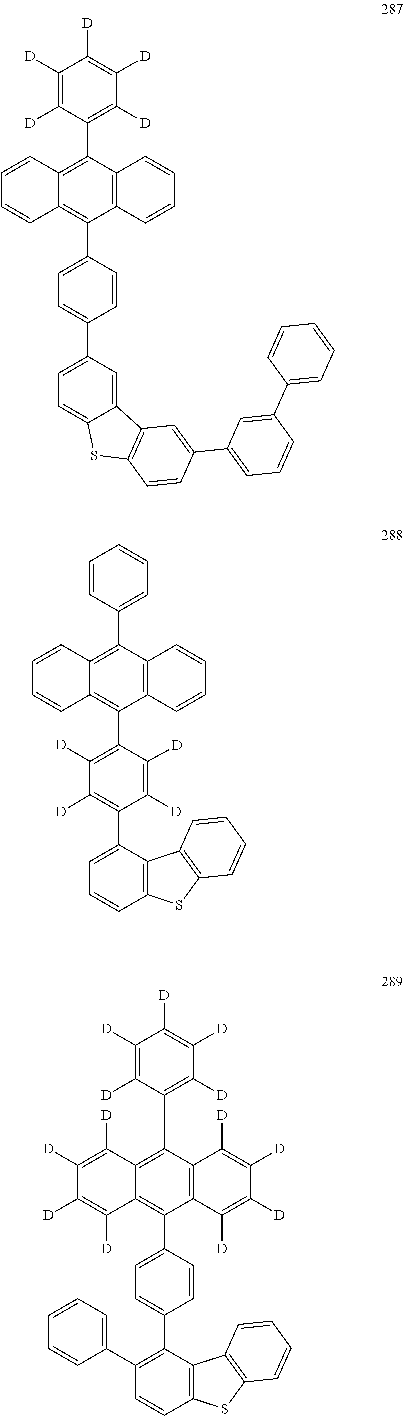 [SMILES: [2H]c1c([2H])c([2H])c(-c2c3ccccc3c(-c3ccc(-c4ccc5sc6ccc(-c7cccc(-c8ccccc8)c7)cc6c5c4)cc3)c3ccccc23)c([2H])c1[2H] ; [2H]c1c([2H])c(-c2cccc3sc4ccccc4c23)c([2H])c([2H])c1-c1c2ccccc2c(-c2ccccc2)c2ccccc12 ; [2H]c1c([2H])c([2H])c(-c2c3c([2H])c([2H])c([2H])c([2H])c3c(-c3ccc(-c4c(-c5ccccc5)ccc5sc6ccccc6c45)cc3)c3c([2H])c([2H])c([2H])c([2H])c23)c([2H])c1[2H]]

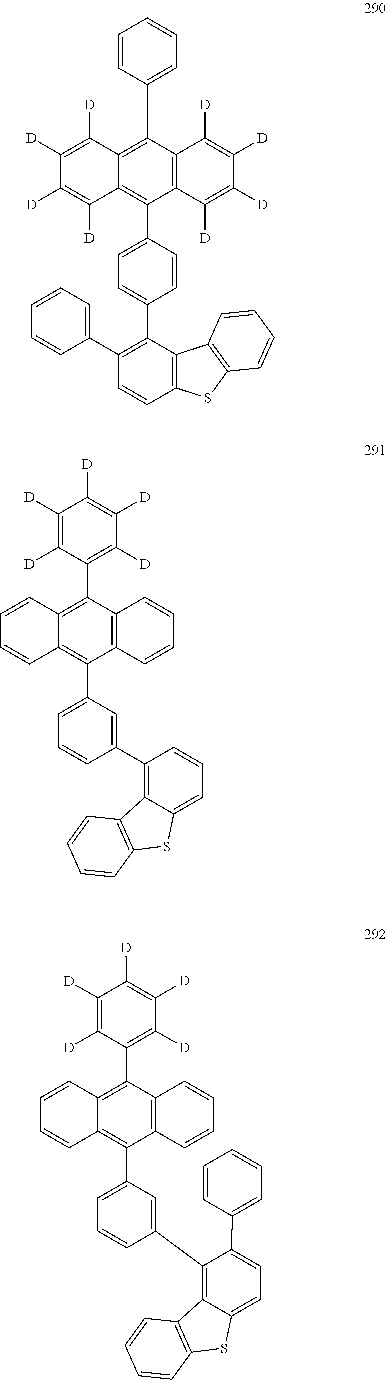 [SMILES: [2H]c1c([2H])c([2H])c2c(-c3ccc(-c4c(-c5ccccc5)ccc5sc6ccccc6c45)cc3)c3c([2H])c([2H])c([2H])c([2H])c3c(-c3ccccc3)c2c1[2H] ; [2H]c1c([2H])c([2H])c(-c2c3ccccc3c(-c3cccc(-c4cccc5sc6ccccc6c45)c3)c3ccccc23)c([2H])c1[2H] ; [2H]c1c([2H])c([2H])c(-c2c3ccccc3c(-c3cccc(-c4c(-c5ccccc5)ccc5sc6ccccc6c45)c3)c3ccccc23)c([2H])c1[2H]]

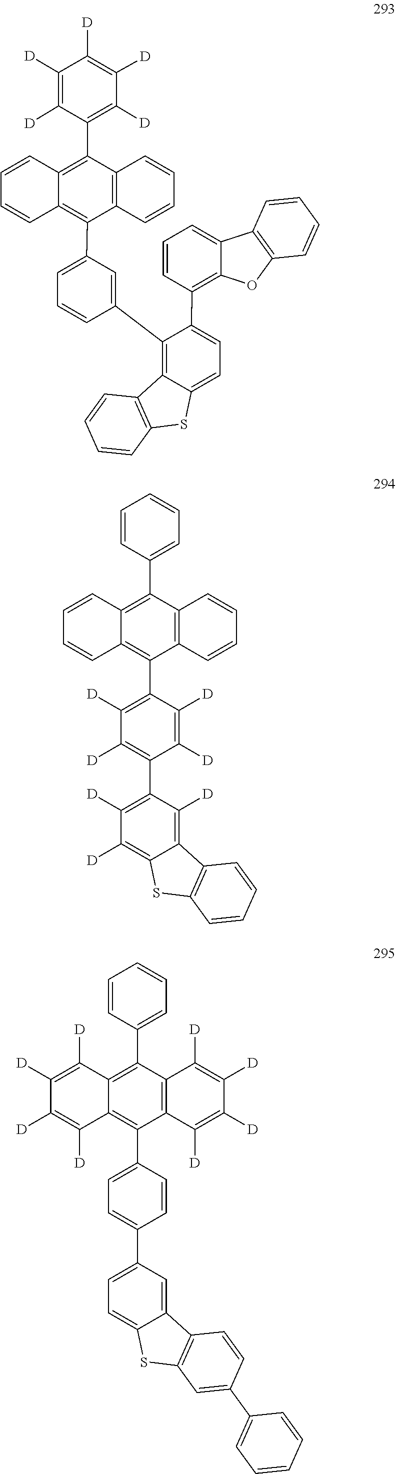

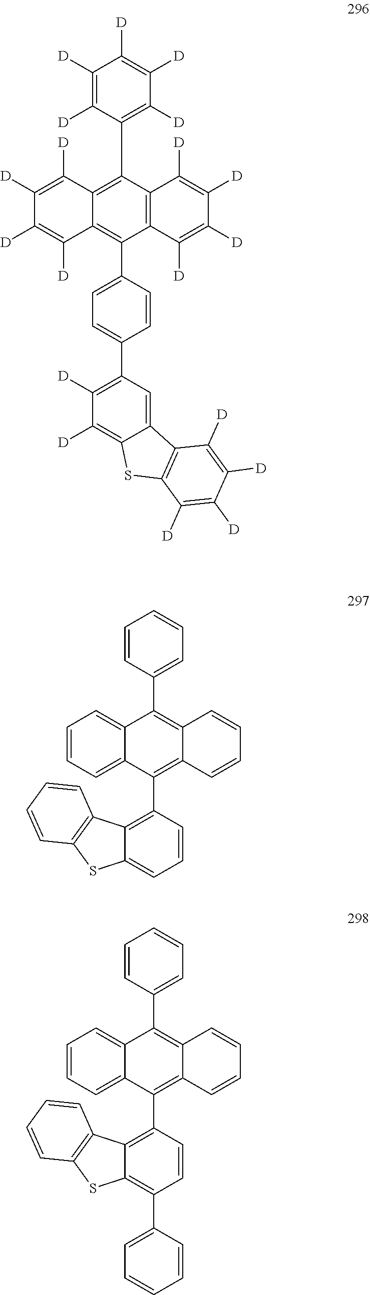 [SMILES: [2H]c1c([2H])c([2H])c(-c2c3c([2H])c([2H])c([2H])c([2H])c3c(-c3ccc(-c4cc5c(sc6c([2H])c([2H])c([2H])c([2H])c65)c([2H])c4[2H])cc3)c3c([2H])c([2H])c([2H])c([2H])c23)c([2H])c1[2H] ; c1ccc(-c2c3ccccc3c(-c3cccc4sc5ccccc5c34)c3ccccc23)cc1 ; c1ccc(-c2c3ccccc3c(-c3ccc(-c4ccccc4)c4sc5ccccc5c34)c3ccccc23)cc1]

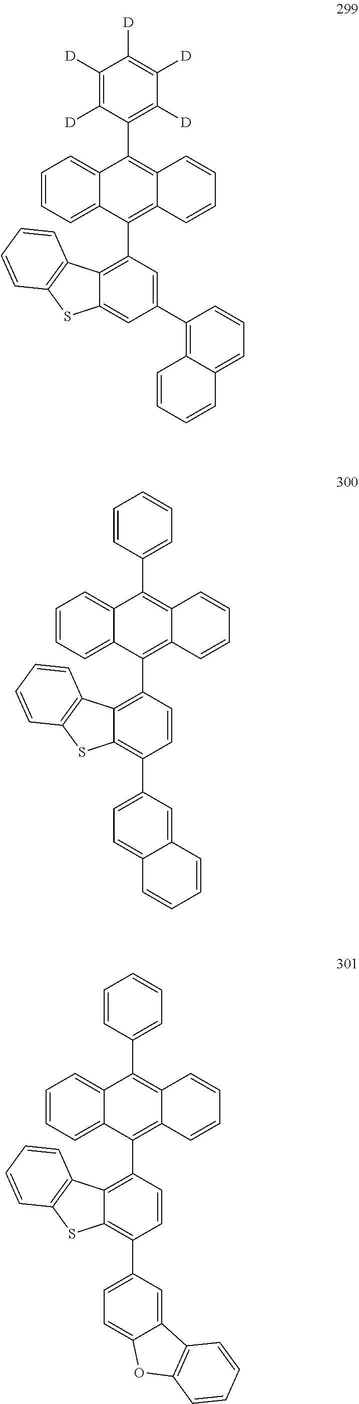 [SMILES: [2H]c1c([2H])c([2H])c(-c2c3ccccc3c(-c3cc(-c4cccc5ccccc45)cc4sc5ccccc5c34)c3ccccc23)c([2H])c1[2H] ; c1ccc(-c2c3ccccc3c(-c3ccc(-c4ccc5ccccc5c4)c4sc5ccccc5c34)c3ccccc23)cc1 ; c1ccc(-c2c3ccccc3c(-c3ccc(-c4ccc5oc6ccccc6c5c4)c4sc5ccccc5c34)c3ccccc23)cc1]

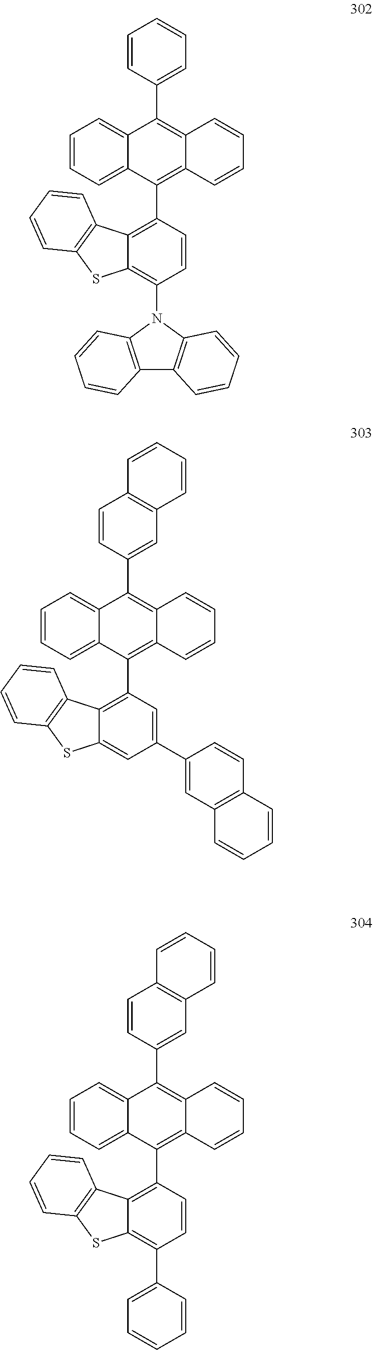 [SMILES: c1ccc(-c2c3ccccc3c(-c3ccc(-n4c5ccccc5c5ccccc54)c4sc5ccccc5c34)c3ccccc23)cc1 ; c1ccc2cc(-c3cc(-c4c5ccccc5c(-c5ccc6ccccc6c5)c5ccccc45)c4c(c3)sc3ccccc34)ccc2c1 ; c1ccc(-c2ccc(-c3c4ccccc4c(-c4ccc5ccccc5c4)c4ccccc34)c3c2sc2ccccc23)cc1]

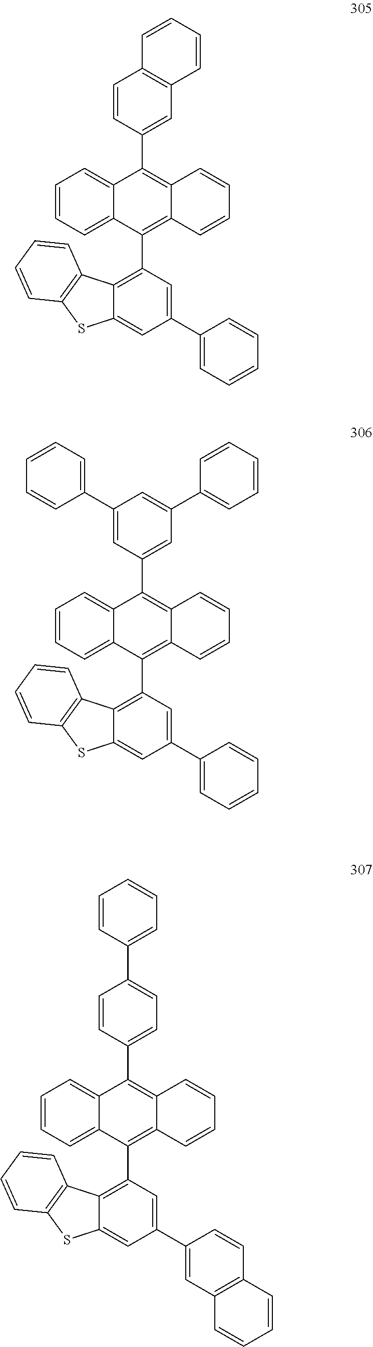 [SMILES: c1ccc(-c2cc(-c3c4ccccc4c(-c4ccc5ccccc5c4)c4ccccc34)c3c(c2)sc2ccccc23)cc1 ; c1ccc(-c2cc(-c3ccccc3)cc(-c3c4ccccc4c(-c4cc(-c5ccccc5)cc5sc6ccccc6c45)c4ccccc34)c2)cc1 ; c1ccc(-c2ccc(-c3c4ccccc4c(-c4cc(-c5ccc6ccccc6c5)cc5sc6ccccc6c45)c4ccccc34)cc2)cc1]

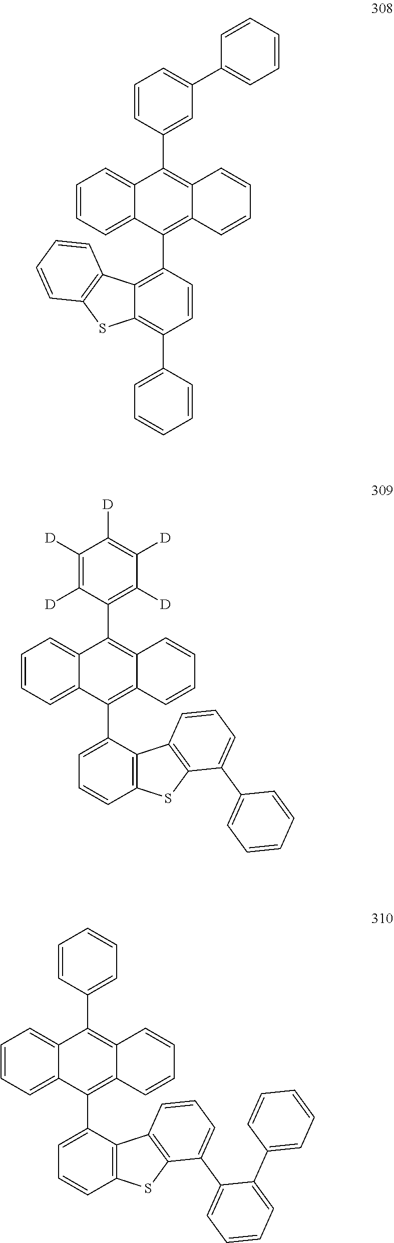 [SMILES: c1ccc(-c2cccc(-c3c4ccccc4c(-c4ccc(-c5ccccc5)c5sc6ccccc6c45)c4ccccc34)c2)cc1 ; [2H]c1c([2H])c([2H])c(-c2c3ccccc3c(-c3cccc4sc5c(-c6ccccc6)cccc5c34)c3ccccc23)c([2H])c1[2H] ; c1ccc(-c2ccccc2-c2cccc3c2sc2cccc(-c4c5ccccc5c(-c5ccccc5)c5ccccc45)c23)cc1]

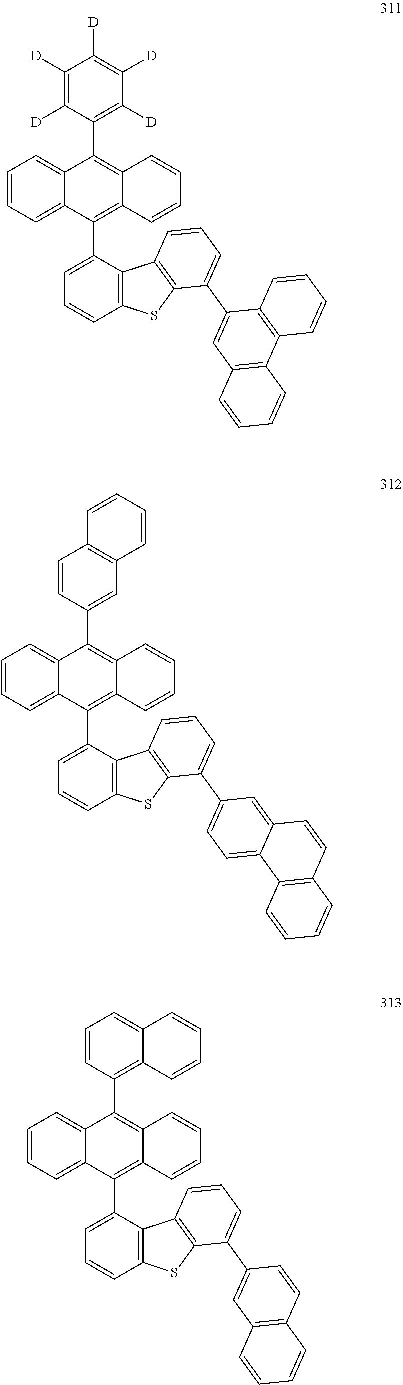 [SMILES: [2H]c1c([2H])c([2H])c(-c2c3ccccc3c(-c3cccc4sc5c(-c6cc7ccccc7c7ccccc67)cccc5c34)c3ccccc23)c([2H])c1[2H] ; c1ccc2cc(-c3c4ccccc4c(-c4cccc5sc6c(-c7ccc8c(ccc9ccccc98)c7)cccc6c45)c4ccccc34)ccc2c1 ; c1ccc2cc(-c3cccc4c3sc3cccc(-c5c6ccccc6c(-c6cccc7ccccc67)c6ccccc56)c34)ccc2c1]

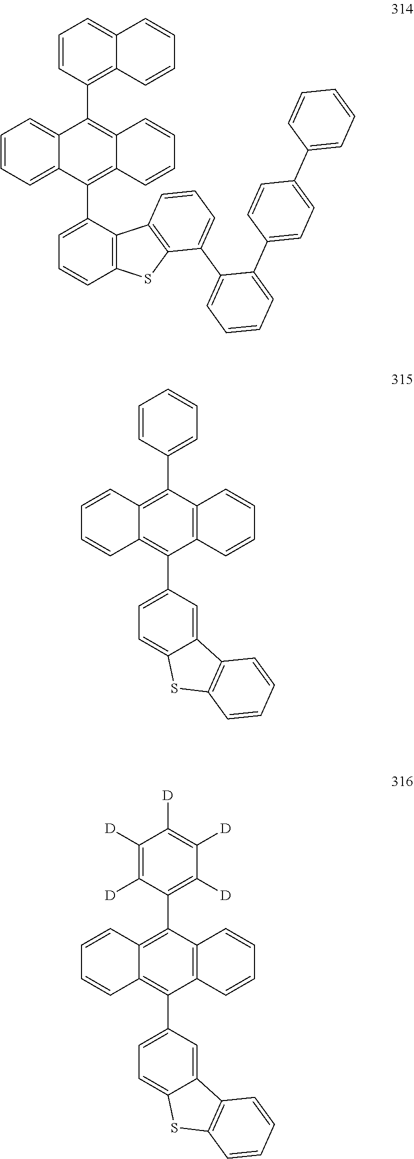 [SMILES: c1ccc(-c2ccc(-c3ccccc3-c3cccc4c3sc3cccc(-c5c6ccccc6c(-c6cccc7ccccc67)c6ccccc56)c34)cc2)cc1 ; c1ccc(-c2c3ccccc3c(-c3ccc4sc5ccccc5c4c3)c3ccccc23)cc1 ; [2H]c1c([2H])c([2H])c(-c2c3ccccc3c(-c3ccc4sc5ccccc5c4c3)c3ccccc23)c([2H])c1[2H]]

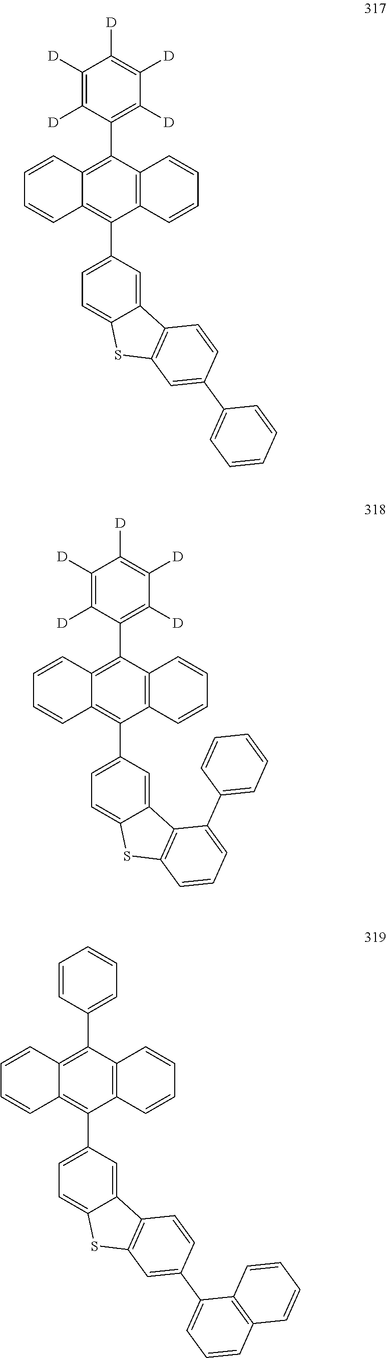 [SMILES: [2H]c1c([2H])c([2H])c(-c2c3ccccc3c(-c3ccc4sc5cc(-c6ccccc6)ccc5c4c3)c3ccccc23)c([2H])c1[2H] ; [2H]c1c([2H])c([2H])c(-c2c3ccccc3c(-c3ccc4sc5cccc(-c6ccccc6)c5c4c3)c3ccccc23)c([2H])c1[2H] ; c1ccc(-c2c3ccccc3c(-c3ccc4sc5cc(-c6cccc7ccccc67)ccc5c4c3)c3ccccc23)cc1]

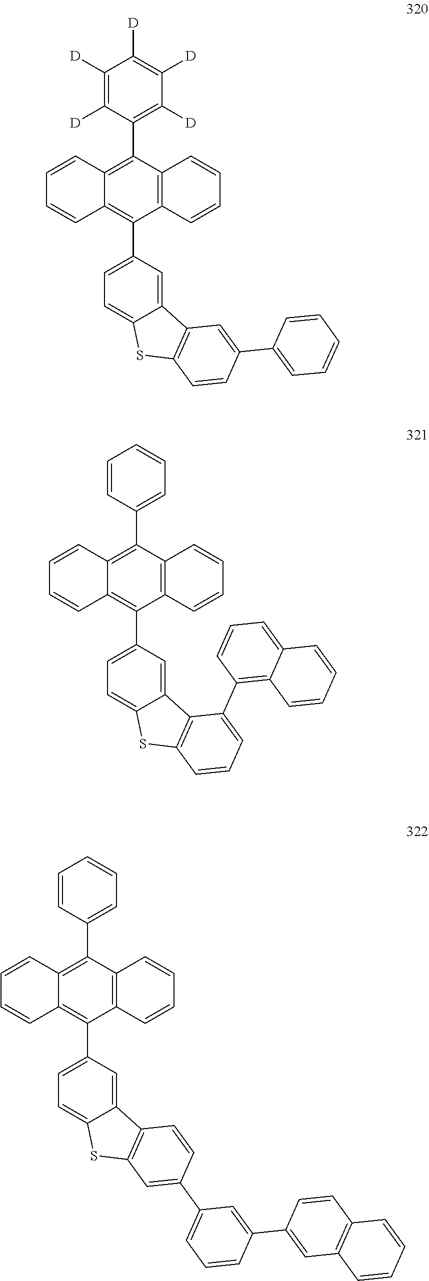 [SMILES: [2H]c1c([2H])c([2H])c(-c2c3ccccc3c(-c3ccc4sc5ccc(-c6ccccc6)cc5c4c3)c3ccccc23)c([2H])c1[2H] ; c1ccc(-c2c3ccccc3c(-c3ccc4sc5cccc(-c6cccc7ccccc67)c5c4c3)c3ccccc23)cc1 ; c1ccc(-c2c3ccccc3c(-c3ccc4sc5cc(-c6cccc(-c7ccc8ccccc8c7)c6)ccc5c4c3)c3ccccc23)cc1]

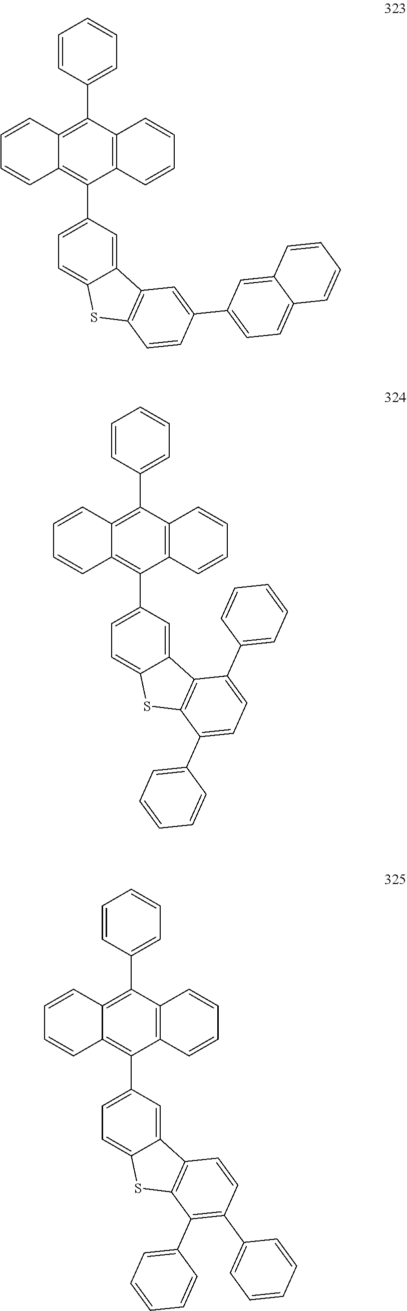 [SMILES: c1ccc(-c2c3ccccc3c(-c3ccc4sc5ccc(-c6ccc7ccccc7c6)cc5c4c3)c3ccccc23)cc1 ; c1ccc(-c2c3ccccc3c(-c3ccc4sc5c(-c6ccccc6)ccc(-c6ccccc6)c5c4c3)c3ccccc23)cc1 ; c1ccc(-c2ccc3c(sc4ccc(-c5c6ccccc6c(-c6ccccc6)c6ccccc56)cc43)c2-c2ccccc2)cc1]

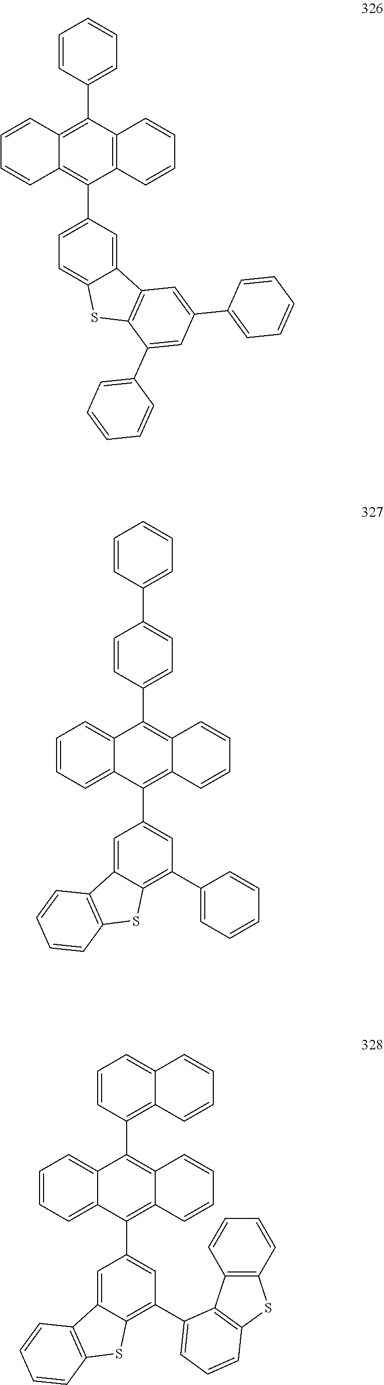 [SMILES: c1ccc(-c2cc(-c3ccccc3)c3sc4ccc(-c5c6ccccc6c(-c6ccccc6)c6ccccc56)cc4c3c2)cc1 ; c1ccc(-c2ccc(-c3c4ccccc4c(-c4cc(-c5ccccc5)c5sc6ccccc6c5c4)c4ccccc34)cc2)cc1 ; c1ccc2c(-c3c4ccccc4c(-c4cc(-c5cccc6sc7ccccc7c56)c5sc6ccccc6c5c4)c4ccccc34)cccc2c1]

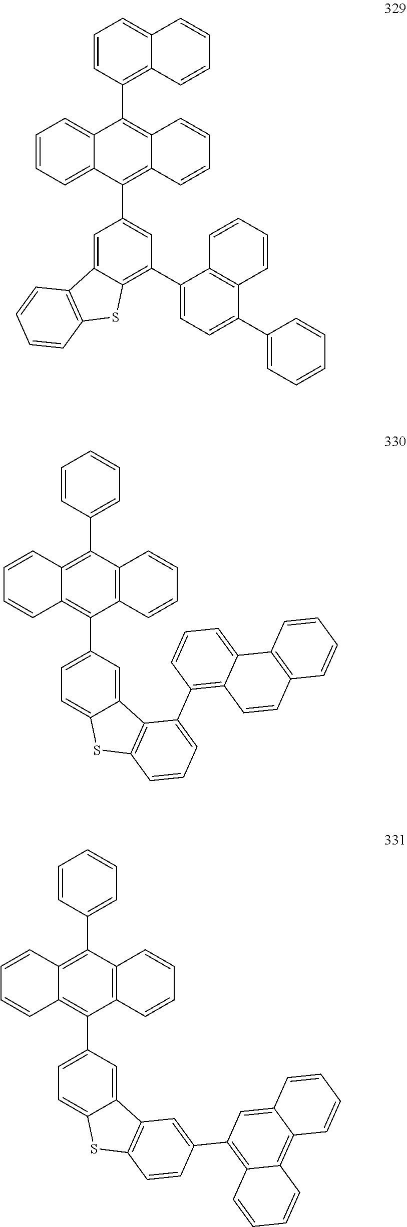 [SMILES: c1ccc(-c2ccc(-c3cc(-c4c5ccccc5c(-c5cccc6ccccc56)c5ccccc45)cc4c3sc3ccccc34)c3ccccc23)cc1 ; c1ccc(-c2c3ccccc3c(-c3ccc4sc5cccc(-c6cccc7c6ccc6ccccc67)c5c4c3)c3ccccc23)cc1 ; c1ccc(-c2c3ccccc3c(-c3ccc4sc5ccc(-c6cc7ccccc7c7ccccc67)cc5c4c3)c3ccccc23)cc1]

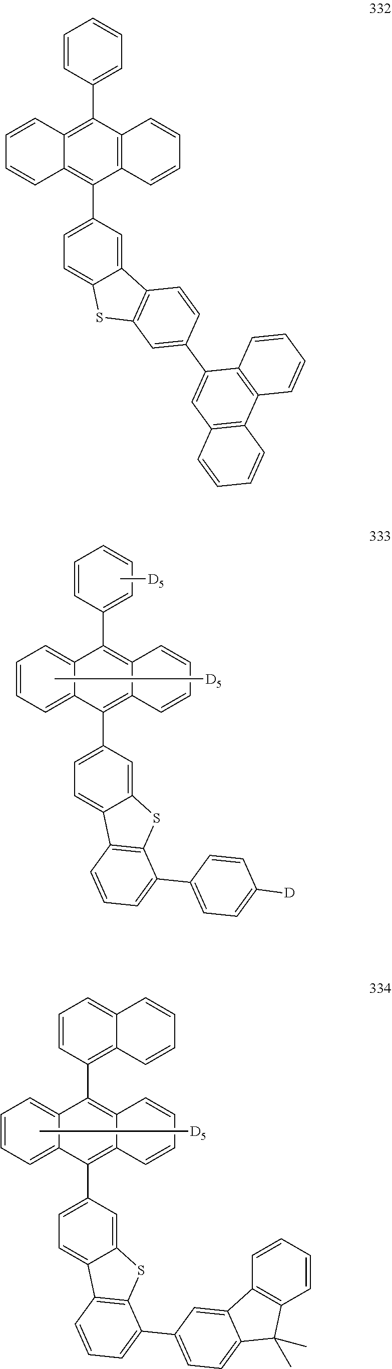

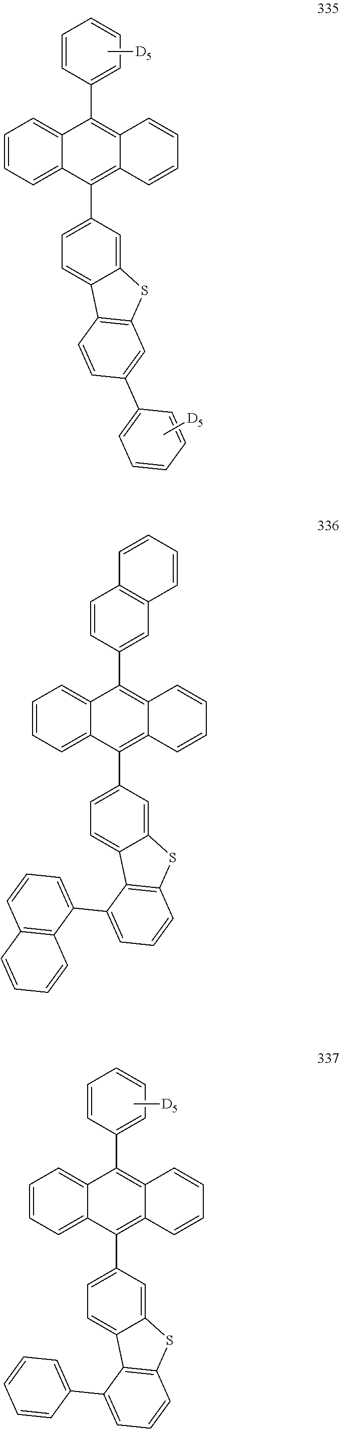

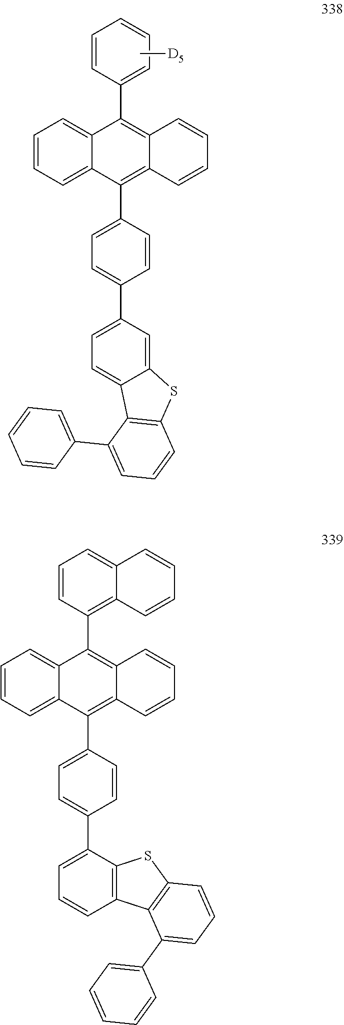

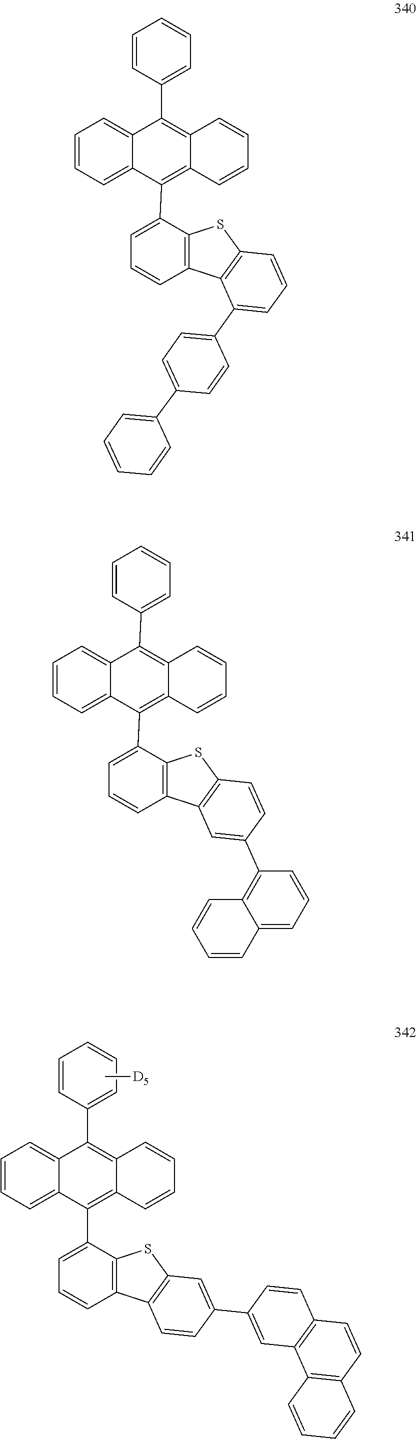

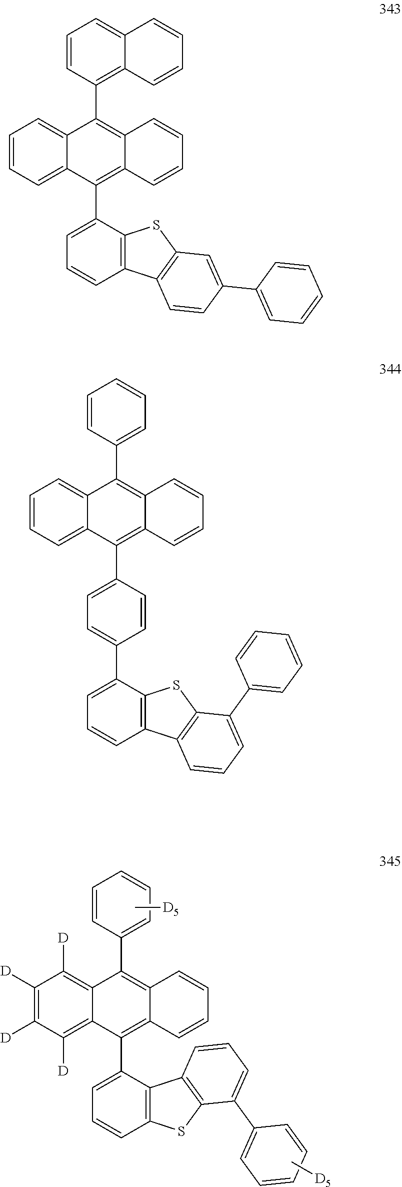

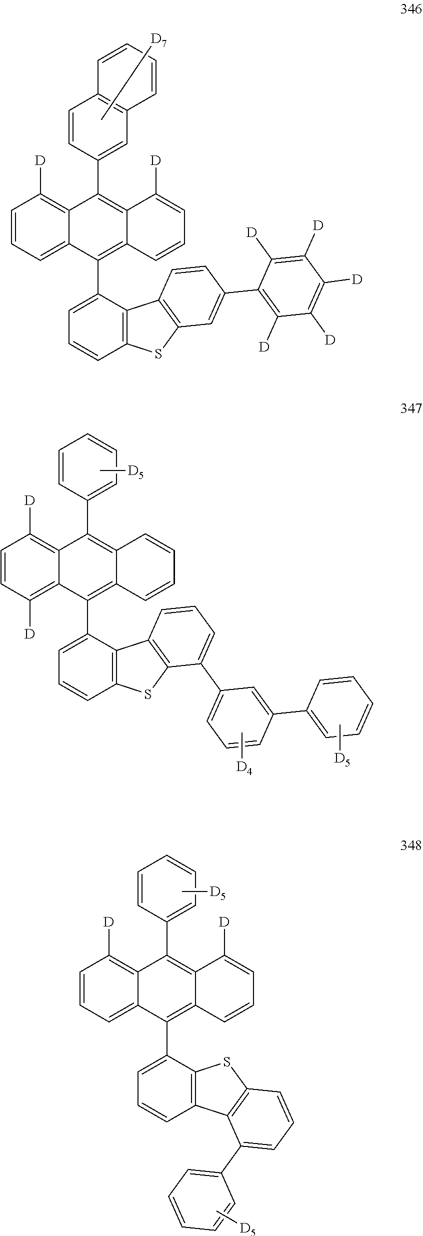

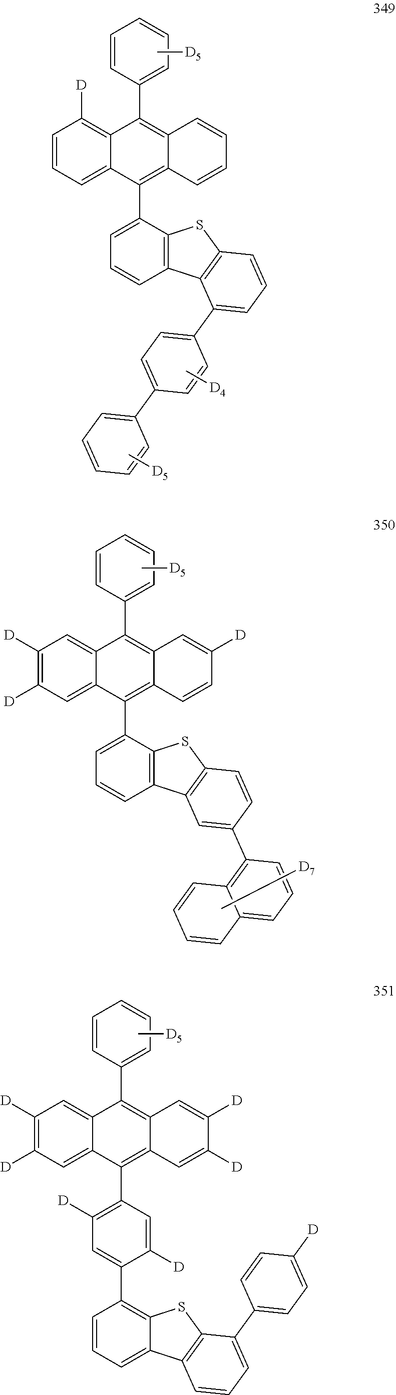

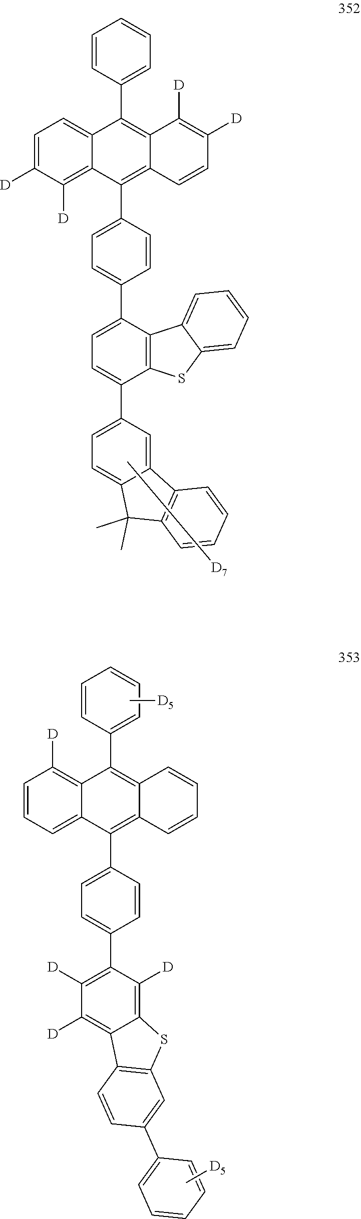

8. The organic electroluminescent device according to claim 1, wherein the light emitting layer comprises the compound represented by A-1 or A-2 as a dopant and the compound represented by B as a host.

9. The organic electroluminescent device according to claim 8, further comprising at least one layer selected from a hole injecting layer, a hole transport layer, a functional layer having functions of both hole injection and hole transport, an electron transport layer, and an electron injecting layer.

10. The organic electroluminescent device according to claim 9, wherein the additional layer is formed by a deposition or solution process.

11. The organic electroluminescent device according to claim 1, wherein the organic electroluminescent device is used in a display or lighting system selected from flat panel displays, flexible displays, monochromatic flat panel lighting systems, white flat panel lighting systems, flexible monochromatic lighting systems, and flexible white lighting systems.
